(19) United States
(12) Patent Application Publication
(10) Pub. No.: US 2025/0221308 A1
(43) Pub. Date: Jul. 3, 2025

(54) HETEROCYCLIC COMPOUND AND ORGANIC LIGHT-EMITTING DEVICE AND ELECTRONIC APPARATUS INCLUDING THE SAME

(71) Applicant: Samsung Electronics Co., Ltd., Suwon-si (KR)

(72) Inventors: Eunkyung Lee, Suwon-si (KR); Yusuke Maruyama, Suwon-si (KR); Sangmo Kim, Suwon-si (KR); Halim Lee, Suwon-si (KR); Soonok Jeon, Suwon-si (KR); Jiwhan Kim, Suwon-si (KR); Joonghee Won, Suwon-si (KR); Hosuk Kang, Suwon-si (KR); Jong Soo Kim, Suwon-si (KR); Sungho Nam, Suwon-si (KR); Yeonkyung Lee, Suwon-si (KR)

(21) Appl. No.: 19/005,056

(22) Filed: Dec. 30, 2024

(30) Foreign Application Priority Data
Jan. 3, 2024 (KR) 10-2024-0000967
Oct. 30, 2024 (KR) 10-2024-0151489

(51) Int. Cl. H10K 85/60; C07F 5/02; C09K 11/02; C09K 11/06; H10K 50/12

(52) U.S. Cl. CPC H10K 85/658; C07F 5/027; C09K 11/02; C09K 11/06; H10K 85/6572; C07B 2200/05; C09K 2211/1007; C09K 2211/1018; H10K 50/121

(57) ABSTRACT

A heterocyclic compound represented by Formula 1:

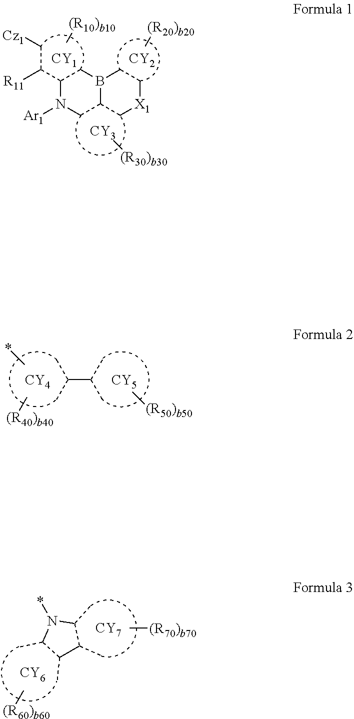

wherein Ar₁ and Ar₂ are each independently a group represented by Formula 2, a substituted or unsubstituted C₆-C₆₀ aryl group, a substituted or unsubstituted C₁-C₆₀ heteroaryl group, a substituted or unsubstituted C₂-C₆₀ alkyl heteroaryl group, a substituted or unsubstituted monovalent non-aromatic condensed polycyclic group, or a substituted or unsubstituted monovalent non-aromatic condensed heteropolycyclic group; ring CY₁ to ring CY₇ are each independently a C₅-C₃₀ carbocyclic group or a C₁-C₃₀ heterocyclic group; Cz₁ is a group represented by Formula 3; and descriptions of the remaining substituents are as provided herein.

### CROSS-REFERENCES TO RELATED APPLICATION

This application claims priority to and the benefit of Korean Patent Application Nos. 10-2024-0000967, filed on Jan. 3, 2024, and 10-2024-0151489, filed on Oct. 30, 2024, in the Korean Intellectual Property Office, and all the benefits accruing therefrom under 35 U.S.C. § 119, the contents of which are incorporated by reference herein in their entireties.

### BACKGROUND

### 1. Field

The subject matter relates to a heterocyclic compound and an organic light-emitting device and an electronic apparatus that include the same.

### 2. Description of the Related Art

Organic light-emitting devices (OLEDs) are self-emissive devices that have excellent characteristics in terms of viewing angles, response time, brightness, driving voltage, response speed, and the like. OLEDs can also produce full-color images.

In an example, an organic light-emitting device includes an anode, a cathode, and an organic layer that is arranged between the anode and the cathode and includes an emission layer. A hole transport region may be arranged between the anode and the emission layer, and an electron transport region may be arranged between the emission layer and the cathode. Holes provided from the first electrode move toward the emission layer through the hole transport region, and electrons provided from the second electrode move toward the emission layer through the electron transport region. The holes and the electrons recombine in the emission layer to produce excitons. The excitons may transition from an excited state to a ground state, thereby generating light.

### SUMMARY

Provided are a heterocyclic compound and an organic light-emitting device and an electronic apparatus that include the same.

Additional aspects will be set forth in part in the detailed description that follows and, in part, will be apparent from the detailed description, or may be learned by practice of the presented embodiments of the disclosure.

According to an aspect, there is provided a heterocyclic compound represented by Formula 1:

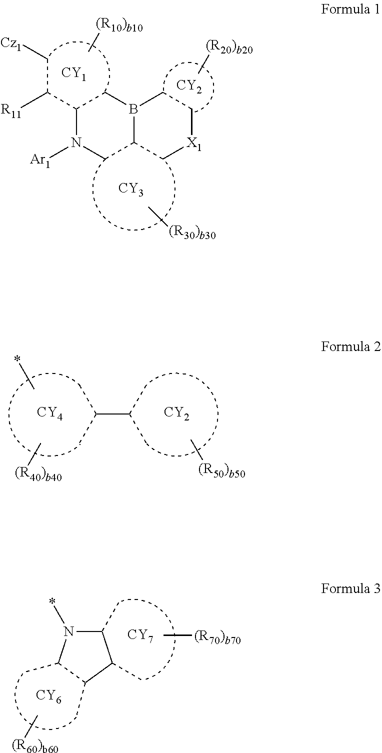

wherein, in Formulae 1, 2, and 3,
X₁ is a single bond, O, S, Se, N(Ar₂), N(R₁), C(R₁)(R₂), Si(R₁)(R₂), Ge(R₁)(R₂), B(R₁), P(R₁), P(═O)(R₁), S(═O)₂, or C(═O), and
Ar₁ and Ar₂ are each independently a group represented by Formula 2, a substituted or unsubstituted C₆-C₆₀ aryl group, a substituted or unsubstituted C₁-C₆₀ heteroaryl group, a substituted or unsubstituted C₂-C₆₀ alkyl heteroaryl group, a substituted or unsubstituted monovalent non-aromatic condensed polycyclic group, or a substituted or unsubstituted monovalent non-aromatic condensed heteropolycyclic group,
ring CY₁ to CY₇ are each independently a C₅-C₃₀ carbocyclic group or a C₁-C₃₀ heterocyclic group,
Cz₁ is a group represented by Formula 3,
R₁₁ is a substituted or unsubstituted C₁-C₆₀ alkyl group, a substituted or unsubstituted C₃-C₁₀ cycloalkyl group, a substituted or unsubstituted C₆-C₆₀ aryl group, a substituted or unsubstituted C₁-C₆₀ heteroaryl group, a substituted or unsubstituted monovalent non-aromatic condensed polycyclic group, or a substituted or unsubstituted monovalent non-aromatic condensed heteropolycyclic group,
R₁, R₂, R₁₀, R₂₀, R₃₀, R₄₀, and R₅₀ are each independently a group represented by Formula 3, hydrogen, deuterium, —F, —Cl, —Br, —I, —SF₅, a hydroxyl group, a cyano group, a nitro group, an amidino group, a hydrazino group, a hydrazono group, a carboxylic acid group or a salt thereof, a sulfonic acid group or a salt thereof, a phosphoric acid group or a salt thereof, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₁-C₆₀ alkylthio group, a substituted or unsubstituted C₃-C₁₀ cycloalkyl group, a substituted or unsubstituted C₁-C₁₀ heterocycloalkyl group, a substituted or unsubstituted C₃-C₁₀ cycloalkenyl group, a substituted or unsubstituted C₁-C₁₀ heterocycloalkenyl group, a substituted or unsubstituted C₆-C₆₀ aryl group, a substituted or unsubstituted C₇-C₆₀ alkyl aryl group, a substituted or unsubstituted C₇-C₆₀ aryl alkyl group, a substituted or unsubstituted C₆-C₆₀ aryloxy group, a substituted or unsubstituted C₆-C₆₀ arylthio group, a substituted or unsubstituted C₁-C₆₀ heteroaryl group, a substituted or unsubstituted C₂-C₆₀ alkyl heteroaryl group, a substituted or unsubstituted C₂-C₆₀ heteroaryl alkyl group, a substituted or unsubstituted C₁-C₆₀ heteroaryloxy group, a substituted or unsubstituted C₁-C₆₀ heteroarylthio group, a substituted or unsubstituted monovalent non-aromatic condensed polycyclic group, a substituted or unsubstituted monovalent non-aromatic condensed heteropolycyclic group, —N(Q₁)(Q₂), —Si(Q₁)(Q₂)(Q₃), —Ge(Q₁)(Q₂)(Q₃), —C(═O)(Q₁), —S(═O)(Q₁), —S(═O)₂(Q₁), —B(Q₁)(Q₂), —P(Q₁)(Q₂), —P(═O)(Q₁)(Q₂), or —P(═S)(Q₁)(Q₂),
R₆₀ and R₇₀ are each independently hydrogen, deuterium, —F, —Cl, —Br, —I, —SF₅, a hydroxyl group, a cyano group, a nitro group, an amidino group, a hydrazino group, a hydrazono group, a carboxylic acid group or a salt thereof, a sulfonic acid group or a salt thereof, a phosphoric acid group or a salt thereof, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₁-C₆₀ alkylthio group, a substituted or unsubstituted C₃-C₁₀ cycloalkyl group, a substituted or unsubstituted C₁-C₁₀ heterocycloalkyl group, a substituted or unsubstituted C₃-C₁₀ cycloalkenyl group, a substituted or unsubstituted C₁-C₁₀ heterocycloalkenyl group, a substituted or unsubstituted C₆-C₆₀ aryl group, a substituted or unsubstituted C₇-C₆₀ alkylaryl group, a substituted or unsubstituted C₆-C₆₀ aryloxy group, a substituted or unsubstituted C₆-C₆₀ arylthio group, a substituted or unsubstituted C₁-C₆₀ heteroaryl group, a substituted or unsubstituted C₂-C₆₀ alkyl heteroaryl group, a substituted or unsubstituted C₂-C₆₀ heteroaryl alkyl group, a substituted or unsubstituted C₁-C₆₀ heteroaryloxy group, a substituted or unsubstituted C₁-C₆₀ heteroarylthio group, a substituted or unsubstituted monovalent non-aromatic condensed polycyclic group, a substituted or unsubstituted monovalent non-aromatic condensed heteropolycyclic group, —N(Q₁)(Q₂), —Si(Q₁)(Q₂)(Q₃), —Ge(Q₁)(Q₂)(Q₃), —C(═O)(Q₁), —S(═O)(Q₁), —S(═O)₂(Q₁), —B(Q₁)(Q₂), —P(Q₁)(Q₂), —P(═O)(Q₁)(Q₂), or —P(═S)(Q₁)(Q₂),
b10, b20, b30, b40, and b50 are each independently 1, 2, 3, 4, 5, 6, 7, 8, 9, 10, 11, 12, 13, or 14,
b60 and b70 may each independently be 1, 2, 3, 4, 5, 6, 7, or 8,
at least two neighboring groups among R₁, R₂, R₁₀, R₁₁, R₂₀, R₃₀, R₄₀, R₅₀, R₆₀, and R₇₀ are optionally bonded together to form a substituted or unsubstituted C₅-C₃₀ carbocyclic group or a substituted or unsubstituted C₁-C₃₀ heterocyclic group, substituents of the substituted C₅-C₃₀ carbocyclic group, the substituted C₁-C₃₀ heterocyclic group, the substituted C₁-C₆₀ alkyl group, the substituted C₂-C₆₀ alkenyl group, the substituted C₂-C₆₀ alkynyl group, the substituted C₁-C₆₀ alkoxy group, the substituted C₁-C₆₀ alkylthio group, the substituted C₃-C₁₀ cycloalkyl group, the substituted C₁-C₁₀ heterocycloalkyl group, the substituted C₃-C₁₀ cycloalkenyl group, the substituted C₁-C₁₀ heterocycloalkenyl group, the substituted C₆-C₆₀ aryl group, the substituted C₇-C₆₀ alkyl aryl group, the substituted C₇-C₆₀ aryl alkyl group, the substituted C₆-C₆₀ aryloxy group, the substituted C₆-C₆₀ arylthio group, the substituted C₁-C₆₀ heteroaryl group, the substituted C₂-C₆₀ alkyl heteroaryl group, the substituted C₂-C₆₀ heteroaryl alkyl group, the substituted C₁-C₆₀ heteroaryloxy group, the substituted C₁-C₆₀ heteroarylthio group, the substituted monovalent non-aromatic condensed polycyclic group, and the substituted monovalent non-aromatic condensed heteropolycyclic group are each independently:
deuterium, —F, —Cl, —Br, —I, —SF₅, —CDs, —CD₂H, —CDH₂, —CF₃, —CF₂H, —CFH₂, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₆₀ alkyl group, a C₂-C₆₀ alkenyl group, a C₂-C₆₀ alkynyl group, a C₁-C₆₀ alkoxy group, or a C₁-C₆₀ alkylthio group;
a C₁-C₆₀ alkyl group, a C₂-C₆₀ alkenyl group, a C₂-C₆₀ alkynyl group, a C₁-C₆₀ alkoxy group, or a C₁-C₆₀ alkylthio group, each substituted with deuterium, —F, —Cl, —Br, —I, —SF₅, —CD₃, —CD₂H, —CDH₂, —CF₃, —CF₂H, —CFH₂, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₇-C₆₀ alkyl aryl group, a C₆-C₆₀ aryloxy group, a C₆-C₆₀ arylthio group, a C₁-C₆₀ heteroaryl group, a C₂-C₆₀ alkyl heteroaryl group, a C₂-C₆₀ heteroaryl alkyl group, a C₁-C₆₀ heteroaryloxy group, a C₁-C₆₀ heteroarylthio group, a monovalent non-aromatic condensed polycyclic group, a monovalent non-aromatic condensed heteropolycyclic group, —N(Q₁₁)(Q₁₂), —Si(Q₁₁)(Q₁₂)(Q₁₃), —Ge(Q₁₁)(Q₁₂)(Q₁₃), —C(═O)(Q₁₁), —S(═O)(Q₁₁), —S(═O)₂(Q₁₁), —B(Q₁₁)(Q₁₂), —P(Q₁₁)(Q₁₂), —P(═O)(Q₁₁)(Q₁₂), —P(═S)(Q₁₁)(Q₁₂), or a combination thereof;
a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₇-C₆₀ alkyl aryl group, a C₆-C₆₀ aryloxy group, a C₆-C₆₀ arylthio group, a C₁-C₆₀ heteroaryl group, a C₂-C₆₀ alkyl heteroaryl group, a C₁-C₆₀ heteroaryloxy group, a C₁-C₆₀ heteroarylthio group, a monovalent non-aromatic condensed polycyclic group, or a monovalent non-aromatic condensed heteropolycyclic group, each unsubstituted or substituted with deuterium, —F, —Cl, —Br, —I, —SF₅, —CD₃, —CD₂H, —CDH₂, —CF₃, —CF₂H, —CFH₂, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₆₀ alkyl group, a C₂-C₆₀ alkenyl group, a C₂-C₆₀ alkynyl group, a C₁-C₆₀ alkoxy group, a C₁-C₆₀ alkylthio group, a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₇-C₆₀ alkyl aryl group, a C₇-C₆₀ aryl alkyl group, a C₆-C₆₀ aryloxy group, a C₆-C₆₀ arylthio group, a C₁-C₆₀ heteroaryl group, a C₂-C₆₀ alkyl heteroaryl group, a C₂-C₆₀ heteroaryl alkyl group, a C₁-C₆₀ heteroaryloxy group, a C₁-C₆₀ heteroarylthio group, a monovalent non-aromatic condensed polycyclic group, a monovalent non-aromatic condensed heteropolycyclic group, —N(Q₂₁)(Q₂₂), —Si(Q₂₁)(Q₂₂)(Q₂₃), —Ge(Q₂₁)(Q₂₂)(Q₂₃), —C(═O)(Q₂₁), —S(═O)(Q₂₁), —S(═O)₂(Q₂₁), —B(Q₂₁)(Q₂₂), —P(Q₂₁)(Q₂₂), —P(═O)(Q₂₁)(Q₂₂), —P(═S)(Q₂₁)(Q₂₂), or a combination thereof;
—N(Q₃₁)(Q₃₂), —Si(Q₃₁)(Q₃₂)(Q₃₃), —Ge(Q₃₁)(Q₃₂)(Q₃₃), —C(═O)(Q₃₁), —S(═O)(Q₃₁), —S(═O)₂(Q₃₁), —B(Q₃₁)(Q₃₂), —P(Q₃₁)(Q₃₂), —P(═O)(Q₃₁)(Q₃₂), or —P(Q₃₁)(Q₃₂); or
a combination thereof,
Q₁ to Q₃, Q₁₁ to Q₁₃, Q₂₁ to Q₂₃, and Q₃₁ to Q₃₃ are each independently hydrogen, deuterium, —F, —Cl, —Br, —I, —SF₅, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₁-C₆₀ alkylthio group, a substituted or unsubstituted C₃-C₁₀ cycloalkyl group, a substituted or unsubstituted C₁-C₁₀ heterocycloalkyl group, a substituted or unsubstituted C₃-C₁₀ cycloalkenyl group, a substituted or unsubstituted C₁-C₁₀ heterocycloalkenyl group, a substituted or unsubstituted C₆-C₆₀ aryl group, a substituted or unsubstituted C₇-C₆₀ alkyl aryl group, a substituted or unsubstituted C₇-C₆₀ aryl alkyl group, a substituted or unsubstituted C₆-C₆₀ aryloxy group, a substituted or unsubstituted C₆-C₆₀ arylthio group, a substituted or unsubstituted C₁-C₆₀ heteroaryl group, a substituted or unsubstituted C₂-C₆₀ alkyl heteroaryl group, a substituted or unsubstituted C₂-C₆₀ heteroaryl alkyl group, a substituted or unsubstituted C₁-C₆₀ heteroaryloxy group, a substituted or unsubstituted C₁-C₆₀ heteroarylthio group, a substituted or unsubstituted monovalent non-aromatic condensed polycyclic group, or a substituted or unsubstituted monovalent non-aromatic condensed heteropolycyclic group, and
* indicates a binding site to a neighboring atom.

According to another aspect, an organic light-emitting device includes at least one of the heterocyclic compounds.

According to another aspect, provided is an organic light-emitting device including a first electrode, a second electrode, and an organic layer arranged between the first electrode and the second electrode, wherein the organic layer comprises an emission layer, and wherein the organic layer further comprises at least one heterocyclic compound represented by Formula 1.

According to another aspect of the disclosure, an electronic apparatus includes at least one of the heterocyclic compounds represented by Formula 1.

According to another aspect, provided is an electronic apparatus that include the organic light-emitting device.

### BRIEF DESCRIPTION OF THE DRAWINGS

The above and other aspects, features, and advantages of certain embodiments will be more apparent from the following detailed description taken in conjunction with the accompanying drawings, in which:

FIG. 1 is a schematic cross-sectional view of an organic light-emitting device according to one or more embodiments; and

FIGS. 2 to 6 are each a schematic diagram showing energy transfer of organic light-emitting devices each according to one or more embodiments.

### DETAILED DESCRIPTION

Reference will now be made in further detail to embodiments, examples of which are illustrated in the accompanying drawings, wherein like reference numerals refer to like elements throughout the specification. In this regard, the present embodiments may have different forms and should not be construed as being limited to the descriptions set forth herein. Accordingly, the embodiments are merely described below, by referring to the figures, to explain aspects. As used herein, the term “and/or” includes any and all combinations of one or more of the associated listed items. Expressions such as “at least one of,” when preceding a list of elements, modify the entire list of elements and do not modify the individual elements of the list.

The terminology used herein is for the purpose of describing one or more exemplary embodiments only and is not intended to be limiting. As used herein, the singular forms “a,” “an,” and “the” are intended to include the plural forms as well, unless the context clearly indicates otherwise. The term “or” means “and/or.” It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

It will be understood that, although the terms first, second, third etc. may be used herein to describe various elements, components, regions, layers, and/or sections, these elements, components, regions, layers, and/or sections should not be limited by these terms. These terms are only used to distinguish one element, component, region, layer, or section from another element, component, region, layer, or section. Thus, a first element, component, region, layer, or section discussed below could be termed a second element, component, region, layer, or section without departing from the teachings of the present embodiments.

Exemplary embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

It will be understood that when an element is referred to as being “on” another element, it can be directly in contact with the other element or intervening elements may be present therebetween. In contrast, when an element is referred to as being “directly on” another element, there are no intervening elements present.

Unless otherwise defined, all terms (including technical and scientific terms) used herein have the same meaning as commonly understood by one of ordinary skill in the art to which this general inventive concept belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±30%, 20%, 10%, 5% of the stated value.

As used herein, an “energy level” (e.g., a highest occupied molecular orbital (HOMO) energy level or a triplet (T₁) energy level) is expressed as an absolute value from a vacuum level. In addition, when the energy level is referred to as being “deep,” “high,” or “large,” the energy level has a large absolute value based on “0 electron Volts (eV)” of the vacuum level, and when the energy level is referred to as being “shallow,” “low,” or “small,” the energy level has a small absolute value based on “0 eV” of the vacuum level.

An aspect provides a heterocyclic compound represented by Formula 1:

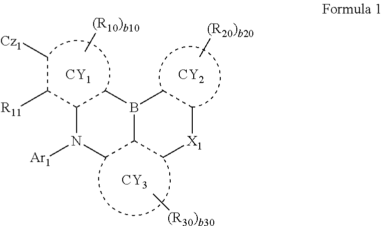

wherein, in Formula 1, X₁ is a single bond, O, S, Se, N(Ar₂), N(R₁), C(R₁)(R₂), Si(R₁)(R₂), Ge(R₁)(R₂), B(R₁), P(R₁), P(═O)(R₁), S(═O)₂, or C(═O).

In one or more embodiments, X₁ may be a single bond, O, S, Se, N(Ar₂), N(R₁), C(R₁)(R₂), or Si(R₁)(R₂).

In Formula 1, Ar₁ and Ar₂ are each independently a group represented by Formula 2, a substituted or unsubstituted C₆-C₆₀ aryl group, a substituted or unsubstituted C₁-C₆₀ heteroaryl group, a substituted or unsubstituted C₂-C₆₀ alkyl heteroaryl group, a substituted or unsubstituted monovalent non-aromatic condensed polycyclic group, or a substituted or unsubstituted monovalent non-aromatic condensed heteropolycyclic group:

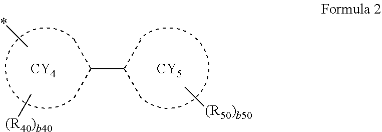

wherein, in Formulae 1 and 2, ring CY₁ to ring CY₅ may each independently be a C₅-C₃₀ carbocyclic group or a C₁-C₃₀ heterocyclic group.

In Formula 2, * indicates a binding site to a neighboring atom.

In Formula 1, Cz₁ is a group represented by Formula 3:

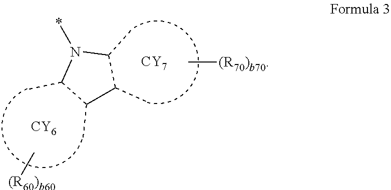

In Formula 3, ring CY₆ and ring CY₇ are each independently a C₅-C₃₀ carbocyclic group or a C₁-C₃₀ heterocyclic group.

Hence, in Formula 1, ring CY₁ to ring CY₇ are each independently a C₅-C₃₀ carbocyclic group or a C₁-C₃₀ heterocyclic group.

In one or more embodiments, ring CY₁ to ring CY₇ may each independently be i) a first ring, ii) a second ring, iii) a condensed ring group in which two or more first rings are condensed with each other, iv) a condensed ring group in which two or more second rings are condensed with each other, or v) a condensed ring group in which one or more first rings are condensed with one or more second rings,
wherein the first ring may be a cyclopentane group, a cyclopentadiene group, a furan group, a thiophene group, a pyrrole group, a silole group, an indene group, a benzofuran group, a benzothiophene group, an indole group, a benzosilole group, an oxazole group, an isoxazole group, an oxadiazole group, an isoxadiazole group, an oxatriazole group, an isoxatriazole group, a thiazole group, an isothiazole group, a thiadiazole group, an isothiadiazole group, a thiatriazole group, an isothiatriazole group, a pyrazole group, an imidazole group, a triazole group, a tetrazole group, an azasilole group, a diazasilole group, or a triazasilole group, and
the second ring may be an adamantane group, a norbornene group, a bicyclo[1.1.1]pentane group, a bicyclo[2.1.1]hexane group, a bicyclo[2.2.1]heptane group (i.e., a norbornane group), a bicyclo[2.2.2]octane group, a cyclohexane group, a cyclohexene group, a benzene group, a pyridine group, a pyrimidine group, a pyrazine group, a pyridazine group, or a triazine group.

In one or more embodiments, ring CY₁ to ring CY₇ may each independently be a C₆-C₆₀ aromatic carbocyclic group or a C₁-C₃₀ aromatic heterocyclic group.

In one or more embodiments, ring CY₁ to ring CY₇ may each independently be a benzene group, a naphthalene group, an anthracene group, a phenanthrene group, a triphenylene group, a pyrene group, a chrysene group, a 1,2,3,4-tetrahydronaphthalene group, a benzothiophene group, a benzofuran group, an indole group, an indene group, a benzosilole group, a benzoborole group, a benzophosphole group, a benzoselenophene group, a benzogermole group, a dibenzothiophene group, a dibenzofuran group, a carbazole group, a fluorene group, a dibenzosilole group, a dibenzoborole group, a dibenzophosphole group, a dibenzoselenophene group, a dibenzogermole group, a dibenzothiophene 5-oxide group, a 9H-fluoren-9-one group, a dibenzothiophene 5,5-dioxide group, an azabenzothiophene group, an azabenzofuran group, an azaindole group, an azaindene group, an azabenzosilole group, an azabenzoborole group, an azabenzophosphole group, an azabenzoselenophene group, an azabenzogermole group, an azadibenzothiophene group, an azadibenzofuran group, an azacarbazole group, an azafluorene group, an azadibenzosilole group, an azadibenzoborole group, an azadibenzophosphole group, an azadibenzoselenophene group, an azadibenzogermole group, an azadibenzothiophene 5-oxide group, an aza-9H-fluoren-9-one group, an azadibenzothiophene 5,5-dioxide group, a pyridine group, a pyrimidine group, a pyrazine group, a pyridazine group, a triazine group, a quinoline group, an isoquinoline group, a quinoxaline group, a quinazoline group, a phenanthroline group, a 5,6,7,8-tetrahydroisoquinoline group, a 5,6,7,8-tetrahydroquinoline group, an adamantane group, a norbornane group, or a norbornene group.

In one or more embodiments, ring CY₁ to ring CY₅ may each independently be a benzene group, a naphthalene group, a phenanthrene group, a fluorene group, a pyridine group, a pyrimidine group, a triazine group, a quinoline group, an isoquinoline group, a phthalazine group, a naphthyridine group, a quinoxaline group, a quinazoline group, a carbazole group, a dibenzofuran group, a dibenzothiophene group, a dibenzosilole group, a dibenzoborole group, a dibenzophosphole group, a dibenzoselenophene group, a dibenzogermole group, a dibenzothiophene 5-oxide group, a 9H-fluorene-9-one group, or a dibenzothiophene 5,5-dioxide group.

In one or more embodiments, ring CY₆ and ring CY₇ may each independently be a benzene group, a naphthalene group, a phenanthrene group, a pyridine group, a pyrimidine group, a quinoline group, an isoquinoline group, a phthalazine group, a naphthyridine group, a quinoxaline group, or a quinazoline group.

In one or more embodiments, a group represented by Formula 2 may be a group represented by one of Formulae 2-1 to 2-3:

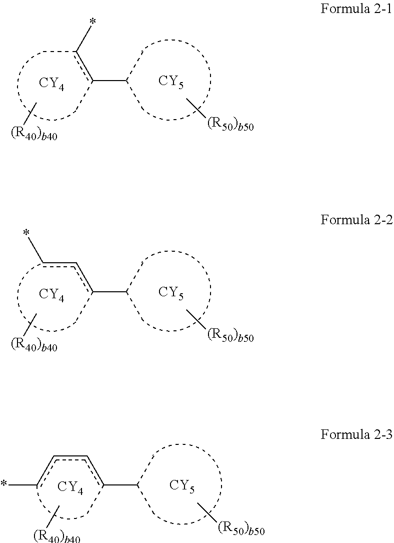

wherein, in Formulae 2-1 to 2-3,
ring CY₄, ring CY₅, R₄₀, R₅₁, b40, and b50 are each the same as described herein,
[symbol] indicates a single bond or a double bond, and
* indicates a binding site to a neighboring atom.

In one or more embodiments, a group represented by Formula 2 may be a group represented by one of Formulae 2A to 2C:

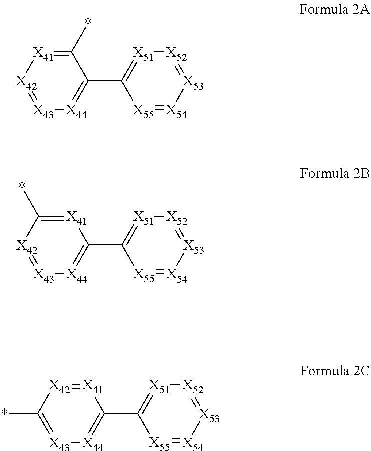

wherein, in Formulae 2A to 2C,
X₄₁ may be C(R₄₁) or N, X₄₂ may be C(R₄₂) or N, X₄₃ may be C(R₄₃) or N, and X₄₄ may be C(R₄₄) or N,
X₅₁ may be C(R₅₁) or N, X₅₂ may be C(R₅₂) or N, X₅₃ may be C(R₅₃) or N, X₅₄ may be C(R₅₄) or N, and X₅₅ may be C(R₅₅) or N,
R₄₁ to R₄₄ are each independently the same as described in the present specification,
R₅₁ to R₅₅ are each independently the same as described in the present specification, and
* indicates a binding site to a neighboring atom.

For example, in Formulae 2A to 2C, one of R₅₁ to R₅₅, preferably R₅₂ or R₅₄, may be a phenyl group, a biphenyl group, or a naphthyl group.

In one or more embodiments, a group represented by Formula 3 may be a group represented by Formula 3A:

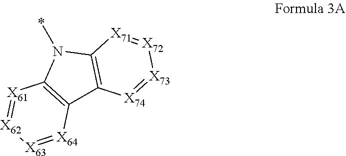

wherein, in Formula 3A,
X₆₁ may be C(R₆₁) or N, X₆₂ may be C(R₆₂) or N, X₆₃ may be C(R₆₃) or N, and X₆₄ may be C(R₆₄) or N,
X₇₁ may be C(R₇₁) or N, X₇₂ may be C(R₇₂) or N, X₇₃ may be C(R₇₃) or N, and X₇₄ may be C(R₇₄) or N,
R₆₁ to R₆₄ are each independently the same as described in connection with R₆₀,
R₇₁ to R₇₄ are each independently the same as described in connection with R₇₀, and
* indicates a binding site to a neighboring atom.

In Formula 1, R₁₁ is a substituted or unsubstituted C₁-C₆₀ alkyl group, a substituted or unsubstituted C₃-C₁₀ cycloalkyl group, a substituted or unsubstituted C₆-C₆₀ aryl group, a substituted or unsubstituted C₁-C₆₀ heteroaryl group, a substituted or unsubstituted monovalent non-aromatic condensed polycyclic group, or a substituted or unsubstituted monovalent non-aromatic condensed heteropolycyclic group.

In Formulae 1 and 2, R₁, R₂, R₁₀, R₂₀, R₃₀, R₄₀, and R₅₀ are each independently a group represented by Formula 3, hydrogen, deuterium, —F, —Cl, —Br, —I, —SF₅, a hydroxyl group, a cyano group, a nitro group, an amidino group, a hydrazino group, a hydrazono group, a carboxylic acid group or a salt thereof, a sulfonic acid group or a salt thereof, a phosphoric acid group or a salt thereof, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₁-C₆₀ alkylthio group, a substituted or unsubstituted C₃-C₁₀ cycloalkyl group, a substituted or unsubstituted C₁-C₁₀ heterocycloalkyl group, a substituted or unsubstituted C₃-C₁₀ cycloalkenyl group, a substituted or unsubstituted C₁-C₁₀ heterocycloalkenyl group, a substituted or unsubstituted C₆-C₆₀ aryl group, a substituted or unsubstituted C₇-C₆₀ alkyl aryl group, a substituted or unsubstituted C₇-C₆₀ aryl alkyl group, a substituted or unsubstituted C₆-C₆₀ aryloxy group, a substituted or unsubstituted C₆-C₆₀ arylthio group, a substituted or unsubstituted C₁-C₆₀ heteroaryl group, a substituted or unsubstituted C₂-C₆₀ alkyl heteroaryl group, a substituted or unsubstituted C₂-C₆₀ heteroaryl alkyl group, a substituted or unsubstituted C₁-C₆₀ heteroaryloxy group, a substituted or unsubstituted C₁-C₆₀ heteroarylthio group, a substituted or unsubstituted monovalent non-aromatic condensed polycyclic group, a substituted or unsubstituted monovalent non-aromatic condensed heteropolycyclic group, —N(Q₁)(Q₂), —Si(Q₁)(Q₂)(Q₃), —Ge(Q₁)(Q₂)(Q₃), —C(═O)(Q₁), —S(═O)(Q₁), —S(═O)₂(Q₁), —B(Q₁)(Q₂), —P(Q₁)(Q₂), —P(═O)(Q₁)(Q₂), or —P(═S)(Q₁)(Q₂).

In Formula 3, R₆₀ and R₇₀ are each independently hydrogen, deuterium, —F, —Cl, —Br, —I, —SF₅, a hydroxyl group, a cyano group, a nitro group, an amidino group, a hydrazino group, a hydrazono group, a carboxylic acid group or a salt thereof, a sulfonic acid group or a salt thereof, a phosphoric acid group or a salt thereof, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₁-C₆₀ alkylthio group, a substituted or unsubstituted C₃-C₁₀ cycloalkyl group, a substituted or unsubstituted C₁-C₁₀ heterocycloalkyl group, a substituted or unsubstituted C₃-C₁₀ cycloalkenyl group, a substituted or unsubstituted C₁-C₁₀ heterocycloalkenyl group, a substituted or unsubstituted C₆-C₆₀ aryl group, a substituted or unsubstituted C₇-C₆₀ alkyl aryl group, a substituted or unsubstituted C₇-C₆₀ aryl alkyl group, a substituted or unsubstituted C₆-C₆₀ aryloxy group, a substituted or unsubstituted C₆-C₆₀ arylthio group, a substituted or unsubstituted C₁-C₆₀ heteroaryl group, a substituted or unsubstituted C₂-C₆₀ alkyl heteroaryl group, a substituted or unsubstituted C₂-C₆₀ heteroaryl alkyl group, a substituted or unsubstituted C₁-C₆₀ heteroaryloxy group, a substituted or unsubstituted C₁-C₆₀ heteroarylthio group, a substituted or unsubstituted monovalent non-aromatic condensed polycyclic group, a substituted or unsubstituted monovalent non-aromatic condensed heteropolycyclic group, —N(Q₁)(Q₂), —Si(Q₁)(Q₂)(Q₃), —Ge(Q₁)(Q₂)(Q₃), —C(═O)(Q₁), —S(═O)(Q₁), —S(═O)₂(Q₁), —B(Q₁)(Q₂), —P(Q₁)(Q₂), —P(═O)(Q₁)(Q₂), or —P(═S)(Q₁)(Q₂).

In one or more embodiments, R₁, R₂, R₁₀, R₂₀, R₃₀, R₄₀, R₅₀, R₆₀, and R₇₀ may each independently be:
a C₁-C₂₀ alkyl group;
a C₁-C₂₀ alkyl group that is substituted with deuterium, —F, —Cl, —Br, —I, —SF₅, —CD₃, —CD₂H, —CDH₂, —CF₃, —CF₂H, —CFH₂, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₂₀ alkyl group, a deuterium-containing C₁-C₂₀ alkyl group, a fluorinated C₁-C₂₀ alkyl group, a cyclopentyl group, a cyclohexyl group, a cycloheptyl group, a cyclooctyl group, an adamantanyl group, a norbornenyl group, a cyclopentenyl group, a cyclohexenyl group, a cycloheptenyl group, a bicyclo[1.1.1]pentyl group, a bicyclo[2.1.1]hexyl group, a bicyclo[2.2.1]heptyl group (a norbornanyl group), a bicyclo[2.2.2]octyl group, a (C₁-C₂₀ alkyl)cyclopentyl group, a (C₁-C₂₀ alkyl)cyclohexyl group, a (C₁-C₂₀ alkyl)cycloheptyl group, a (C₁-C₂₀ alkyl)cyclooctyl group, a (C₁-C₂₀ alkyl)adamantanyl group, a (C₁-C₂₀ alkyl)norbornenyl group, a (C₁-C₂₀ alkyl)cyclopentenyl group, a (C₁-C₂₀ alkyl)cyclohexenyl group, a (C₁-C₂₀ alkyl)cycloheptenyl group, a (C₁-C₂₀ alkyl)bicyclo[1.1.1]pentyl group, a (C₁-C₂₀ alkyl)bicyclo[2.1.1]hexyl group, a (C₁-C₂₀ alkyl)bicyclo[2.2.1]heptyl group, a (C₁-C₂₀ alkyl)bicyclo[2.2.2]octyl group, silolanyl group(silolanyl), phenyl group, (C₁-C₂₀ alkyl)phenyl group, a biphenyl group, a terphenyl group, a naphthyl group, a 1,2,3,4-tetrahydronaphthyl group, a pyridinyl group, a pyrimidinyl group, or a combination thereof; or
a cyclopentyl group, a cyclohexyl group, a cycloheptyl group, a cyclooctyl group, an adamantanyl group, a norbornenyl group, a cyclopentenyl group, a cyclohexenyl group, a cycloheptenyl group, a bicyclo[1.1.1]pentyl group, a bicyclo[2.1.1]hexyl group, a bicyclo[2.2.1]heptyl group, a bicyclo[2.2.2]octyl group, a silolanyl group, a phenyl group, a (C₁-C₂₀ alkyl)phenyl group, a biphenyl group, a terphenyl group, a naphthyl group, a 1,2,3,4-tetrahydronaphthyl group, a fluorenyl group, a phenanthrenyl group, an anthracenyl group, a fluoranthenyl group, a triphenylenyl group, a pyrenyl group, a chrysenyl group, a pyrrolyl group, a thiophenyl group, a furanyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a quinoxalinyl group, a quinazolinyl group, a cinnolinyl group, a carbazolyl group, a phenanthrolinyl group, a benzoimidazolyl group, a benzofuranyl group, a benzothiophenyl group, an isobenzothiazolyl group, a benzoxazolyl group, an isobenzoxazolyl group, a triazolyl group, a tetrazolyl group, an oxadiazolyl group, a triazinyl group, a dibenzofuranyl group, a dibenzothiophenyl group, a benzocarbazolyl group, a dibenzocarbazolyl group, an imidazopyridinyl group, an imidazopyrimidinyl group, an azacarbazolyl group, an azadibenzofuranyl group, or an azadibenzothiophenyl group, each unsubstituted or substituted with deuterium, —F, —Cl, —Br, —I, —SF₅, —CD₃, —CD₂H, —CDH₂, —CF₃, —CF₂H, —CFH₂, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₂₀ alkyl group, a deuterium-containing C₁-C₂₀ alkyl group, a fluorinated C₁-C₂₀ alkyl group, a C₁-C₂₀ alkoxy group, a C₁-C₂₀ alkylthio group, a cyclopentyl group, a cyclohexyl group, a cycloheptyl group, a cyclooctyl group, an adamantanyl group, a norbornenyl group, a cyclopentenyl group, a cyclohexenyl group, a cycloheptenyl group, a bicyclo[1.1.1]pentyl group, a bicyclo[2.1.1]hexyl group, a bicyclo[2.2.1]heptyl group, a bicyclo[2.2.2]octyl group, a (C₁-C₂₀ alkyl)cyclopentyl group, a (C₁-C₂₀ alkyl)cyclohexyl group, a (C₁-C₂₀ alkyl)cycloheptyl group, a (C₁-C₂₀ alkyl)cyclooctyl group, a (C₁-C₂₀ alkyl)adamantanyl group, a (C₁-C₂₀ alkyl)norbornenyl group, a (C₁-C₂₀ alkyl)cyclopentenyl group, a (C₁-C₂₀ alkyl)cyclohexenyl group, a (C₁-C₂₀ alkyl)cycloheptenyl group, a (C₁-C₂₀ alkyl)bicyclo[1.1.1]pentyl group, a (C₁-C₂₀ alkyl)bicyclo[2.1.1]hexyl group, a (C₁-C₂₀ alkyl)bicyclo[2.2.1]heptyl group, a (C₁-C₂₀ alkyl)bicyclo[2.2.2]octyl group, a silolanyl group, a phenyl group, a (C₁-C₂₀ alkyl)phenyl group, a biphenyl group, a terphenyl group, a naphthyl group, a 1,2,3,4-tetrahydronaphthyl group, a fluorenyl group, a phenanthrenyl group, an anthracenyl group, a fluoranthenyl group, a triphenylenyl group, a pyrenyl group, a chrysenyl group, a pyrrolyl group, a thiophenyl group, a furanyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a quinoxalinyl group, a quinazolinyl group, a cinnolinyl group, a carbazolyl group, a phenanthrolinyl group, a benzoimidazolyl group, a benzofuranyl group, a benzothiophenyl group, an isobenzothiazolyl group, a benzoxazolyl group, an isobenzoxazolyl group, a triazolyl group, a tetrazolyl group, an oxadiazolyl group, a triazinyl group, a dibenzofuranyl group, a dibenzothiophenyl group, a benzocarbazolyl group, a dibenzocarbazolyl group, an imidazopyridinyl group, an imidazopyrimidinyl group, an azacarbazolyl group, an azadibenzofuranyl group, an azadibenzothiophenyl group, or a combination thereof.

In one or more embodiments, R₁, R₂, R₁₀, R₂₀, R₃₀, R₄₀, R₅₀, R₆₀, and R₇₀ may each independently be:
hydrogen, deuterium, —F, —Cl, —Br, —I, —SF₅, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, —SF₅, a C₁-C₂₀ alkyl group, a C₁-C₂₀ alkoxy group, or a C₁-C₁₀ alkylthio group;
a C₁-C₂₀ alkyl group, a C₁-C₂₀ alkoxy group, or a C₁-C₂₀ alkylthio group, each substituted with deuterium, —F, —Cl, —Br, —I, —SF₅, —CD₃, —CD₂H, —CDH₂, —CF₃, —CF₂H, —CFH₂, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₂₀ alkyl group, a deuterium-containing C₁-C₂₀ alkyl group, a fluorinated C₁-C₂₀ alkyl group, a cyclopentyl group, a cyclohexyl group, a cycloheptyl group, a cyclooctyl group, an adamantanyl group, a norbornenyl group, a cyclopentenyl group, a cyclohexenyl group, a cycloheptenyl group, a bicyclo[1.1.1]pentyl group, a bicyclo[2.1.1]hexyl group, a bicyclo[2.2.1]heptyl group (a norbornanyl group), a bicyclo[2.2.2]octyl group, a (C₁-C₂₀ alkyl)cyclopentyl group, a (C₁-C₂₀ alkyl)cyclohexyl group, a (C₁-C₂₀ alkyl)cycloheptyl group, a (C₁-C₂₀ alkyl)cyclooctyl group, a (C₁-C₂₀ alkyl)adamantanyl group, a (C₁-C₂₀ alkyl)norbornenyl group, a (C₁-C₂₀ alkyl)cyclopentenyl group, a (C₁-C₂₀ alkyl)cyclohexenyl group, a (C₁-C₂₀ alkyl)cycloheptenyl group, a (C₁-C₂₀ alkyl)bicyclo[1.1.1]pentyl group, a (C₁-C₂₀ alkyl)bicyclo[2.1.1]hexyl group, a (C₁-C₂₀ alkyl)bicyclo[2.2.1]heptyl group, a (C₁-C₂₀ alkyl)bicyclo[2.2.2]octyl group, silolanyl group(silolanyl), phenyl group, (C₁-C₂₀ alkyl)phenyl group, a biphenyl group, a terphenyl group, a naphthyl group, a 1,2,3,4-tetrahydronaphthyl group, a pyridinyl group, a pyrimidinyl group, or a combination thereof; a cyclopentyl group, a cyclohexyl group, a cycloheptyl group, a cyclooctyl group, an adamantanyl group, a norbornenyl group, a cyclopentenyl group, a cyclohexenyl group, a cycloheptenyl group, a bicyclo[1.1.1]pentyl group, a bicyclo[2.1.1]hexyl group, a bicyclo[2.2.1]heptyl group, a bicyclo[2.2.2]octyl group, a silolanyl group, a phenyl group, a (C₁-C₂₀ alkyl)phenyl group, a biphenyl group, a terphenyl group, a naphthyl group, a 1,2,3,4-tetrahydronaphthyl group, a fluorenyl group, a phenanthrenyl group, an anthracenyl group, a fluoranthenyl group, a triphenylenyl group, a pyrenyl group, a chrysenyl group, a pyrrolyl group, a thiophenyl group, a furanyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a quinoxalinyl group, a quinazolinyl group, a cinnolinyl group, a carbazolyl group, a phenanthrolinyl group, a benzoimidazolyl group, a benzofuranyl group, a benzothiophenyl group, an isobenzothiazolyl group, a benzoxazolyl group, an isobenzoxazolyl group, a triazolyl group, a tetrazolyl group, an oxadiazolyl group, a triazinyl group, a dibenzofuranyl group, a dibenzothiophenyl group, a benzocarbazolyl group, a dibenzocarbazolyl group, an imidazopyridinyl group, an imidazopyrimidinyl group, an azacarbazolyl group, an azadibenzofuranyl group, or an azadibenzothiophenyl group, each unsubstituted or substituted with deuterium, —F, —Cl, —Br, —I, —SF₅, —CD₃, —CD₂H, —CDH₂, —CF₃, —CF₂H, —CFH₂, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₂₀ alkyl group, a deuterium-containing C₁-C₂₀ alkyl group, a fluorinated C₁-C₂₀ alkyl group, a C₁-C₂₀ alkoxy group, a C₁-C₂₀ alkylthio group, a cyclopentyl group, a cyclohexyl group, a cycloheptyl group, a cyclooctyl group, an adamantanyl group, a norbornenyl group, a cyclopentenyl group, a cyclohexenyl group, a cycloheptenyl group, a bicyclo[1.1.1]pentyl group, a bicyclo[2.1.1]hexyl group, a bicyclo[2.2.1]heptyl group, a bicyclo[2.2.2]octyl group, a (C₁-C₂₀ alkyl)cyclopentyl group, a (C₁-C₂₀ alkyl)cyclohexyl group, a (C₁-C₂₀ alkyl)cycloheptyl group, a (C₁-C₂₀ alkyl)cyclooctyl group, a (C₁-C₂₀ alkyl)adamantanyl group, a (C₁-C₂₀ alkyl)norbornenyl group, a (C₁-C₂₀ alkyl)cyclopentenyl group, a (C₁-C₂₀ alkyl)cyclohexenyl group, a (C₁-C₂₀ alkyl)cycloheptenyl group, a (C₁-C₂₀ alkyl)bicyclo[1.1.1]pentyl group, a (C₁-C₂₀ alkyl)bicyclo[2.1.1]hexyl group, a (C₁-C₂₀ alkyl)bicyclo[2.2.1]heptyl group, a (C₁-C₂₀ alkyl)bicyclo[2.2.2]octyl group, a silolanyl group, a phenyl group, a (C₁-C₂₀ alkyl)phenyl group, a biphenyl group, a terphenyl group, a naphthyl group, a 1,2,3,4-tetrahydronaphthyl group, a fluorenyl group, a phenanthrenyl group, an anthracenyl group, a fluoranthenyl group, a triphenylenyl group, a pyrenyl group, a chrysenyl group, a pyrrolyl group, a thiophenyl group, a furanyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a quinoxalinyl group, a quinazolinyl group, a cinnolinyl group, a carbazolyl group, a phenanthrolinyl group, a benzoimidazolyl group, a benzofuranyl group, a benzothiophenyl group, an isobenzothiazolyl group, a benzoxazolyl group, an isobenzoxazolyl group, a triazolyl group, a tetrazolyl group, an oxadiazolyl group, a triazinyl group, a dibenzofuranyl group, a dibenzothiophenyl group, a benzocarbazolyl group, a dibenzocarbazolyl group, an imidazopyridinyl group, an imidazopyrimidinyl group, an azacarbazolyl group, an azadibenzofuranyl group, an azadibenzothiophenyl group, or a combination thereof; or
—N(Q₁)(Q₂), —Si(Q₁)(Q₂)(Q₃), —Ge(Q₁)(Q₂)(Q₃), —C(═O)(Q₁), —S(═O)(Q₁), —S(═O)₂(Q₁), —B(Q₁)(Q₂), —P(Q₁)(Q₂), —P(═O)(Q₁)(Q₂), or —P(═S)(Q₁)(Q₂).

In one or more embodiments, R₁₁ may be a group represented by one of Formulae 9-1 to 9-61, 9-201 to 9-244, 10-1 to 10-154, or 10-201 to 10-350.

In one or more embodiments, R₁, R₂, R₁₀, R₂₀, R₃₀, R₄₀, R₅₀, R₆₀, and R₇₀ may each independently be:
hydrogen, deuterium, —F, —Cl, —Br, —I, —SF₅, —CD₃, —CD₂H, —CDH₂, —CF₃, —CF₂H, —CFH₂, a C₁-C₆₀ alkyl group, a C₂-C₆₀ alkenyl group, a C₂-C₆₀ alkynyl group, a C₁-C₆₀ alkoxy group, or a C₁-C₆₀ alkylthio group; or
a group represented by one of Formulae 9-1 to 9-61, 9-201 to 9-244, 10-1 to 10-154, or 10-201 to 10-350:

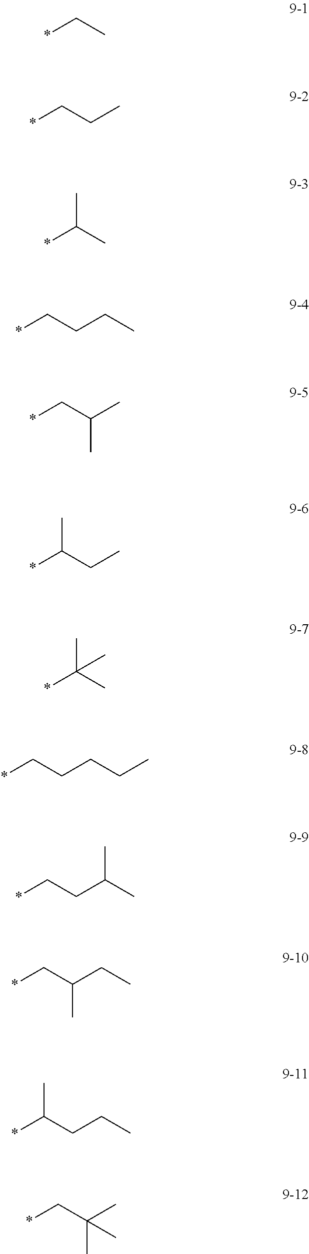

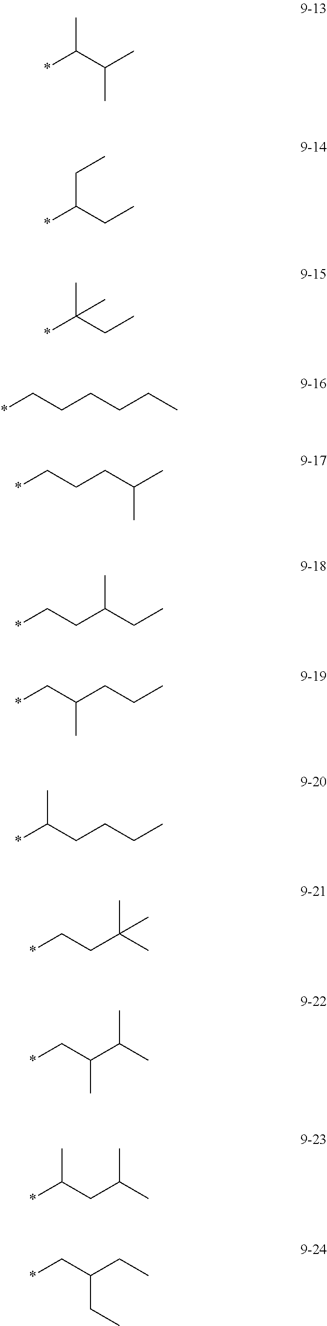

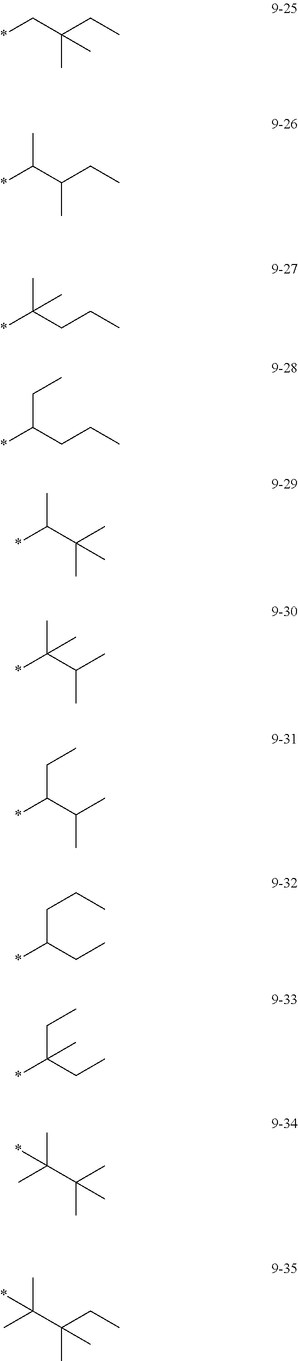

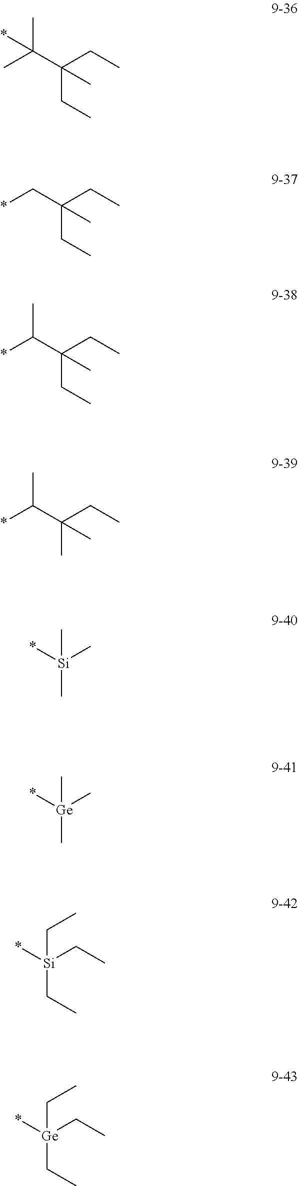

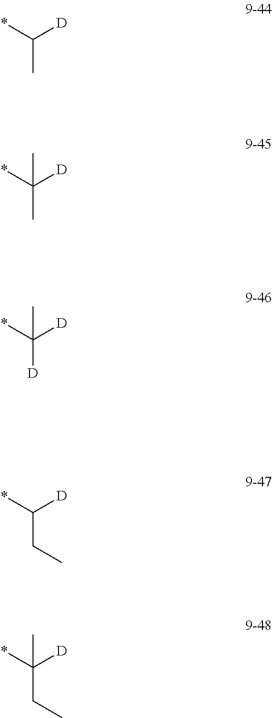

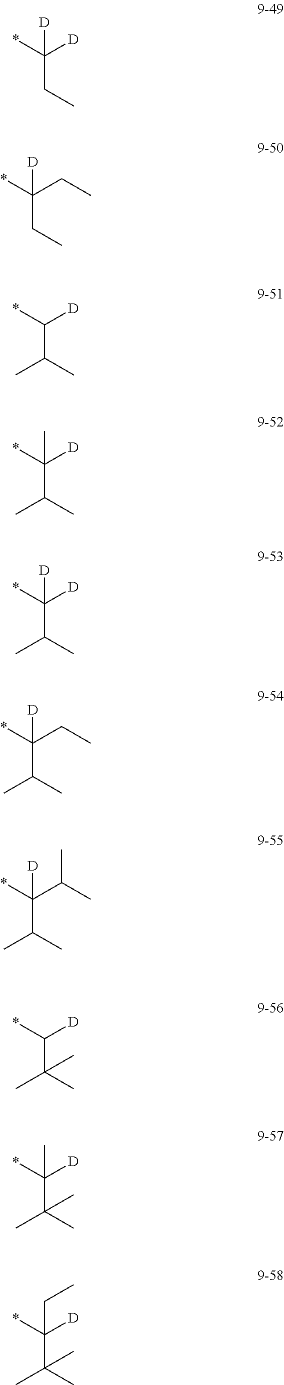

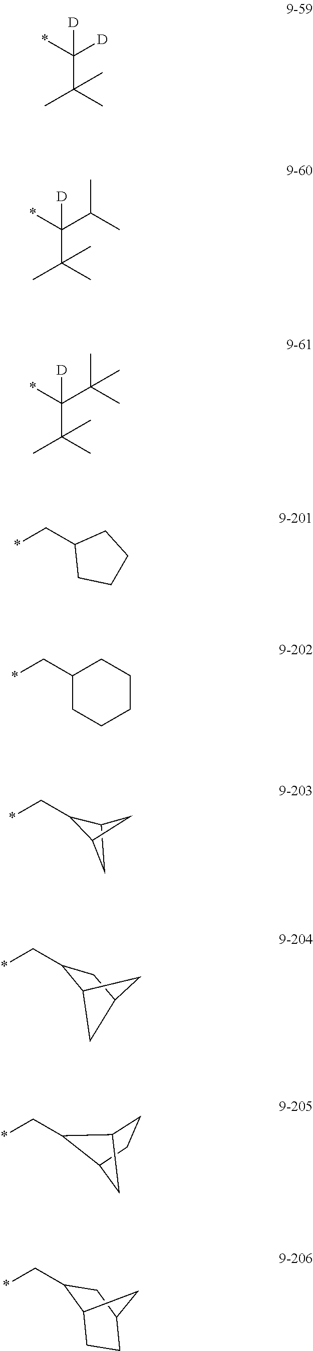

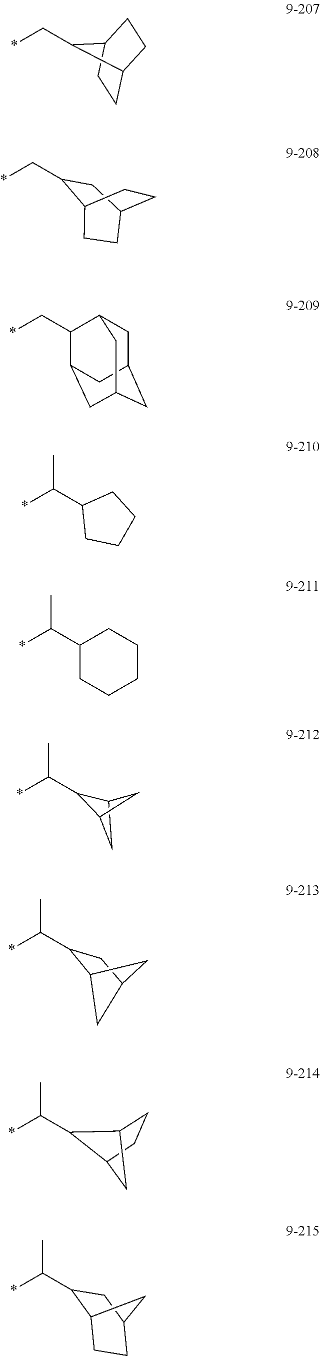

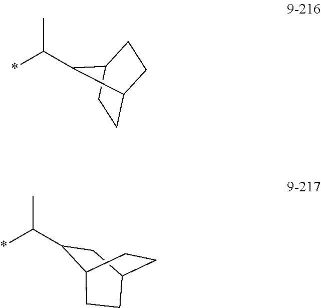

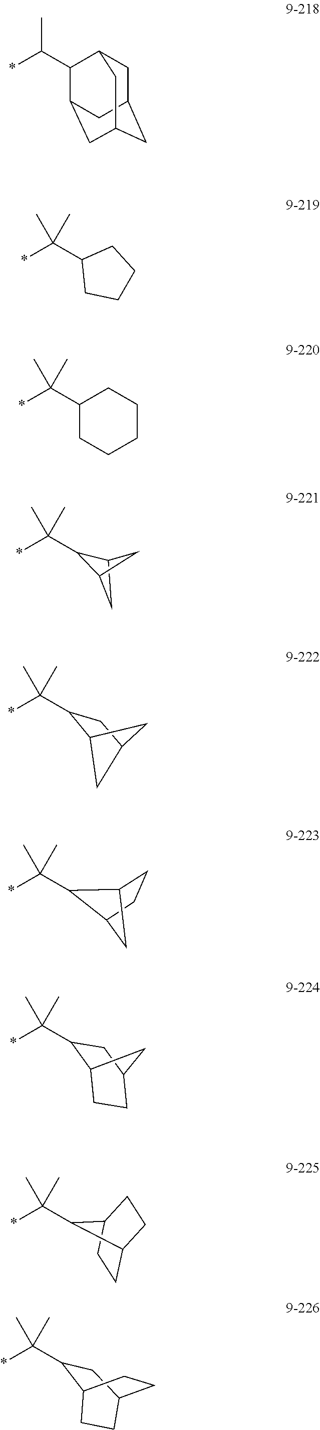

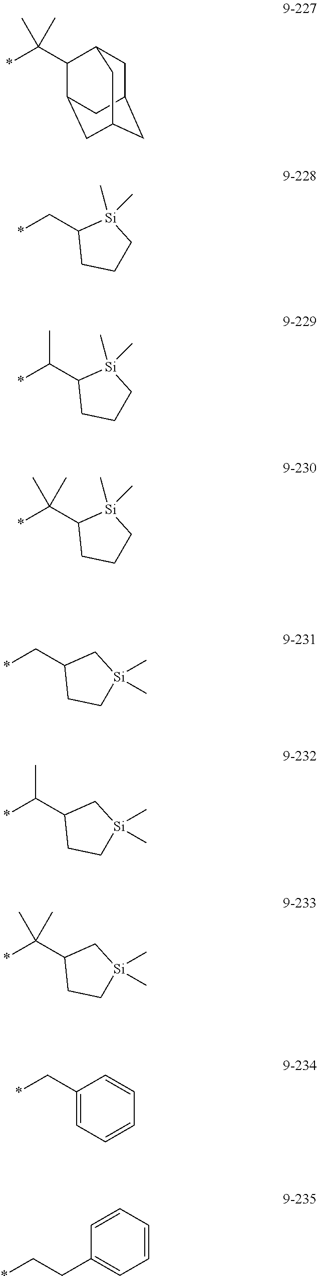

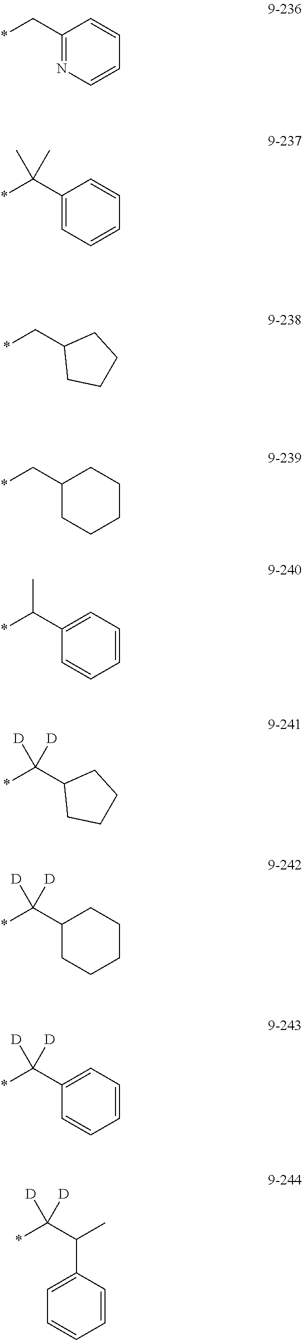

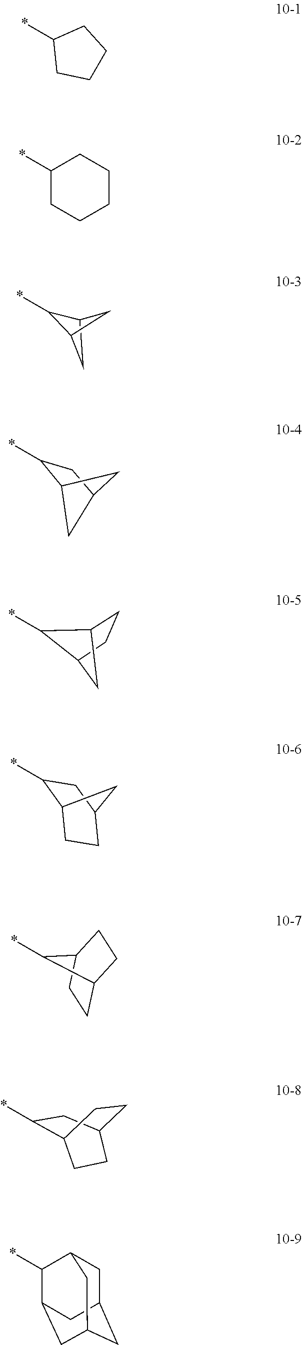

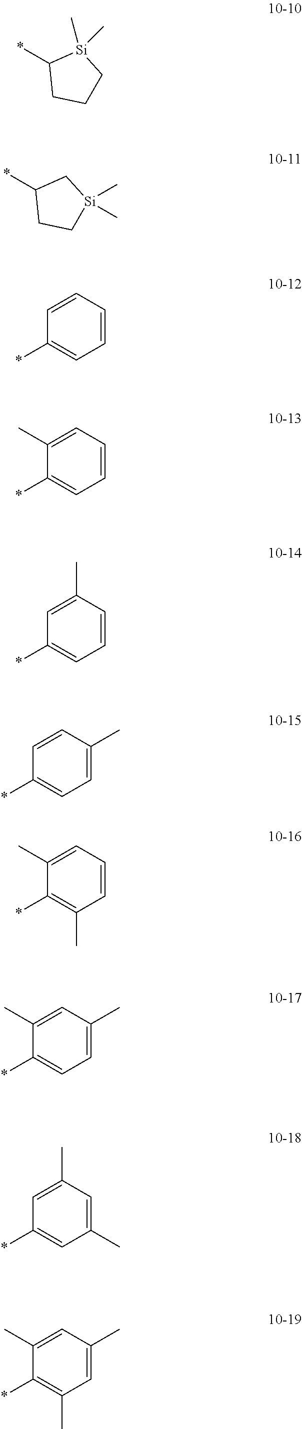

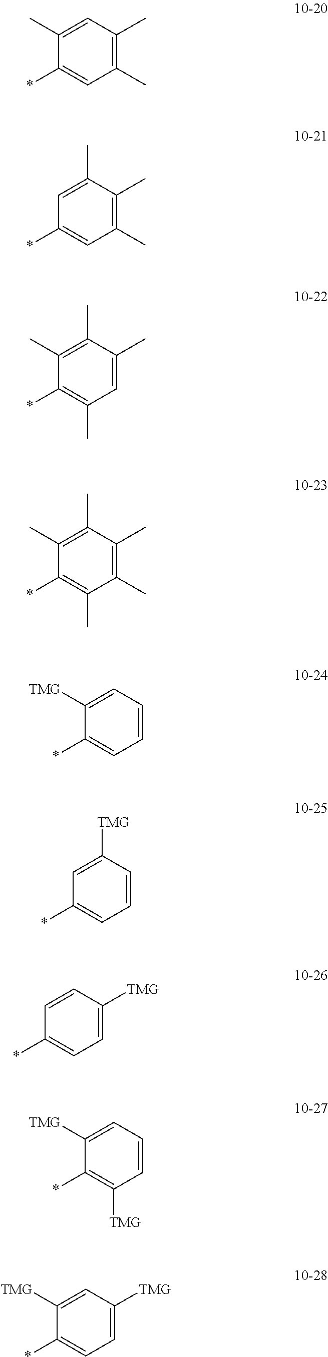

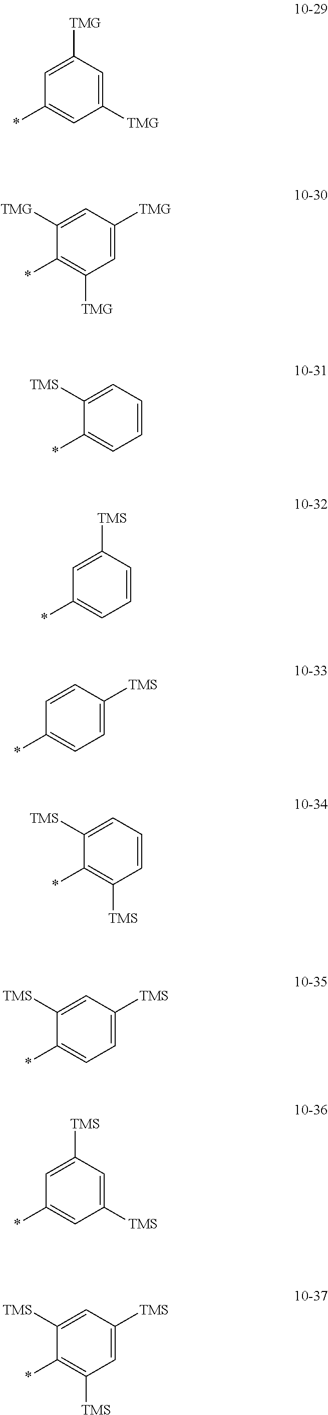

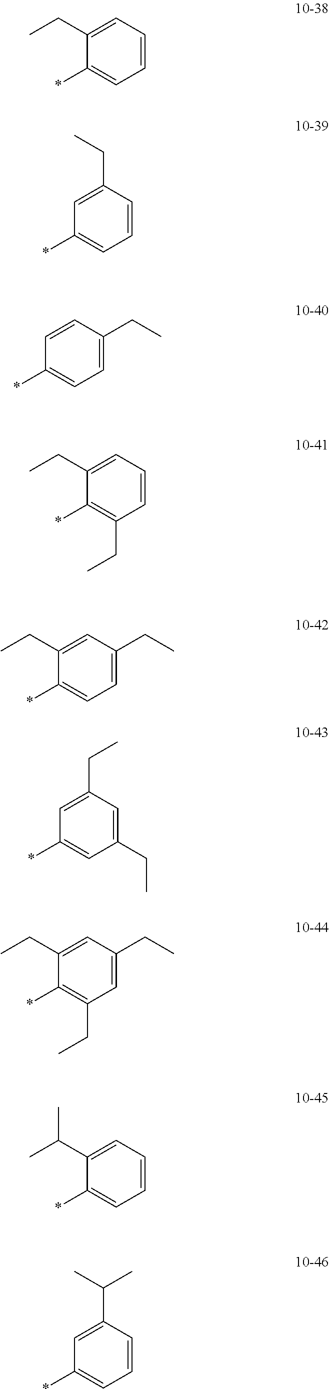

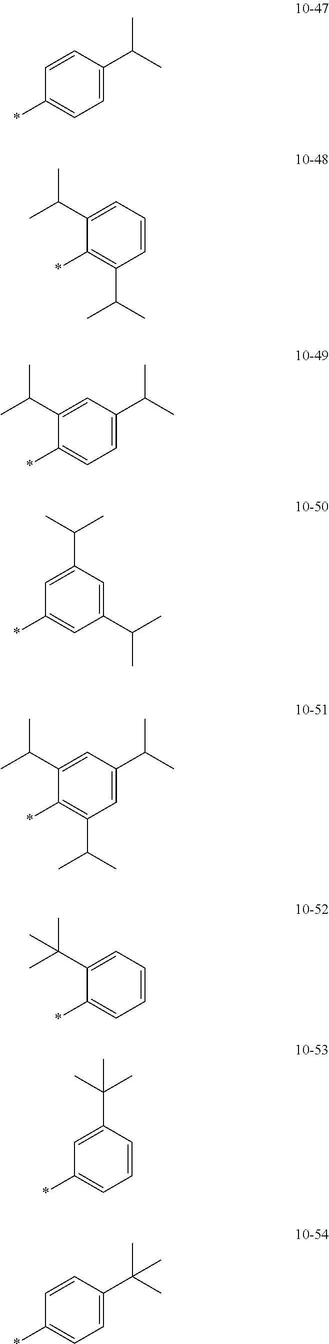

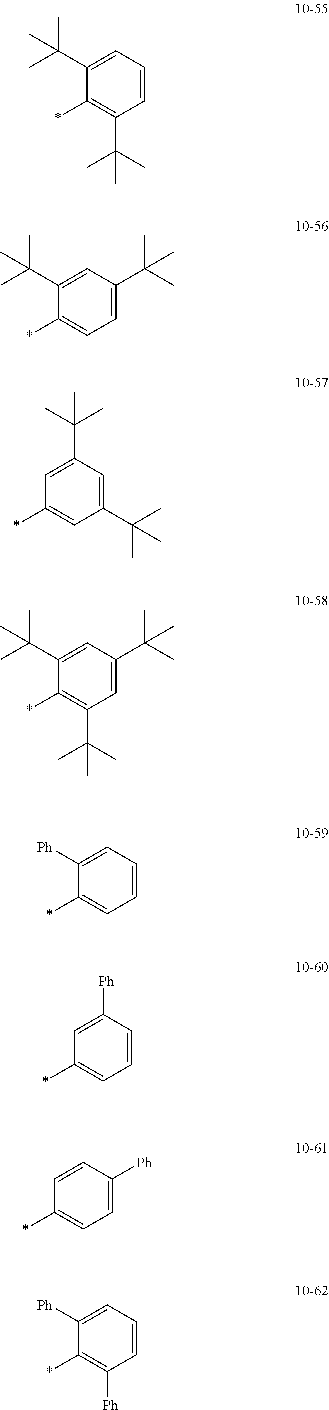

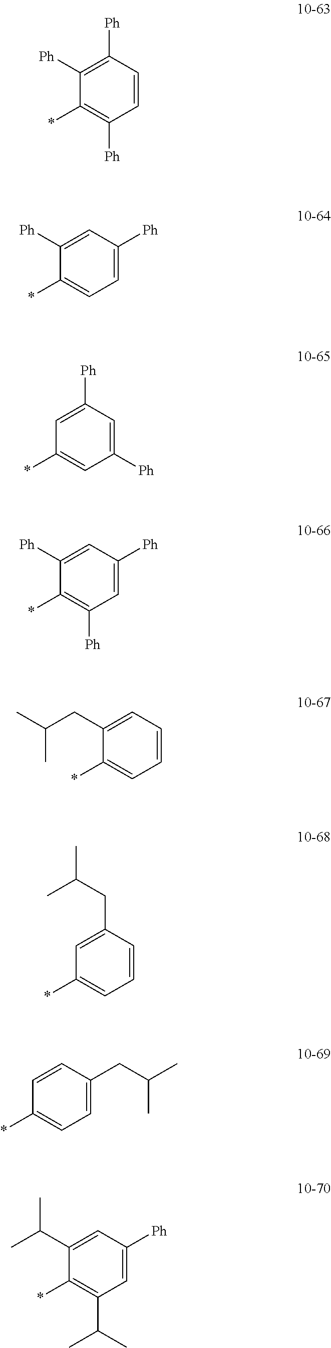

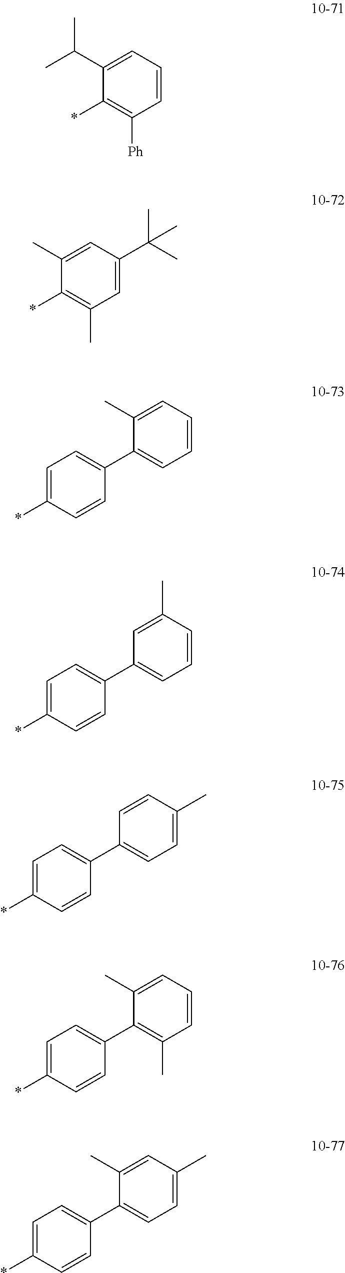

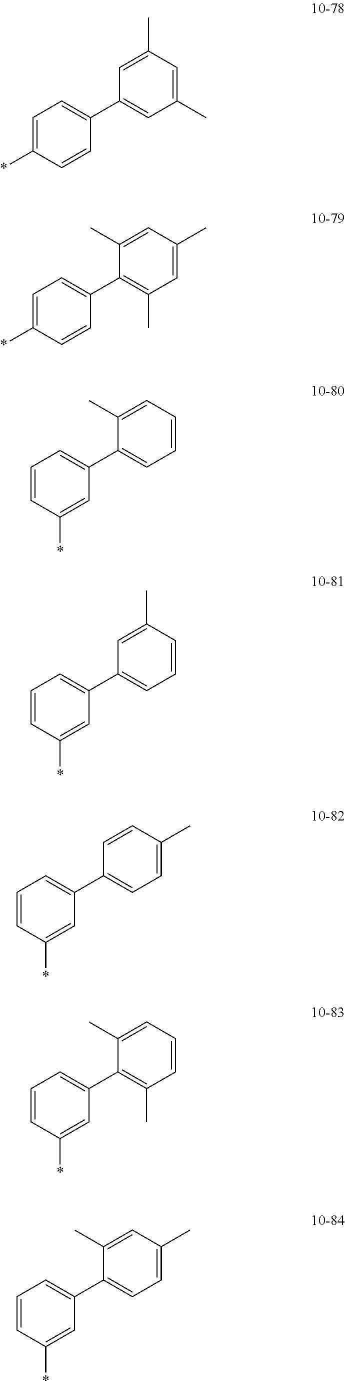

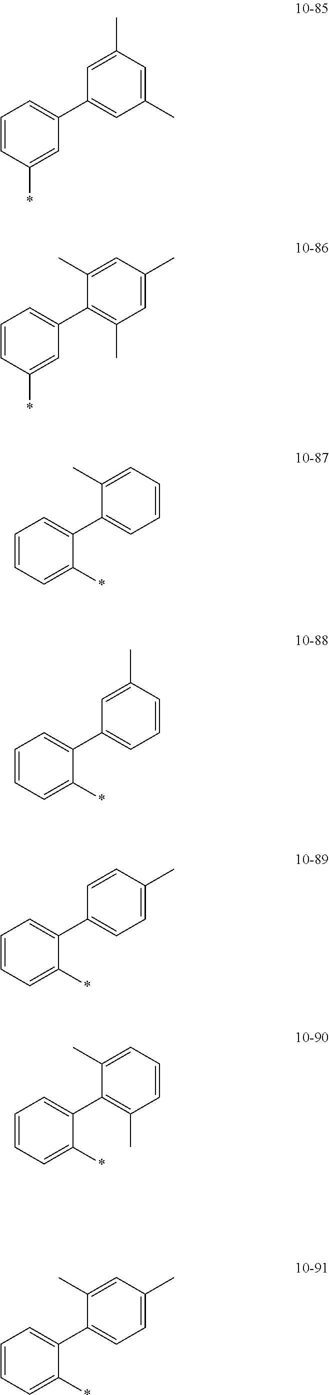

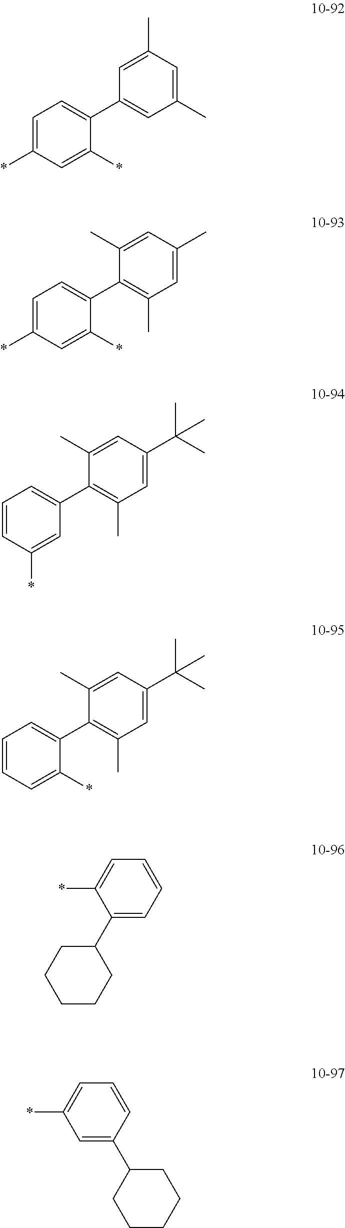

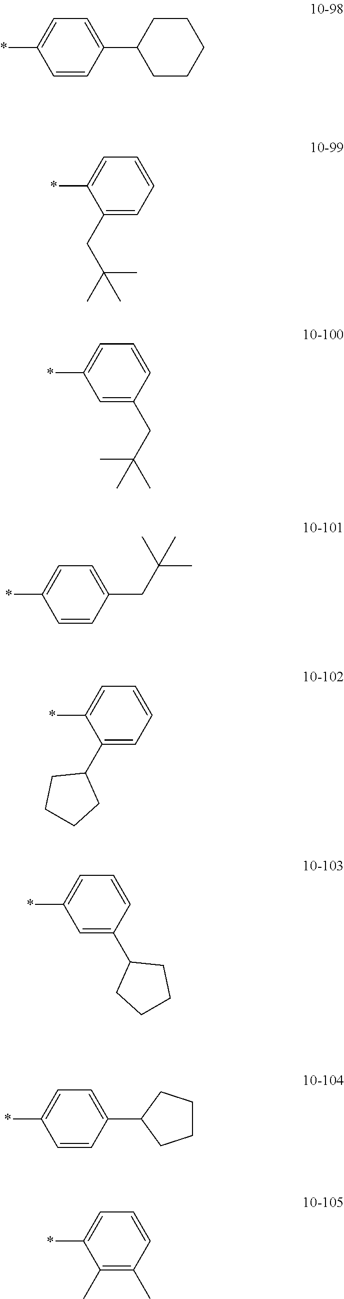

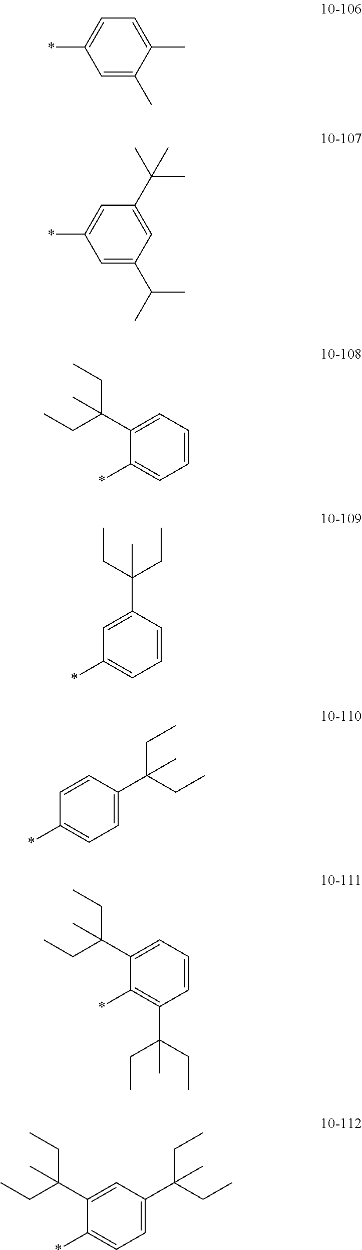

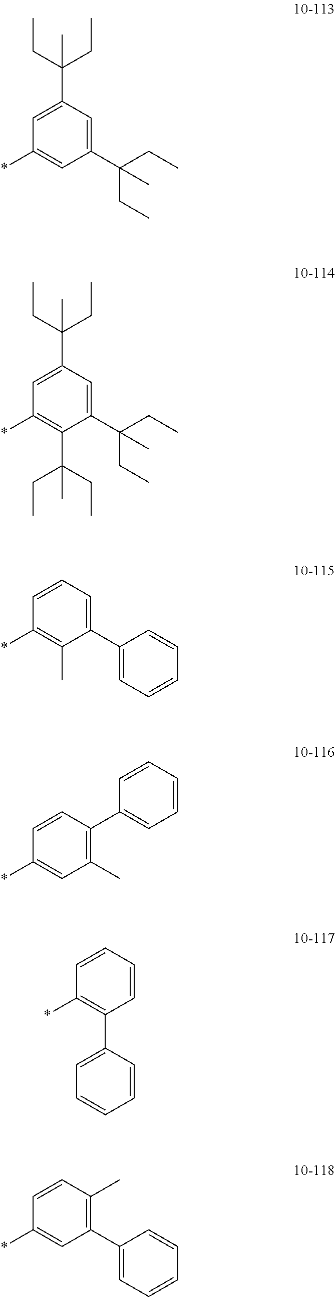

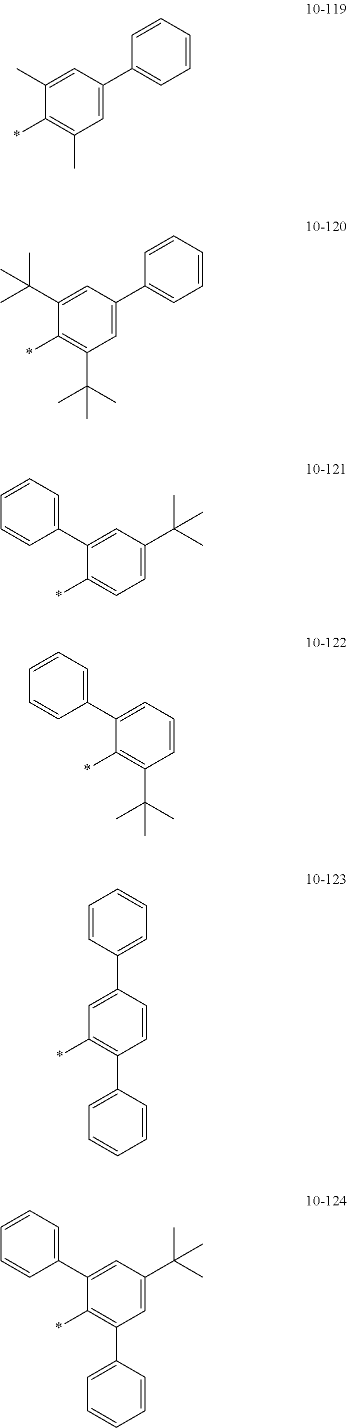

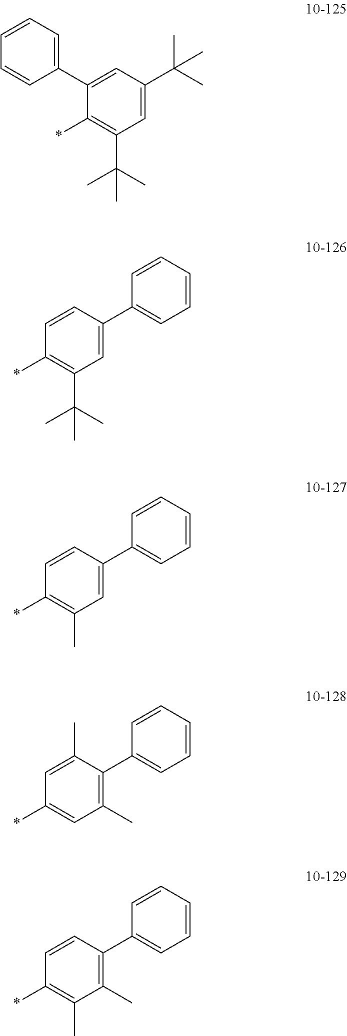

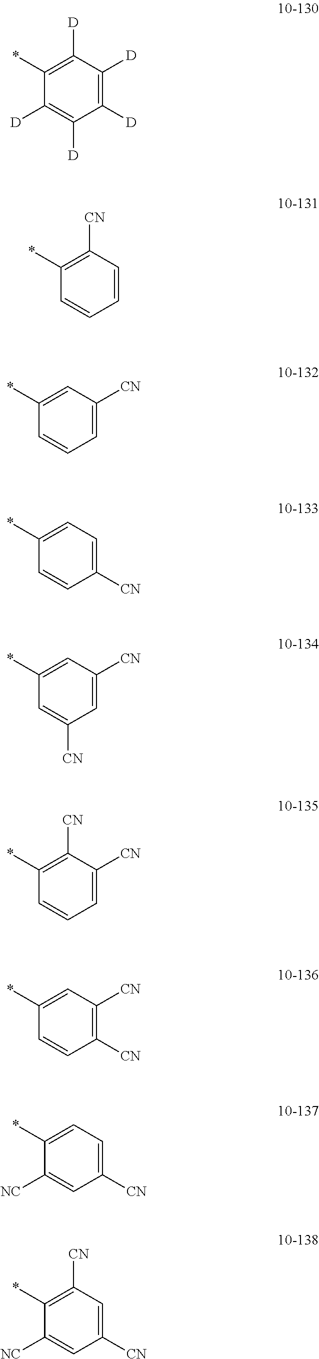

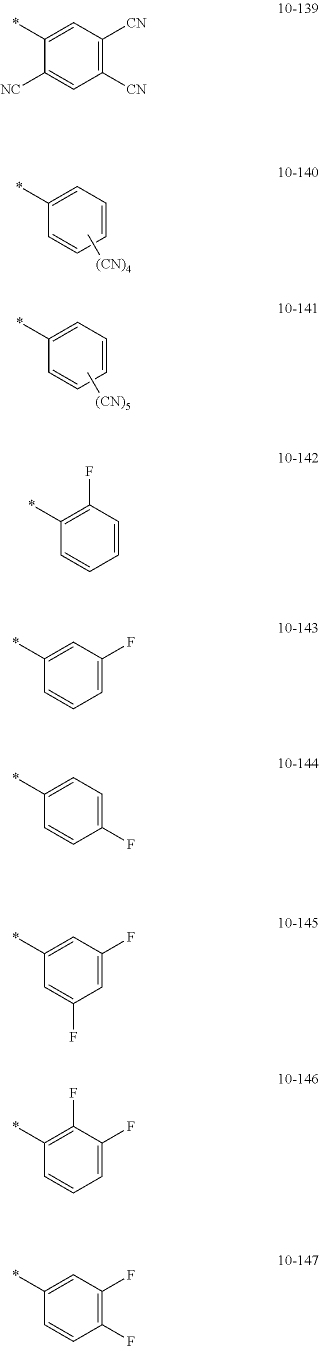

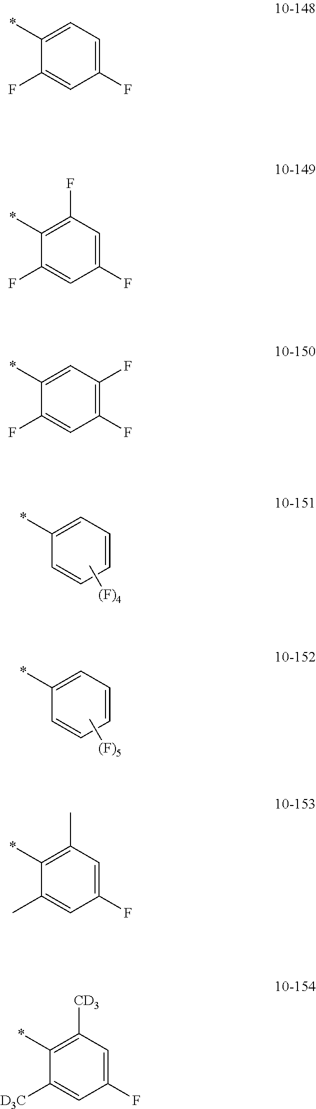

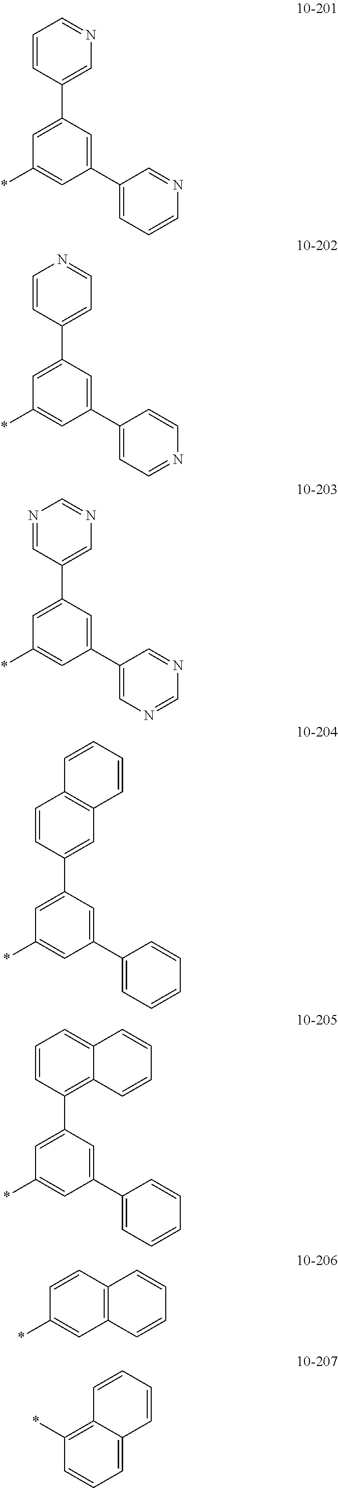

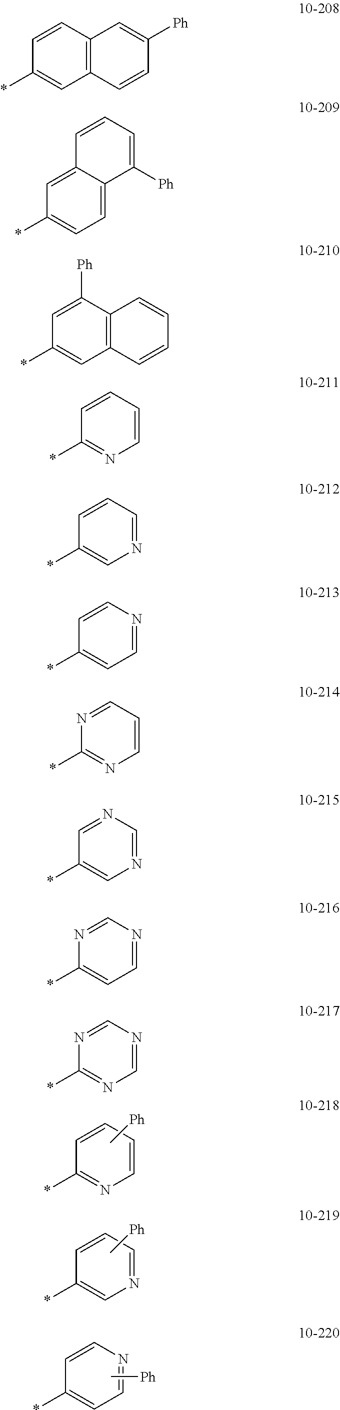

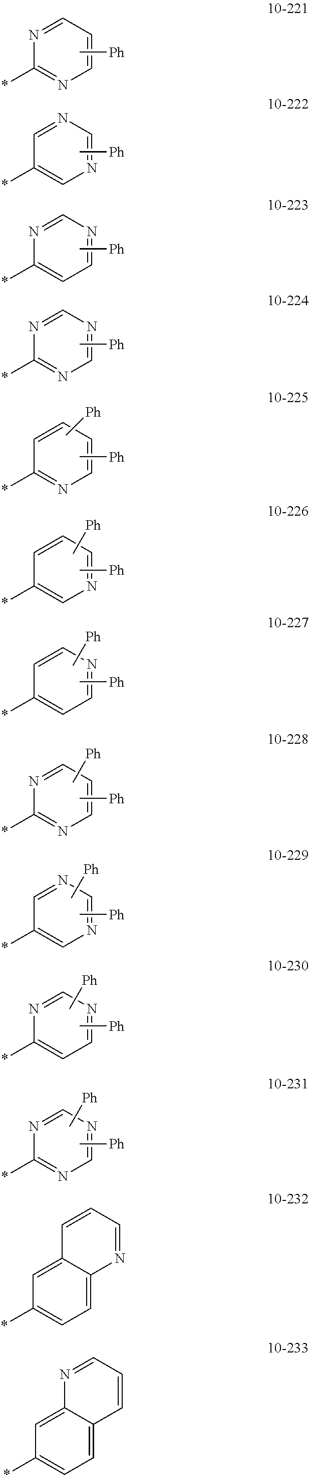

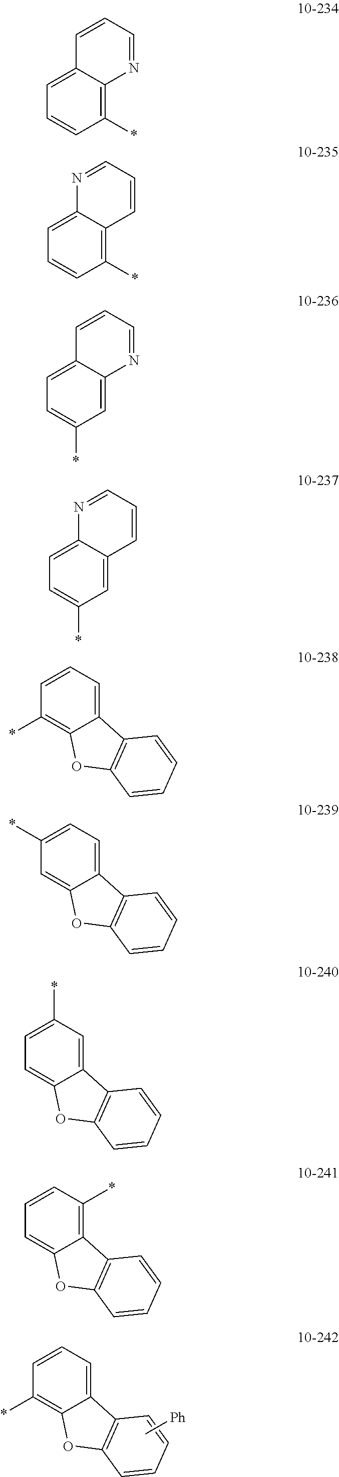

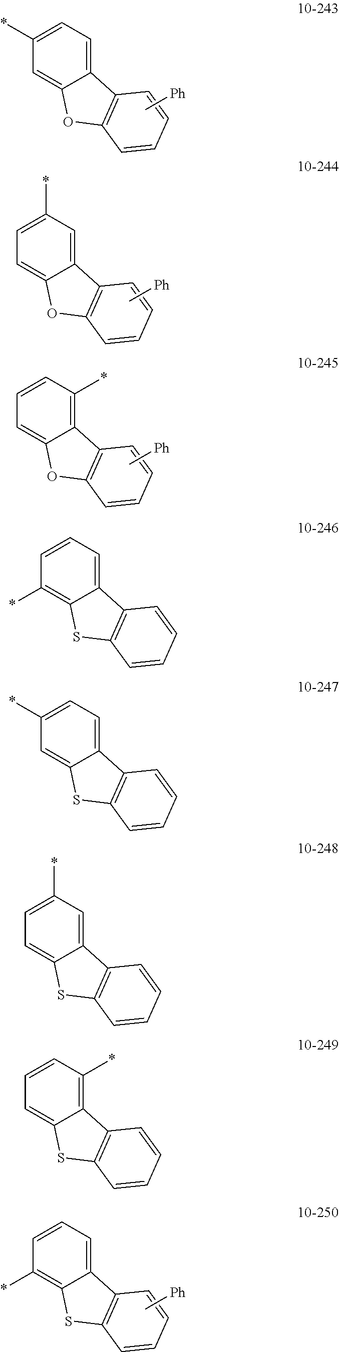

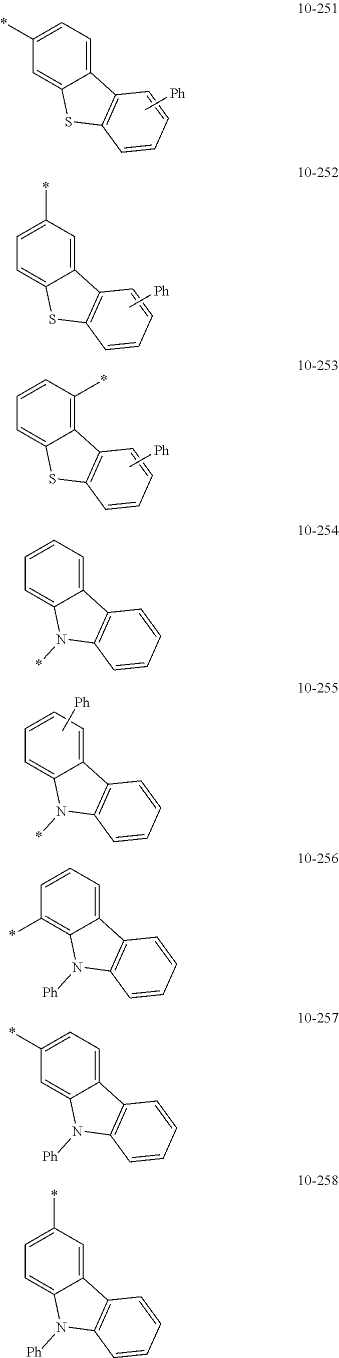

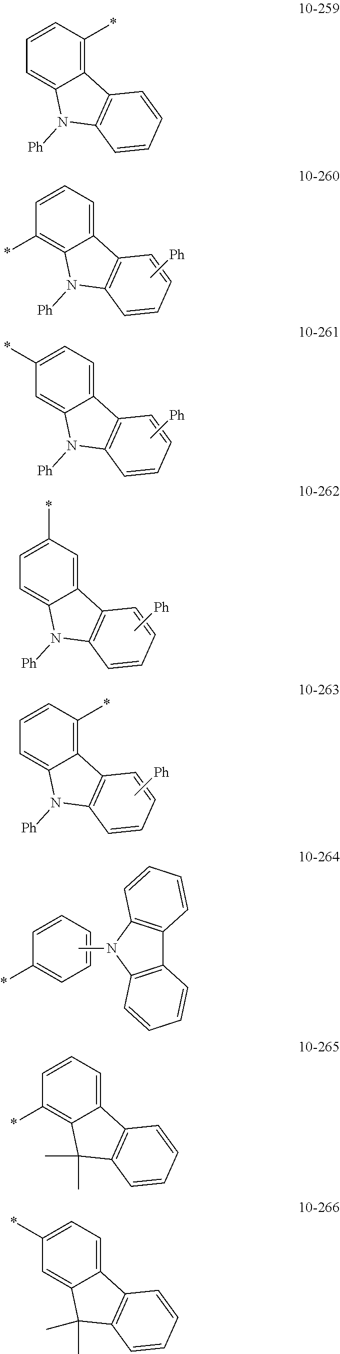

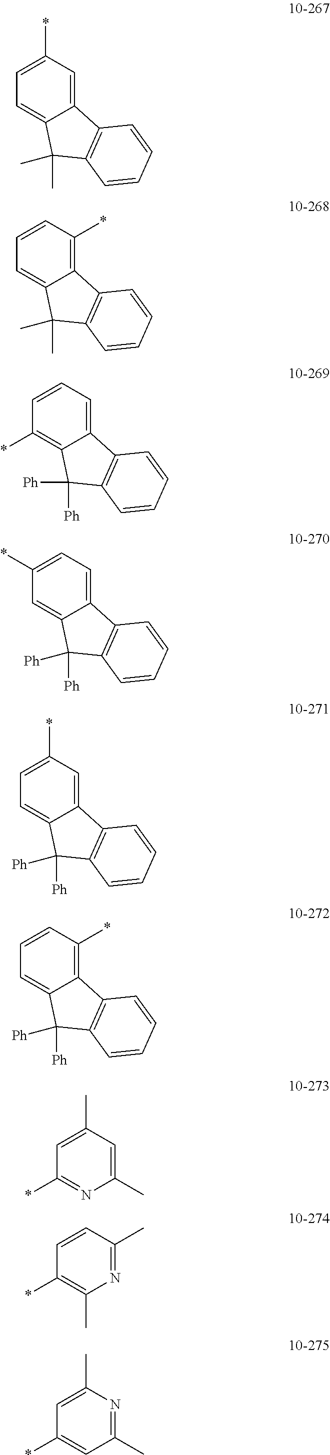

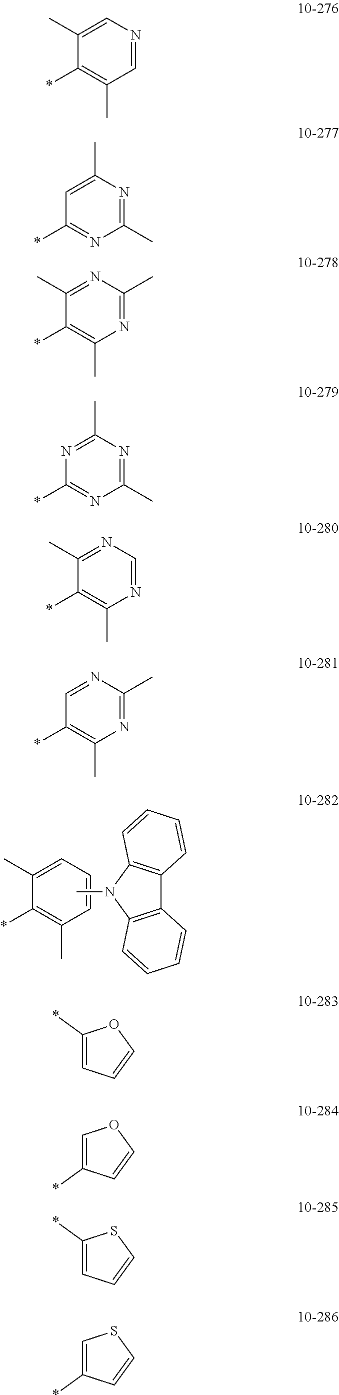

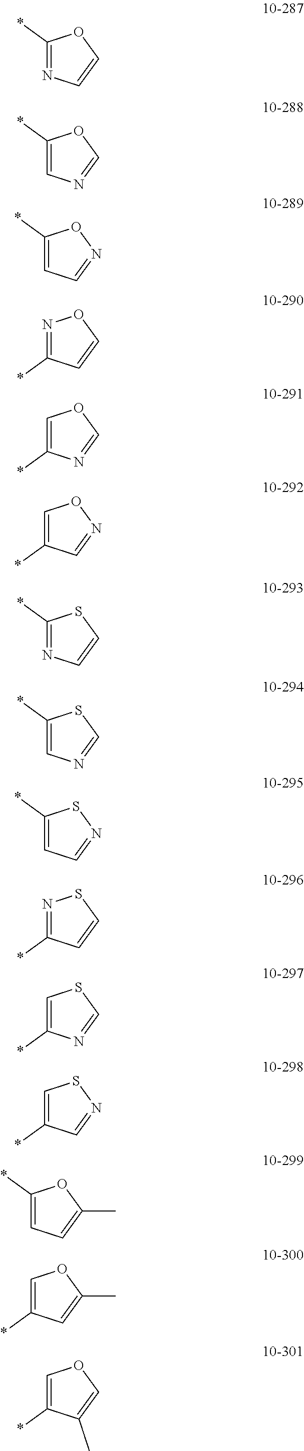

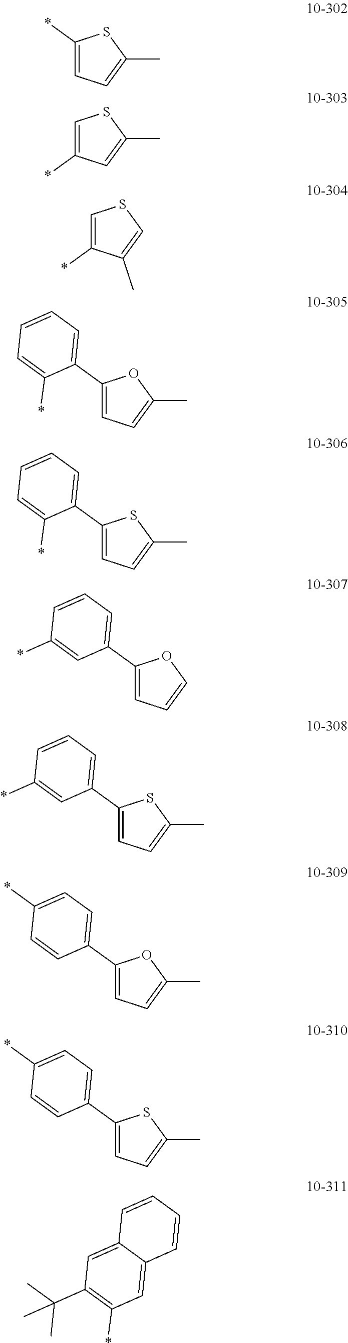

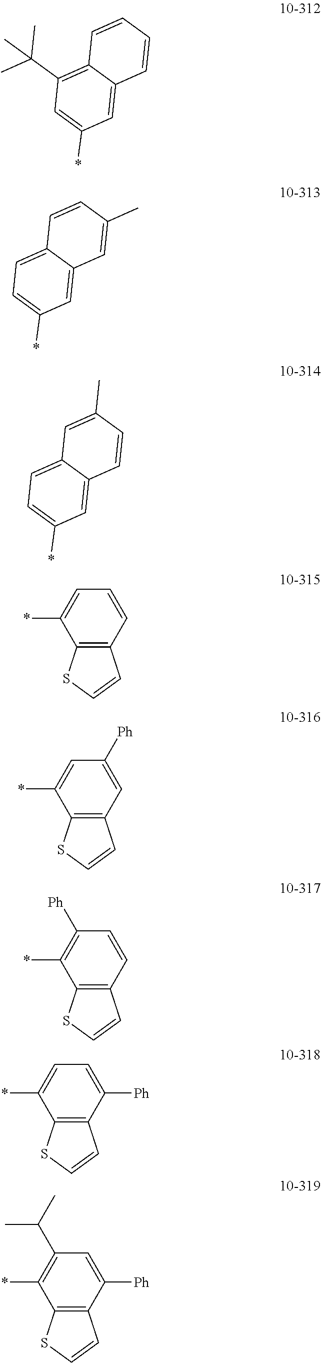

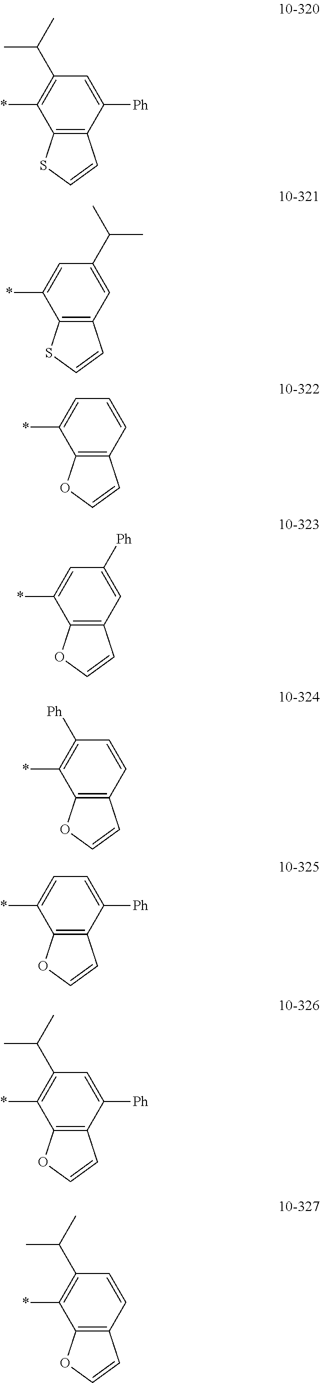

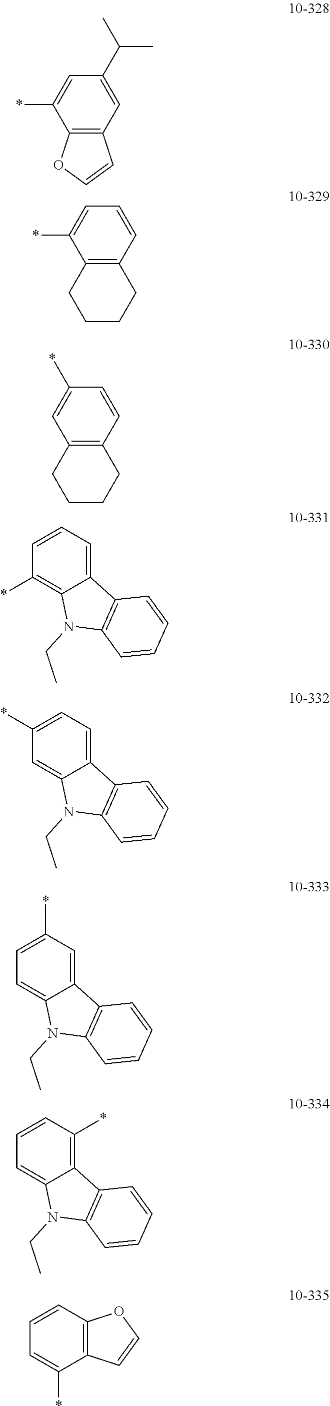

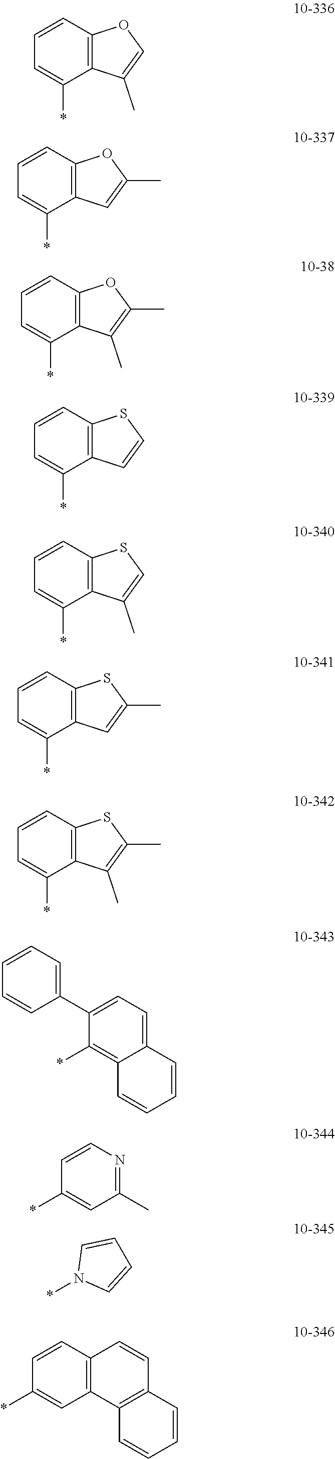

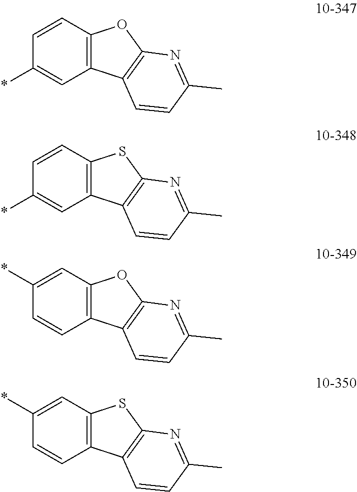

wherein, in Formulae 9-1 to 9-61, 9-201 to 9-244, 10-1 to 10-154, and 10-201 to 10-350, * indicates a binding site to an adjacent atom, “Ph” represents a phenyl group, “TMS” represents a trimethylsilyl group, and “TMG” represents a trimethylgermyl group.

In one or more embodiments, R₁, R₂, R₁₀, R₂₀, R₃₀, R₄₀, R₅₀, R₆₀, and R₇₀ may each independently be:
a group represented by Formula 3, hydrogen, deuterium, —F, —Cl, —Br, —I, —SF₅, —CD₃, —CD₂H, —CDH₂, —CF₃, —CF₂H, —CFH₂, a C₁-C₆₀ alkyl group, a C₂-C₆₀ alkenyl group, a C₂-C₆₀ alkynyl group, a C₁-C₆₀ alkoxy group, or a C₁-C₂₀ alkylthio group; or
a group represented by one of Formulae 9-1 to 9-61, 9-201 to 9-244, 10-1 to 10-154, or 10-201 to 10-350.

In one or more embodiments, at least one of R₁₀, R₂₀, and R₃₀ may be a group represented by Formula 3.

For example, at least one of R₁₀ in the number of b10, at least one of R₂₀ in the number of b20, and/or at least one of R₃₀ in the number of b30 may be a group represented by Formula 3.

In one or more embodiments, at least one of R₁₀ in the number of b10 may be a group represented by Formula 3.

In one or more embodiments, at least one of R₂₀ in the number of b20 may be a group represented by Formula 3.

In one or more embodiments, at least one of R₃₀ in the number of b30 may be a group represented by Formula 3.

R₁₁ is a substituted or unsubstituted C₁-C₆₀ alkyl group, a substituted or unsubstituted C₃-C₁₀ cycloalkyl group, a substituted or unsubstituted C₆-C₆₀ aryl group, a substituted or unsubstituted C₁-C₆₀ heteroaryl group, a substituted or unsubstituted monovalent non-aromatic condensed polycyclic group, or a substituted or unsubstituted monovalent non-aromatic condensed heteropolycyclic group.

In one or more embodiments, R₁₁ may be a methyl group, an ethyl group, an n-propyl group, an isopropyl group, an n-butyl group, an isobutyl group, a sec-butyl group, a tert-butyl group, an n-pentyl group, an isopentyl group, a 2-methylbutyl group, a sec-pentyl group, a tert-pentyl group, a neo-pentyl group, a 3-pentyl group, a 3-methyl-2-butyl group, a phenyl group, a biphenyl group, a C₁-C₂₀ alkylphenyl group, or a naphthyl group.

In one or more embodiments, at least one of R₂₀ in the number of b20 may be a group represented by Formula 3.

In Formulae 1 and 2, b10, b20, b30, b40, and b50 are each independently 1, 2, 3, 4, 5, 6, 7, 8, 9, 10, 11, 12, 13, or 14.

In Formula 3, b60 and b70 are each independently 1, 2, 3, 4, 5, 6, 7, or 8.

In Formulae 1 and 2, at least two neighboring groups among R₁, R₂, R₁₀, R₁₁, R₂₀, R₃₀, R₄₀, R₅₀, R₆₀, and R₇₀ are optionally bonded together to form a substituted or unsubstituted C₅-C₃₀ carbocyclic group or a substituted or unsubstituted C₁-C₃₀ heterocyclic group.

In one or more embodiments, the heterocyclic compound may be represented by Formula 11 or 12:

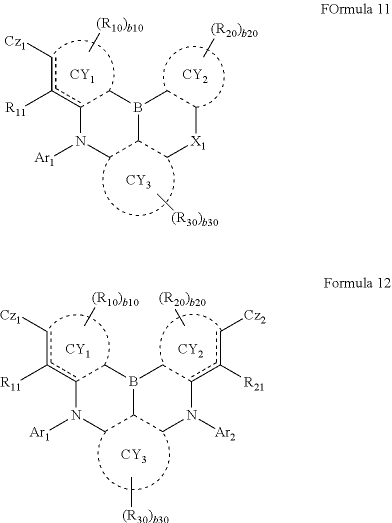

wherein, in Formulae 11 and 12,
ring CY₁ to ring CY₃, X₁, Ar₁, Ar₂, X₁, Cz₁, R₁₀, R₁₁, R₂₀, R₃₀, b10, b20, and b30 are each the same as described herein,
Cz₂ is the same as described in connection with Cz₁,
R₂₁ is the same as described in connection with R₂₀, and
[symbol] indicates a single bond or a double bond.

In one or more embodiments, the heterocyclic compound may be represented by Formula 21 or 22:

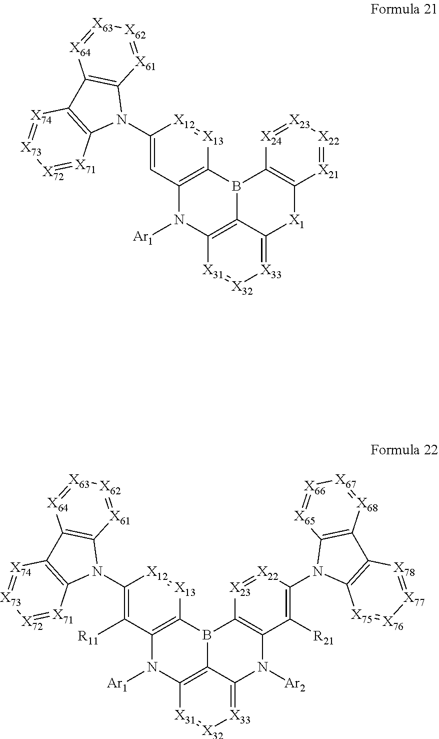

wherein, in Formulae 21 and 22,
Ar₁, Ar₂, X₁, and R₁₁ are each the same as described herein,
X₁₂ may be C(R₁₂) or N, and X₁₃ may be C(R₁₃) or N,
X₂₁ may be C(R₂₁) or N, X₂₂ may be C(R₂₂) or N, X₂₃ may be C(R₂₃) or N, and X₂₄ may be C(R₂₄) or N,
X₃₁ may be C(R₃₁) or N, X₃₂ may be C(R₃₂) or N, and X₃₃ may be C(R₃₃) or N,
X₆₁ may be C(R₆₁) or N, X₆₂ may be C(R₆₂) or N, X₆₃ may be C(R₆₃) or N, X₆₄ may be C(R₆₄) or N, X₆₅ may be C(R₆₅) or N, X₆₆ may be C(R₆₆) or N, X₆₇ may be C(R₆₇) or N, and X₆₈ may be C(R₆₈) or N,
X₇₁ may be C(R₇₁) or N, X₇₂ may be C(R₇₂) or N, X₇₃ may be C(R₇₃) or N, X₇₄ may be C(R₇₄) or N, X₇₅ may be C(R₇₅) or N, X₇₆ may be C(R₇₆) or N, X₇₇ may be C(R₇₇) or N, and X₇₈ may be C(R₇₈) or N
R₁₂ and R₁₃ are each independently the same as described in connection with R₁₀,
R₂₁ to R₂₄ are each independently the same as described in connection with R₂₀,
R₃₁ to R₃₃ may each independently be the same as described in connection with R₃₀,
R₆₁ to R₆₈ are each independently the same as described in connection with R₆₀, and
R₇₁ to R₇₈ are each independently the same as described in connection with R₇₀.

In one or more embodiments, the heterocyclic compound may be represented by Formula 31 or 32:

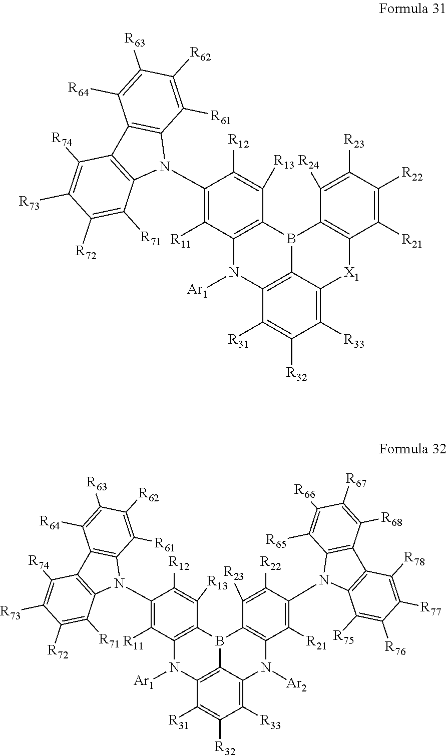

wherein, in Formulae 31 and 32,
Ar₁, Ar₂, X₁, and R₁₁ are each the same as described herein,
R₁₂ and R₁₃ are each independently the same as described in connection with R₁₀,
R₂₁ to R₂₄ are each independently the same as described in connection with R₂₀,
R₃₁ to R₃₃ are each independently the same as described in connection with R₃₀,
R₆₁ to R₆₈ are each independently the same as described in connection with R₆₀, and
R₇₁ to R₇₈ are each independently the same as described in connection with R₇₀.

For example, in Formulae 31 and 32, Ar₁ and Ar₂ may each independently be a group represented by one of Formulae 2A to 2C, and in Formulae 2A to 2C, one of R₅₁ to R₅₅, preferably R₅₂ or R₅₄, may be a phenyl group, a biphenyl group, or a naphthyl group. In Formulae 31 and 32, R₁₁ may be a C₁-C₂₀ alkyl group (e.g., C₁-C₁₀ alkyl group or C₁-C₅ alkyl group) unsubstituted or substituted with deuterium, —F, —Cl, —Br, —I, —CD₃, —CD₂H, —CDH₂, —CF₃, —CF₂H, —CFH₂, a cyano group, a C₁-C₂₀ alkyl group, a C₁-C₂₀ alkoxy group, or a C₁-C₂₀ alkylthio group. In Formulae 31 and 32, R₂₁ may be the same as or different from R₁₁. In Formulae 31 and 32, R₃₂ may be a C₁-C₂₀ alkyl group (e.g., C₁-C₂₀ linear alkyl group or C₃-C₂₀ branched alkyl group, such as C₁-C₁₀ linear alkyl group or C₃-C₁₀ branched alkyl group) unsubstituted or substituted with deuterium, —F, —Cl, —Br, —I, —CD₃, —CD₂H, —CDH₂, —CF₃, —CF₂H, —CFH₂, a cyano group, a C₁-C₂₀ alkyl group, a C₁-C₂₀ alkoxy group, or a C₁-C₂₀ alkylthio group.

In one or more embodiments, the heterocyclic compound represented by Formula 1 may have a symmetric structure or an asymmetric structure.

For example, the heterocyclic compound represented by Formula 1 may have a symmetric structure.

In one or more embodiments, the heterocyclic compound represented by Formula 1 may have an asymmetric structure.

As used herein, substituents of the substituted C₅-C₃₀ carbocyclic group, the substituted C₁-C₃₀ heterocyclic group, the substituted C₁-C₆₀ alkyl group, the substituted C₂-C₆₀ alkenyl group, the substituted C₂-C₆₀ alkynyl group, the substituted C₁-C₆₀ alkoxy group, the substituted C₁-C₆₀ alkylthio group, the substituted C₃-C₁₀ cycloalkyl group, the substituted C₁-C₁₀ heterocycloalkyl group, the substituted C₃-C₁₀ cycloalkenyl group, the substituted C₁-C₁₀ heterocycloalkenyl group, the substituted C₆-C₆₀ aryl group, the substituted C₇-C₆₀ alkyl aryl group, the substituted C₇-C₆₀ aryl alkyl group, the substituted C₆-C₆₀ aryloxy group, the substituted C₆-C₆₀ arylthio group, the substituted C₁-C₆₀ heteroaryl group, the substituted C₂-C₆₀ alkyl heteroaryl group, the substituted C₂-C₆₀ heteroaryl alkyl group, the substituted C₁-C₆₀ heteroaryloxy group, the substituted C₁-C₆₀ heteroarylthio group, the substituted monovalent non-aromatic condensed polycyclic group, the substituted monovalent non-aromatic condensed heteropolycyclic group, the substituted C₃-C₁₀ cycloalkylene group, the substituted C₁-C₁₀ heterocycloalkylene group, the substituted C₃-C₁₀ cycloalkenylene group, the substituted C₁-C₁₀ heterocycloalkenylene group, the substituted C₆-C₆₀ arylene group, the substituted C₁-C₁₀ heteroarylene group, the substituted divalent non-aromatic condensed polycyclic group, and the substituted divalent non-aromatic condensed heteropolycyclic group may each independently be:
deuterium, —F, —Cl, —Br, —I, —SF₅, —CD₃, —CD₂H, —CDH₂, —CF₃, —CF₂H, —CFH₂, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₆₀ alkyl group, a C₂-C₆₀ alkenyl group, a C₂-C₆₀ alkynyl group, a C₁-C₆₀ alkoxy group, or a C₁-C₆₀ alkylthio group;
a C₁-C₆₀ alkyl group, a C₂-C₆₀ alkenyl group, a C₂-C₆₀ alkynyl group, a C₁-C₆₀ alkoxy group, or a C₁-C₆₀ alkylthio group, each substituted with deuterium, —F, —Cl, —Br, —I, —SF₅, —CD₃, —CD₂H, —CDH₂, —CF₃, —CF₂H, —CFH₂, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₇-C₆₀ alkyl aryl group, a C₆-C₆₀ aryloxy group, a C₆-C₆₀ arylthio group, a C₁-C₆₀ heteroaryl group, a C₂-C₆₀ alkyl heteroaryl group, a C₁-C₆₀ heteroaryloxy group, a C₁-C₆₀ heteroarylthio group, a monovalent non-aromatic condensed polycyclic group, a monovalent non-aromatic condensed heteropolycyclic group, —N(Q₁₁)(Q₁₂), —Si(Q₁₁)(Q₁₂)(Q₁₃), —Ge(Q₁₁)(Q₁₂)(Q₁₃), —C(═O)(Q₁₁), —S(═O)(Q₁₁), —S(═O)₂(Q₁₁), —B(Q₁₁)(Q₁₂), —P(Q₁₁)(Q₁₂), —P(═O)(Q₁₁)(Q₁₂), —P(═S)(Q₁₁)(Q₁₂), or a combination thereof;
a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₇-C₆₀ alkyl aryl group, a C₆-C₆₀ aryloxy group, a C₆-C₆₀ arylthio group, a C₁-C₆₀ heteroaryl group, a C₂-C₆₀ alkyl heteroaryl group, a C₁-C₆₀ heteroaryloxy group, a C₁-C₆₀ heteroarylthio group, a monovalent non-aromatic condensed polycyclic group, or a monovalent non-aromatic condensed heteropolycyclic group, each unsubstituted or substituted with deuterium, —F, —Cl, —Br, —I, —SF₅, —CD₃, —CD₂H, —CDH₂, —CF₃, —CF₂H, —CFH₂, a hydroxyl group, a cyano group, a nitro group, an amidino group, a hydrazine group, a hydrazone group, a carboxylic acid group or a salt thereof, a sulfonic acid group or a salt thereof, a phosphoric acid group or a salt thereof, a C₁-C₆₀ alkyl group, a C₂-C₆₀ alkenyl group, a C₂-C₆₀ alkynyl group, a C₁-C₆₀ alkoxy group, a C₁-C₆₀ alkylthio group, a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₇-C₆₀ alkyl aryl group, a C₇-C₆₀ aryl alkyl group, a C₆-C₆₀ aryloxy group, a C₆-C₆₀ arylthio group, a C₁-C₆₀ heteroaryl group, a C₂-C₆₀ alkyl heteroaryl group, a C₂-C₆₀ heteroaryl alkyl group, a C₁-C₆₀ heteroaryloxy group, a C₁-C₆₀ heteroarylthio group, a monovalent non-aromatic condensed polycyclic group, a monovalent non-aromatic condensed heteropolycyclic group, —N(Q₂₁)(Q₂₂), —Si(Q₂₁)(Q₂₂)(Q₂₃), —Ge(Q₂₁)(Q₂₂)(Q₂₃), —C(═O)(Q₂₁), —S(═O)(Q₂₁), —S(═O)₂(Q₂₁), —B(Q₂₁)(Q₂₂), —P(Q₂₁)(Q₂₂), —P(═O)(Q₂₁)(Q₂₂), —P(═S)(Q₂₁)(Q₂₂), or a combination thereof;
—N(Q₃₁)(Q₃₂), —Si(Q₃₁)(Q₃₂)(Q₃₃), —Ge(Q₃₁)(Q₃₂)(Q₃₃), —C(═O)(Q₃₁), —S(═O)(Q₃₁), —S(═O)₂(Q₃₁), —B(Q₃₁)(Q₃₂), —P(Q₃₁)(Q₃₂), —P(═O)(Q₃₁)(Q₃₂), or —P(═S)(Q₃₁)(Q₃₂); or
a combination thereof.

As used herein, Q₁ to Q₃, Q₁₁ to Q₁₃, Q₂₁ to Q₂₃, and Q₃₁ to Q₃₃ are each independently hydrogen, deuterium, —F, —Cl, —Br, —I, —SF₅, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a substituted or unsubstituted C₁-C₆₀ alkyl group, a substituted or unsubstituted C₂-C₆₀ alkenyl group; a substituted or unsubstituted C₂-C₆₀ alkynyl group; a substituted or unsubstituted C₁-C₆₀ alkoxy group; a substituted or unsubstituted C₁-C₆₀ alkylthio group, a substituted or unsubstituted C₃-C₁₀ cycloalkyl group; a substituted or unsubstituted C₁-C₁₀ heterocycloalkyl group; a substituted or unsubstituted C₃-C₁₀ cycloalkenyl group; a substituted or unsubstituted C₁-C₁₀ heterocycloalkenyl group, a substituted or unsubstituted C₆-C₆₀ aryl group, a substituted or unsubstituted C₇-C₆₀ alkyl aryl group, a substituted or unsubstituted C₇-C₆₀ aryl alkyl group, a substituted or unsubstituted C₆-C₆₀ aryloxy group; a substituted or unsubstituted C₆-C₆₀ arylthio group; a substituted or unsubstituted C₁-C₆₀ heteroaryl group; a substituted or unsubstituted C₂-C₆₀ alkyl heteroaryl group, a substituted or unsubstituted C₂-C₆₀ heteroaryl alkyl group, a substituted or unsubstituted C₁-C₆₀ heteroaryloxy group, a substituted or unsubstituted C₁-C₆₀ heteroarylthio group, a substituted or unsubstituted monovalent non-aromatic condensed polycyclic group; or a substituted or unsubstituted monovalent non-aromatic condensed heteropolycyclic group.

For example, Q₁ to Q₃, Q₁₁ to Q₁₃, Q₂₁ to Q₂₃, and Q₃₁ to Q₃₃ described herein may each independently be:
—CH₃, —CD₃, —CD₂H, —CDH₂, —CH₂CH₃, —CH₂CD₃, —CH₂CD₂H, —CH₂CDH₂, —CHDCH₃, —CHDCD₂H, —CHDCDH₂, —CHDCD₃, —CD₂CD₃, —CD₂CD₂H, or —CD₂CDH₂; or
an n-propyl group, an isopropyl group, an n-butyl group, a sec-butyl group, an isobutyl group, a tert-butyl group, an n-pentyl group, a tert-pentyl group, an neopentyl group, an isopentyl group, a sec-pentyl group, a 3-pentyl group, a sec-isopentyl group, a phenyl group, a biphenyl group, or a naphthyl group, each unsubstituted or substituted with deuterium, a C₁-C₁₀ alkyl group, a phenyl group, or a combination thereof.

In one or more embodiments, the heterocyclic compound may include at least one of Compounds 1 to 83, but embodiments are not limited thereto:

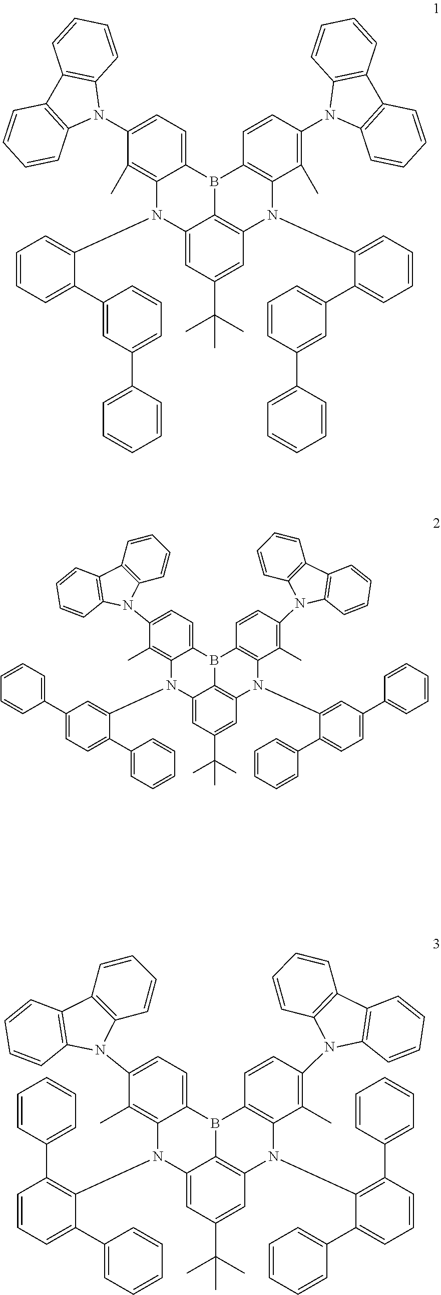 [SMILES: Cc1c(-n2c3ccccc3c3ccccc32)ccc2c1N(c1ccccc1-c1cccc(-c3ccccc3)c1)c1cc(C(C)(C)C)cc3c1B2c1ccc(-n2c4ccccc4c4ccccc42)c(C)c1N3c1ccccc1-c1cccc(-c2ccccc2)c1 ; Cc1c(-n2c3ccccc3c3ccccc32)ccc2c1N(c1cc(-c3ccccc3)ccc1-c1ccccc1)c1cc(C(C)(C)C)cc3c1B2c1ccc(-n2c4ccccc4c4ccccc42)c(C)c1N3c1cc(-c2ccccc2)ccc1-c1ccccc1 ; Cc1c(-n2c3ccccc3c3ccccc32)ccc2c1N(c1c(-c3ccccc3)cccc1-c1ccccc1)c1cc(C(C)(C)C)cc3c1B2c1ccc(-n2c4ccccc4c4ccccc42)c(C)c1N3c1c(-c2ccccc2)cccc1-c1ccccc1]

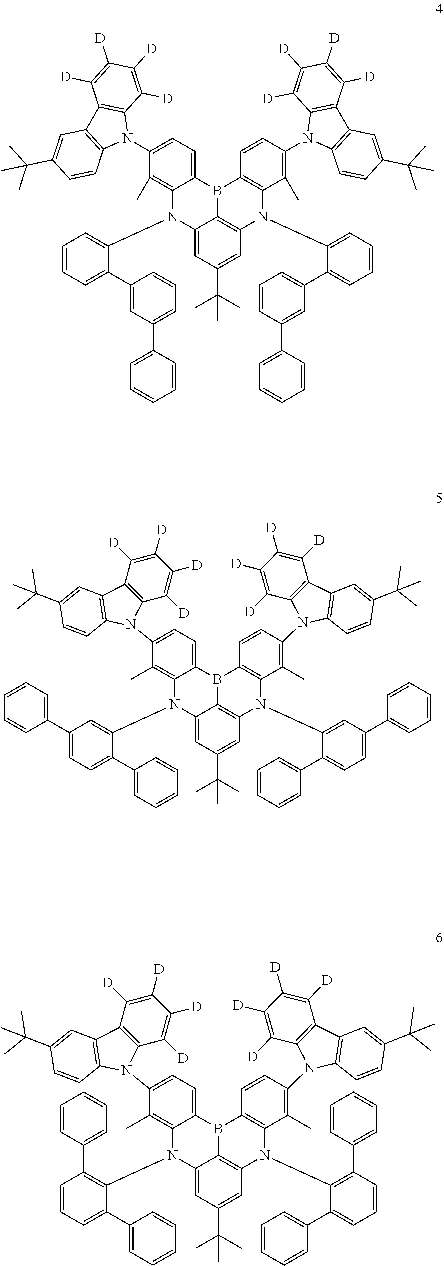

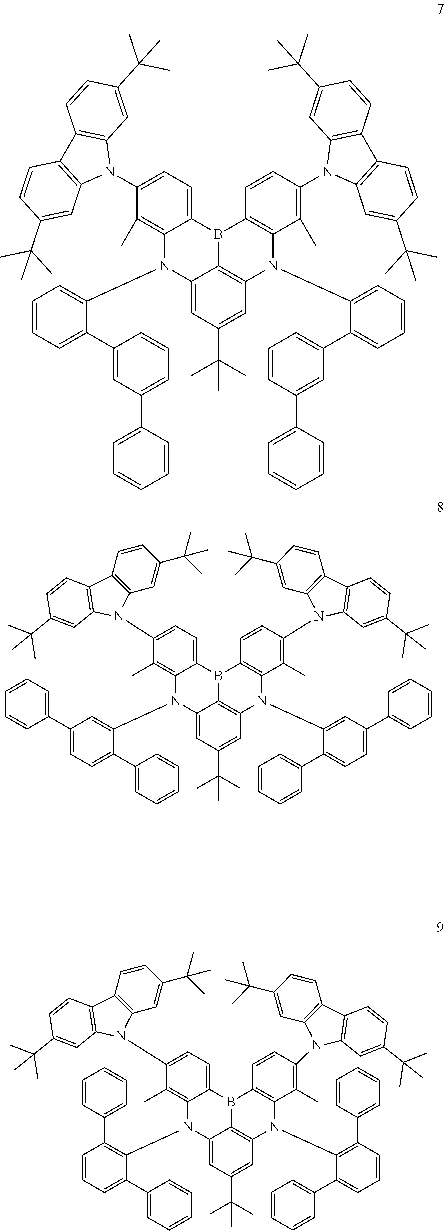

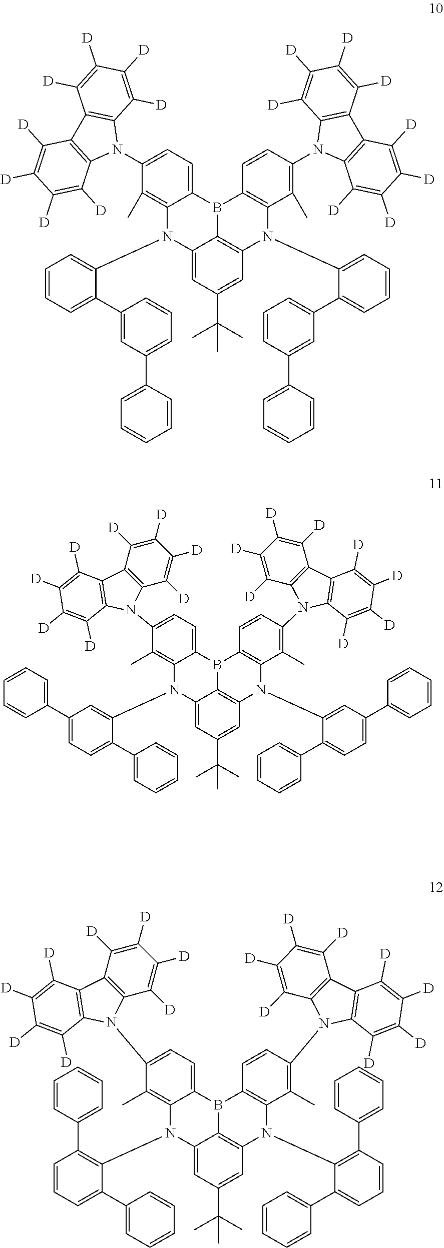

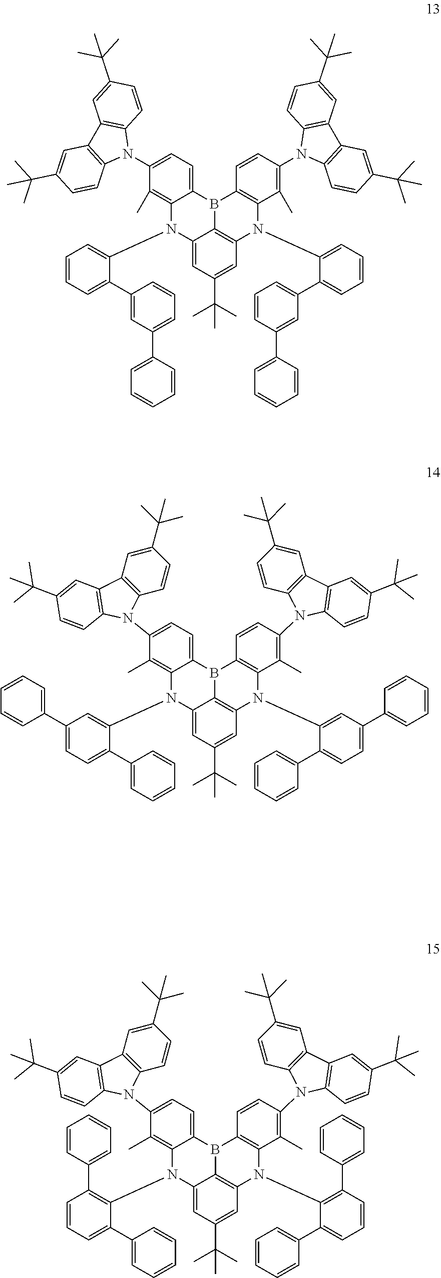

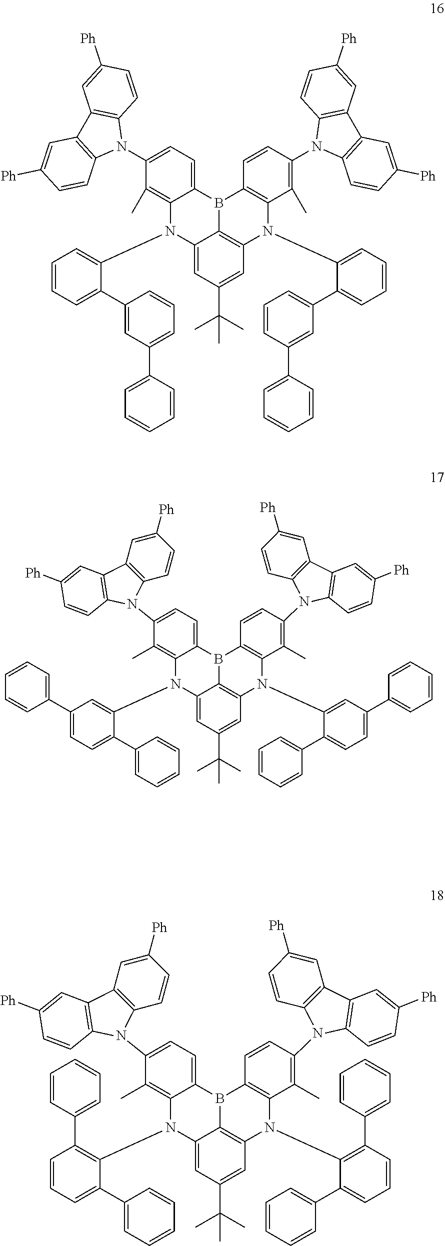

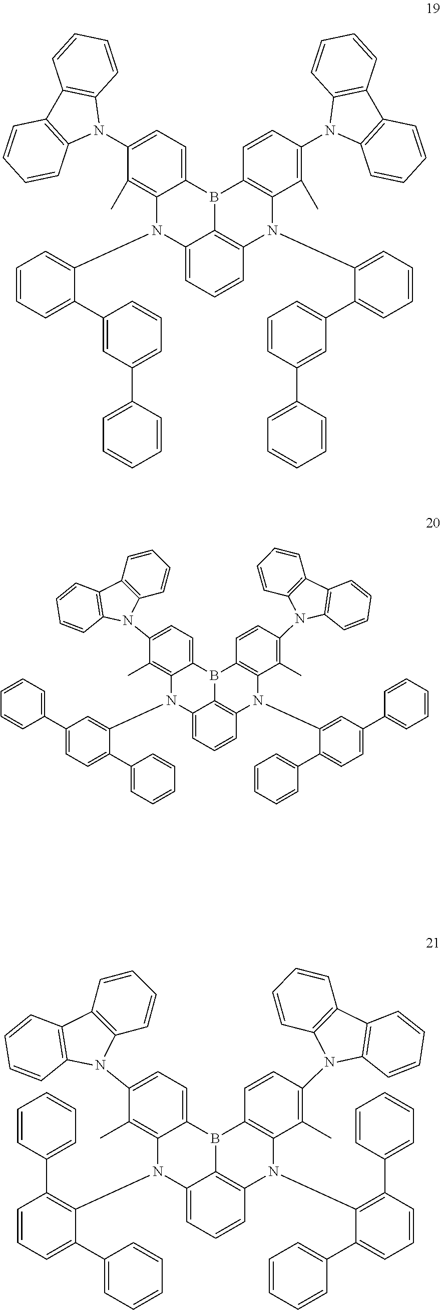 [SMILES: Cc1c(-n2c3ccccc3c3ccccc32)ccc2c1N(c1ccccc1-c1cccc(-c3ccccc3)c1)c1cccc3c1B2c1ccc(-n2c4ccccc4c4ccccc42)c(C)c1N3c1ccccc1-c1cccc(-c2ccccc2)c1 ; Cc1c(-n2c3ccccc3c3ccccc32)ccc2c1N(c1cc(-c3ccccc3)ccc1-c1ccccc1)c1cccc3c1B2c1ccc(-n2c4ccccc4c4ccccc42)c(C)c1N3c1cc(-c2ccccc2)ccc1-c1ccccc1 ; Cc1c(-n2c3ccccc3c3ccccc32)ccc2c1N(c1c(-c3ccccc3)cccc1-c1ccccc1)c1cccc3c1B2c1ccc(-n2c4ccccc4c4ccccc42)c(C)c1N3c1c(-c2ccccc2)cccc1-c1ccccc1]

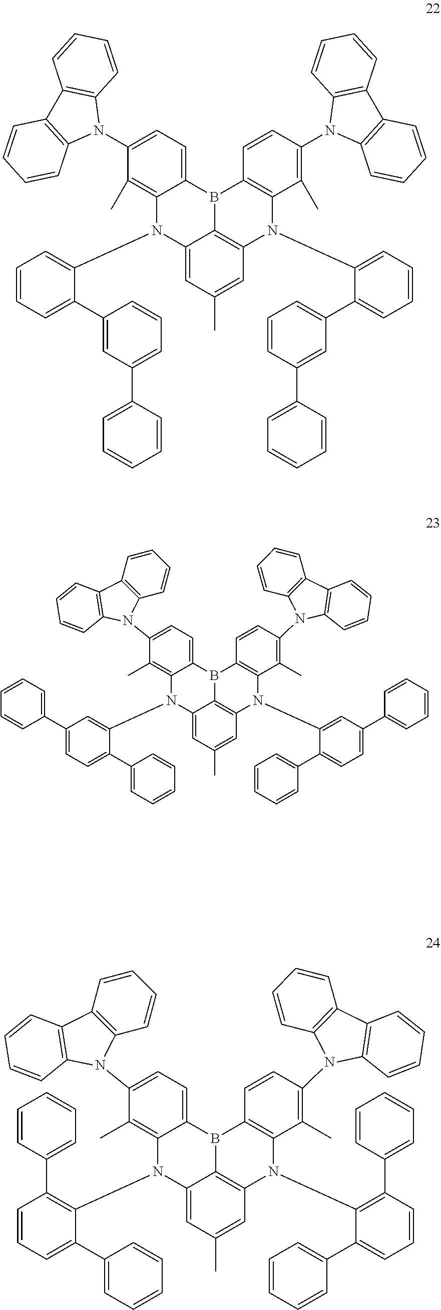 [SMILES: Cc1cc2c3c(c1)N(c1ccccc1-c1cccc(-c4ccccc4)c1)c1c(ccc(-n4c5ccccc5c5ccccc54)c1C)B3c1ccc(-n3c4ccccc4c4ccccc43)c(C)c1N2c1ccccc1-c1cccc(-c2ccccc2)c1 ; Cc1cc2c3c(c1)N(c1cc(-c4ccccc4)ccc1-c1ccccc1)c1c(ccc(-n4c5ccccc5c5ccccc54)c1C)B3c1ccc(-n3c4ccccc4c4ccccc43)c(C)c1N2c1cc(-c2ccccc2)ccc1-c1ccccc1 ; Cc1cc2c3c(c1)N(c1c(-c4ccccc4)cccc1-c1ccccc1)c1c(ccc(-n4c5ccccc5c5ccccc54)c1C)B3c1ccc(-n3c4ccccc4c4ccccc43)c(C)c1N2c1c(-c2ccccc2)cccc1-c1ccccc1]

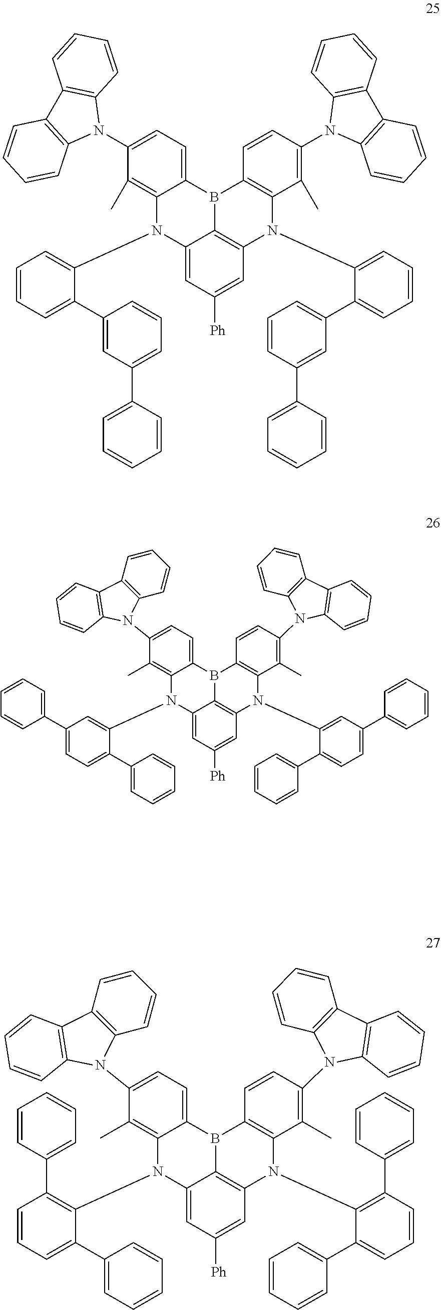 [SMILES: Cc1c(-n2c3ccccc3c3ccccc32)ccc2c1N(c1ccccc1-c1cccc(-c3ccccc3)c1)c1cc(-c3ccccc3)cc3c1B2c1ccc(-n2c4ccccc4c4ccccc42)c(C)c1N3c1ccccc1-c1cccc(-c2ccccc2)c1 ; Cc1c(-n2c3ccccc3c3ccccc32)ccc2c1N(c1cc(-c3ccccc3)ccc1-c1ccccc1)c1cc(-c3ccccc3)cc3c1B2c1ccc(-n2c4ccccc4c4ccccc42)c(C)c1N3c1cc(-c2ccccc2)ccc1-c1ccccc1 ; Cc1c(-n2c3ccccc3c3ccccc32)ccc2c1N(c1c(-c3ccccc3)cccc1-c1ccccc1)c1cc(-c3ccccc3)cc3c1B2c1ccc(-n2c4ccccc4c4ccccc42)c(C)c1N3c1c(-c2ccccc2)cccc1-c1ccccc1]

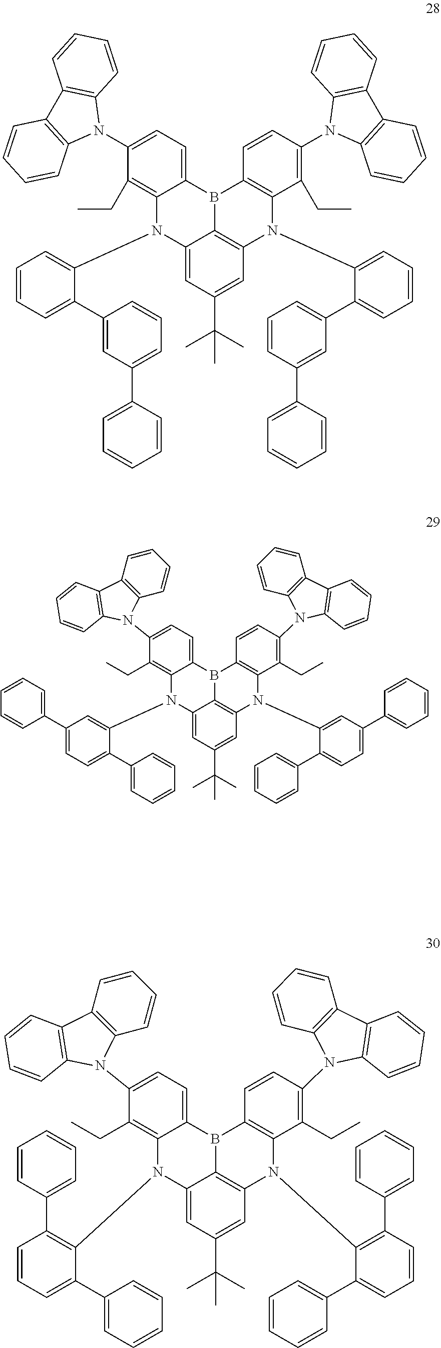 [SMILES: CCc1c(-n2c3ccccc3c3ccccc32)ccc2c1N(c1ccccc1-c1cccc(-c3ccccc3)c1)c1cc(C(C)(C)C)cc3c1B2c1ccc(-n2c4ccccc4c4ccccc42)c(CC)c1N3c1ccccc1-c1cccc(-c2ccccc2)c1 ; CCc1c(-n2c3ccccc3c3ccccc32)ccc2c1N(c1cc(-c3ccccc3)ccc1-c1ccccc1)c1cc(C(C)(C)C)cc3c1B2c1ccc(-n2c4ccccc4c4ccccc42)c(CC)c1N3c1cc(-c2ccccc2)ccc1-c1ccccc1 ; CCc1c(-n2c3ccccc3c3ccccc32)ccc2c1N(c1c(-c3ccccc3)cccc1-c1ccccc1)c1cc(C(C)(C)C)cc3c1B2c1ccc(-n2c4ccccc4c4ccccc42)c(CC)c1N3c1c(-c2ccccc2)cccc1-c1ccccc1]

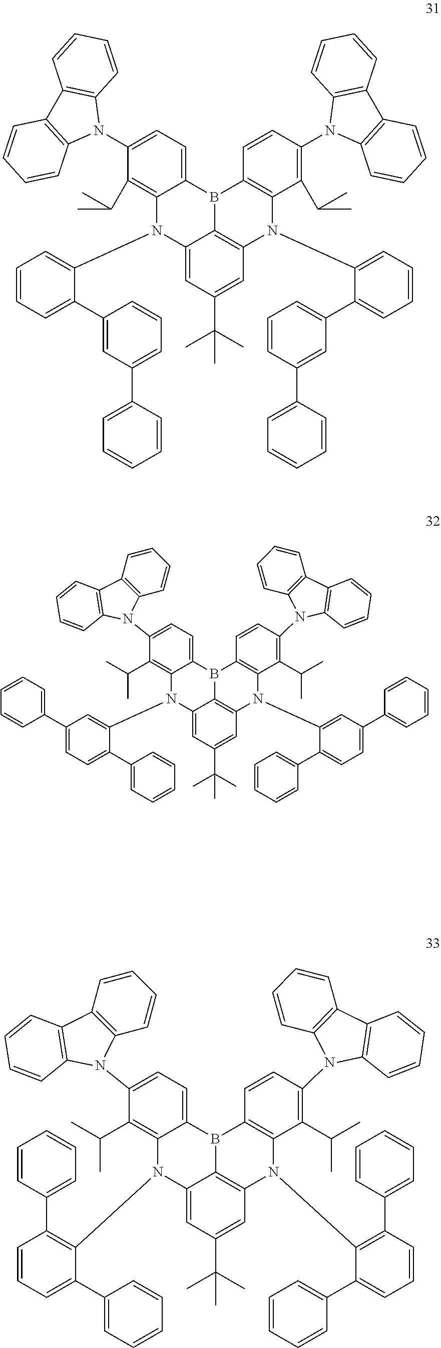 [SMILES: CC(C)c1c(-n2c3ccccc3c3ccccc32)ccc2c1N(c1ccccc1-c1cccc(-c3ccccc3)c1)c1cc(C(C)(C)C)cc3c1B2c1ccc(-n2c4ccccc4c4ccccc42)c(C(C)C)c1N3c1ccccc1-c1cccc(-c2ccccc2)c1 ; CC(C)c1c(-n2c3ccccc3c3ccccc32)ccc2c1N(c1cc(-c3ccccc3)ccc1-c1ccccc1)c1cc(C(C)(C)C)cc3c1B2c1ccc(-n2c4ccccc4c4ccccc42)c(C(C)C)c1N3c1cc(-c2ccccc2)ccc1-c1ccccc1 ; CC(C)c1c(-n2c3ccccc3c3ccccc32)ccc2c1N(c1c(-c3ccccc3)cccc1-c1ccccc1)c1cc(C(C)(C)C)cc3c1B2c1ccc(-n2c4ccccc4c4ccccc42)c(C(C)C)c1N3c1c(-c2ccccc2)cccc1-c1ccccc1]

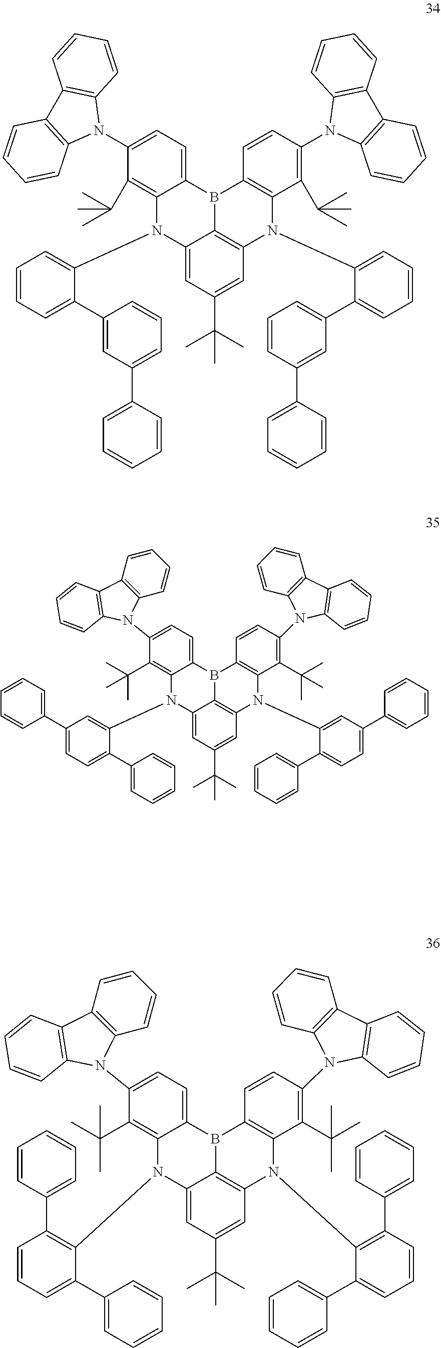 [SMILES: CC(C)(C)c1cc2c3c(c1)N(c1ccccc1-c1cccc(-c4ccccc4)c1)c1c(ccc(-n4c5ccccc5c5ccccc54)c1C(C)(C)C)B3c1ccc(-n3c4ccccc4c4ccccc43)c(C(C)(C)C)c1N2c1ccccc1-c1cccc(-c2ccccc2)c1 ; CC(C)(C)c1cc2c3c(c1)N(c1cc(-c4ccccc4)ccc1-c1ccccc1)c1c(ccc(-n4c5ccccc5c5ccccc54)c1C(C)(C)C)B3c1ccc(-n3c4ccccc4c4ccccc43)c(C(C)(C)C)c1N2c1cc(-c2ccccc2)ccc1-c1ccccc1 ; CC(C)(C)c1cc2c3c(c1)N(c1c(-c4ccccc4)cccc1-c1ccccc1)c1c(ccc(-n4c5ccccc5c5ccccc54)c1C(C)(C)C)B3c1ccc(-n3c4ccccc4c4ccccc43)c(C(C)(C)C)c1N2c1c(-c2ccccc2)cccc1-c1ccccc1]

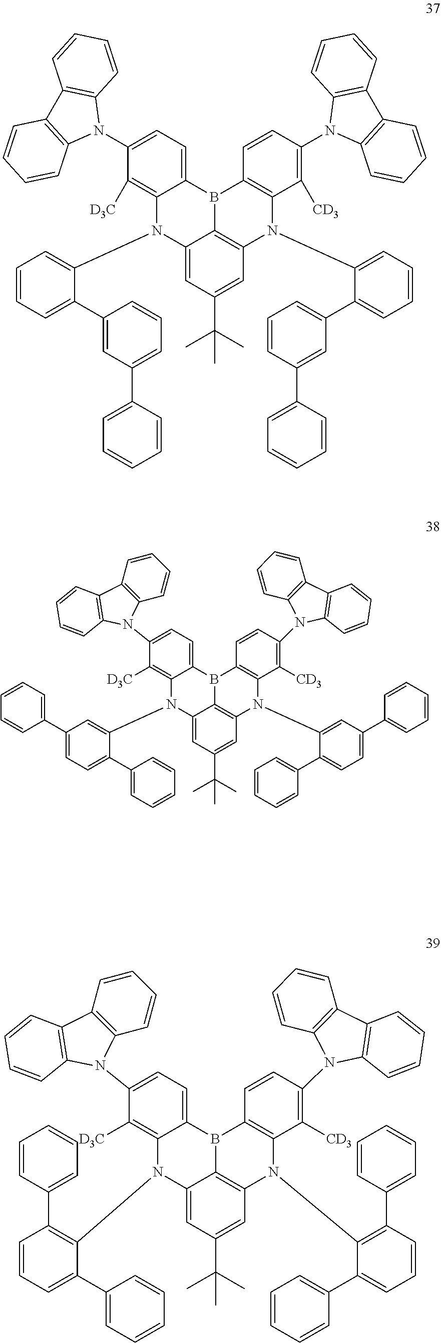

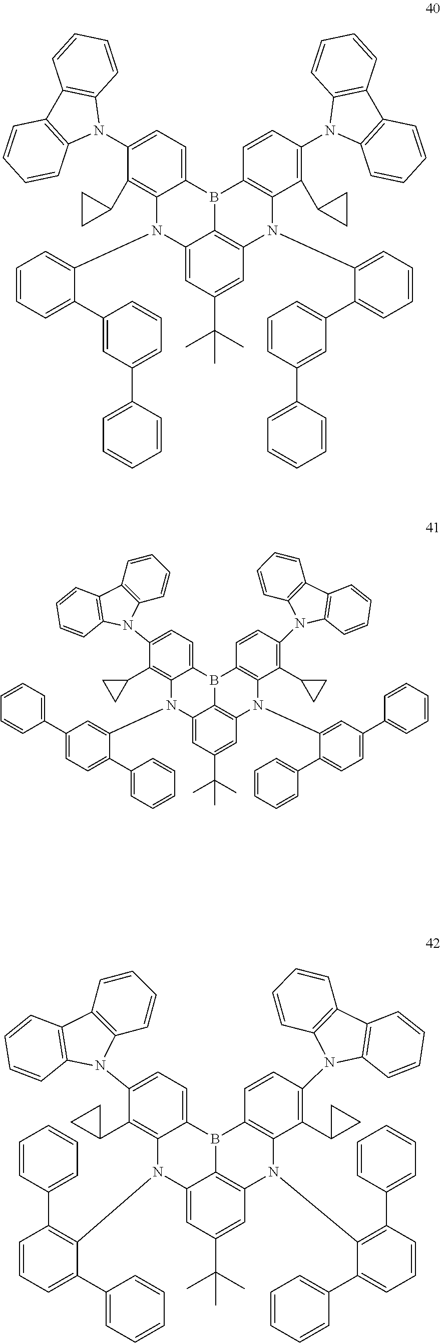 [SMILES: CC(C)(C)c1cc2c3c(c1)N(c1ccccc1-c1cccc(-c4ccccc4)c1)c1c(ccc(-n4c5ccccc5c5ccccc54)c1C1CC1)B3c1ccc(-n3c4ccccc4c4ccccc43)c(C3CC3)c1N2c1ccccc1-c1cccc(-c2ccccc2)c1 ; CC(C)(C)c1cc2c3c(c1)N(c1cc(-c4ccccc4)ccc1-c1ccccc1)c1c(ccc(-n4c5ccccc5c5ccccc54)c1C1CC1)B3c1ccc(-n3c4ccccc4c4ccccc43)c(C3CC3)c1N2c1cc(-c2ccccc2)ccc1-c1ccccc1 ; CC(C)(C)c1cc2c3c(c1)N(c1c(-c4ccccc4)cccc1-c1ccccc1)c1c(ccc(-n4c5ccccc5c5ccccc54)c1C1CC1)B3c1ccc(-n3c4ccccc4c4ccccc43)c(C3CC3)c1N2c1c(-c2ccccc2)cccc1-c1ccccc1]

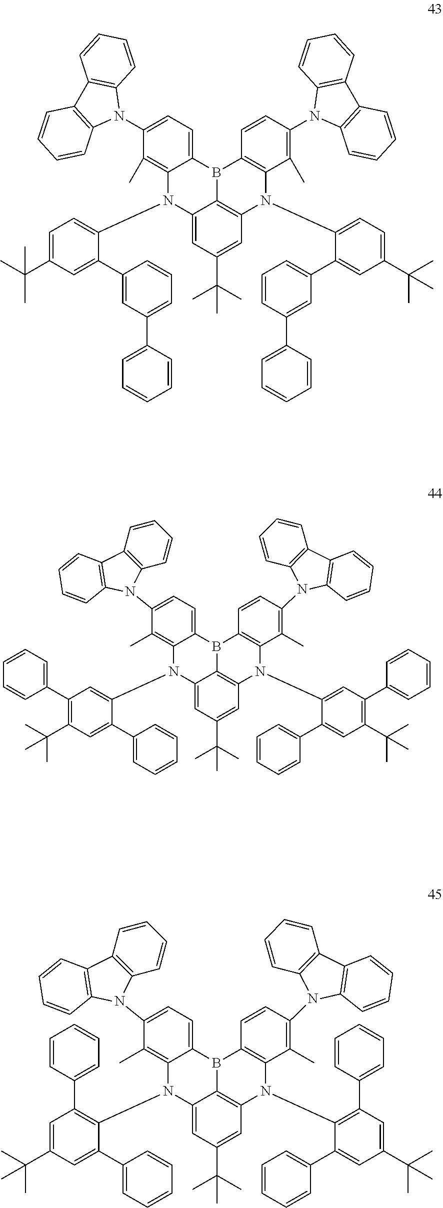

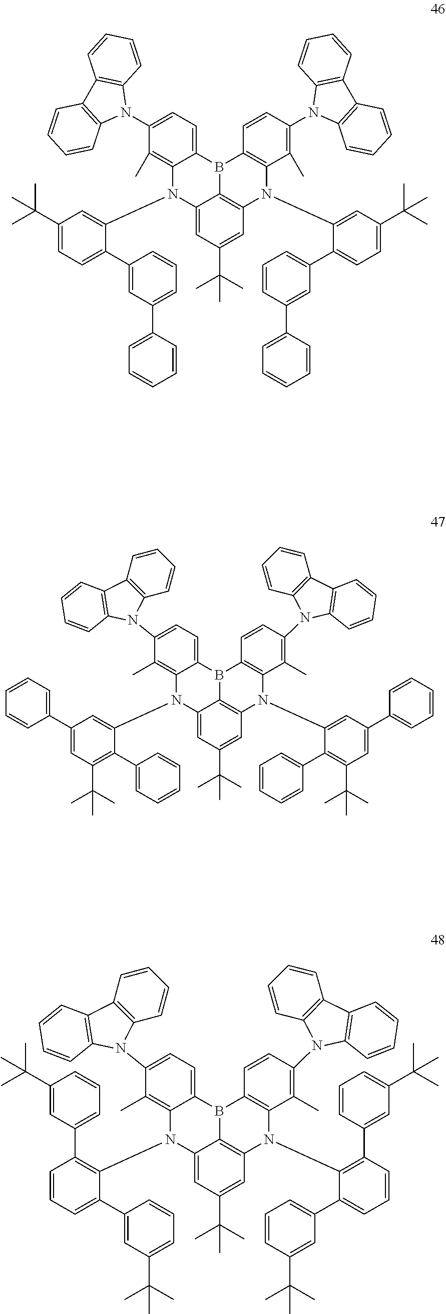

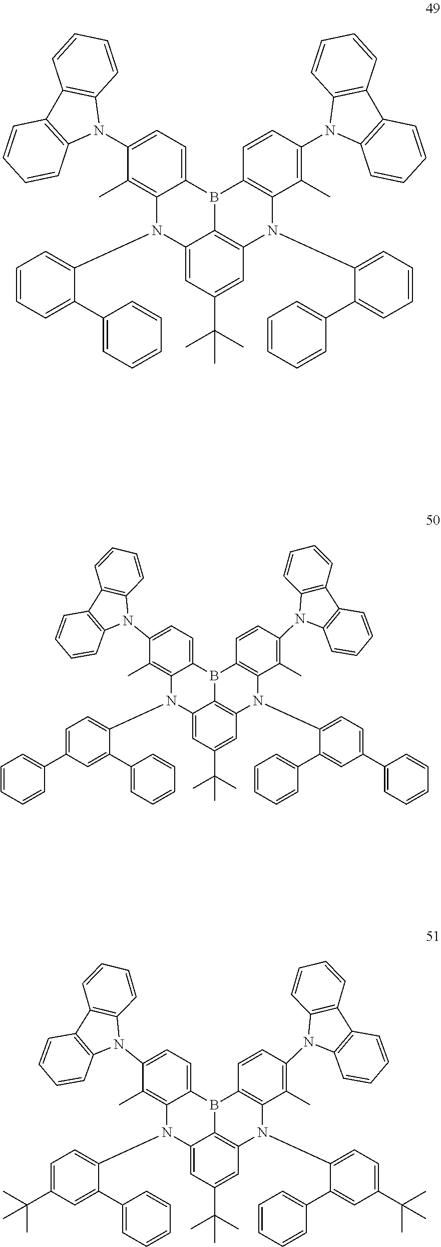 [SMILES: Cc1c(-n2c3ccccc3c3ccccc32)ccc2c1N(c1ccccc1-c1ccccc1)c1cc(C(C)(C)C)cc3c1B2c1ccc(-n2c4ccccc4c4ccccc42)c(C)c1N3c1ccccc1-c1ccccc1 ; Cc1c(-n2c3ccccc3c3ccccc32)ccc2c1N(c1ccc(-c3ccccc3)cc1-c1ccccc1)c1cc(C(C)(C)C)cc3c1B2c1ccc(-n2c4ccccc4c4ccccc42)c(C)c1N3c1ccc(-c2ccccc2)cc1-c1ccccc1 ; Cc1c(-n2c3ccccc3c3ccccc32)ccc2c1N(c1ccc(C(C)(C)C)cc1-c1ccccc1)c1cc(C(C)(C)C)cc3c1B2c1ccc(-n2c4ccccc4c4ccccc42)c(C)c1N3c1ccc(C(C)(C)C)cc1-c1ccccc1]

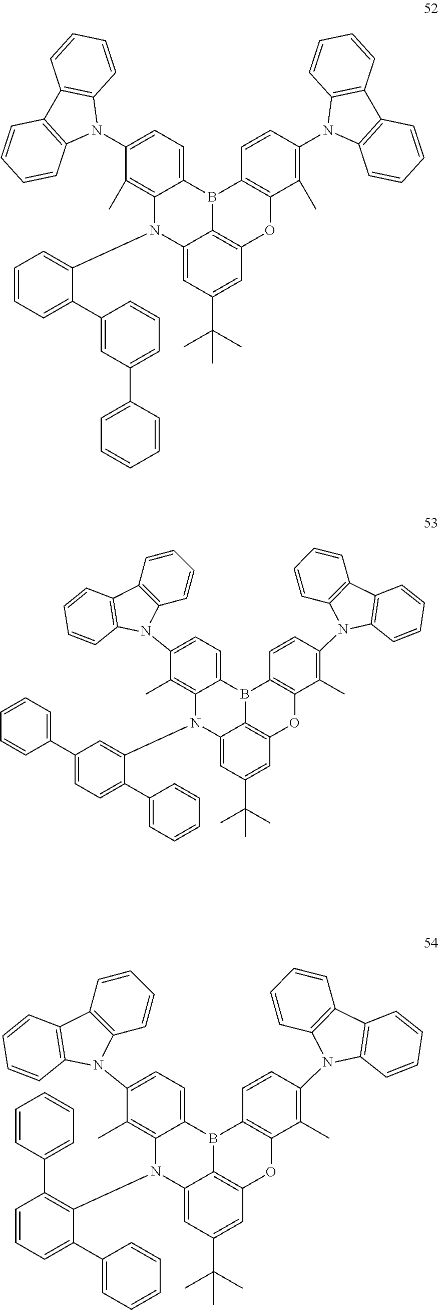 [SMILES: Cc1c(-n2c3ccccc3c3ccccc32)ccc2c1Oc1cc(C(C)(C)C)cc3c1B2c1ccc(-n2c4ccccc4c4ccccc42)c(C)c1N3c1ccccc1-c1cccc(-c2ccccc2)c1 ; Cc1c(-n2c3ccccc3c3ccccc32)ccc2c1Oc1cc(C(C)(C)C)cc3c1B2c1ccc(-n2c4ccccc4c4ccccc42)c(C)c1N3c1cc(-c2ccccc2)ccc1-c1ccccc1 ; Cc1c(-n2c3ccccc3c3ccccc32)ccc2c1Oc1cc(C(C)(C)C)cc3c1B2c1ccc(-n2c4ccccc4c4ccccc42)c(C)c1N3c1c(-c2ccccc2)cccc1-c1ccccc1]

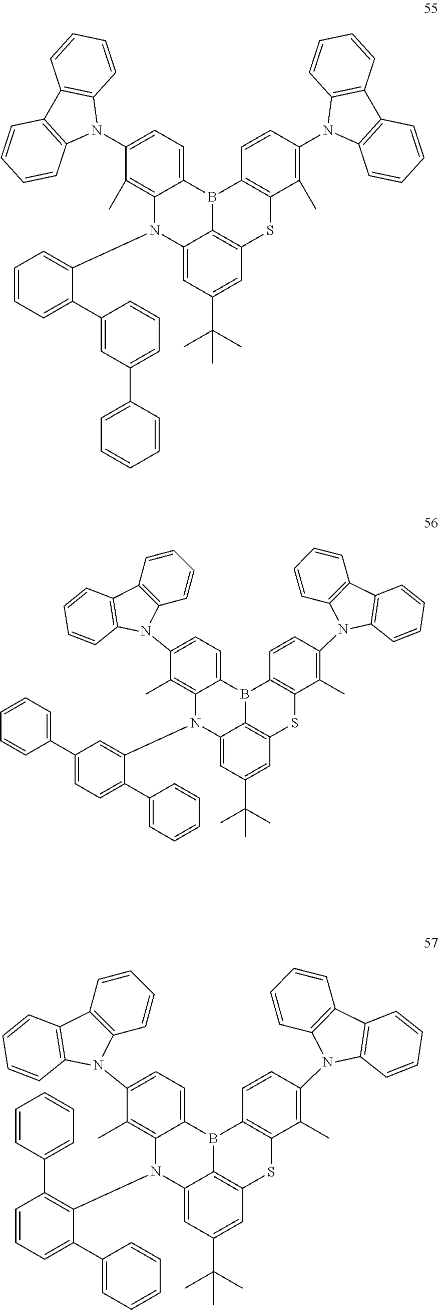 [SMILES: Cc1c(-n2c3ccccc3c3ccccc32)ccc2c1Sc1cc(C(C)(C)C)cc3c1B2c1ccc(-n2c4ccccc4c4ccccc42)c(C)c1N3c1ccccc1-c1cccc(-c2ccccc2)c1 ; Cc1c(-n2c3ccccc3c3ccccc32)ccc2c1Sc1cc(C(C)(C)C)cc3c1B2c1ccc(-n2c4ccccc4c4ccccc42)c(C)c1N3c1cc(-c2ccccc2)ccc1-c1ccccc1 ; Cc1c(-n2c3ccccc3c3ccccc32)ccc2c1Sc1cc(C(C)(C)C)cc3c1B2c1ccc(-n2c4ccccc4c4ccccc42)c(C)c1N3c1c(-c2ccccc2)cccc1-c1ccccc1]

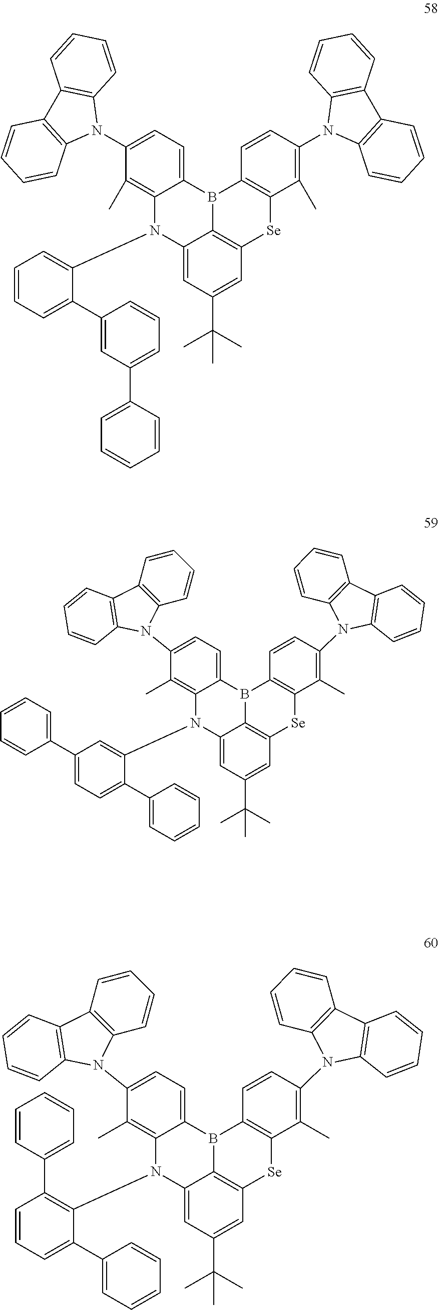 [SMILES: Cc1c(-n2c3ccccc3c3ccccc32)ccc2c1[Se]c1cc(C(C)(C)C)cc3c1B2c1ccc(-n2c4ccccc4c4ccccc42)c(C)c1N3c1ccccc1-c1cccc(-c2ccccc2)c1 ; Cc1c(-n2c3ccccc3c3ccccc32)ccc2c1[Se]c1cc(C(C)(C)C)cc3c1B2c1ccc(-n2c4ccccc4c4ccccc42)c(C)c1N3c1cc(-c2ccccc2)ccc1-c1ccccc1 ; Cc1c(-n2c3ccccc3c3ccccc32)ccc2c1[Se]c1cc(C(C)(C)C)cc3c1B2c1ccc(-n2c4ccccc4c4ccccc42)c(C)c1N3c1c(-c2ccccc2)cccc1-c1ccccc1]

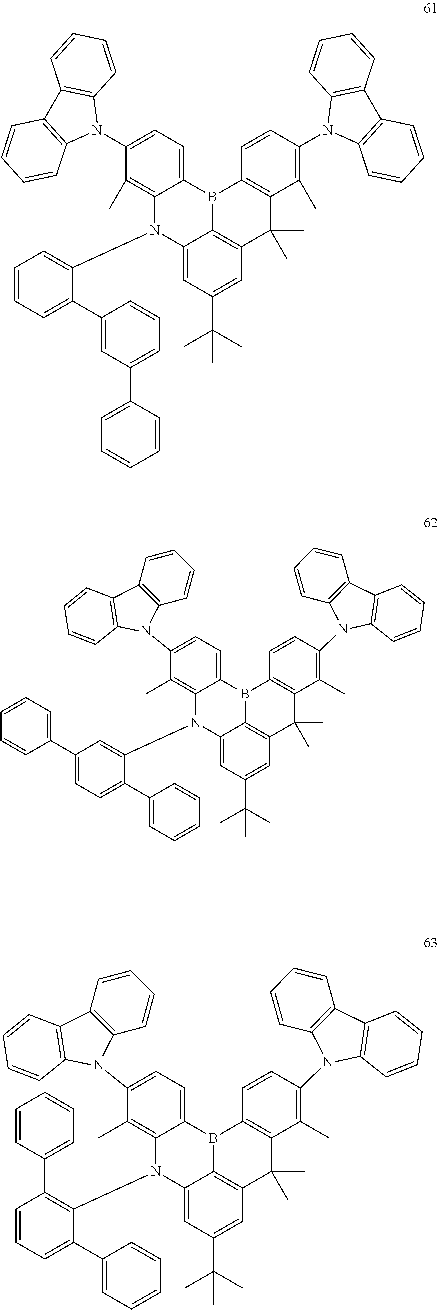 [SMILES: Cc1c(-n2c3ccccc3c3ccccc32)ccc2c1N(c1ccccc1-c1cccc(-c3ccccc3)c1)c1cc(C(C)(C)C)cc3c1B2c1ccc(-n2c4ccccc4c4ccccc42)c(C)c1C3(C)C ; Cc1c(-n2c3ccccc3c3ccccc32)ccc2c1N(c1cc(-c3ccccc3)ccc1-c1ccccc1)c1cc(C(C)(C)C)cc3c1B2c1ccc(-n2c4ccccc4c4ccccc42)c(C)c1C3(C)C ; Cc1c(-n2c3ccccc3c3ccccc32)ccc2c1N(c1c(-c3ccccc3)cccc1-c1ccccc1)c1cc(C(C)(C)C)cc3c1B2c1ccc(-n2c4ccccc4c4ccccc42)c(C)c1C3(C)C]

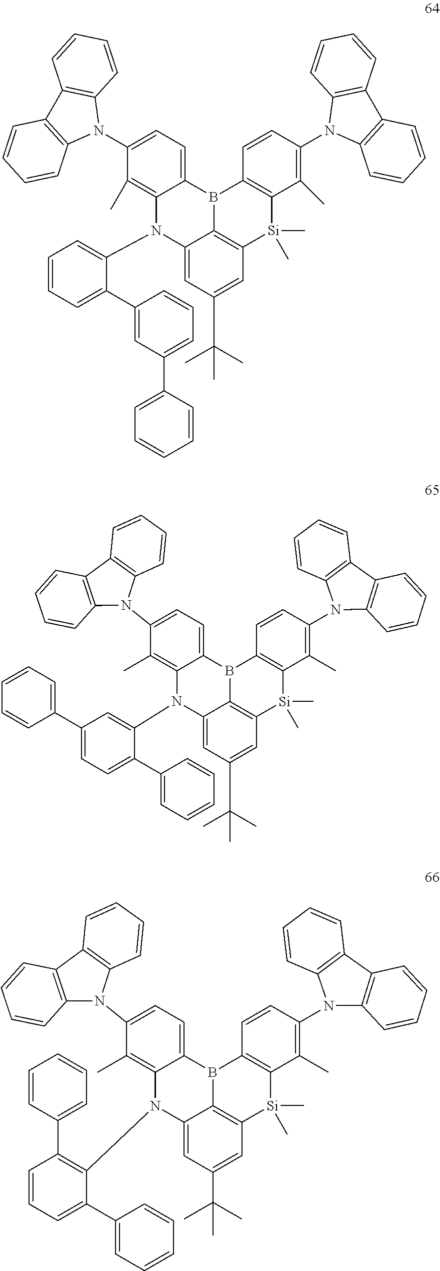 [SMILES: Cc1c(-n2c3ccccc3c3ccccc32)ccc2c1N(c1ccccc1-c1cccc(-c3ccccc3)c1)c1cc(C(C)(C)C)cc3c1B2c1ccc(-n2c4ccccc4c4ccccc42)c(C)c1[Si]3(C)C ; Cc1c(-n2c3ccccc3c3ccccc32)ccc2c1N(c1cc(-c3ccccc3)ccc1-c1ccccc1)c1cc(C(C)(C)C)cc3c1B2c1ccc(-n2c4ccccc4c4ccccc42)c(C)c1[Si]3(C)C ; Cc1c(-n2c3ccccc3c3ccccc32)ccc2c1N(c1c(-c3ccccc3)cccc1-c1ccccc1)c1cc(C(C)(C)C)cc3c1B2c1ccc(-n2c4ccccc4c4ccccc42)c(C)c1[Si]3(C)C]

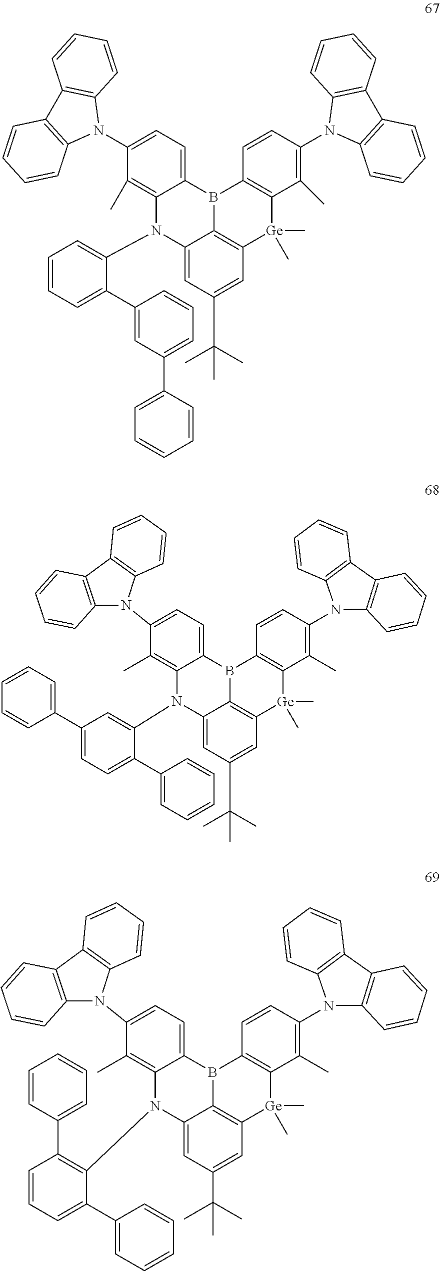

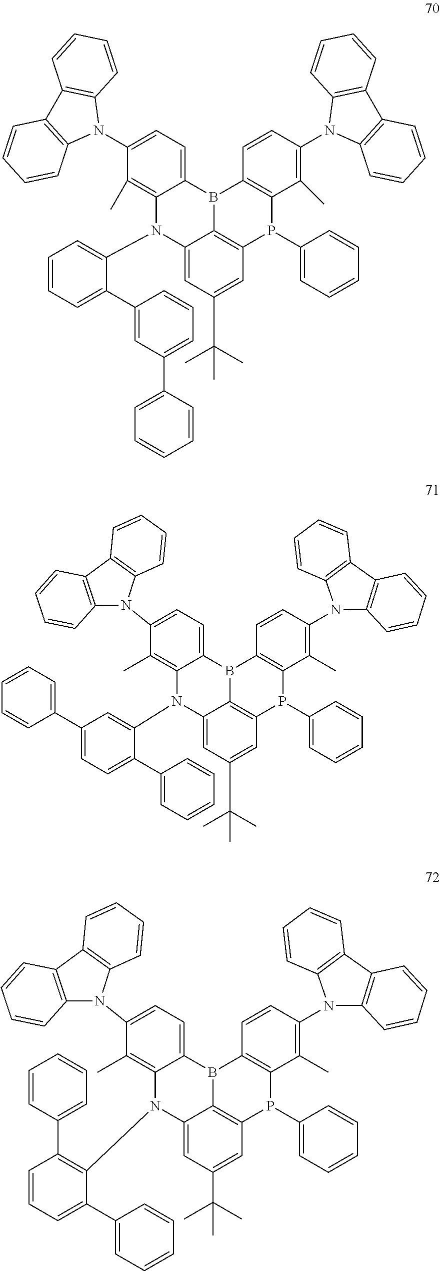 [SMILES: Cc1c(-n2c3ccccc3c3ccccc32)ccc2c1N(c1ccccc1-c1cccc(-c3ccccc3)c1)c1cc(C(C)(C)C)cc3c1B2c1ccc(-n2c4ccccc4c4ccccc42)c(C)c1P3c1ccccc1 ; Cc1c(-n2c3ccccc3c3ccccc32)ccc2c1N(c1cc(-c3ccccc3)ccc1-c1ccccc1)c1cc(C(C)(C)C)cc3c1B2c1ccc(-n2c4ccccc4c4ccccc42)c(C)c1P3c1ccccc1 ; Cc1c(-n2c3ccccc3c3ccccc32)ccc2c1N(c1c(-c3ccccc3)cccc1-c1ccccc1)c1cc(C(C)(C)C)cc3c1B2c1ccc(-n2c4ccccc4c4ccccc42)c(C)c1P3c1ccccc1]

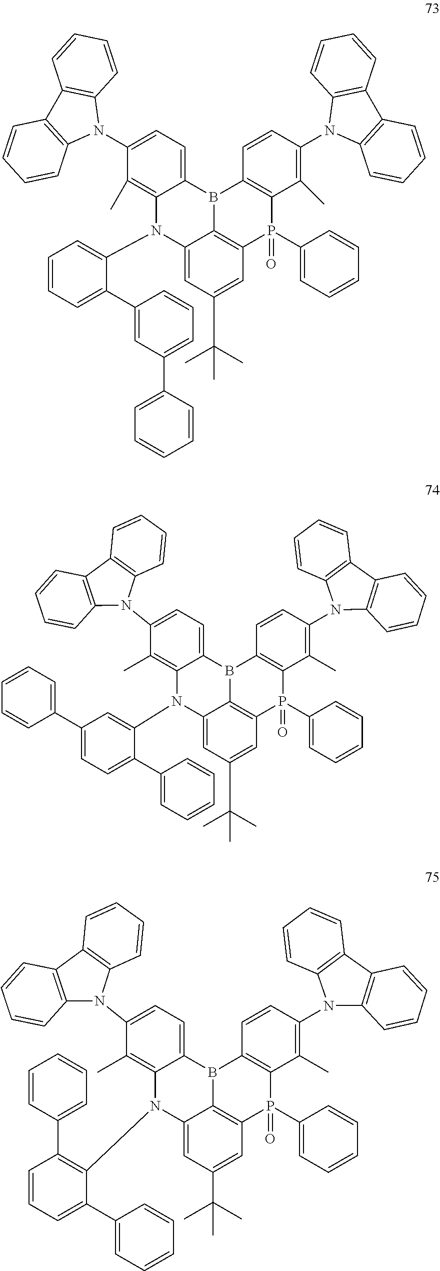 [SMILES: Cc1c(-n2c3ccccc3c3ccccc32)ccc2c1N(c1ccccc1-c1cccc(-c3ccccc3)c1)c1cc(C(C)(C)C)cc3c1B2c1ccc(-n2c4ccccc4c4ccccc42)c(C)c1P3(=O)c1ccccc1 ; Cc1c(-n2c3ccccc3c3ccccc32)ccc2c1N(c1cc(-c3ccccc3)ccc1-c1ccccc1)c1cc(C(C)(C)C)cc3c1B2c1ccc(-n2c4ccccc4c4ccccc42)c(C)c1P3(=O)c1ccccc1 ; Cc1c(-n2c3ccccc3c3ccccc32)ccc2c1N(c1c(-c3ccccc3)cccc1-c1ccccc1)c1cc(C(C)(C)C)cc3c1B2c1ccc(-n2c4ccccc4c4ccccc42)c(C)c1P3(=O)c1ccccc1]

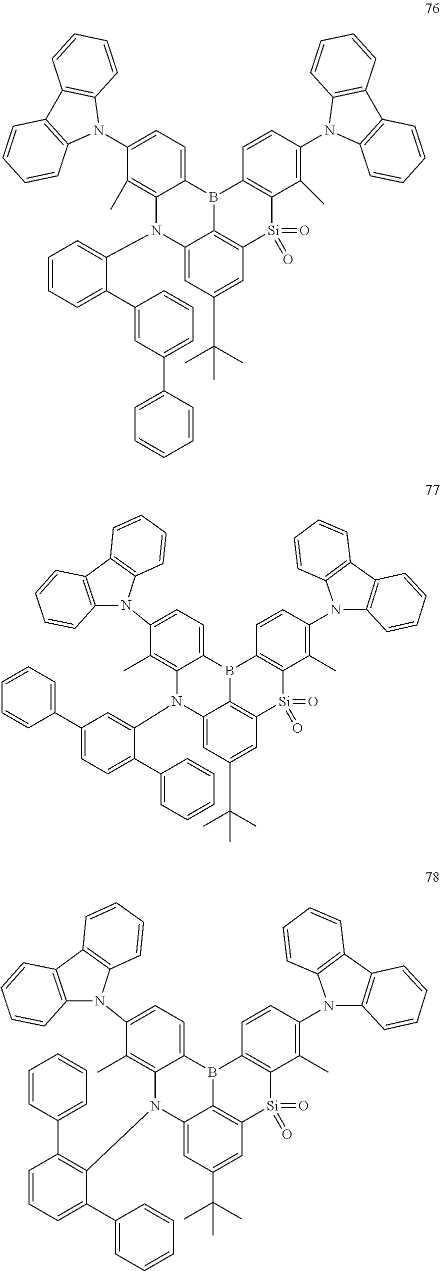

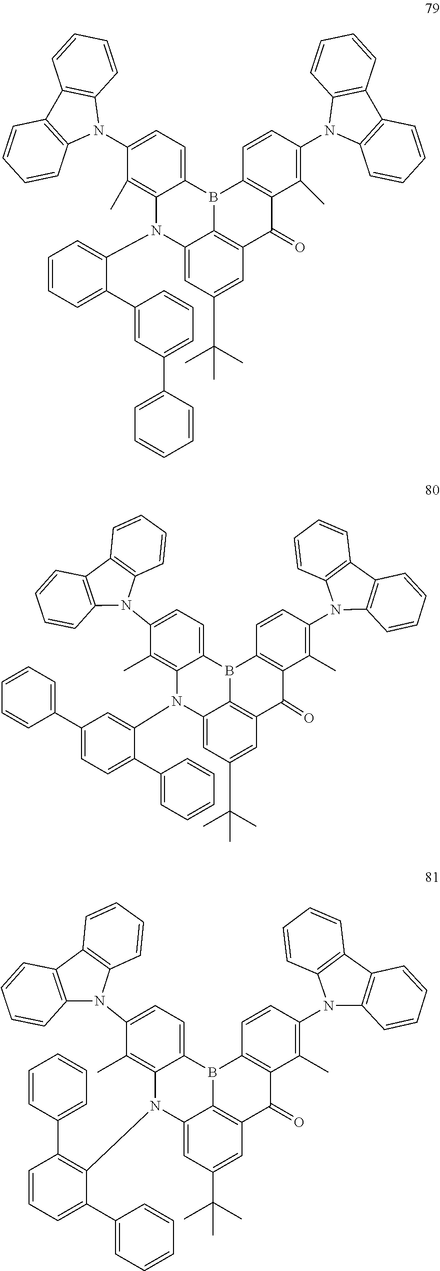 [SMILES: Cc1c(-n2c3ccccc3c3ccccc32)ccc2c1C(=O)c1cc(C(C)(C)C)cc3c1B2c1ccc(-n2c4ccccc4c4ccccc42)c(C)c1N3c1ccccc1-c1cccc(-c2ccccc2)c1 ; Cc1c(-n2c3ccccc3c3ccccc32)ccc2c1C(=O)c1cc(C(C)(C)C)cc3c1B2c1ccc(-n2c4ccccc4c4ccccc42)c(C)c1N3c1cc(-c2ccccc2)ccc1-c1ccccc1 ; Cc1c(-n2c3ccccc3c3ccccc32)ccc2c1C(=O)c1cc(C(C)(C)C)cc3c1B2c1ccc(-n2c4ccccc4c4ccccc42)c(C)c1N3c1c(-c2ccccc2)cccc1-c1ccccc1]

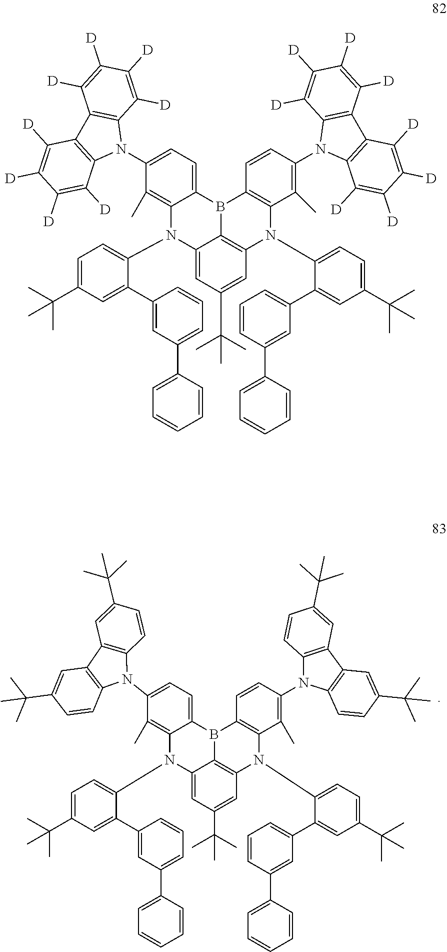 [SMILES: [2H]c1c([2H])c([2H])c2c(c1[2H])c1c([2H])c([2H])c([2H])c([2H])c1n2-c1ccc2c(c1C)N(c1ccc(C(C)(C)C)cc1-c1cccc(-c3ccccc3)c1)c1cc(C(C)(C)C)cc3c1B2c1ccc(-n2c4c([2H])c([2H])c([2H])c([2H])c4c4c([2H])c([2H])c([2H])c([2H])c42)c(C)c1N3c1ccc(C(C)(C)C)cc1-c1cccc(-c2ccccc2)c1 ; Cc1c(-n2c3ccc(C(C)(C)C)cc3c3cc(C(C)(C)C)ccc32)ccc2c1N(c1ccc(C(C)(C)C)cc1-c1cccc(-c3ccccc3)c1)c1cc(C(C)(C)C)cc3c1B2c1ccc(-n2c4ccc(C(C)(C)C)cc4c4cc(C(C)(C)C)ccc42)c(C)c1N3c1ccc(C(C)(C)C)cc1-c1cccc(-c2ccccc2)c1]

The heterocyclic compound represented by Formula 1 satisfies the aforementioned structure of Formula 1, and has a structure in which a group represented by Formula 3 is substituted onto ring CY₁ of Formula 1. Due to this structure, the heterocyclic compound represented by Formula 1 may have excellent luminescence characteristics, and in particular, may achieve short-wavelength deep blue color.

Although not limited to any particular theory, the heterocyclic compound represented by Formula 1 may have a high singlet (S₁) energy levels by having the aforementioned structure in which a group represented by Formula 3 and R₁₁ are linked at the ortho position, and thus may have high photo-orientation. Accordingly, when the heterocyclic compound is used as a luminescent material, Dexter energy transfer may be inhibited, resulting in excellent lifespan characteristics.

In addition, since the heterocyclic compound represented by Formula 1 includes a combination of R₁₁ at the ortho position of the group represented by Formula 3 with the group represented by Formula 2 (e.g., a terphenyl group), an electronic device, e.g., an organic light-emitting device, including at least one of the heterocyclic compounds represented by Formula 1 may have high efficiency and long lifespan.

A highest occupied molecular orbital (HOMO) energy level, a lowest unoccupied molecular orbital (LUMO) energy level, a S₁ energy level, and a triplet (T₁) energy level of some compounds of the heterocyclic compound represented by Formula 1 are evaluated by using the Gaussian 09 program with the molecular structure optimization obtained by B3LYP-based density functional theory (DFT), and results thereof are shown in Table 1.

TABLE 1

| | HOMO | LUMO | S₁ | T₁ |
|---|---|---|---|---|
| | (eV) | (eV) | (eV) | (eV) |
| Compound 1 | −5.059 | −1.462 | 2.973 | 2.585 |
| Compound A | −4.832 | −1.282 | 3.107 | 2.657 |

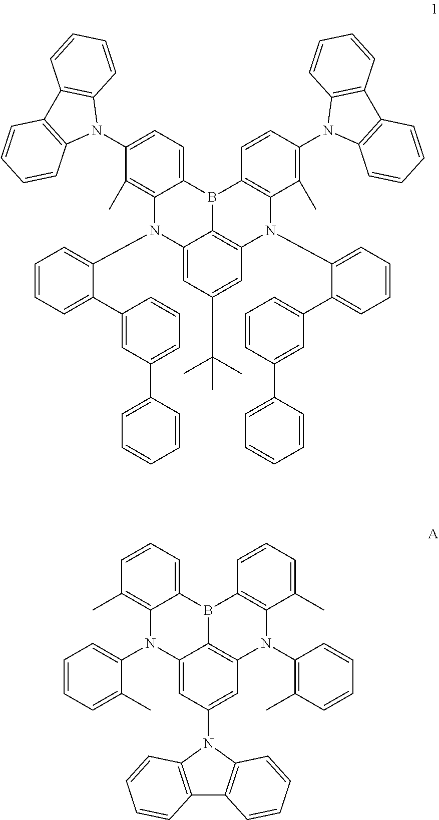 [SMILES: Cc1c(-n2c3ccccc3c3ccccc32)ccc2c1N(c1ccccc1-c1cccc(-c3ccccc3)c1)c1cc(C(C)(C)C)cc3c1B2c1ccc(-n2c4ccccc4c4ccccc42)c(C)c1N3c1ccccc1-c1cccc(-c2ccccc2)c1 ; Cc1ccccc1N1c2cc(-n3c4ccccc4c4ccccc43)cc3c2B(c2cccc(C)c21)c1cccc(C)c1N3c1ccccc1C]

Referring to Table 1, it was confirmed that the heterocyclic compound represented by Formula 1 has electrical characteristics suitable for use as a dopant (e.g., an emitter or a sensitizer) of an electronic device such as an organic light-emitting device.

In one or more embodiments, a full width at half maximum (FWHM) of the emission peak of the emission spectrum or the electroluminescence spectrum of the heterocyclic compound represented by Formula 1 may be 60 nanometers (nm) or less. For example, the FWHM of the emission peak of the emission spectrum or the electroluminescence spectrum of the heterocyclic compound represented by Formula 1 may be about 5 nm to about 50 nm, about 7 nm to about 40 nm, or about 10 nm to about 30 nm.

The method of synthesizing the heterocyclic compound represented by Formula 1 may be recognized by those skilled in the art and with reference to the Synthesis Examples to be described later.

A way to confirm the structure of the heterocyclic compound represented by Formula 1 is not particularly limited. In one or more embodiments, the structure of the heterocyclic compound may be identified by a known method (e.g., NMR, LC-MS, etc.).

### Organic Light-Emitting Device

Another aspect provides an organic light-emitting device including the heterocyclic compound represented by Formula 1.

In one or more embodiments, the organic light-emitting device includes a first electrode; a second electrode; and an organic layer arranged between the first electrode and the second electrode, wherein the organic layer includes an emission layer, and
wherein the organic layer further includes at least one of the heterocyclic compounds represented by Formula 1.

In one or more embodiments, the emission layer may include at least one of the heterocyclic compounds represented by Formula 1.

In one or more embodiments, the emission layer may include a host and an emitter, and the emitter may include at least one of the heterocyclic compounds represented by Formula 1.

In one or more embodiments, based on a weight, an amount of the host in the emission layer may be greater than an amount of the at least one heterocyclic compound represented by Formula 1 in the emission layer.

In one or more embodiments, the emission layer may further include a sensitizer.

In one or more embodiments, the sensitizer may include a phosphorescent compound, a delayed fluorescence compound, or a combination thereof.

Detailed description of the aforementioned host, emitter, and sensitizer are as provided herein.

When the organic light-emitting device includes the emission layer including at least one of the aforementioned heterocyclic compounds represented by Formula 1, the organic light-emitting device may have a relatively narrow FWHM of the emission peak of the electroluminescence spectrum, excellent efficiency, and long lifespan characteristics.

In one or more embodiments, the heterocyclic compound represented by Formula 1 may serve as a dopant (e.g., an emitter or a sensitizer) in the emission layer, and the emission layer may further include a host (that is, in the emission layer, an amount of the at least one heterocyclic compound represented by Formula 1 may be less than an amount of the host in the emission layer, based on weight).

In one or more embodiments, the emission layer may emit a blue light. In one or more embodiments, the emission layer may emit a blue light having a maximum emission wavelength of about 410 nm to about 490 nm.

The expressions that “(emission layer) includes at least one of the heterocyclic compounds represented by Formula 1” and an “(emission layer) includes at least one heterocyclic compound represented by Formula 1” may be used exchangeably herein and may be construed as meaning that the “(emission layer) may include one heterocyclic compound of Formula 1 or two or more different heterocyclic compounds of Formula 1”.

In one or more embodiments, the emission layer may include only Compound 1 as the at least one heterocyclic compound represented by Formula 1. In this regard, Compound 1 may be present in the emission layer of the organic light-emitting device. In one or more embodiments, the emission layer may include Compounds 1 and 2 as the at least one heterocyclic compound represented by Formula 1, wherein Compounds 1 and 2 are different from each other.

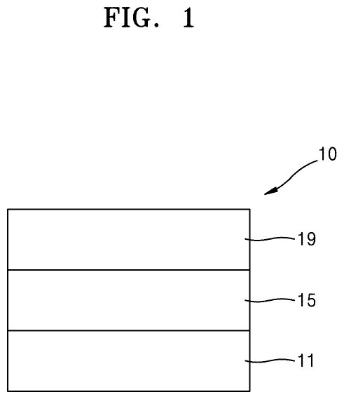

### Description of FIG. 1

FIG. 1 is a schematic cross-sectional view of an organic light-emitting device 10 according to one or more embodiments. Hereinafter, the structure and manufacturing method of the organic light-emitting device 10 according to one or more embodiments will be described in connection with the FIG. 1.

In FIG. 1, the organic light-emitting device 10 includes a first electrode 11, a second electrode 19 facing the first electrode 11, and an organic layer 15 arranged between the first electrode 11 and the second electrode 19.

The organic layer 15 includes an emission layer, and may further include a hole transport region arranged between the first electrode 11 and the emission layer, and an electron transport region arranged between the emission layer and the second electrode 19.

A substrate may be additionally arranged under the first electrode 11 or on the second electrode 19. For use as the substrate, a substrate generally used in organic light-emitting devices, e.g., a glass substrate or a transparent plastic substrate, having excellent mechanical strength, thermal stability, transparency, surface smoothness, ease of handling, and/or water repellency may be used.

### First Electrode 11

The first electrode 11 may be formed by, for example, depositing or sputtering, onto the substrate, a material for forming the first electrode 11. The first electrode 11 may be an anode. The material for forming the first electrode 11 may be selected from materials with a high work function for easy hole injection.

The first electrode 11 may be a reflective electrode, a transflective electrode, or a transmissive electrode. In one or more embodiments, when the first electrode 11 is a transmissive electrode, the material for forming the first electrode 11 may include indium tin oxide (ITO), indium zinc oxide (IZO), tin oxide (SnO₂), zinc oxide (ZnO), or a combination thereof. In one or more embodiments, when the first electrode 11 is a semi-transmissive electrode or a reflective electrode, the material for forming the first electrode 11 may be magnesium (Mg), silver (Ag), aluminum (Al), aluminum-lithium (Al—Li), calcium (Ca), magnesium-indium (Mg—In), magnesium-silver (Mg—Ag), or a combination thereof, but embodiments are not limited thereto.

The first electrode 11 may have a single-layer structure or a multi-layer structure including a plurality of layers.

### Emission Layer

The emission layer may include at least one of the heterocyclic compounds represented by Formula 1.

A thickness of the emission layer may be about 100 angstroms (Å) to about 1,000 Å, for example, about 200 Å to about 600 Å. When the thickness of the emission layer is within these ranges, excellent luminescence characteristics may be obtained without a substantial increase in driving voltage.

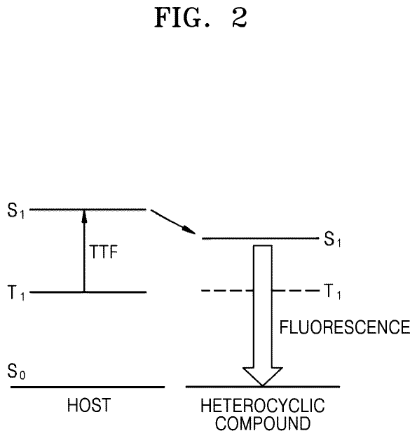

### Description of FIG. 2

In one or more embodiments, the heterocyclic compound represented by Formula 1 may serve as a fluorescent emitter.

In one or more embodiments, the emission layer may further include a host (hereinafter referred to as ‘Host A’, wherein Host A is the not the same as the heterocyclic compound represented by Formula 1). Host A may be understood with reference to a host material described herein, but embodiments are not limited thereto. Host A may serve as a fluorescent host.

Referring to FIG. 2, the energy transfer according to one or more embodiments is described as follows.

Singlet excitons may be formed in Host A of the emission layer, and these singlet excitons formed in Host A may be transferred to the fluorescent emitter through Förster energy transfer (or, Förster resonance energy transfer (FRET)).

Since the singlet excitons formed in Host A only account for 25%, the efficiency of the organic light-emitting device may be further improved by allowing triplet excitons, which are formed in Host A and account for 75%, to fuse with each other and be converted to singlet excitons. That is, by using the triplet-triplet fusion (TTF) mechanism, the efficiency of the organic light-emitting device may be further improved.

In one or more embodiments, a ratio of emission components emitted from the heterocyclic compound represented by Formula 1 to the total emission components emitted from the emission layer may be 80% or more, for example, 90% or more. In one or more embodiments, a ratio of emission components emitted from the heterocyclic compound represented by Formula 1 to the total emission components emitted from the emission layer may be 95% or more.

Here, the heterocyclic compound represented by Formula 1 may emit phosphorescence or delayed fluorescence, whereas the host may not emit a light.

In one or more embodiments, when the emission layer further includes Host A in addition to the heterocyclic compound represented by Formula 1, the amount of the heterocyclic compound represented by Formula 1 in the emission layer may be, based on 100 parts by weight of the emission layer, 50 parts by weight or less, for example, 30 parts by weight less or less, and the amount of Host A in the emission layer amount may be, based on 100 parts by weight of the emission layer, 50 parts by weight or more, for example, 70 parts by weight or more, but embodiments are not limited thereto.

In one or more embodiments, when the emission layer further includes Host A in addition to the heterocyclic compound represented by Formula 1, Host A and the heterocyclic compound may satisfy Condition A:

$${E ( {H}_{A} )}_{S 1} > {E}_{S 1} \qquad Condition A$$

wherein, in Condition A,
E(H_{A})_{S1} represents a lowest excitation singlet energy level of Host A, and
E_{S1} represents a lowest excitation singlet energy level of the heterocyclic compound represented by Formula 1.

Here, E(H_{A})_{S1} and E_{S1} are evaluated by using the DFT method of the Gaussian program, which is structure-optimized at the B3LYP/6-31G(d,p) basis sets level.

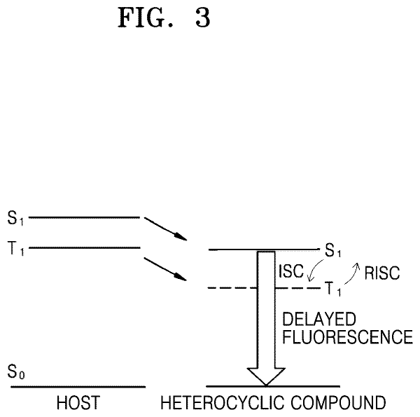

### Description of FIG. 3

In one or more embodiments, the heterocyclic compound represented by Formula 1 may serve as a delayed fluorescence emitter.

In one or more embodiments, the emission layer may further include a host (hereinafter referred to as ‘Host B’, wherein Host B is the not the same as the heterocyclic compound represented by Formula 1). Host B may be understood with reference to a host material described herein, but embodiments are not limited thereto.

Referring to FIG. 3, the energy transfer according to one or more embodiments is described as follows.

The singlet excitons which are formed in Host B of the emission layer and account for 25%, may be transferred to the delayed fluorescence emitter. In addition, the triplet excitons which are formed in Host B of the emission layer and account for 75%, may be transferred to the delayed fluorescence emitter through Dexter energy transfer. Here, at least a part of the energy at a singlet state of the delayed fluorescence emitter may be transferred to the energy at a triplet state by intersystem crossing (ISC). The energy transferred to the triplet state of the delayed fluorescence emitter may be transferred back to the singlet state by reverse intersystem crossing (RISC). Accordingly, all of the singlet and triplet excitons generated in the emission layer may be transferred to the heterocyclic compound, thereby obtaining the organic light-emitting device having improved efficiency.

In one or more embodiments, a ratio of emission components emitted from the heterocyclic compound represented by Formula 1 to the total emission components emitted from the emission layer may be 80% or more, for example, 90% or more. In one or more embodiments, a ratio of emission components emitted from the heterocyclic compound represented by Formula 1 to the total emission components emitted from the emission layer may be 95% or more.

In this regard, the heterocyclic compound represented by Formula 1 may emit fluorescence and/or delayed fluorescence, and the emission components of the heterocyclic compound represented by Formula 1 may be the sum of prompt emission components of the heterocyclic compound and delayed fluorescence components associated with RISC of the heterocyclic compound. Also, Host B may not emit a light.

In one or more embodiments, when the emission layer further includes Host B in addition to the heterocyclic compound represented by Formula 1, the amount of the heterocyclic compound represented by Formula 1 in the emission layer may be, based on 100 parts by weight of the emission layer, 50 parts by weight or less, for example, 30 parts by weight or less, and the amount of Host B in the emission layer amount may be, based on 100 parts by weight of the emission layer, 50 parts by weight or more, for example, 70 parts by weight or more, but embodiments are not limited thereto.

In one or more embodiments, when the emission layer further includes Host B in addition to the heterocyclic compound represented by Formula 1, Host B and the heterocyclic compound represented by Formula 1 may satisfy Condition B:

$${E ( {H}_{B} )}_{S 1} > {E}_{S 1} \qquad Condition B$$

wherein, in Condition B,
E(H_{B})_{S1} represents a lowest excitation singlet energy level of Host B, and
E_{S1} represents a lowest excitation singlet energy level of the heterocyclic compound represented by Formula 1.

Here, E(H_{B})_{S1} and E_{S1} are evaluated by using the DFT method of the Gaussian program, which is structure-optimized at the B3LYP/6-31G(d,p) basis sets level.

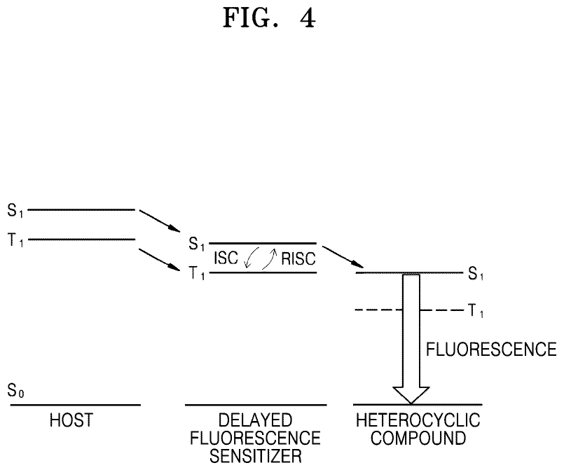

### Description of FIG. 4

In one or more embodiments, the heterocyclic compound represented by Formula 1 may be used as a fluorescence emitter, and the emission layer may include a sensitizer, specifically, a delayed fluorescence sensitizer. In this embodiment, the emission layer may further include a host (hereinafter referred to as ‘Host C’, wherein Host C is not the same as the heterocyclic compound represented by Formula 1 and the sensitizer) and a sensitizer (hereinafter referred to as ‘Sensitizer A’, wherein Sensitizer A is not the same as Host C and the heterocyclic compound represented by Formula 1). Host C and Sensitizer A may be understood by referring to a host material and a sensitizer material described later, but embodiments are not limited thereto.

In one or more embodiments, a ratio of emission components emitted from the heterocyclic compound represented by Formula 1 to the total emission components emitted from the emission layer may be 80% or more, for example, 90% or more (or for example, 95% or more). For example, the heterocyclic compound represented by Formula 1 may emit fluorescence. Also, each of Host C and Sensitizer A may not emit a light.

Referring to FIG. 4, the energy transfer according to one or more embodiments is described as follows.

In Host C of the emission layer, singlet and triplet excitons are formed, and these singlet and triplet excitons formed in Host C may be transferred to Sensitizer A first, and then transferred back to the heterocyclic compound represented by Formula 1 through FRET. The singlet excitons, which are formed in Host C and account for 25%, may be transferred to Sensitizer A through FRET, and the energy of triplet excitons, which are formed in Host C and account for 75%, may be transferred to the singlet and triplet states of Sensitizer A. Among these, at least a part of the energy at a singlet state of Sensitizer A may be transferred to the energy at a triplet state by ISC. The energy transferred to the triplet state of Sensitizer A may be transferred to the singlet state by RISC, and then, the singlet energy of Sensitizer A may be transferred to the heterocyclic compound represented by Formula 1 through FRET.

Accordingly, all of the singlet and triplet excitons generated in the emission layer may be transferred to a dopant (e.g., an emitter), thereby obtaining the organic light-emitting device having improved efficiency. In addition, since the organic light-emitting device thus obtained has a significantly reduced energy loss, the lifespan characteristics of the organic light-emitting device may be also improved.

Referring to FIG. 4, when the emission layer further includes Host C and Sensitizer A in addition to the heterocyclic compound represented by Formula 1, the heterocyclic compound, Host C and Sensitizer A may satisfy Condition C-1 and/or C-2:

$${S}_{1} ( {H}_{C} ) \geq {S}_{1} ( {S}_{A} ) \qquad Condition C - 1$$

$${S}_{1} ( {S}_{A} ) \geq {S}_{1} ( HC ) \qquad Condition C - 2$$

wherein, in Conditions C-1 and C-2,
S₁(H_{c}) represents a lowest excitation singlet energy level of Host C,
S₁(S_{A}) represents a lowest excitation singlet energy level of Sensitizer A, and
S₁(HC) represents a lowest excitation singlet energy level of the heterocyclic compound represented by Formula 1.

Here, S₁(H_{C}), S₁(S_{A}), and S₁(H_{C}) are evaluated by using the DFT method of the Gaussian program, which is structure-optimized at the B3LYP/6-31G(d,p) basis level.

When Host C, Sensitizer A, and the heterocyclic compound represented by Formula 1 satisfy Condition C-1 and/or C-2, FRET from Sensitizer A to the heterocyclic compound represented by Formula 1 may be promoted, thereby improving the luminescence efficiency of the organic light-emitting device.

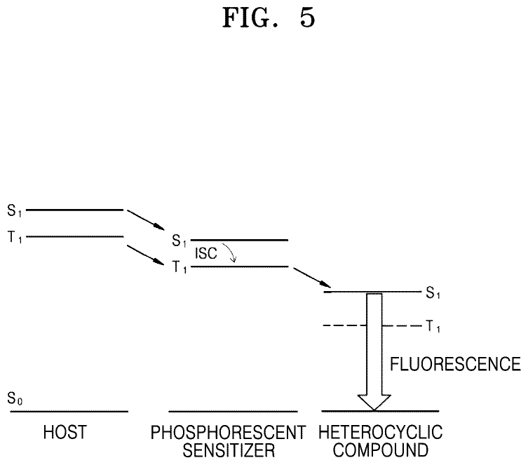

### Description of FIG. 5

In one or more embodiments, the heterocyclic compound represented by Formula 1 may be used as a fluorescent emitter, and the emission layer may include a sensitizer, specifically, a phosphorescent sensitizer.

In this embodiment, the emission layer may further include a host (hereinafter referred to as ‘Host D’, wherein Host D is not the same as the heterocyclic compound represented by Formula 1 and the sensitizer) and a sensitizer (hereinafter referred to as ‘Sensitizer B’, wherein Sensitizer B is not the same as Host D and the heterocyclic compound represented by Formula 1). Host D and Sensitizer B may be understood by referring to a host material and a sensitizer material described herein, but embodiments are not limited thereto.

In one or more embodiments, a ratio of emission components emitted from the heterocyclic compound represented by Formula 1 to the total emission components emitted from the emission layer may be 80% or more, for example, 90% or more (or for example, 95% or more). For example, the heterocyclic compound represented by Formula 1 may emit fluorescence. Also, each of Host D and Sensitizer B may not emit a light.

Referring to FIG. 5, the energy transfer according to one or more embodiments is described as follows.

Triplet excitons, which are formed in Host D of the emission layer and account for 75%, may be transferred to Sensitizer B through Dexter energy transfer, and the energy of singlet excitons, which are formed in Host D of the emission layer and account for 25%, may be transferred to the singlet and triplet states of Sensitizer B. Among these, the energy transferred to the singlet state of Sensitizer B may be transferred to the triplet state by ISC, and then, the triplet energy of Sensitizer B may be transferred to the heterocyclic compound represented by Formula 1 through FRET.

Accordingly, all of the singlet and triplet excitons generated in the emission layer may be transferred to a dopant (e.g., an emitter), thereby obtaining the organic light-emitting device having improved efficiency. In addition, since the organic light-emitting device thus obtained has a significantly reduced energy loss, the lifespan characteristics of the organic light-emitting device may be also improved.

In one or more embodiments, when the emission layer further includes Host D and Sensitizer B in addition to the heterocyclic compound represented by Formula 1, the heterocyclic compound, Host D and Sensitizer B may satisfy Condition D-1 and/or D-2:

$${T}_{1} ( {H}_{D} ) \geq {T}_{1} ( {S}_{B} ) \qquad Condition D - 1$$

$${T}_{1} ( {S}_{B} ) \geq {S}_{1} ( HC ) \qquad Condition D - 2$$

wherein, in Conditions D-1 and D-2,
T₁(H_{D}) represents a lowest excitation triplet energy level of Host D,
T₁(S_{B}) represents a lowest excitation triplet energy level of Sensitizer B, and
S₁(HC) represents a lowest excitation singlet energy level of the heterocyclic compound represented by Formula 1.

Here, T₁(H_{D}), T₁(S_{B}), and S₁(H_{C}) are evaluated by using the DFT method of the Gaussian program, which is structure-optimized at the B3LYP/6-31G(d,p) basis level.

When Host D, Sensitizer B, and the heterocyclic compound represented by Formula 1 satisfy Condition D-1 and/or D-2, FRET from Sensitizer B to the heterocyclic compound represented by Formula 1 may be promoted, thereby improving the luminescence efficiency of the organic light-emitting device.

In one or more embodiments, the amount of the sensitizer in the emission layer may be about 5 wt % to about 50 wt %, for example, about 10 wt % to about 30 wt %, based on total weight of the emission layer. When the amount is within these ranges, the energy transfer in the emission layer may be effectively achieved, and thus the organic light-emitting device having high efficiency and long lifespan may be implemented.

In one or more embodiments, the amount of the heterocyclic compound represented by Formula 1 in the emission layer may be about 0.01 wt % to about 15 wt %, for example, about 0.05 wt % to about 3 wt %, based on total weight of the emission layer, but embodiments are not limited thereto.

In one or more embodiments, the heterocyclic compound represented by Formula 1 may further satisfy Condition 5:

$$0 μs < {T}_{decay} ( H C ) < 5 μs \qquad Condition 5$$

wherein, in Condition 5,
T_{decay}(HC) represents the decay time (microseconds, μs) of the heterocyclic compound represented by Formula 1.

The decay time of the heterocyclic compound represented by Formula 1 may be calculated from a time-resolved photoluminescence (TRPL) spectrum at room temperature for a 40 nm-thick film (hereinafter referred to as “Film HC”) which is obtained by vacuum-co-depositing the host and the heterocyclic compound represented by Formula 1 on a quartz substrate at a vacuum pressure of 10⁻⁷ torr, wherein the host and the heterocyclic compound represented by Formula 1 are included at a weight ratio of 90:10 in the emission layer.

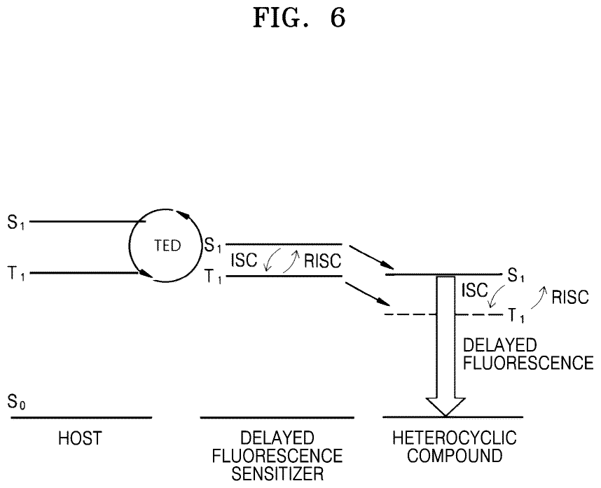

### Description of FIG. 6

In one or more embodiments, the heterocyclic compound represented by Formula 1 may be used as a delayed fluorescence emitter, and the emission layer may include a sensitizer, specifically, a delayed fluorescence emitter.

In this embodiment, the emission layer may further include a host (hereinafter referred to as ‘Host E’, wherein Host E is not the same as the heterocyclic compound represented by Formula 1 and the sensitizer) and a sensitizer (hereinafter referred to as ‘Sensitizer C’, wherein Sensitizer C is not the same as Host E and the heterocyclic compound). Host E and Sensitizer C may be understood by referring to a host material and a sensitizer material described herein, but embodiments are not limited thereto.

In one or more embodiments, a ratio of emission components emitted from the heterocyclic compound represented by Formula 1 to the total emission components emitted from the emission layer may be 80% or more, for example, 90% or more (or for example, 95% or more). For example, the heterocyclic compound represented by Formula 1 may emit fluorescence and/or delayed fluorescence. Also, each of Host E and Sensitizer C may not emit a light.

In this regard, the heterocyclic compound represented by Formula 1 may emit fluorescence and/or delayed fluorescence, and the emission components of the heterocyclic compound represented by Formula 1 may be the sum of prompt emission components of the heterocyclic compound represented by Formula 1 and delayed fluorescence components associated with RISC of the heterocyclic compound represented by Formula 1.

Referring to FIG. 6, the energy transfer according to one or more embodiments is described as follows.

The singlet excitons, which are formed in Host E of the emission layer and account for 25%, may be transferred to the singlet state of Sensitizer C through FRET, and the energy of triplet excitons, which are formed in Host E of the emission layer and account for 75%, may be transferred to the triplet state of Sensitizer C. Then, the singlet energy of Sensitizer C may be transferred back to the heterocyclic compound represented by Formula 1 through FRET, and the triplet energy of Sensitizer C may be transferred to the heterocyclic compound represented by Formula 1 through Dexter energy transfer. Among these, the energy transferred to the triplet state of Sensitizer C may be transferred back to the singlet state by RISC. Also, in the case of Sensitizer C, the energy of triplet excitons formed in Sensitizer C may be transferred to Host E by triplet exciton distributing (TED), and then transferred back to the heterocyclic compound represented by Formula 1, thereby emitting light through RISC.

Accordingly, all of the singlet and triplet excitons generated in the emission layer may be transferred to a dopant (e.g., an emitter), thereby obtaining the organic light-emitting device having improved efficiency. In addition, since the organic light-emitting device thus obtained has a significantly reduced energy loss, the lifespan characteristics of the organic light-emitting device may be also improved.

In one or more embodiments, when the emission layer further includes Host E and Sensitizer C in addition to the heterocyclic compound represented by Formula 1, the heterocyclic compound, Host E and Sensitizer C may satisfy Condition E-1, E-2, and/or E-3:

$${S}_{1} ( {H}_{E} ) \geq {S}_{1} ( {S}_{C} ) \qquad Condition E - 1$$

$${S}_{1} ( {S}_{C} ) \geq {S}_{1} ( HC ) \qquad Condition E - 2$$

$${T}_{1} ( {S}_{C} ) \geq {T}_{1} ( HC ) \qquad Condition E - 3$$

wherein, in Conditions E-1, E-2, and E-3,
S₁(H_{E}) represents a lowest excitation singlet energy level of Host E,
S₁(S_{C}) represents a lowest excitation singlet energy level of Sensitizer C,
S₁(H_{C}) represents a lowest excitation singlet energy level of the heterocyclic compound represented by Formula 1,
T₁(S_{C}) represents a lowest excitation triplet energy level of Sensitizer C, and
T₁(H_{C}) represents a lowest excitation triplet energy level of the heterocyclic compound represented by Formula 1.

Here, S₁(H_{E}), S₁(S_{C}), S₁(H_{C}), T₁(S_{C}), and T₁(H_{C}) are evaluated by using the DFT method of the Gaussian program, which is structure-optimized at the B3LYP/6-31G(d,p) basis sets level.

When Host E, Sensitizer C, and the heterocyclic compound represented by Formula 1 satisfy Condition E-1, E-2, and/or E-3, Dexter transfer and FRET from Sensitizer C to the heterocyclic compound represented by Formula 1 may be promoted, thereby improving the luminescence efficiency of the organic light-emitting device.

In one or more embodiments, the amount of Sensitizer C in the emission layer may be about 5 wt % to about 50 wt %, for example, about 10 wt % to about 30 wt %, based on total weight of the emission layer. When the amount is within these ranges, the energy transfer in the emission layer may be effectively achieved, and thus the organic light-emitting device having high efficiency and long lifespan may be implemented.

In one or more embodiments, the amount of the heterocyclic compound represented by Formula 1 in the emission layer may be about 0.01 wt % to about 15 wt %, for example, about 0.05 wt % to about 3 wt %, based on total weight of the emission layer, but embodiments are not limited thereto.

### Host in Emission Layer

In one or more embodiments, the host may not include a metal atom.

In one or more embodiments, the host may include at least one of a fluorene-containing compound, a carbazole-containing compound, a dibenzofuran-containing compound, a dibenzothiophene-containing compound, an indenocarbazole-containing compound, an indolocarbazole-containing compound, a benzofurocarbazole-containing compound, a benzothienocarbazole-containing compound, an acridine-containing compound, a dihydroacridine-containing compound, a triindolobenzene-containing compound, a pyridine-containing compound, a pyrimidine-containing compound, a triazine-containing compound, a silicon-containing compound, a cyano group-containing compound, a phosphine oxide-containing compound, a sulfoxide-containing compound, or a sulfonyl-containing compound.

For example, the host may be a compound, which includes at least one carbazole ring and at least one cyano group, or a phosphine oxide-containing compound.

In one or more embodiments, the host may consist of one type of host. When the host consists of one type of host, the one type of host may be a bipolar host, an electron-transporting host, or a hole-transporting host, which will be described herein.

In one or more embodiments, the host may be a mixture of two or more types of different hosts. In one or more embodiments, the host may be a mixture of an electron-transporting host and a hole-transporting host, a mixture of two types of different electron-transporting hosts, or a mixture of two types of different hole-transporting hosts. The electron-transporting host and the hole-transporting host may be understood by referring to a description to be presented later.

In one or more embodiments, the host may include an electron-transporting host including at least one electron-transporting moiety; and a hole-transporting host not including an electron-transporting moiety.

The electron-transporting moiety used herein may be a cyano group, a π electron-deficient nitrogen-containing ring group, or a group represented by one of the following formulae:

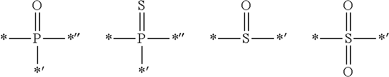

wherein, in the formulae above, *, *′, and *″ each indicate a binding site to a neighboring atom.

In one or more embodiments, the electron-transporting host in the emission layer may include at least one of a cyano group and a π-electron deficient nitrogen-containing ring group.

In one or more embodiments, the electron-transporting host in the emission layer may include at least one cyano group.

In one or more embodiments, the electron-transporting host in the emission layer may include at least one cyano group and at least one π electron-deficient nitrogen-containing ring group.

In one or more embodiments, the host may include an electron-transporting host and a hole-transporting host, wherein the electron-transporting host may include at least one π electron-deficient nitrogen-free ring group and at least one electron-transporting moiety, and the hole-transporting host may include at least one π electron-deficient nitrogen-free ring group and may not include an electron-transporting moiety.

The term “π electron-deficient nitrogen-containing ring group” as used herein refers to a ring group having at least one *—N=*′ moiety, and for example, may include an imidazole group, a pyrazole group, a thiazole group, an isothiazole group, an oxazole group, an isoxazole group, a pyridine group, a pyrazine group, a pyridazine group, a pyrimidine group, an indazole group, a purine group, a quinoline group, an isoquinoline group, a benzoquinoline group, a phthalazine group, a naphthyridine group, a quinoxaline group, a quinazoline group, a cinnoline group, a phenanthridine group, an acridine group, a phenanthroline group, a phenazine group, a benzimidazole group, an isobenzothiazole group, a benzoxazole group, an isobenzoxazole group, a triazole group, a tetrazole group, an oxadiazole group, a triazine group, a thiadiazole group, an imidazopyridine group, an imidazopyrimidine group, and an azacarbazole group; or a condensed ring group in which two or more π electron-deficient nitrogen-containing ring groups are condensed with each other.

In one or more embodiments, the π electron-deficient nitrogen-free ring group may be a benzene group, a heptalene group, an indene group, a naphthalene group, an azulene group, an indacene group, an acenaphthylene group, a fluorene group, a spiro-bifluorene group, a benzofluorene group, a dibenzofluorene group, a phenalene group, a phenanthrene group, an anthracene group, a fluoranthene group, a triphenylene group, a pyrene group, a chrysene group, a naphthacene group, a picene group, a perylene group, a pentaphene group, a hexacene group, a pentacene group, a rubicene group, a coronene group, an ovalene group, a pyrrole group, an isoindole group, an indole group, a furan group, a thiophene group, a benzofuran group, a benzothiophene group, a benzocarbazole group, a dibenzocarbazole group, a dibenzofuran group, a dibenzothiophene group, a dibenzothiophene sulfone group, a carbazole group, a dibenzosilole group, an indenocarbazole group, an indolocarbazole group, a benzofurocarbazole group, a benzothienocarbazole group, and a triindolobenzene group; or a condensed ring group of two or more π electron-deficient nitrogen-free ring groups, but embodiments are not limited thereto.

In one or more embodiments, when the host is a mixture of the electron-transporting host and the hole-transporting host, a weight ratio of the electron-transporting host to the hole-transporting host may be about 1:9 to about 9:1, for example, about 2:8 to about 8:2, or for example, about 4:6 to about 6:4, or for example, 5:5. When the weight ratio of the electron transport host to the hole transport host satisfies the ranges above, the hole-and-electron transport balance in the emission layer may be achieved.

The host may include at least one of 1,3,5-tri(1-phenyl-1H-benzo[d]imidazol-2-yl)benzene (TPBi), 3-tert-butyl-9,10-di(naphth-2-yl)anthracene (TBADN), 9,10-di(naphth-2-yl)anthracene (ADN) (also referred to as “DNA”), 4,4′-bis(N-carbazolyl)-1,1′-biphenyl (CBP), 4,4′-bis(9-carbazolyl)-2,2′-dimethyl-biphenyl (CDBP), 1,3,5-tris(carbazol-9-yl)benzene (TCP), 1,3-bis(N-carbazolyl)benzene (mCP), Compound H50, or Compound H51, but embodiments are not limited thereto:

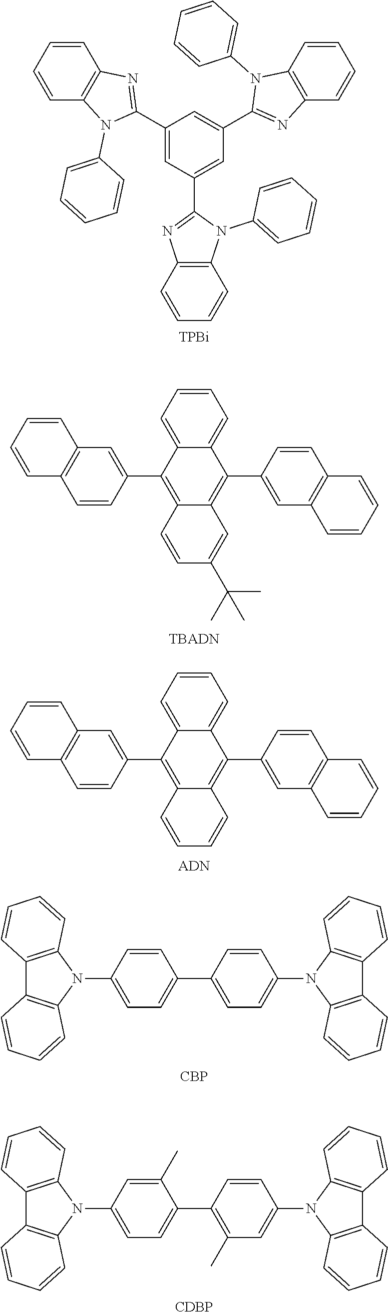

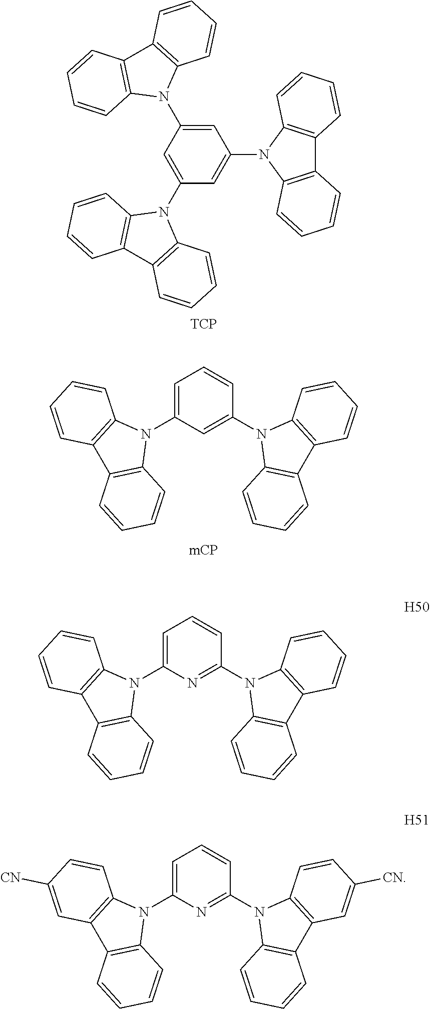

In one or more embodiments, the host may further include a compound represented by Formula 301:

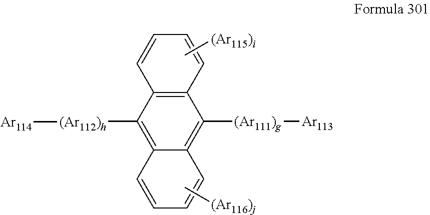

wherein, in Formula 301, Ar₁₁₁ and Ar₁₁₂ may each independently be:
a phenylene group, a naphthylene group, a phenanthrenylene group, or a pyrenylene group; or
a phenylene group, a naphthylene group, a phenanthrenylene group, or a pyrenylene group, each substituted with at least one of a phenyl group, a naphthyl group, or an anthracenyl group.

In Formula 301, Ar₁₁₃ to Ar₁₁₆ may each independently be:
a C₁-C₁₀ alkyl group, a phenyl group, a naphthyl group, a phenanthrenyl group, or a pyrenyl group; or
a phenyl group, a naphthyl group, a phenanthrenyl group, or a pyrenyl group, each substituted with at least one of a phenyl group, a naphthyl group, or an anthracenyl group.

In Formula 301, g, h, i, and j may each independently be an integer from 0 to 4, or for example, 0, 1, or 2.

In Formula 301, Ar₁₁₃ to Ar₁₁₆ may each independently be:
a C₁-C₁₀ alkyl group substituted with at least one of a phenyl group, a naphthyl group, or an anthracenyl group;
a phenyl group, a naphthyl group, an anthracenyl group, a pyrenyl group, a phenanthrenyl group, or a fluorenyl group;
a phenyl group, a naphthyl group, an anthracenyl group, a pyrenyl group, a phenanthrenyl group, or a fluorenyl group, each substituted with at least one of deuterium, —F, —Cl, —Br, —I, —SF₅, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₆₀ alkyl group, a C₂-C₆₀ alkenyl group, a C₂-C₆₀ alkynyl group, a C₁-C₆₀ alkoxy group, a C₁-C₆₀ alkylthio group, a phenyl group, a naphthyl group, an anthracenyl group, a pyrenyl group, a phenanthrenyl group, or a fluorenyl group; or

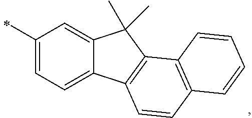

but embodiments are not limited thereto.

In one or more embodiments, the host may include a compound represented by Formula 302:

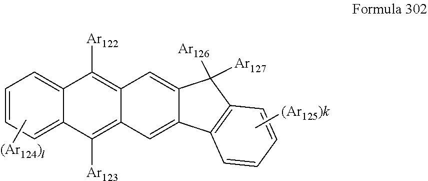

wherein, in Formula 302, Ar₁₂₂ to Ar₁₂₅ are each the same as described in connection with Ar₁₁₃ in Formula 301.

In Formula 302, Ar₁₂₆ and Ar₁₂₇ may each independently be a C₁-C₁₀ alkyl group (e.g., a methyl group, an ethyl group, a propyl group, or the like).

In Formula 302, k and l may each independently be an integer from 0 to 4. For example, k and l may each independently be 0, 1, or 2.

In one or more embodiments, the host may include at least one of Compounds H1 to H26:

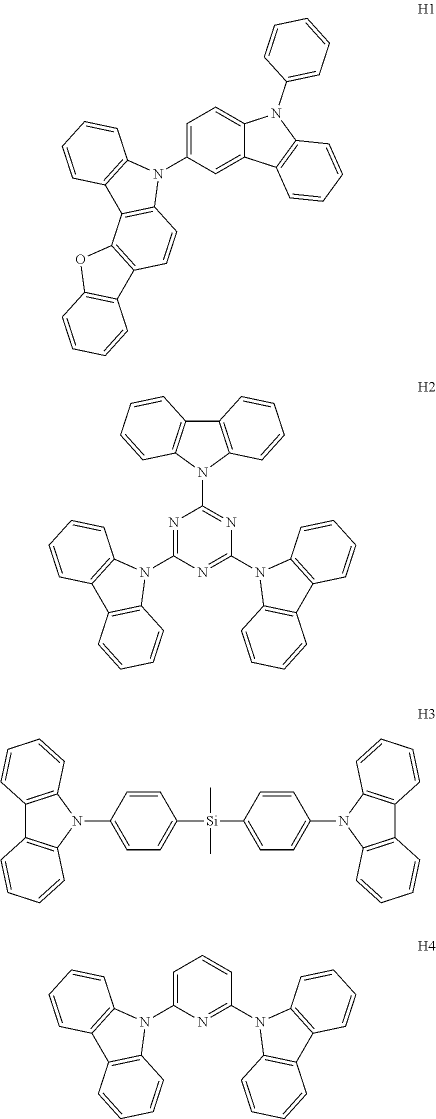 [SMILES: c1ccc(-n2c3ccccc3c3cc(-n4c5ccccc5c5c6oc7ccccc7c6ccc54)ccc32)cc1 ; c1ccc2c(c1)c1ccccc1n2-c1nc(-n2c3ccccc3c3ccccc32)nc(-n2c3ccccc3c3ccccc32)n1 ; C[Si](C)(c1ccc(-n2c3ccccc3c3ccccc32)cc1)c1ccc(-n2c3ccccc3c3ccccc32)cc1 ; c1cc(-n2c3ccccc3c3ccccc32)nc(-n2c3ccccc3c3ccccc32)c1]

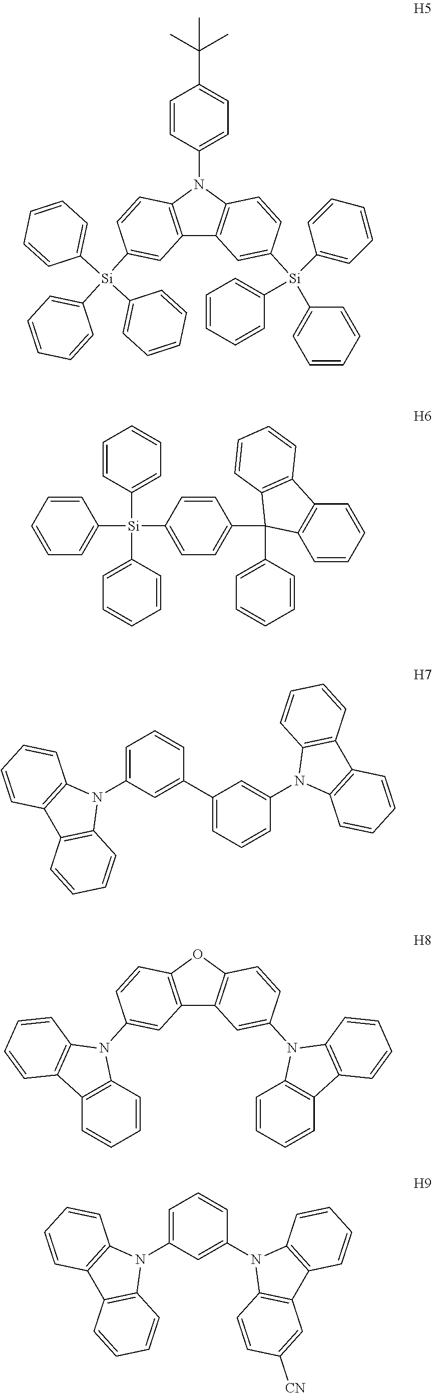 [SMILES: CC(C)(C)c1ccc(-n2c3ccc([Si](c4ccccc4)(c4ccccc4)c4ccccc4)cc3c3cc([Si](c4ccccc4)(c4ccccc4)c4ccccc4)ccc32)cc1 ; c1ccc(C2(c3ccc([Si](c4ccccc4)(c4ccccc4)c4ccccc4)cc3)c3ccccc3-c3ccccc32)cc1 ; c1cc(-c2cccc(-n3c4ccccc4c4ccccc43)c2)cc(-n2c3ccccc3c3ccccc32)c1 ; c1ccc2c(c1)c1ccccc1n2-c1ccc2oc3ccc(-n4c5ccccc5c5ccccc54)cc3c2c1 ; N#Cc1ccc2c(c1)c1ccccc1n2-c1cccc(-n2c3ccccc3c3ccccc32)c1]

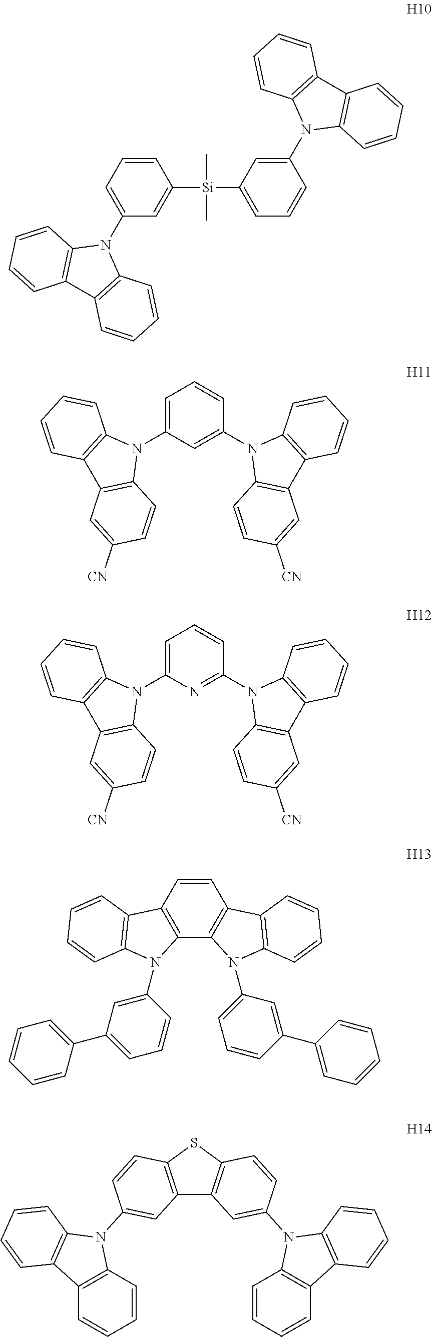

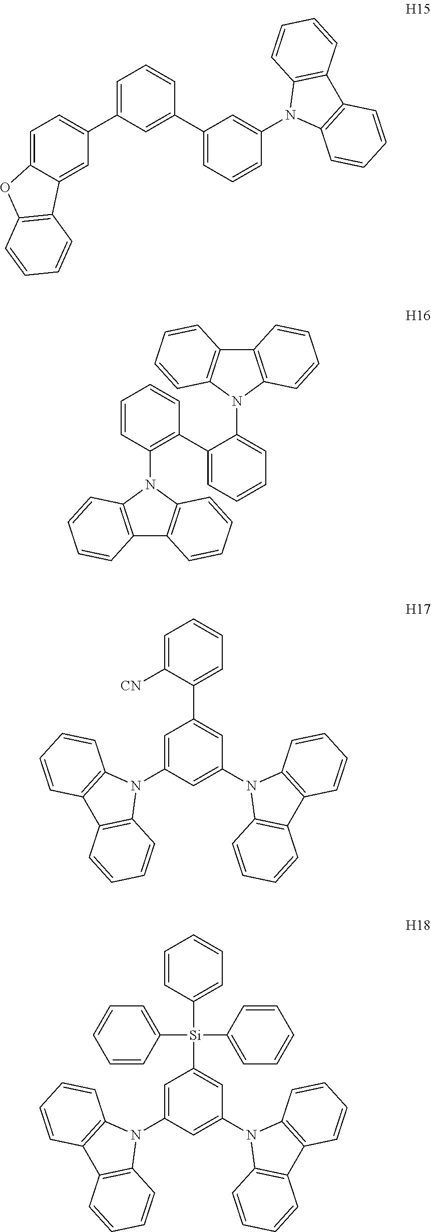

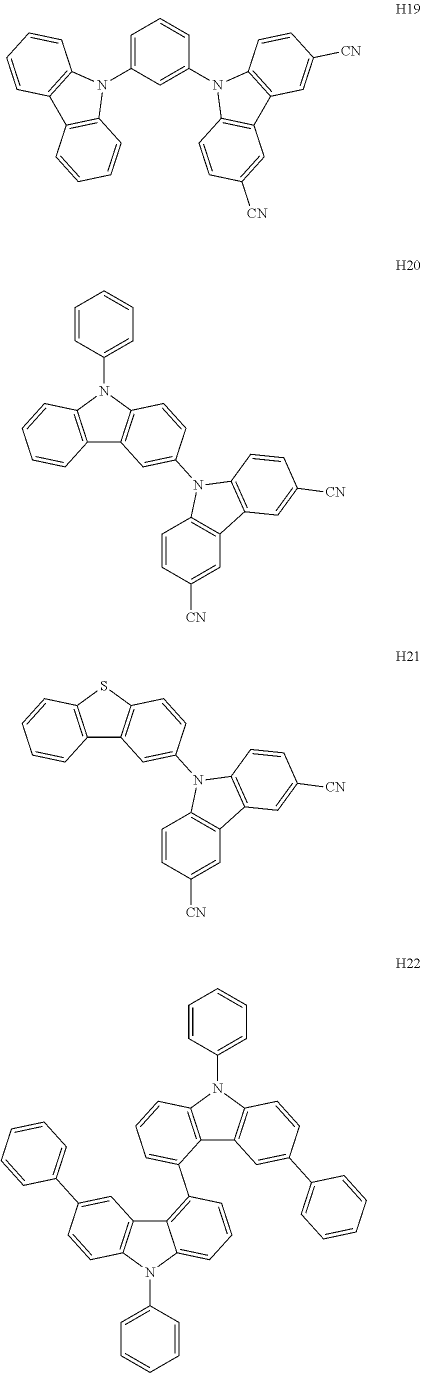 [SMILES: N#Cc1ccc2c(c1)c1cc(C#N)ccc1n2-c1cccc(-n2c3ccccc3c3ccccc32)c1 ; N#Cc1ccc2c(c1)c1cc(C#N)ccc1n2-c1ccc2c(c1)c1ccccc1n2-c1ccccc1 ; N#Cc1ccc2c(c1)c1cc(C#N)ccc1n2-c1ccc2sc3ccccc3c2c1 ; c1ccc(-c2ccc3c(c2)c2c(-c4cccc5c4c4cc(-c6ccccc6)ccc4n5-c4ccccc4)cccc2n3-c2ccccc2)cc1]

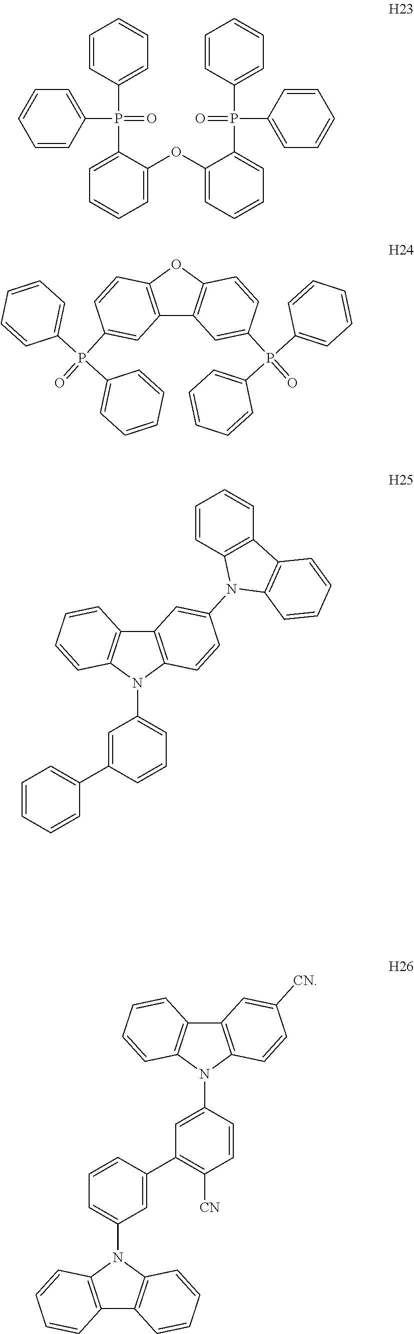 [SMILES: O=P(c1ccccc1)(c1ccccc1)c1ccccc1Oc1ccccc1P(=O)(c1ccccc1)c1ccccc1 ; O=P(c1ccccc1)(c1ccccc1)c1ccc2oc3ccc(P(=O)(c4ccccc4)c4ccccc4)cc3c2c1 ; c1ccc(-c2cccc(-n3c4ccccc4c4cc(-n5c6ccccc6c6ccccc65)ccc43)c2)cc1 ; N#Cc1ccc2c(c1)c1ccccc1n2-c1ccc(C#N)c(-c2cccc(-n3c4ccccc4c4ccccc43)c2)c1]

In one or more embodiments, the host may consist of one type of compound. For example, the one type of compound may be optionally selected from the first material (e.g., a hole-transporting host) or the second material (e.g., an electron-transporting host).

In one or more embodiments, the host may include two or more types of compounds. For example, the host may include two or more types of different hole-transporting hosts; two or more types of different electron-transporting hosts; or a combination of one or more types of hole-transporting hosts and one or more types of electron-transporting hosts.

### Emitter in Emission Layer

The emitter may include at least one of the heterocyclic compounds represented by Formula 1.

### Sensitizer in Emission Layer

In one or more embodiments, the sensitizer may include a phosphorescent compound.

In one or more embodiments, the phosphorescent compound may be an organometallic compound including at least one type of metal.

In one or more embodiments, the organometallic compound may include at least one type of metal (M₁₁) selected from transition metals and an organic ligand (L₁₁), wherein L₁₁ and M₁₁ may form 1, 2, 3, or 4 cyclometallated rings.

In one or more embodiments, the organometallic compound may be represented by Formula 101:

M₁₁(L₁₁)ₙ₁₁(L₁₂)ₙ₁₂ Formula 101

wherein, in Formula 101,
M₁₁ may be a transition metal,
L₁₁ may be a ligand represented by one of Formulae 1-1 to 1-4,
L₁₂ may be a monodentate ligand or a bidentate ligand,
n11 may be 1, and
n12 may be 0, 1, or 2,

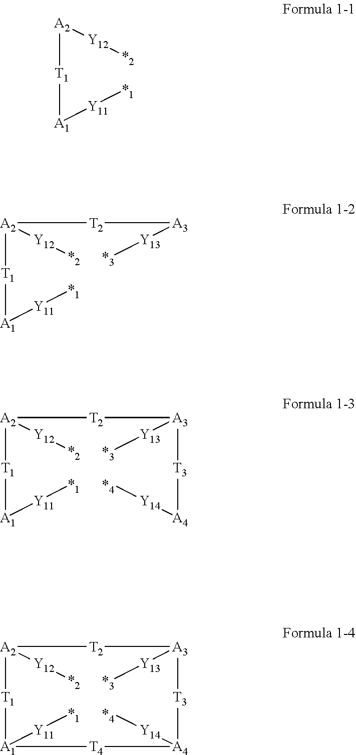

wherein, in Formulae 1-1 to 1-4,
A₁ to A₄ may each independently be a substituted or unsubstituted C₅-C₃₀ carbocyclic group, a substituted or unsubstituted C₁-C₃₀ heterocyclic group, or a non-cyclic group,
Y₁₁ to Y₁₄ may each independently be a chemical bond, O, S, N(R₉₁), B(R₉₁), P(R₉₁), or C(R₉₁)(R₉₂),
T₁ to T₄ may each independently be a single bond, a double bond, *—N(R₉₃)—*′, *—B(R₉₃)—*′, *—P(R₉₃)—*′, *—C(R₉₃)(R₉₄)—*′, *—Si(R₉₃)(R₉₄)—*′, *—Ge(R₉₃)(R₉₄)—*′, *—S—*′, *—Se—*′, * O—*′, *—C(═O)—*′, *—S(═O)—*′, *—S(═O)₂—*′, *—C(R₉₃)=*′, *=C(R₉₃)—*′, *—C(R₉₃)═C(R₉₄)—*′, *—C(=S)—*′, or *—C≡C—*′,
a substituent of the substituted C₅-C₃₀ carbocyclic group, a substituent of the substituted C₁-C₃₀ heterocyclic group, and R₉₁ to R₉₄ may each independently be hydrogen, deuterium, —F, —Cl, —Br, —I, —SF₅, a hydroxyl group, a cyano group, a nitro group, an amidino group, a hydrazine group, a hydrazone group, a carboxylic acid group or a salt thereof, a sulfonic acid group or a salt thereof, a phosphoric acid group or a salt thereof, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₁-C₆₀ alkylthio group, a substituted or unsubstituted C₃-C₁₀ cycloalkyl group, a substituted or unsubstituted C₁-C₁₀ heterocycloalkyl group, a substituted or unsubstituted C₃-C₁₀ cycloalkenyl group, a substituted or unsubstituted C₁-C₁₀ heterocycloalkenyl group, a substituted or unsubstituted C₆-C₆₀ aryl group, a substituted or unsubstituted C₇-C₆₀ alkyl aryl group, a substituted or unsubstituted C₇-C₆₀ aryl alkyl group, a substituted or unsubstituted C₆-C₆₀ aryloxy group, a substituted or unsubstituted C₆-C₆₀ arylthio group, a substituted or unsubstituted C₁-C₆₀ heteroaryl group, a substituted or unsubstituted C₂-C₆₀ alkyl heteroaryl group, a substituted or unsubstituted C₂-C₆₀ heteroaryl alkyl group, a substituted or unsubstituted C₁-C₆₀ heteroaryloxy group, a substituted or unsubstituted C₁-C₆₀ heteroarylthio group, a substituted or unsubstituted monovalent aromatic condensed polycyclic group, a substituted or unsubstituted monovalent aromatic condensed heteropolycyclic group, a substituted or unsubstituted monovalent non-aromatic condensed polycyclic group, a substituted or unsubstituted monovalent non-aromatic condensed heteropolycyclic group, —N(Q₁)(Q₂), —Si(Q₁)(Q₂)(Q₃), —Ge(Q₁)(Q₂)(Q₃), —C(═O)(Q₁), —S(═O)(Q₁), —S(═O)₂(Q₁), —B(Q₁)(Q₂), —P(Q₁)(Q₂), —P(═O)(Q₁)(Q₂), or —P(═S)(Q₁)(Q₂), wherein substituents of the substituted C₅-C₃₀ carbocyclic group and the substituent of the substituted C₁-C₃₀ heterocyclic group may not be hydrogen,
*₁, *₂, *₃, and *₄ each indicate a binding site to M₁₁, and
Q₁ to Q₃ may each independently be:
hydrogen, deuterium, —F, —Cl, —Br, —I, —SF₅, a hydroxyl group, a cyano group, a nitro group, an amino group, an amidino group, a hydrazino group, a hydrazono group, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₁-C₆₀ alkylthio group, a substituted or unsubstituted C₃-C₁₀ cycloalkyl group, a substituted or unsubstituted C₁-C₁₀ heterocycloalkyl group, a substituted or unsubstituted C₃-C₁₀ cycloalkenyl group, a substituted or unsubstituted C₁-C₁₀ heterocycloalkenyl group, a substituted or unsubstituted C₆-C₆₀ aryl group, a substituted or unsubstituted C₇-C₆₀ alkyl aryl group, a substituted or unsubstituted C₇-C₆₀ aryl alkyl group, a C₆-C₆₀ aryloxy group, a substituted or unsubstituted C₆-C₆₀ arylthio group, a substituted or unsubstituted C₁-C₆₀ heteroaryl group, a substituted or unsubstituted C₂-C₆₀ alkyl heteroaryl group, a substituted or unsubstituted C₂-C₆₀ heteroaryl alkyl group, a substituted or unsubstituted C₁-C₆₀ heteroaryloxy group, a substituted or unsubstituted C₁-C₆₀ heteroarylthio group, a substituted or unsubstituted monovalent aromatic condensed polycyclic group, a substituted or unsubstituted monovalent aromatic condensed heteropolycyclic group, a substituted or unsubstituted monovalent non-aromatic condensed polycyclic group, or a substituted or unsubstituted monovalent non-aromatic condensed heteropolycyclic group, a C₁-C₆₀ alkyl group substituted with at least one of deuterium, —F, a cyano group, a C₁-C₆₀ alkyl group, or a C₆-C₆₀ aryl group, or a C₆-C₆₀ aryl group substituted with at least one of deuterium, —F, a cyano group, a C₁-C₆₀ alkyl group, or a C₆-C₆₀ aryl group.

In one or more embodiments, the transition metal may include platinum (Pt), palladium (Pd), gold (Au), iridium (Ir), osmium (Os), titanium (Ti), zirconium (Zr), hafnium (Hf), europium (Eu), terbium (Tb), thulium (Tm), or rhodium (Rh).

In one or more embodiments, the sensitizer may include a delayed fluorescence compound.

In one or more embodiments, the delayed fluorescence compound may be represented by Formula 101 or 102:

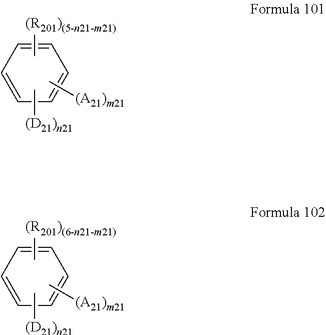

wherein, in Formulae 101 and 102,
A₂₁ may be an acceptor group,
D₂₁ may be a donor group,
m21 may be 1, 2, or 3, and n21 may be 1, 2, or 3,
a sum of n21 and m21 in Formula 101 may be 5 or less, and a sum of n21 and m21 in Formula 102 may be 6 or less,
R₂₀₁ may be hydrogen, deuterium, —F, —Cl, —Br, —I, —SF₅, a hydroxyl group, a cyano group, a nitro group, an amidino group, a hydrazino group, a hydrazono group, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₁-C₆₀ alkylthio group, a substituted or unsubstituted C₃-C₁₀ cycloalkyl group, a substituted or unsubstituted C₁-C₁₀ heterocycloalkyl group, a substituted or unsubstituted C₃-C₁₀ cycloalkenyl group, a substituted or unsubstituted C₁-C₁₀ heterocycloalkenyl group, a substituted or unsubstituted C₆-C₆₀ aryl group, a substituted or unsubstituted C₇-C₆₀ alkyl aryl group, a substituted or unsubstituted C₇-C₆₀ aryl alkyl group, a substituted or unsubstituted C₆-C₆₀ aryloxy group, a substituted or unsubstituted C₆-C₆₀ arylthio group, a substituted or unsubstituted C₁-C₆₀ heteroaryl group, a substituted or unsubstituted C₂-C₆₀ alkyl heteroaryl group, a substituted or unsubstituted C₂-C₆₀ heteroaryl alkyl group, a substituted or unsubstituted C₁-C₆₀ heteroaryloxy group, a substituted or unsubstituted C₁-C₆₀ heteroarylthio group, a substituted or unsubstituted monovalent non-aromatic condensed polycyclic group, a substituted or unsubstituted monovalent non-aromatic condensed heteropolycyclic group, —N(Q₁)(Q₂), —Si(Q₁)(Q₂)(Q₃), —Ge(Q₁)(Q₂)(Q₃), —C(═O)(Q₁), —S(═O)(Q₁), —S(═O)₂(Q₁), —B(Q₁)(Q₂), —P(Q₁)(Q₂), —P(═O)(Q₁)(Q₂), or —P(═S)(Q₁)(Q₂), wherein a plurality of R₂₀₁ may optionally be bonded together to form a substituted or unsubstituted C₅-C₃₀ carbocyclic group or a substituted or unsubstituted C₁-C₃₀ heterocyclic group, and
Q₁ to Q₃ may each independently be:
hydrogen, deuterium, —F, —Cl, —Br, —I, —SF₅, a hydroxyl group, a cyano group, a nitro group, an amino group, an amidino group, a hydrazino group, a hydrazono group, a C₁-C₁₀ alkyl group, a C₂-C₆₀ alkenyl group, a C₂-C₆₀ alkynyl group, a C₁-C₆₀ alkoxy group, a C₁-C₆₀ alkylthio group, a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₇-C₆₀ alkyl aryl group, a substituted or unsubstituted C₇-C₆₀ aryl alkyl group, a C₆-C₆₀ aryloxy group, a C₆-C₆₀ arylthio group, a C₁-C₆₀ heteroaryl group, a C₂-C₆₀ alkyl heteroaryl group, a substituted or unsubstituted C₂-C₆₀ heteroaryl alkyl group, a C₁-C₆₀ heteroaryloxy group, a C₁-C₆₀ heteroarylthio group, a monovalent aromatic condensed polycyclic group, a monovalent aromatic condensed heteropolycyclic group, a monovalent non-aromatic condensed polycyclic group, or a monovalent non-aromatic condensed heteropolycyclic group,
a C₁-C₆₀ alkyl group substituted with at least one of deuterium, —F, a cyano group, a C₁-C₆₀ alkyl group, or a C₆-C₆₀ aryl group; or
a C₆-C₆₀ aryl group, or a C₆-C₆₀ aryl group substituted with at least one of deuterium, —F, a cyano group, a C₁-C₆₀ alkyl group, and a C₆-C₆₀ aryl group.

In one or more embodiments, in Formulae 101 and 102, A₂₁ may be a substituted or unsubstituted π electron-deficient nitrogen-free ring group.

In one or more embodiments, the π electron-deficient nitrogen-free ring group may be a benzene group, a heptalene group, an indene group, a naphthalene group, an azulene group, an indacene group, an acenaphthylene group, a fluorene group, a spiro-bifluorene group, a benzofluorene group, a dibenzofluorene group, a phenalene group, a phenanthrene group, an anthracene group, a fluoranthene group, a triphenylene group, a pyrene group, a chrysene group, a naphthacene group, a picene group, a perylene group, a pentaphene group, a hexacene group, a pentacene group, a rubicene group, a coronene group, an ovalene group, a pyrrole group, an isoindole group, an indole group, a furan group, a thiophene group, a benzofuran group, a benzothiophene group, a benzocarbazole group, a dibenzocarbazole group, a dibenzofuran group, a dibenzothiophene group, a dibenzothiophene sulfone group, a carbazole group, a dibenzosilole group, an indenocarbazole group, an indolocarbazole group, a benzofurocarbazole group, a benzothienocarbazole group, a triindolobenzene group; or a condensed ring group of two or more π electron-deficient nitrogen-free ring groups, but embodiments are not limited thereto.

In one or more embodiments, in Formulae 101 and 102, D₂₁ may be:
—F, a cyano group, or a π electron-deficient nitrogen-containing ring group;
a C₁-C₆₀ alkyl group, a π-electron deficient nitrogen-containing ring group, or an π electron-deficient nitrogen-free ring group, each substituted with at least one of —F or a cyano group; or
a π-electron deficient nitrogen-containing ring group substituted with at least one of deuterium, a C₁-C₆₀ alkyl group, a π-electron deficient nitrogen-containing ring group, or a π electron-deficient nitrogen-free ring group.

In one or more embodiments, the r electron-deficient nitrogen-free ring group may be the same as described above.

The term “r electron-deficient nitrogen-containing ring group” as used herein refers to a ring group having at least one *—N=*′ moiety, and, for example, may be an imidazole group, a pyrazole group, a thiazole group, an isothiazole group, an oxazole group, an isoxazole group, a pyridine group, a pyrazine group, a pyridazine group, a pyrimidine group, an indazole group, a purine group, a quinoline group, an isoquinoline group, a benzoquinoline group, a phthalazine group, a naphthyridine group, a quinoxaline group, a quinazoline group, a cinnoline group, a phenanthridine group, an acridine group, a phenanthroline group, a phenazine group, a benzimidazole group, an isobenzothiazole group, a benzoxazole group, an isobenzoxazole group, a triazole group, a tetrazole group, an oxadiazole group, a triazine group, a thiadiazole group, an imidazopyridine group, an imidazopyrimidine group, an azacarbazole group, a benzimidazole group, or a condensed ring group in which two or more r electron-deficient nitrogen-containing ring groups are condensed with each other.

In one or more embodiments, an amount of the sensitizer in the organic layer may be greater than an amount of the emitter in the organic layer, based on weight or volume. For example, a volume ratio of the sensitizer and the emitter may be in a range of about 30:0.1 to about 10:3 or about 10:0.1 to about 20:5. In one or more embodiments, a weight ratio of the sensitizer and the emitter may be in a range of about 10:0.1 to about 20:5. In one or more embodiments, a weight ratio of the host and the sensitizer in the organic layer may be in a range of about 60:40 to about 95:5 or about 70:30 to about 90:10. In one or more embodiments, the weight ratio of the host and the sensitizer in the organic layer may be in a range of about 60:40 to about 95:5. When the amount is satisfied within the ranges above, the organic light-emitting device may have improved luminescence efficiency and/or long lifespan characteristics.

FIG. 1 is a schematic cross-sectional view of an organic light-emitting device 10 according to one or more embodiments. Hereinafter, the structure and manufacturing method of the organic light-emitting device 10 according to one or more embodiments of the disclosure will be described in connection with FIG. 1. The organic light-emitting device 10 has a structure in which a first electrode 11, an organic layer 15, and a second electrode 19 are sequentially stacked.

A substrate may be additionally arranged under the first electrode 11 or on the second electrode 19. For use as the substrate, a substrate generally used in organic light-emitting devices, e.g., a glass substrate or a transparent plastic substrate, having excellent mechanical strength, thermal stability, transparency, surface smoothness, ease of handling, and water repellency may be used.

The first electrode 11 may be formed by, for example, depositing or sputtering, onto the substrate, a material for forming the first electrode 11. The first electrode 11 may be an anode. The material for forming the first electrode 11 may be selected from materials with a high work function for easy hole injection. The first electrode 11 may be a reflective electrode, a transflective electrode, or a transmissive electrode. The material for forming the first electrode 11 may be indium tin oxide (ITO), indium zinc oxide (IZO), tin oxide (SnO₂), or zinc oxide (ZnO). In one or more embodiments, the material for forming the first electrode 11 may be a metal, such as magnesium (Mg), aluminum (Al), aluminum-lithium (Al—Li), calcium (Ca), magnesium-indium (Mg—In), or magnesium-silver (Mg—Ag).

The first electrode 11 may have a single-layer structure or a multi-layer structure including a plurality of layers. For example, the first electrode 11 may have a three-layer structure of ITO/Ag/ITO, but embodiments are not limited thereto.

The organic layer 15 is arranged on the first electrode 11.

The organic layer 15 may include a hole transport region; an emission layer; and an electron transport region.

The hole transport region may be arranged between the first electrode 11 and the emission layer.

The hole transport region may include a hole injection layer, a hole transport layer, an electron blocking layer, a buffer layer, or a combination thereof.

The hole transport region may include only either a hole injection layer or a hole transport layer. The hole transport region may have a hole injection layer/hole transport layer structure, a hole injection layer/hole transport layer/electron blocking layer structure, or a hole injection layer/a first hole transport layer/a second hole transport layer/an electron blocking layer structure, wherein the constituent layers are sequentially stacked in this stated order from the first electrode 11.

When the hole transport region includes a hole injection layer, the hole injection layer may be formed on the first electrode 11 by using various methods, for example, vacuum deposition, spin coating, casting, and/or Langmuir-Blodgett (LB) deposition, but embodiments are not limited thereto.

When the hole injection layer is formed by a vacuum deposition method, deposition conditions may vary depending on a compound used as a material for forming the hole injection layer, a structure and thermal characteristics of the desired hole injection layer, and the like. For example, a deposition temperature may be about 100° C. to about 500° C., a vacuum pressure may be about 10⁻⁸ torr to about 10⁻³ torr, and a deposition rate may be about 0.01 angstroms per second (A/sec) to about 100 Å/sec, but embodiments are not limited thereto.

When the hole injection layer is formed by a spin coating method, coating conditions may vary depending on a compound that is used as a material for forming the hole injection layer, a structure and thermal characteristics of the desired hole injection layer, and the like. For example, a coating rate may be about 2,000 revolutions per minute (rpm) to about 5,000 rpm, and a temperature at which heat treatment is performed to remove a solvent after coating may be about 80° C. to about 200° C., but embodiments are not limited thereto.

In this regard, conditions for forming the hole transport layer and the electron blocking layer may be understood by referring to the conditions for forming the hole injection layer.

The hole transport region may include at least one of 4,4′,4″-tris(3-methylphenylphenylamino)triphenylamine (m-MTDATA), 4,4′,4″-tris(N,N-diphenylamino)triphenylamine (TDATA), 4,4′,4″-tris{N-(2-naphthyl)-N-phenylamino}-triphenylamine (2-TNATA), N,N′-di(1-naphthyl)-N,N′diphenylbenzidine (NPB), β-NPB, N,N-bis(3-methylphenyl)-N,N′-diphenyl-[1,1-biphenyl]-4,4′-diamine (TPD), Spiro-TPD, Spiro-NPB, methylated NPB, 4,4′cyclohexylidene bis[N,N-bis(4-methylphenyl)benzenamine](TAPC), 4,4′-bis[N,N′-(3-tolyl)amino]-3,3′-dimethylbiphenyl (HMTPD), 4,4′,4″-tris(N-carbazolyl)triphenylamine (TCTA), polyaniline/dodecylbenzenesulfonic acid (PANI/DBSA), poly(3,4-ethylenedioxythiophene)/poly(4-styrenesulfonate) (PEDOT/PSS), polyaniline/camphor sulfonic acid (PANI/CSA), polyaniline/poly(4-styrenesulfonate) (PANI/PSS), a compound represented by Formula 201, or a compound represented by Formula 202:

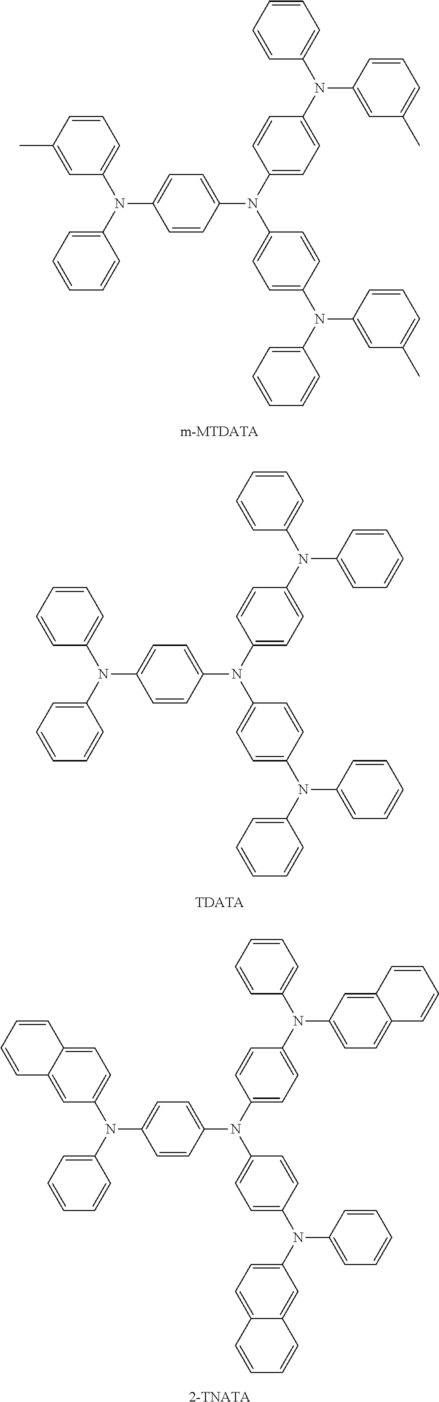

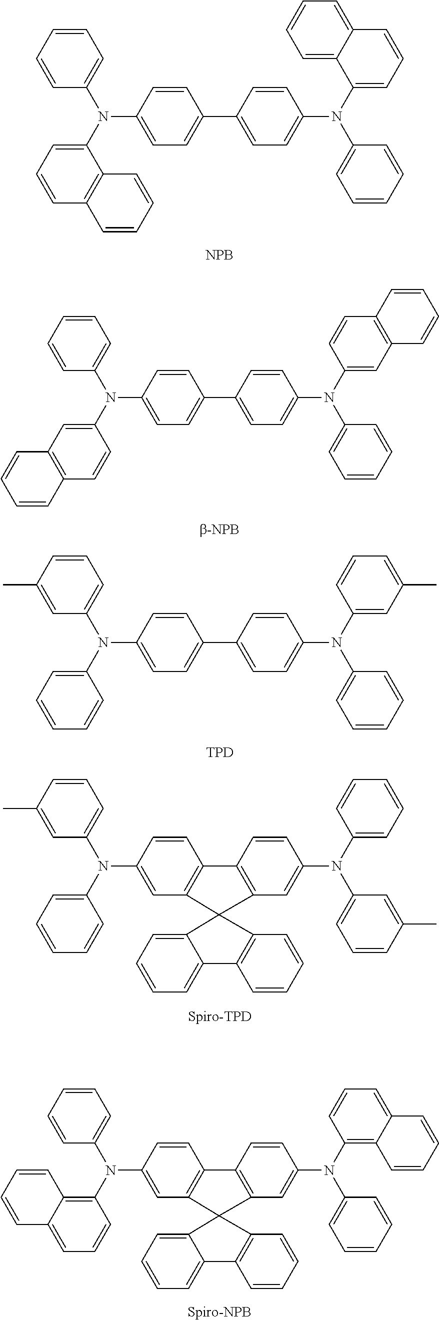

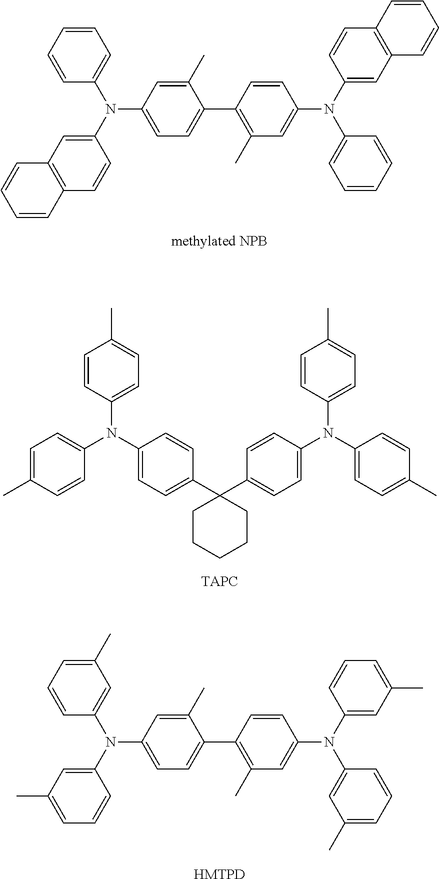

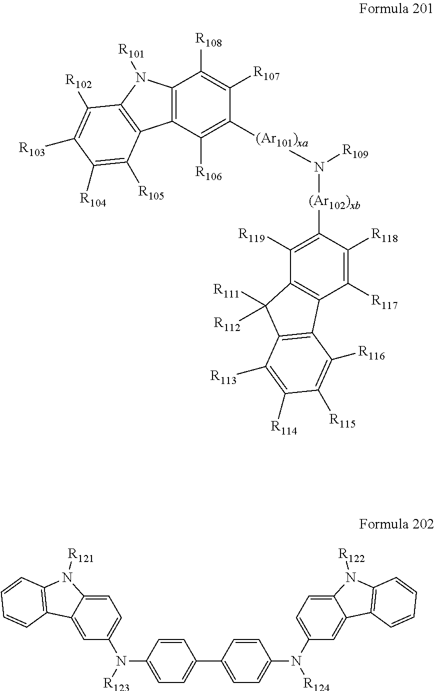

wherein, in Formula 201, Ar₁₀₁ and Ar₁₀₂ may each independently be:
a phenylene group, a pentalenylene group, an indenylene group, a naphthylene group, an azulenylene group, a heptalenylene group, an acenaphthenylene group, a fluorenylene group, a phenalenylene group, a phenanthrenylene group, an anthracenylene group, a fluoranthenylene group, a triphenylenylene group, a pyrenylene group, a chrysenylenylene group, a naphthacenylene group, a picenylene group, a perylenylene group, or a pentacenylene group; or
a phenylene group, a pentalenylene group, an indenylene group, a naphthylene group, an azulenylene group, a heptalenylene group, an acenaphthenylene group, a fluorenylene group, a phenalenylene group, a phenanthrenylene group, an anthracenylene group, a fluoranthenylene group, a triphenylenylene group, a pyrenylene group, a chrysenylene group, a naphthacenyl group, a picenylene group, a perylenylene group, or a pentacenylene group, each substituted with deuterium, —F, —Cl, —Br, —I, —SF₅, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₆₀ alkyl group, a C₂-C₆₀ alkenyl group, a C₂-C₆₀ alkynyl group, a C₁-C₆₀ alkoxy group, a C₁-C₆₀ alkylthio group, a C₃-C₁₀ cycloalkyl group, a C₃-C₁₀ cycloalkenyl group, a C₁-C₁₀ heterocycloalkyl group, a C₁-C₁₀ heterocycloalkenyl group, a C₆-C₆₀ aryl group, a C₇-C₆₀ alkyl aryl group, a C₇-C₆₀ aryl alkyl group, a C₆-C₆₀ aryloxy group, a C₆-C₆₀ arylthio group, a C₁-C₆₀ heteroaryl group, a C₂-C₆₀ alkyl heteroaryl group, a C₂-C₆₀ heteroaryl alkyl group, a C₁-C₆₀ heteroaryloxy group, a C₁-C₆₀ heteroarylthio group, a monovalent non-aromatic condensed polycyclic group, a monovalent non-aromatic condensed heteropolycyclic group, or a combination thereof.

In Formula 201, xa and xb may each independently be an integer from 0 to 5, or may each independently be 0, 1, or 2. For example, xa may be 1, and xb may be 0, but embodiments are not limited thereto.

In Formulae 201 and 202, R₁₀₁ to R₁₀₈, R₁₁₁ to R₁₁₉, and R₁₂₁ to R₁₂₄ may each independently be:
hydrogen, deuterium, —F, —Cl, —Br, —I, —SF₅, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₁₀ alkyl group (e.g., a methyl group, an ethyl group, a propyl group, a butyl group, a pentyl group, a hexyl group, or the like), a C₁-C₁₀ alkoxy group (e.g., a methoxy group, an ethoxy group, a propoxy group, a butoxy group, a pentoxy group, or the like), or a C₁-C₁₀ alkylthio group;
a C₁-C₁₀ alkyl group, a C₁-C₁₀ alkoxy group, or a C₁-C₁₀ alkylthio group, each substituted with deuterium, —F, —Cl, —Br, —I, —SF₅, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, or a combination thereof;
a phenyl group, a naphthyl group, an anthracenyl group, a fluorenyl group, or a pyrenyl group; or
a phenyl group, a naphthyl group, an anthracenyl group, a fluorenyl group, or a pyrenyl group, each substituted with deuterium, —F, —Cl, —Br, —I, —SF₅, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₁₀ alkyl group, a C₁-C₁₀ alkoxy group, a C₁-C₁₀ alkylthio group, or a combination thereof, but embodiments are not limited thereto.

In Formula 201, R₁₀₉ may be:
a phenyl group, a naphthyl group, an anthracenyl group, or a pyridinyl group; or a phenyl group, a naphthyl group, an anthracenyl group, or a pyridinyl group, each substituted with deuterium, —F, —Cl, —Br, —I, —SF₅, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₂₀ alkyl group, a C₁-C₂₀ alkoxy group, a C₁-C₂₀ alkylthio group, a phenyl group, a naphthyl group, an anthracenyl group, a pyridinyl group, or a combination thereof.

In one or more embodiments, the compound represented by Formula 201 may be represented by Formula 201A, but embodiments are not limited thereto:

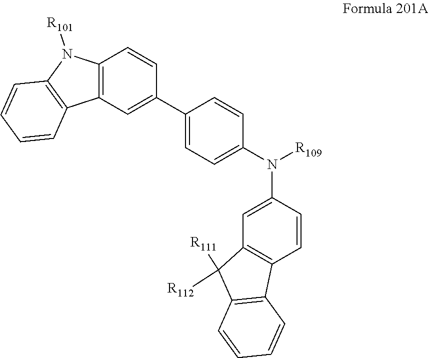

wherein, in Formula 201A, R₁₀₁, R₁₁₁, R₁₁₂, and R₁₀₉ may each be as defined herein.

For example, the compound represented by Formula 201 and the compound represented by Formula 202 may include at least one of Compounds HT1 to HT20, but embodiments are not limited thereto:

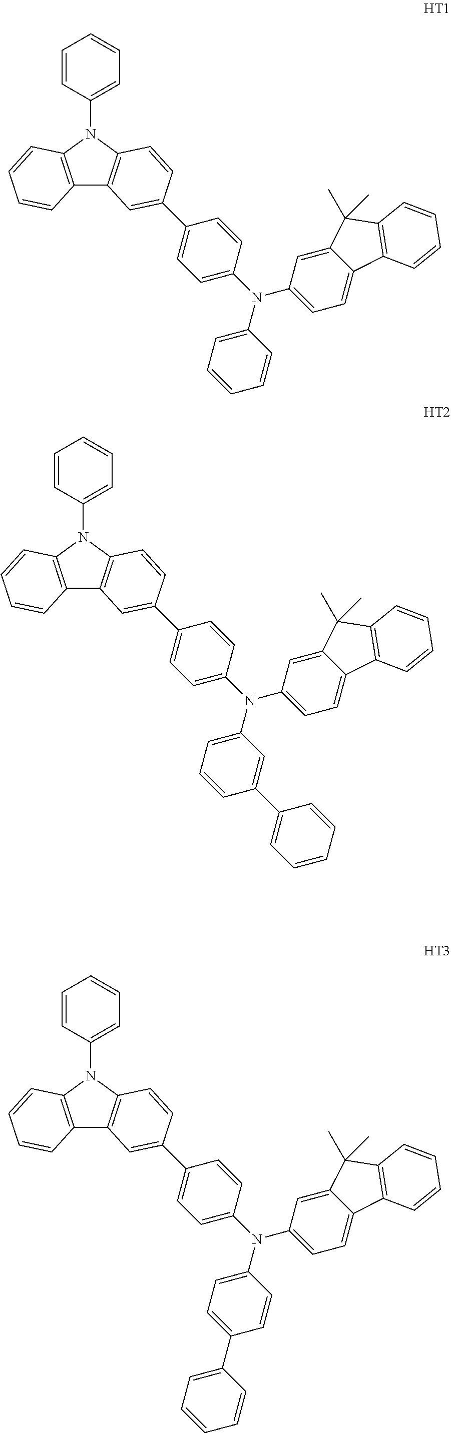 [SMILES: CC1(C)c2ccccc2-c2ccc(N(c3ccccc3)c3ccc(-c4ccc5c(c4)c4ccccc4n5-c4ccccc4)cc3)cc21 ; CC1(C)c2ccccc2-c2ccc(N(c3ccc(-c4ccc5c(c4)c4ccccc4n5-c4ccccc4)cc3)c3cccc(-c4ccccc4)c3)cc21 ; CC1(C)c2ccccc2-c2ccc(N(c3ccc(-c4ccccc4)cc3)c3ccc(-c4ccc5c(c4)c4ccccc4n5-c4ccccc4)cc3)cc21]

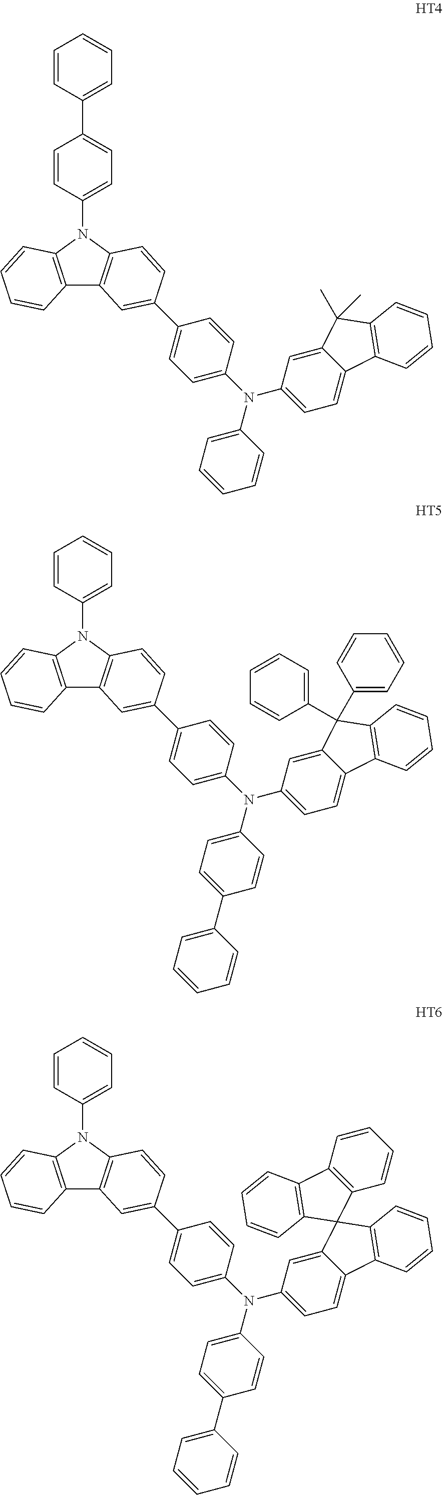 [SMILES: CC1(C)c2ccccc2-c2ccc(N(c3ccccc3)c3ccc(-c4ccc5c(c4)c4ccccc4n5-c4ccc(-c5ccccc5)cc4)cc3)cc21 ; c1ccc(-c2ccc(N(c3ccc(-c4ccc5c(c4)c4ccccc4n5-c4ccccc4)cc3)c3ccc4c(c3)C(c3ccccc3)(c3ccccc3)c3ccccc3-4)cc2)cc1 ; c1ccc(-c2ccc(N(c3ccc(-c4ccc5c(c4)c4ccccc4n5-c4ccccc4)cc3)c3ccc4c(c3)C3(c5ccccc5-c5ccccc53)c3ccccc3-4)cc2)cc1]

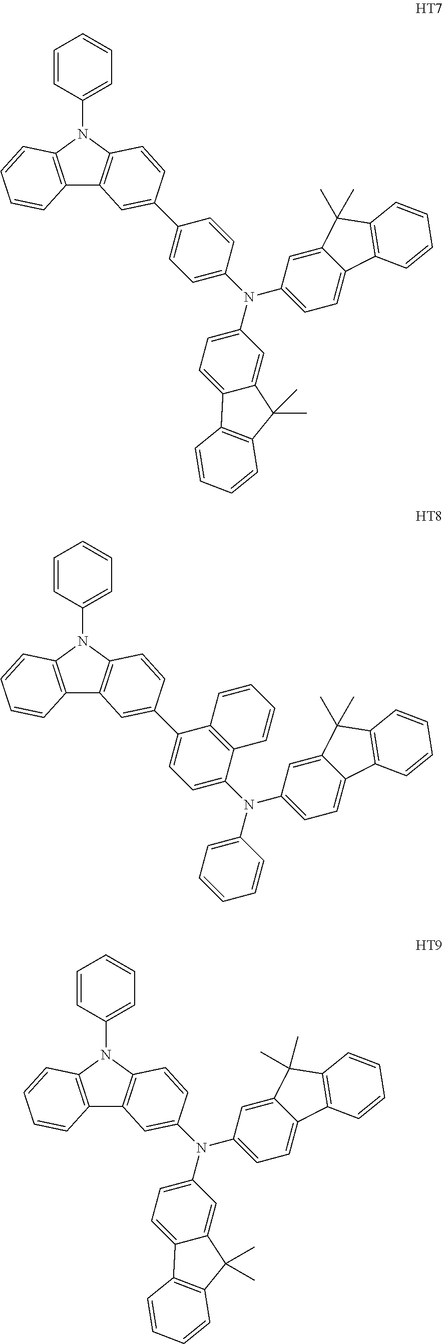 [SMILES: CC1(C)c2ccccc2-c2ccc(N(c3ccc(-c4ccc5c(c4)c4ccccc4n5-c4ccccc4)cc3)c3ccc4c(c3)C(C)(C)c3ccccc3-4)cc21 ; CC1(C)c2ccccc2-c2ccc(N(c3ccccc3)c3ccc(-c4ccc5c(c4)c4ccccc4n5-c4ccccc4)c4ccccc34)cc21 ; CC1(C)c2ccccc2-c2ccc(N(c3ccc4c(c3)C(C)(C)c3ccccc3-4)c3ccc4c(c3)c3ccccc3n4-c3ccccc3)cc21]

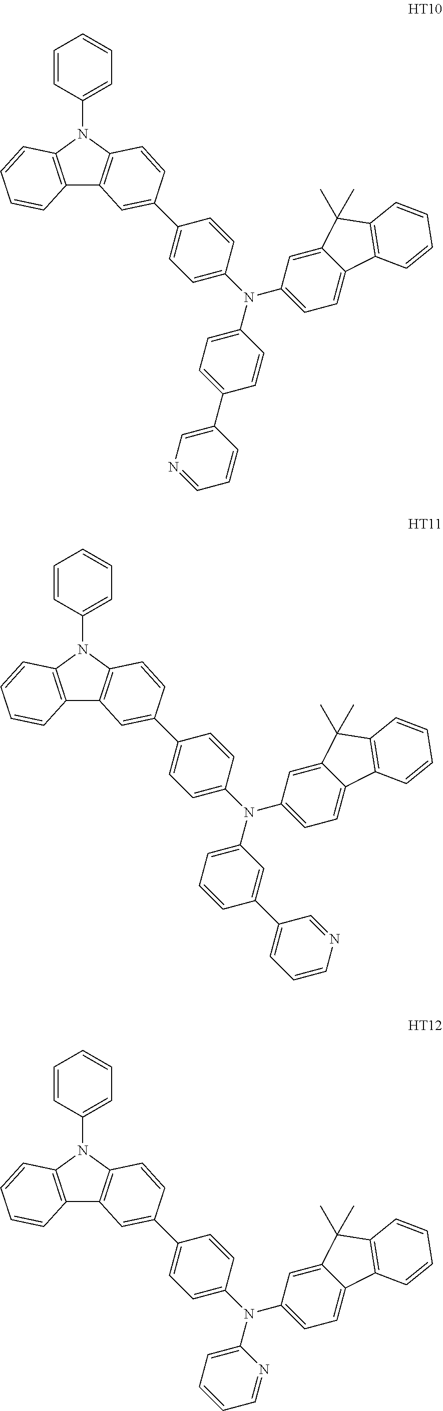 [SMILES: CC1(C)c2ccccc2-c2ccc(N(c3ccc(-c4cccnc4)cc3)c3ccc(-c4ccc5c(c4)c4ccccc4n5-c4ccccc4)cc3)cc21 ; CC1(C)c2ccccc2-c2ccc(N(c3ccc(-c4ccc5c(c4)c4ccccc4n5-c4ccccc4)cc3)c3cccc(-c4cccnc4)c3)cc21 ; CC1(C)c2ccccc2-c2ccc(N(c3ccc(-c4ccc5c(c4)c4ccccc4n5-c4ccccc4)cc3)c3ccccn3)cc21]

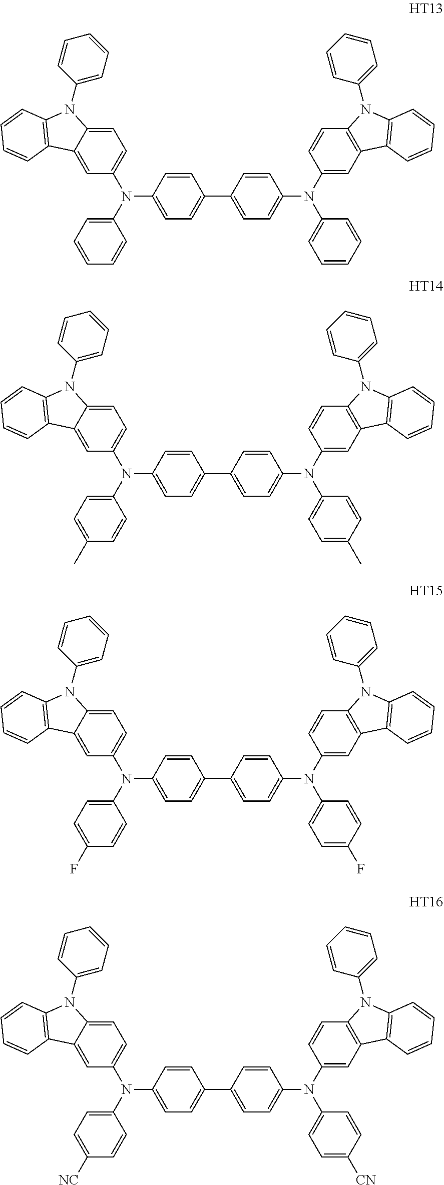 [SMILES: c1ccc(N(c2ccc(-c3ccc(N(c4ccccc4)c4ccc5c(c4)c4ccccc4n5-c4ccccc4)cc3)cc2)c2ccc3c(c2)c2ccccc2n3-c2ccccc2)cc1 ; Cc1ccc(N(c2ccc(-c3ccc(N(c4ccc(C)cc4)c4ccc5c(c4)c4ccccc4n5-c4ccccc4)cc3)cc2)c2ccc3c(c2)c2ccccc2n3-c2ccccc2)cc1 ; Fc1ccc(N(c2ccc(-c3ccc(N(c4ccc(F)cc4)c4ccc5c(c4)c4ccccc4n5-c4ccccc4)cc3)cc2)c2ccc3c(c2)c2ccccc2n3-c2ccccc2)cc1 ; N#Cc1ccc(N(c2ccc(-c3ccc(N(c4ccc(C#N)cc4)c4ccc5c(c4)c4ccccc4n5-c4ccccc4)cc3)cc2)c2ccc3c(c2)c2ccccc2n3-c2ccccc2)cc1]

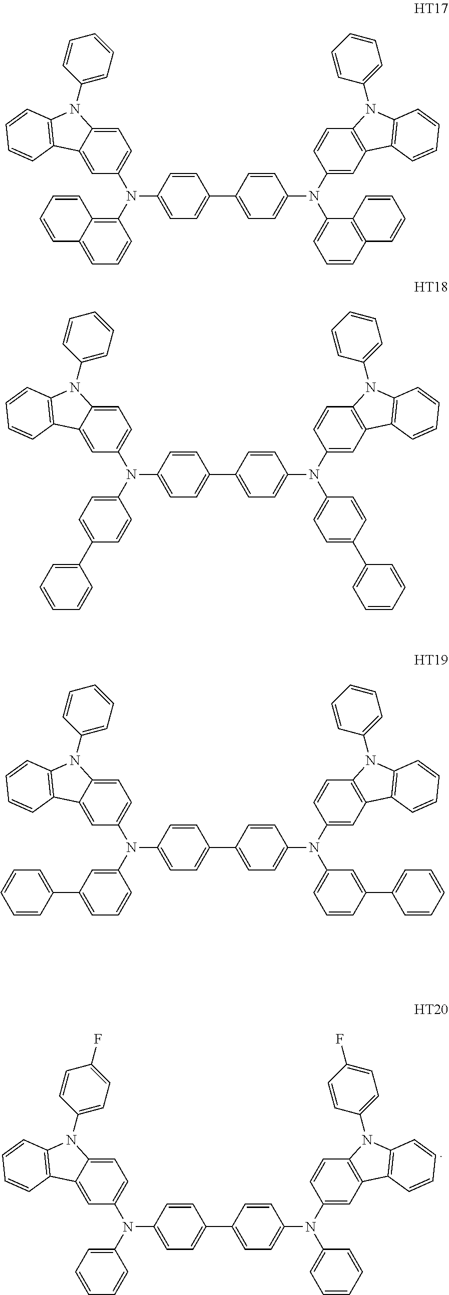 [SMILES: c1ccc(-n2c3ccccc3c3cc(N(c4ccc(-c5ccc(N(c6ccc7c(c6)c6ccccc6n7-c6ccccc6)c6cccc7ccccc67)cc5)cc4)c4cccc5ccccc45)ccc32)cc1 ; c1ccc(-c2ccc(N(c3ccc(-c4ccc(N(c5ccc(-c6ccccc6)cc5)c5ccc6c(c5)c5ccccc5n6-c5ccccc5)cc4)cc3)c3ccc4c(c3)c3ccccc3n4-c3ccccc3)cc2)cc1 ; c1ccc(-c2cccc(N(c3ccc(-c4ccc(N(c5cccc(-c6ccccc6)c5)c5ccc6c(c5)c5ccccc5n6-c5ccccc5)cc4)cc3)c3ccc4c(c3)c3ccccc3n4-c3ccccc3)c2)cc1 ; Fc1ccc(-n2c3ccccc3c3cc(N(c4ccccc4)c4ccc(-c5ccc(N(c6ccccc6)c6ccc7c(c6)c6ccccc6n7-c6ccc(F)cc6)cc5)cc4)ccc32)cc1]

A thickness of the hole transport region may be about 100 Å to about 10,000 Å, for example, about 100 Å to about 1,000 Å. When the hole transport region includes at least one of a hole injection layer and a hole transport layer, a thickness of the hole injection layer may be about 50 Å to about 10,000 Å, for example, about 100 Å to about 1,000 Å, and a thickness of the hole transport layer may be about 50 Å to about 2,000 Å, for example, about 100 Å to about 1,500 Å. When the thicknesses of the hole transport region, the hole injection layer, and the hole transport layer are within these ranges, satisfactory hole transporting characteristics may be obtained without a substantial increase in driving voltage.

The hole transport region may further include, in addition to the aforementioned materials, a charge-generation material for the improvement of conductive properties. The charge-generation material may be homogeneously or non-homogeneously dispersed in the hole transport region.

The charge-generation material may be, for example, a p-dopant. The p-dopant may be one of a quinone derivative, a metal oxide, or a cyano group-containing compound, but embodiments are not limited thereto. Non-limiting examples of the p-dopant include a quinone derivative, such as tetracyanoquinonedimethane (TCNQ) or 2,3,5,6-tetrafluoro-tetracyano-1,4-benzoquinonedimethane (F4-TCNQ); a metal oxide, such as a tungsten oxide or a molybdenum oxide; or a cyano group-containing compound, such as Compound HT-D1 or F12, but are not limited thereto:

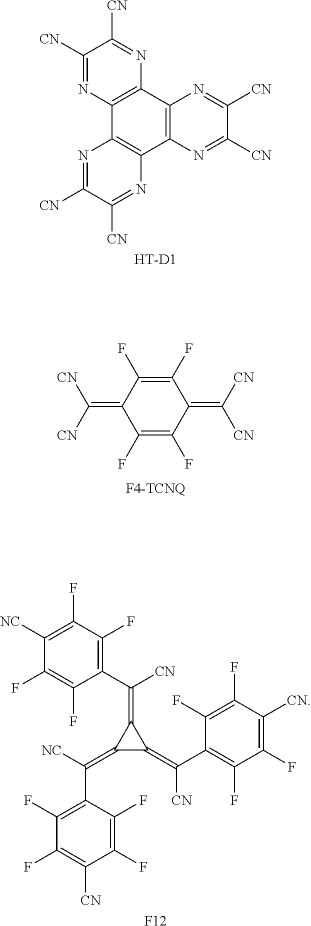

The hole transport region may further include a buffer layer.

The buffer layer may compensate for an optical resonance distance according to a wavelength of light emitted from the emission layer 15, and thus, efficiency of a formed organic light-emitting device may be improved.

Then, the emission layer may be formed on the hole transport region by vacuum deposition, spin coating, casting, LB deposition, or the like. When the emission layer is formed by vacuum deposition or spin coating, the deposition or coating conditions may be similar to those applied in forming the hole injection layer although the deposition or coating conditions may vary depending on a material to be used to form the emission layer.

Meanwhile, when the hole transport region includes an electron blocking layer, a material for forming the electron blocking layer may be selected from the aforementioned materials for forming the hole transport region and host materials to be described later, but embodiments are not limited thereto. For example, when the hole transport region includes an electron blocking layer, a material for forming the electron blocking layer may be mCP which will be described later.

When the organic light-emitting device 10 is a full-color organic light-emitting device, the emission layer may be patterned into a red emission layer, a green emission layer, and/or a blue emission layer. Due to a structure in which a red emission layer, a green emission layer, and/or a blue emission layer is stacked, the emission layer may emit a white light.

When the emission layer includes a host and a dopant, an amount of the dopant in the emission layer may be about 0.01 parts by weight to about 15 parts by weight, based on 100 parts by weight of the host, but embodiments are not limited thereto.

A thickness of the emission layer may be about 100 Å to about 1,000 Å, for example, about 200 Å to about 600 Å. When the thickness of the emission layer is within these ranges, excellent luminescence characteristics may be obtained without a substantial increase in driving voltage.

An electron transport region may be arranged on the emission layer.

The electron transport region may include a hole blocking layer, an electron transport layer, an electron injection layer, or a combination thereof.

For example, the electron transport region may have a hole blocking layer/electron transport layer/electron injection layer structure, or an electron transport layer/electron injection layer structure, but embodiments are not limited thereto. The electron transport layer may have a single-layer structure or a multi-layer structure including a plurality of layers.

Conditions for forming the hole blocking layer, the electron transport layer, and the electron injection layer which constitute the electron transport region may be understood by referring to the conditions for forming the hole injection layer.

When the electron transport region includes a hole blocking layer, the hole blocking layer may include, for example, at least one of 2,9-dimethyl-4,7-diphenyl-1,10-phenanthroline (BCP), 4,7-diphenyl-1,10-phenanthroline (Bphen), or bis(2-methyl-8-quinolinolato-N1,O8)-(1,1′-biphenyl-4-olato)aluminum (BAlq), but embodiments are not limited thereto:

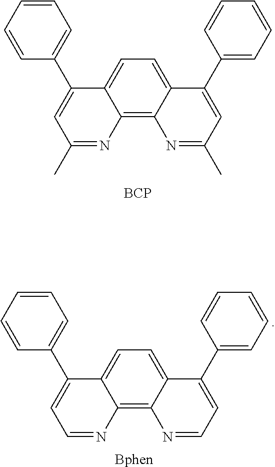

A thickness of the hole blocking layer may be about 20 Å to about 1,000 Å, for example, about 30 Å to about 300 Å. When the thickness of the hole blocking layer is within these ranges, excellent hole blocking characteristics may be obtained without a substantial increase in driving voltage.

The electron transport layer may further include at least one of 2,9-dimethyl-4,7-diphenyl-1,10-phenanthroline (BCP), 4,7-diphenyl-1,10-phenanthroline (Bphen), tris(8-hydroxy-quinolinato)aluminum (Alq₃), bis(2-methyl-8-quinolinolato-N1,O8)-(1,1′-biphenyl-4-olato)aluminum (BAlq), 3-(4-biphenylyl)-4-phenyl-5-tert-butylphenyl-1,2,4-triazole (TAZ), or 4-(naphthalen-1-yl)-3,5-diphenyl-4H-1,2,4-triazole (NTAZ), but embodiments are not limited thereto:

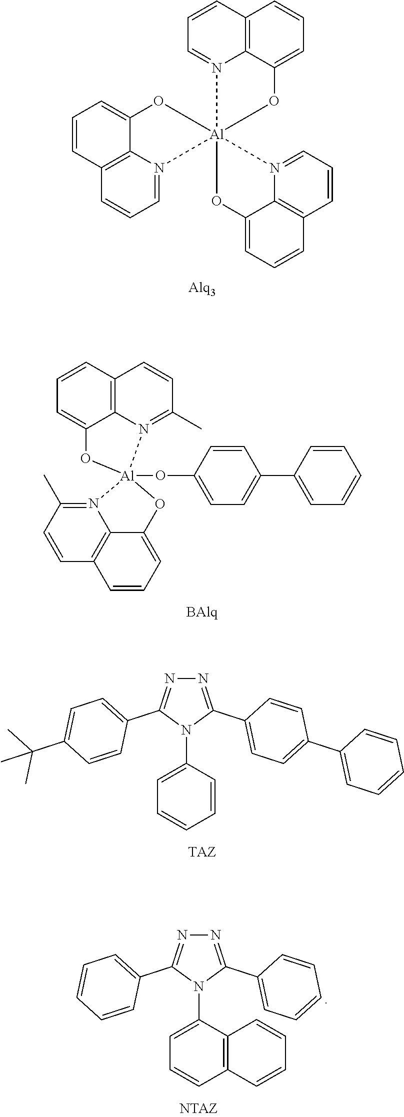

The electron transport layer may include at least one of Compounds ET1 to ET25, but embodiments are not limited thereto:

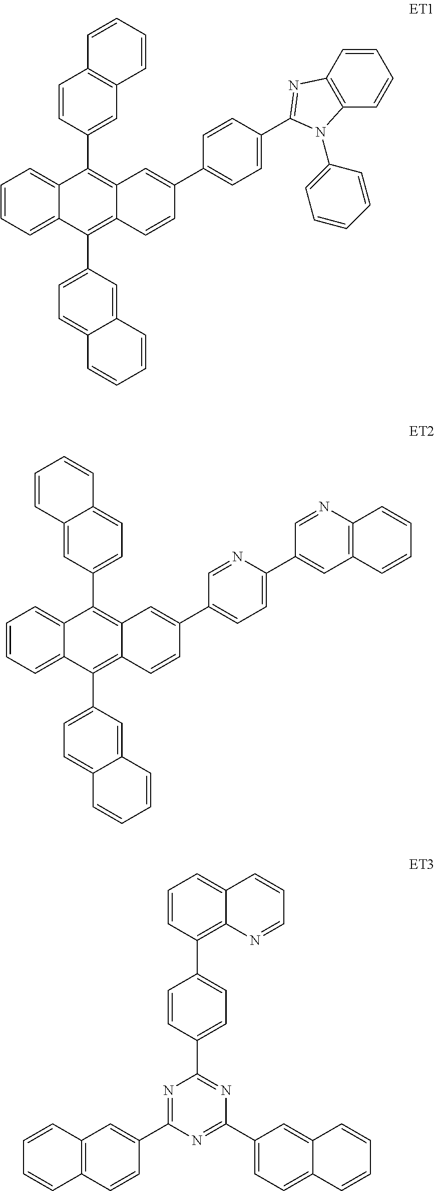 [SMILES: c1ccc(-n2c(-c3ccc(-c4ccc5c(-c6ccc7ccccc7c6)c6ccccc6c(-c6ccc7ccccc7c6)c5c4)cc3)nc3ccccc32)cc1 ; c1ccc2cc(-c3c4ccccc4c(-c4ccc5ccccc5c4)c4cc(-c5ccc(-c6cnc7ccccc7c6)nc5)ccc34)ccc2c1 ; c1ccc2cc(-c3nc(-c4ccc(-c5cccc6cccnc56)cc4)nc(-c4ccc5ccccc5c4)n3)ccc2c1]

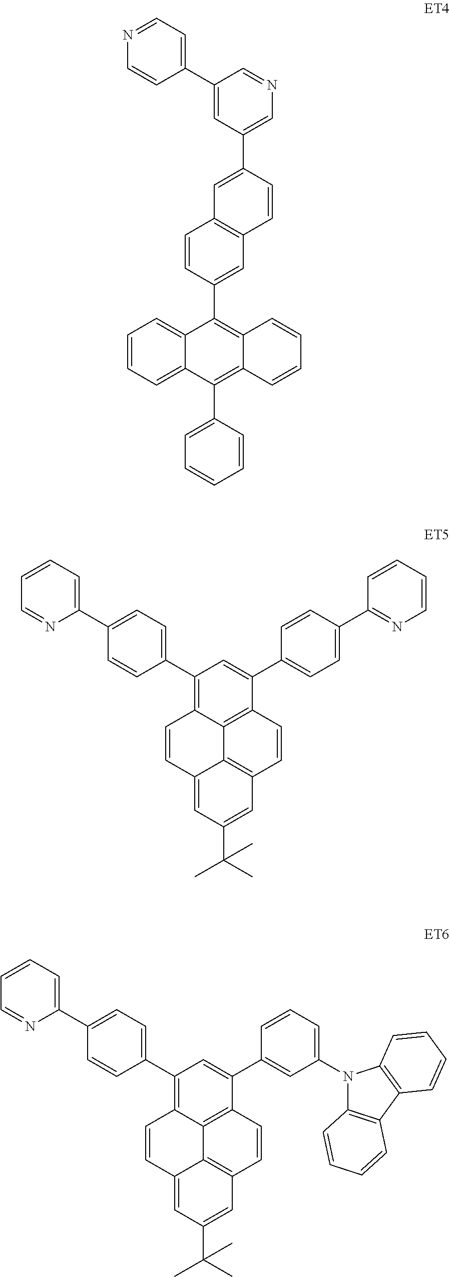 [SMILES: c1ccc(-c2c3ccccc3c(-c3ccc4cc(-c5cncc(-c6ccncc6)c5)ccc4c3)c3ccccc23)cc1 ; CC(C)(C)c1cc2ccc3c(-c4ccc(-c5ccccn5)cc4)cc(-c4ccc(-c5ccccn5)cc4)c4ccc(c1)c2c34 ; CC(C)(C)c1cc2ccc3c(-c4ccc(-c5ccccn5)cc4)cc(-c4cccc(-n5c6ccccc6c6ccccc65)c4)c4ccc(c1)c2c34]

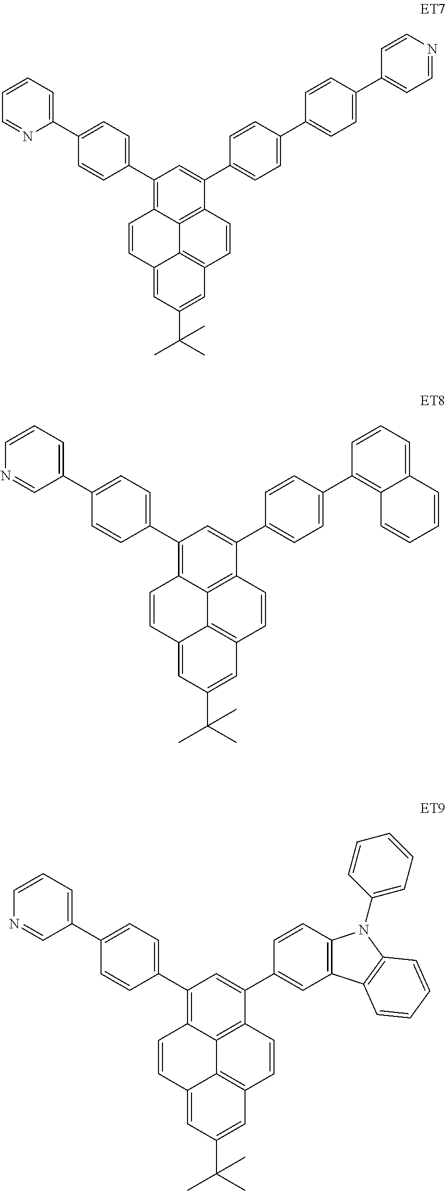 [SMILES: CC(C)(C)c1cc2ccc3c(-c4ccc(-c5ccc(-c6ccncc6)cc5)cc4)cc(-c4ccc(-c5ccccn5)cc4)c4ccc(c1)c2c34 ; CC(C)(C)c1cc2ccc3c(-c4ccc(-c5cccnc5)cc4)cc(-c4ccc(-c5cccc6ccccc56)cc4)c4ccc(c1)c2c34 ; CC(C)(C)c1cc2ccc3c(-c4ccc(-c5cccnc5)cc4)cc(-c4ccc5c(c4)c4ccccc4n5-c4ccccc4)c4ccc(c1)c2c34]

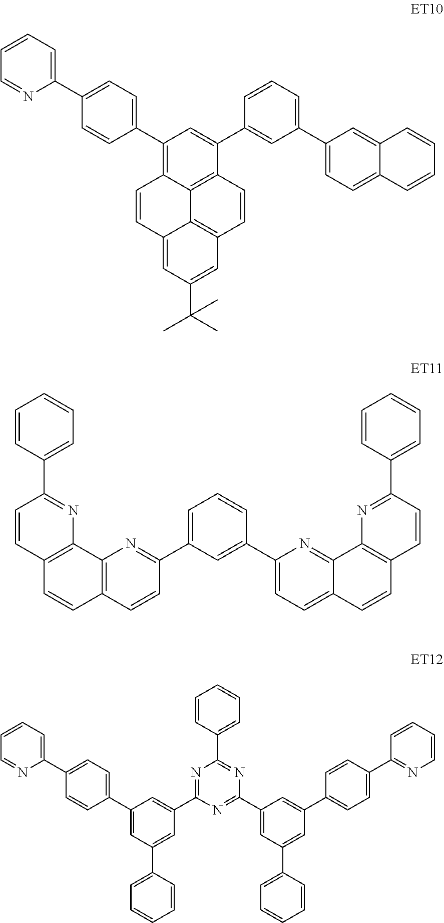 [SMILES: CC(C)(C)c1cc2ccc3c(-c4ccc(-c5ccccn5)cc4)cc(-c4cccc(-c5ccc6ccccc6c5)c4)c4ccc(c1)c2c34 ; c1ccc(-c2ccc3ccc4ccc(-c5cccc(-c6ccc7ccc8ccc(-c9ccccc9)nc8c7n6)c5)nc4c3n2)cc1 ; c1ccc(-c2cc(-c3ccc(-c4ccccn4)cc3)cc(-c3nc(-c4ccccc4)nc(-c4cc(-c5ccccc5)cc(-c5ccc(-c6ccccn6)cc5)c4)n3)c2)cc1]

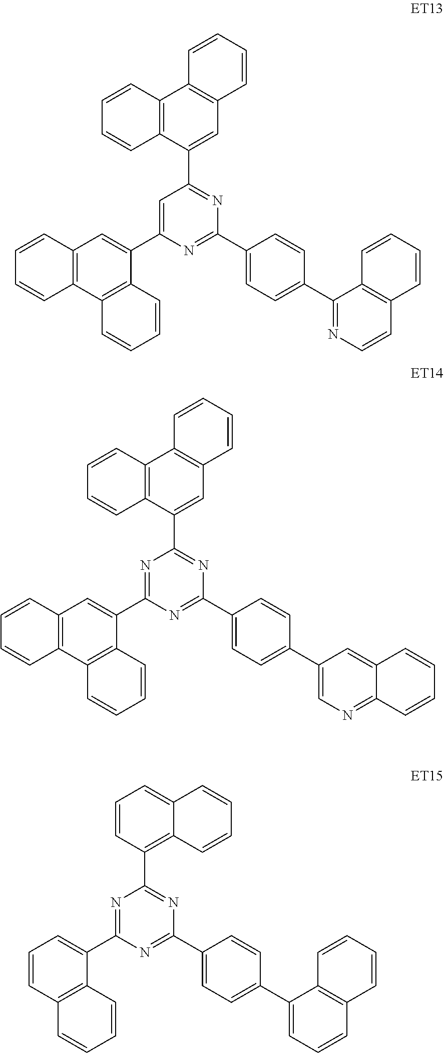 [SMILES: c1ccc2c(-c3ccc(-c4nc(-c5cc6ccccc6c6ccccc56)cc(-c5cc6ccccc6c6ccccc56)n4)cc3)nccc2c1 ; c1ccc2ncc(-c3ccc(-c4nc(-c5cc6ccccc6c6ccccc56)nc(-c5cc6ccccc6c6ccccc56)n4)cc3)cc2c1 ; c1ccc2c(-c3ccc(-c4nc(-c5cccc6ccccc56)nc(-c5cccc6ccccc56)n4)cc3)cccc2c1]

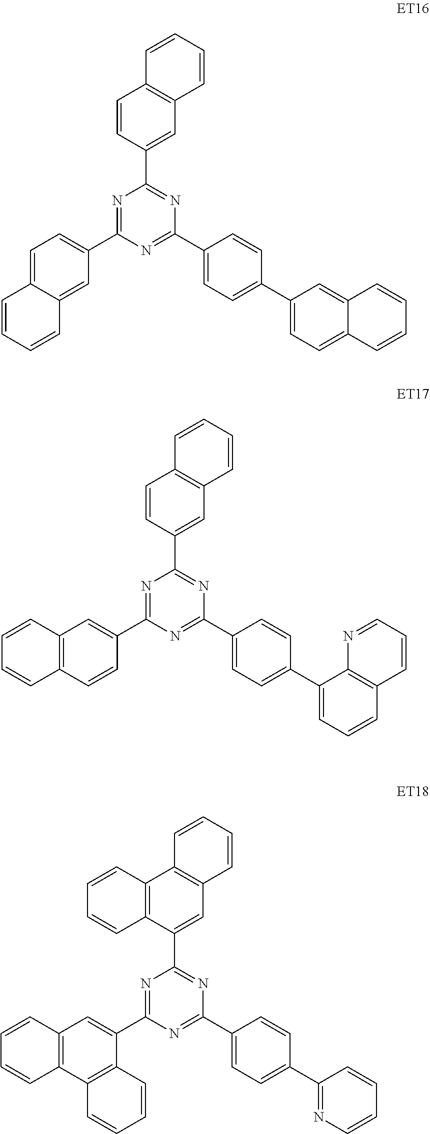 [SMILES: c1ccc2cc(-c3ccc(-c4nc(-c5ccc6ccccc6c5)nc(-c5ccc6ccccc6c5)n4)cc3)ccc2c1 ; c1ccc2cc(-c3nc(-c4ccc(-c5cccc6cccnc56)cc4)nc(-c4ccc5ccccc5c4)n3)ccc2c1 ; c1ccc(-c2ccc(-c3nc(-c4cc5ccccc5c5ccccc45)nc(-c4cc5ccccc5c5ccccc45)n3)cc2)nc1]

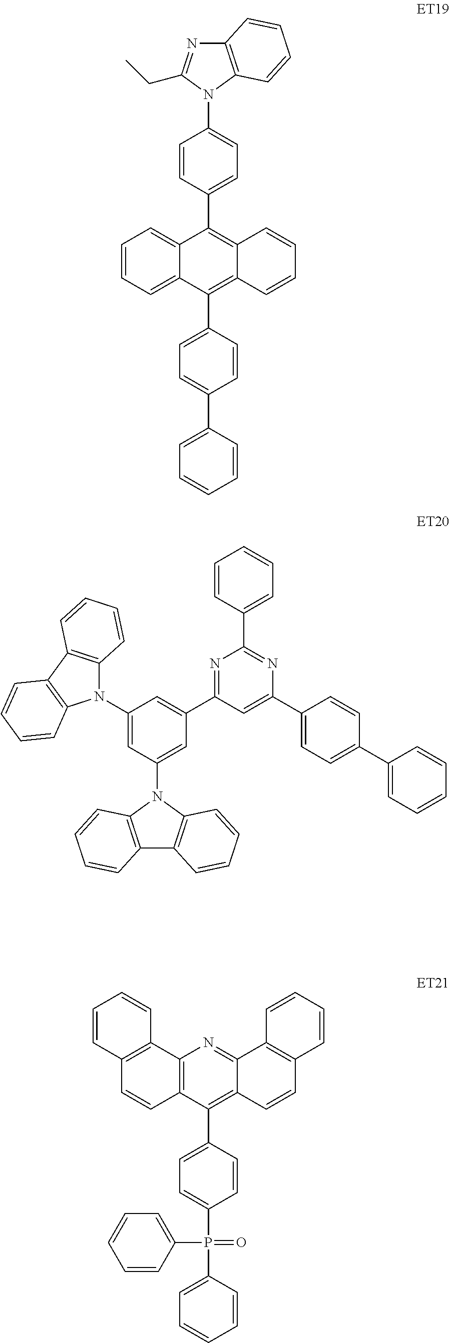 [SMILES: CCc1nc2ccccc2n1-c1ccc(-c2c3ccccc3c(-c3ccc(-c4ccccc4)cc3)c3ccccc23)cc1 ; c1ccc(-c2ccc(-c3cc(-c4cc(-n5c6ccccc6c6ccccc65)cc(-n5c6ccccc6c6ccccc65)c4)nc(-c4ccccc4)n3)cc2)cc1 ; O=P(c1ccccc1)(c1ccccc1)c1ccc(-c2c3ccc4ccccc4c3nc3c2ccc2ccccc23)cc1]

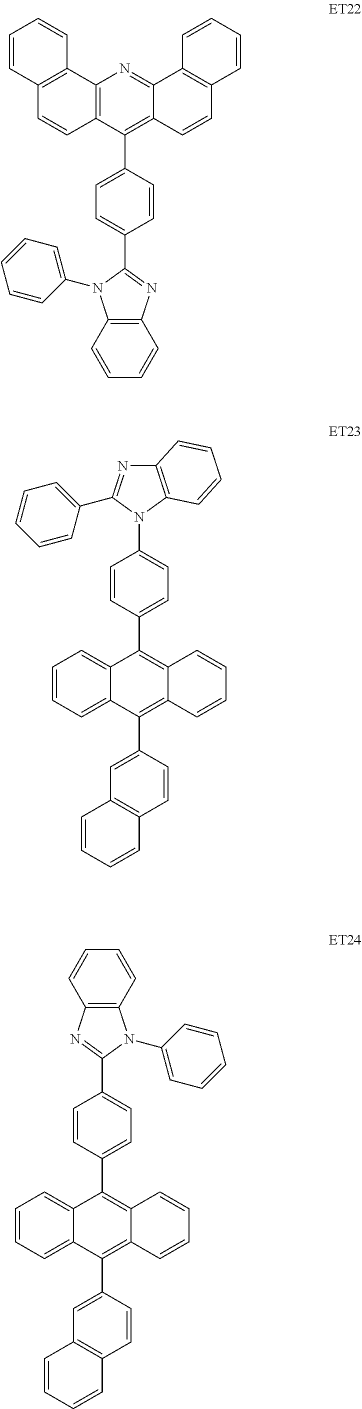 [SMILES: c1ccc(-n2c(-c3ccc(-c4c5ccc6ccccc6c5nc5c4ccc4ccccc45)cc3)nc3ccccc32)cc1 ; c1ccc(-c2nc3ccccc3n2-c2ccc(-c3c4ccccc4c(-c4ccc5ccccc5c4)c4ccccc34)cc2)cc1 ; c1ccc(-n2c(-c3ccc(-c4c5ccccc5c(-c5ccc6ccccc6c5)c5ccccc45)cc3)nc3ccccc32)cc1]

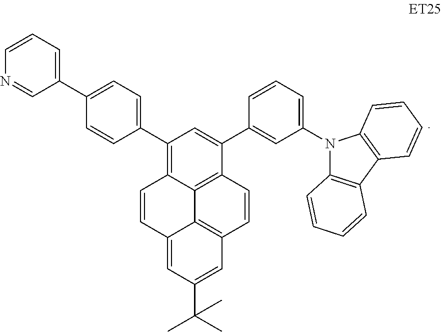 [SMILES: CC(C)(C)c1cc2ccc3c(-c4ccc(-c5cccnc5)cc4)cc(-c4cccc(-n5c6ccccc6c6ccccc65)c4)c4ccc(c1)c2c34]

A thickness of the electron transport layer may be about 100 Å to about 1,000 Å, for example, about 150 Å to about 500 Å. When the thickness of the electron transport layer is within these ranges, satisfactory electron transporting characteristics may be obtained without a substantial increase in driving voltage.

The electron transport layer may further include, in addition to the aforementioned materials, a metal-containing material.

The metal-containing material may include a Li complex. The Li complex may include, for example, Compound ET-D1 (lithium quinolate, LiQ) or ET-D2, but embodiments are not limited thereto:

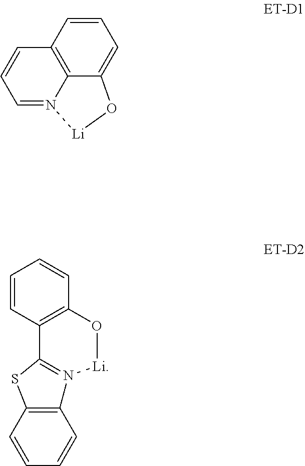

The electron transport region may also include an electron injection layer that facilitates the injection of electrons from the second electrode 19.

The electron injection layer may include LiQ, LiF, NaCl, CsF, Li₂O, BaO, or a combination thereof.

A thickness of the electron injection layer may be about 1 Å to about 100 Å, for example, about 3 Å to about 90 Å. When the thickness of the electron injection layer is within these ranges, satisfactory electron injection characteristics may be obtained without a substantial increase in driving voltage.

The second electrode 19 is arranged on the organic layer 15. The second electrode 19 may be a cathode. A material for forming the second electrode 19 may be metal, an alloy, an electrically conductive compound, or a combination thereof, each having a relatively low work function. For example, the material for forming the second electrode 19 may include lithium (Li), magnesium (Mg), aluminum (Al), silver (Ag), aluminum-lithium (Al—Li), calcium (Ca), magnesium-indium (Mg—In), magnesium-silver (Mg—Ag), and the like. To manufacture a top-emission type light-emitting device, a transmissive electrode formed using ITO or IZO may be used as the second electrode 19.

Hereinbefore, the organic light-emitting device has been described with reference to FIG. 1, but embodiments are not limited thereto.

Another aspect provides an electronic apparatus including the organic light-emitting device.

The electronic apparatus may further include a thin-film transistor in addition to the aforementioned organic light-emitting device. The thin-film transistor may include a source electrode, a drain electrode, and an active layer, wherein any one of the source electrode and the drain electrode may be electrically connected to any one of the first electrode and the second electrode of the organic light-emitting device.

Another aspect provides a diagnostic composition including at least one of the heterocyclic compounds represented by Formula 1.

The diagnostic composition may include at least one type of heterocyclic compound represented by Formula 1.

The heterocyclic compound represented by Formula 1 may be able to provide high luminescence efficiency, and thus the diagnostic composition including at least one of the heterocyclic compounds represented by Formula 1 may have high diagnostic efficiency.

The diagnostic composition may be used in various applications including a diagnosis kit, a diagnosis reagent, a biosensor, a biomarker, or the like, but embodiments are not limited thereto.

The term “C₁-C₆₀ alkyl group” as used herein refers to a linear or branched saturated aliphatic hydrocarbon monovalent group having 1 to 60 carbon atoms. The term “C₁-C₆₀ alkylene group” as used herein refers to a divalent group having the same structure as the C₁-C₆₀ alkyl group.

Non-limiting examples of the C₁-C₆₀ alkyl group, the C₁-C₂₀ alkyl group, and/or the C₁-C₁₀ alkyl group include a methyl group, an ethyl group, an n-propyl group, an isopropyl group, an n-butyl group, a sec-butyl group, an isobutyl group, a tert-butyl group, an n-pentyl group, a tert-pentyl group, a neopentyl group, an isopentyl group, a sec-pentyl group, a 3-pentyl group, a sec-isopentyl group, an n-hexyl group, an isohexyl group, a sec-hexyl group, a tert-hexyl group, an n-heptyl group, an isoheptyl group, a sec-heptyl group, a tert-heptyl group, an n-octyl group, an isooctyl group, a sec-octyl group, a tert-octyl group, an n-nonyl group, an isononyl group, a sec-nonyl group, a tert-nonyl group, an n-decyl group, an isodecyl group, a sec-decyl group, or a tert-decyl group, each unsubstituted or substituted with a methyl group, an ethyl group, an n-propyl group, an isopropyl group, an n-butyl group, a sec-butyl group, an isobutyl group, a tert-butyl group, an n-pentyl group, a tert-pentyl group, a neopentyl group, an isopentyl group, a sec-pentyl group, a 3-pentyl group, a sec-isopentyl group, an n-hexyl group, an isohexyl group, a sec-hexyl group, a tert-hexyl group, an n-heptyl group, an isoheptyl group, a sec-heptyl group, a tert-heptyl group, an n-octyl group, an isooctyl group, a sec-octyl group, a tert-octyl group, an n-nonyl group, an isononyl group, a sec-nonyl group, a tert-nonyl group, an n-decyl group, an isodecyl group, a sec-decyl group, a tert-decyl group, or a combination thereof. For example, a group represented by Formula 9-33 may be a C₆ alkyl group, such as a tert-butyl group substituted with two methyl groups.

The term “C₁-C₆₀ alkoxy group” as used herein refers to a monovalent group represented by —OA₁₀₁ (wherein A₁₀₁ is the C₁-C₆₀ alkyl group), and non-limiting examples thereof include a methoxy group, an ethoxy group, an isopropyloxy group, an n-propoxy group, a butoxy group, a pentoxy group, or the like.

The term “C₁-C₆₀ alkylthio group” as used herein refers to a monovalent group represented by —SA₁₀₁, (wherein A₁₀₁, is the C₁-C₆₀ alkyl group).

The term “C₂-C₆₀ alkenyl group” as used herein refers to a hydrocarbon group formed by substituting at least one carbon-carbon double bond in the middle or at the terminus of the C₂-C₆₀ alkyl group, and non-limiting examples thereof include an ethenyl group, a propenyl group, a butenyl group, or the like. The term “C₂-C₆₀ alkenylene group” as used herein refers to a divalent group having the same structure as the C₂-C₆₀ alkenyl group.

The term “C₂-C₆₀ alkynyl group” as used herein refers to a hydrocarbon group formed by substituting at least one carbon-carbon triple bond in the middle or at the terminus of the C₂-C₆₀ alkyl group, and non-limiting examples thereof include an ethynyl group, a propynyl group, or the like. The term “C₂-C₆₀ alkynylene group” as used herein refers to a divalent group having the same structure as the C₂-C₆₀ alkynyl group.

The term “C₃-C₁₀ cycloalkyl group” as used herein refers to a monovalent saturated hydrocarbon group having 3 to 10 carbon atoms. The term “C₃-C₁₀ cycloalkylene group” as used herein refers to a divalent group having the same structure as the C₃-C₁₀ cycloalkyl group.

Non-limiting examples of the C₃-C₁₀ cycloalkyl group include a cyclopropyl group, a cyclobutyl group, a cyclopentyl group, a cyclohexyl group, a cycloheptyl group, a cyclooctyl group, an adamantanyl group, a bicyclo[1.1.1]pentyl group, a bicyclo[2.1.1]hexyl group, a bicyclo[2.2.1]heptyl(norbornanyl) group, a bicyclo[2.2.2]octyl group, or the like.

The term “C₁-C₁₀ heterocycloalkyl group” as used herein refers to a monovalent group having at least one heteroatom selected from B, N, O, P, Si, S, Se, and Ge as a ring-forming atom and 1 to 10 carbon atoms as ring-forming atom(s). The term “C₁-C₁₀ heterocycloalkylene group” as used herein refers to a divalent group having the same structure as the C₁-C₁₀ heterocycloalkyl group.

Non-limiting examples of the C₁-C₁₀ heterocycloalkyl group include a silolanyl group, a silinanyl group, tetrahydrofuranyl group, a tetrahydro-2H-pyranyl group, a tetrahydrothiophenyl group, or the like.

The term “C₃-C₁₀ cycloalkenyl group” as used herein refers to a monovalent monocyclic group that has 3 to 10 carbon atoms, at least one carbon-carbon double bond in the ring thereof, and no aromaticity, and non-limiting examples thereof include a cyclopentenyl group, a cyclohexenyl group, a cycloheptenyl group, and the like. The term “C₃-C₁₀ cycloalkenylene group” as used herein refers to a divalent group having the same structure as the C₃-C₁₀ cycloalkenyl group.

The term “C₁-C₁₀ heterocycloalkenyl group” as used herein refers to a monovalent group that has at least one heteroatom selected from B, N, O, P, Si, S, Se, and Ge as a ring-forming atom, 1 to 10 carbon atoms as ring-forming atom(s), and at least one double bond in the ring structure thereof. Non-limiting examples of the C₁-C₁₀ heterocycloalkenyl group include a 2,3-dihydrofuranyl group, a 2,3-dihydrothiophenyl group, or the like. The term “C₁-C₁₀ heterocycloalkenylene group” as used herein refers to a divalent group having the same structure as the C₁-C₁₀ heterocycloalkenyl group.

The term “C₆-C₆₀ aryl group” as used herein refers to a monovalent group having a carbocyclic aromatic ring system having 6 to 60 carbon atoms, and the term “C₆-C₆₀ arylene group” as used herein refers to a divalent group having a carbocyclic aromatic ring system having 6 to 60 carbon atoms. Non-limiting examples of the C₆-C₆₀ aryl group include a phenyl group, a naphthyl group, an anthracenyl group, a phenanthrenyl group, a pyrenyl group, a chrysenyl group, or the like. When the C₆-C₆₀ aryl group and the C₆-C₆₀ arylene group each include two or more rings, the rings may be fused with each other.

The term “C₇-C₆₀ alkyl aryl group” as used herein refers to a C₆-C₆₀ aryl group substituted with at least one C₁-C₆₀ alkyl group. The term “C₇-C₆₀ aryl alkyl group” as used herein refers to a C₁-C₆₀ alkyl group substituted with at least one C₆-C₆₀ aryl group.

The term “C₁-C₆₀ heteroaryl group” as used herein refers to a monovalent group having a heteroaromatic ring system having at least one heteroatom selected from B, N, O, P, Si, S, Se, and Ge as a ring-forming atom and 1 to 60 carbon atoms as ring-forming atom(s), and the term “C₁-C₆₀ heteroarylene group” as used herein refers to a divalent group having a heteroaromatic ring system having at least one heteroatom selected from B, N, O, P, Si, S, Se, and Ge as a ring-forming atom and 1 to 60 carbon atoms as ring-forming atom(s). Non-limiting examples of the C₁-C₆₀ heteroaryl group include a pyridinyl group, a pyrimidinyl group, a pyrazinyl group, a pyridazinyl group, a triazinyl group, a quinolinyl group, an isoquinolinyl group, or the like. When the C₁-C₆₀ heteroaryl group and the C₁-C₆₀ heteroarylene group each include two or more rings, the rings may be fused with each other.

The term “C₂-C₆₀ alkyl heteroaryl group” as used herein refers to a C₁-C₆₀ heteroaryl group substituted with at least one C₁-C₆₀ alkyl group. The term “C₂-C₆₀ heteroaryl alkyl group” as used herein refers to a C₁-C₆₀ alkyl group substituted with at least one C₁-C₆₀ heteroaryl group.

The term “C₆-C₆₀ aryloxy group” as used herein refers to —OA₁₀₂ (wherein A₁₀₂ is the C₆-C₆₀ aryl group), and the term “C₆-C₆₀ arylthio group” as used herein refers to —SA₁₀₃ (wherein A₁₀₃ is the C₆-C₆₀ aryl group).

The term “C₁-C₆₀ heteroaryloxy group” as used herein indicates —OA₁₀₄ (wherein A₁₀₄ is the C₁-C₆₀ heteroaryl group), and the term “C₁-C₆₀ heteroarylthio group” as used herein indicates —SA₁₀₅ (wherein A₁₀₅ is the C₁-C₆₀ heteroaryl group).

The term “monovalent non-aromatic condensed polycyclic group” as used herein refers to a monovalent group (for example, having 8 to 60 carbon atoms) having two or more rings condensed to each other, only carbon atoms as ring-forming atoms, and no aromaticity in the entire molecular structure. Non-limiting examples of the monovalent non-aromatic condensed polycyclic group include a fluorenyl group or the like. The term “divalent non-aromatic condensed polycyclic group” as used herein refers to a divalent group having the same structure as the monovalent non-aromatic condensed polycyclic group described above.

The term “monovalent non-aromatic condensed heteropolycyclic group” as used herein refers to a monovalent group (for example, having 1 to 60 carbon atoms) having two or more rings condensed with each other, a heteroatom selected from B, N, O, P, Si, S, Se, and Ge, other than carbon atoms, as a ring-forming atom, and no aromaticity in the entire molecular structure thereof. Non-limiting examples of the monovalent non-aromatic condensed heteropolycyclic group include a carbazolyl group or the like. The term “divalent non-aromatic condensed heteropolycyclic group” as used herein refers to a divalent group having the same structure as the monovalent non-aromatic condensed heteropolycyclic group.

The term “C₅-C₃₀ carbocyclic group” as used herein refers to a saturated or unsaturated ring group having, as a ring-forming atom, 5 to 30 carbon atoms only. The C₅-C₃₀ carbocyclic group may be a monocyclic group or a polycyclic group. Non-limiting examples of the “C₅-C₃₀ carbocyclic group (unsubstituted or substituted with at least one Ria)” as used herein include an adamantane group, a norbornene group, a bicyclo[1.1.1]pentane group, a bicyclo[2.1.1]hexane group, a bicyclo[2.2.1]heptane(norbornane) group, a bicyclo[2.2.2]octane group, a cyclopentane group, a cyclohexane group, a cyclohexene group, a benzene group, a naphthalene group, an anthracene group, a phenanthrene group, a triphenylene group, a pyrene group, a chrysene group, a 1,2,3,4-tetrahydronaphthalene group, a cyclopentadiene group, an indene group, a fluorene group, or the like (each unsubstituted or substituted with at least one R₁ₐ).

The term “C₁-C₃₀ heterocyclic group” as used herein refers to a saturated or unsaturated ring group having at least one heteroatom selected from B, N, O, P, Si, S, Se, and Ge, other than 1 to 30 carbon atoms, as a ring-forming atom. The C₁-C₃₀ heterocyclic group may be a monocyclic group or a polycyclic group. Non-limiting examples of the “C₁-C₃₀ heterocyclic group (unsubstituted or substituted with at least one R₁ₐ)” as used herein include a thiophene group, a furan group, a pyrrole group, a silole group, borole group, a phosphole group, a selenophene group, a germole group, a benzothiophene group, a benzofuran group, an indole group, a silole group, a benzosilole group, a benzoborole group, a benzophosphole group, a benzoselenophene group, a benzogermole group, a dibenzothiophene group, a dibenzofuran group, a carbazole group, a dibenzosilole group, a dibenzoborole group, a dibenzophosphole group, a dibenzoselenophene group, a dibenzogermole group, a dibenzothiophene 5-oxide group, a 9H-fluoren-9-one group, a dibenzothiophene 5,5-dioxide group, an azabenzothiophene group, an azabenzofuran group, an azaindole group, an azaindene group, an azabenzosilole group, an azabenzoborole group, an azabenzophosphole group, an azabenzoselenophene group, an azabenzogermole group, an azadibenzothiophene group, an azadibenzofuran group, an azacarbazole group, an azafluorene group, an azadibenzosilole group, an azadibenzoborole group, an azadibenzophosphole group, an azadibenzoselenophene group, an azadibenzogermole group, an azadibenzothiophene 5-oxide group, an aza-9H-fluoren-9-one group, an azadibenzothiophene 5,5-dioxide group, a pyridine group, a pyrimidine group, a pyrazine group, a pyridazine group, a triazine group, a quinoline group, an isoquinoline group, a quinoxaline group, a quinazoline group, a phenanthroline group, a pyrazole group, an imidazole group, a triazole group, an oxazole group, an isooxazole group, a thiazole group, an isothiazole group, an oxadiazole group, a thiadiazole group, a benzopyrazole group, a benzimidazole group, a benzoxazole group, a benzothiazole group, a benzoxadiazole group, a benzothiadiazole group, a 5,6,7,8-tetrahydroisoquinoline group, a 5,6,7,8-tetrahydroquinoline group, or the like (each unsubstituted or substituted with at least one R₁ₐ).

In the present specification, “TMS” indicates *—Si(CH₃)₃, and “TMG” indicates *—Ge(CH₃)₃.

At least one substituent of the substituted C₅-C₃₀ carbocyclic group, the substituted C₁-C₃₀ heterocyclic group, the substituted C₁-C₆₀ alkyl group, the substituted C₂-C₆₀ alkenyl group, the substituted C₂-C₆₀ alkynyl group, the substituted C₁-C₆₀ alkoxy group, the substituted C₁-C₆₀ alkylthio group, the substituted C₃-C₁₀ cycloalkyl group, the substituted C₁-C₁₀ heterocycloalkyl group, the substituted C₃-C₁₀ cycloalkenyl group, the substituted C₁-C₁₀ heterocycloalkenyl group, the substituted C₆-C₆₀ aryl group, the substituted C₇-C₆₀ alkyl aryl group, the substituted C₇-C₆₀ aryl alkyl group, the substituted C₆-C₆₀ aryloxy group, the substituted C₆-C₆₀ arylthio group, the substituted C₁-C₆₀ heteroaryl group, the substituted C₂-C₆₀ alkyl heteroaryl group, the substituted C₂-C₆₀ heteroaryl alkyl group, the substituted C₁-C₆₀ heteroaryloxy group, the substituted C₁-C₆₀ heteroarylthio group, the substituted monovalent non-aromatic condensed polycyclic group, and the substituted monovalent non-aromatic condensed heteropolycyclic group may be:
deuterium, —F, —Cl, —Br, —I, —SF₅, —CD₃, —CD₂H, —CDH₂, —CF₃, —CF₂H, —CFH₂, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₆₀ alkyl group, a C₂-C₆₀ alkenyl group, a C₂-C₆₀ alkynyl group, a C₁-C₆₀ alkoxy group, or a C₁-C₆₀ alkylthio group;
a C₁-C₆₀ alkyl group, a C₂-C₆₀ alkenyl group, a C₂-C₆₀ alkynyl group, a C₁-C₆₀ alkoxy group, or a C₁-C₆₀ alkylthio group, each substituted with deuterium, —F, —Cl, —Br, —I, —SF₅, —CD₃, —CD₂H, —CDH₂, —CF₃, —CF₂H, —CFH₂, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₇-C₆₀ alkyl aryl group, a C₆-C₆₀ aryloxy group, a C₆-C₆₀ arylthio group, a C₁-C₆₀ heteroaryl group, a C₂-C₆₀ alkyl heteroaryl group, a C₁-C₆₀ heteroaryloxy group, a C₁-C₆₀ heteroarylthio group, a monovalent non-aromatic condensed polycyclic group, a monovalent non-aromatic condensed heteropolycyclic group, —N(Q₁₁)(Q₁₂), —Si(Q₁₁)(Q₁₂)(Q₁₃), —Ge(Q₁₁)(Q₁₂)(Q₁₃), —C(═O)(Q₁), —S(═O)(Q₁), —S(═O)₂(Q₁), —B(Q₁)(Q₂), —P(Q₁)(Q₂), —P(═O)(Q₁)(Q₂), or —P(═S)(Q₁)(Q₂), or a combination thereof;
a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₇-C₆₀ alkyl aryl group, a C₆-C₆₀ aryloxy group, a C₆-C₆₀ arylthio group, a C₁-C₆₀ heteroaryl group, a C₂-C₆₀ alkyl heteroaryl group, a C₁-C₆₀ heteroaryloxy group, a C₁-C₆₀ heteroarylthio group, a monovalent non-aromatic condensed polycyclic group, or a monovalent non-aromatic condensed heteropolycyclic group;
a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₇-C₆₀ alkyl aryl group, a C₆-C₆₀ aryloxy group, a C₆-C₆₀ arylthio group, a C₁-C₆₀ heteroaryl group, a C₂-C₆₀ alkyl heteroaryl group, a C₁-C₆₀ heteroaryloxy group, a C₁-C₆₀ heteroarylthio group, a monovalent non-aromatic condensed polycyclic group, or a monovalent non-aromatic condensed heteropolycyclic group, each substituted with deuterium, —F, —Cl, —Br, —I, —SF₅, —CD₃, —CD₂H, —CDH₂, —CF₃, —CF₂H, —CFH₂, a hydroxyl group, a cyano group, a nitro group, an amidino group, a hydrazine group, a hydrazone group, a carboxylic acid group or a salt thereof, a sulfonic acid group or a salt thereof, a phosphoric acid group or a salt thereof, a C₁-C₆₀ alkyl group, a C₂-C₆₀ alkenyl group, a C₂-C₆₀ alkynyl group, a C₁-C₆₀ alkoxy group, a C₁-C₆₀ alkylthio group, a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₇-C₆₀ alkyl aryl group, a C₇-C₆₀ aryl alkyl group, a C₆-C₆₀ aryloxy group, a C₆-C₆₀ arylthio group, a C₁-C₆₀ heteroaryl group, a C₂-C₆₀ alkyl heteroaryl group, a C₂-C₆₀ heteroaryl alkyl group, a C₁-C₆₀ heteroaryloxy group, a C₁-C₆₀ heteroarylthio group, a monovalent non-aromatic condensed polycyclic group, a monovalent non-aromatic condensed heteropolycyclic group, —N(Q₂₁)(Q₂₂), —Si(Q₂₁)(Q₂₂)(Q₂₃), —Ge(Q₂₁)(Q₂₂)(Q₂₃), —C(═O)(Q₂₁), —S(═O)(Q₂₁), —S(═O)₂(Q₂₁), —B(Q₂₁)(Q₂₂), —P(Q₂₁)(Q₂₂), —P(═O)(Q₂₁)(Q₂₂), —P(═S)(Q₂₁)(Q₂₂), or a combination thereof; or
—N(Q₃₁)(Q₃₂), —Si(Q₃₁)(Q₃₂)(Q₃₃), —Ge(Q₃₁)(Q₃₂)(Q₃₃), —C(═O)(Q₃₁), —S(═O)(Q₃₁), —S(═O)₂(Q₃₁), —B(Q₃₁)(Q₃₂), —P(Q₃₁)(Q₃₂), —P(═O)(Q₃₁)(Q₃₂), or —P(═S)(Q₃₁)(Q₃₂), and
Q₁ to Q₃, Q₁₁ to Q₁₃, Q₂₁ to Q₂₃, and Q₃₁ to Q₃₃ may each independently be hydrogen, deuterium, —F, —Cl, —Br, —I, —SF₅, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₁-C₆₀ alkylthio group, a substituted or unsubstituted C₃-C₁₀ cycloalkyl group, a substituted or unsubstituted C₁-C₁₀ heterocycloalkyl group, a substituted or unsubstituted C₃-C₁₀ cycloalkenyl group, a substituted or unsubstituted C₂-C₁₀ heterocycloalkenyl group, a substituted or unsubstituted C₆-C₆₀ aryl group, a substituted or unsubstituted C₇-C₆₀ alkyl aryl group, a substituted or unsubstituted C₇-C₆₀ aryl alkyl group, a substituted or unsubstituted C₆-C₆₀ aryloxy group, a substituted or unsubstituted C₆-C₆₀ arylthio group, a substituted or unsubstituted C₁-C₆₀ heteroaryl group, a C₂-C₆₀ alkyl heteroaryl group, a C₂-C₆₀ heteroaryl alkyl group, a C₁-C₆₀ heteroaryloxy group, a C₁-C₆₀ heteroarylthio group, a substituted or unsubstituted monovalent non-aromatic condensed polycyclic group, or a substituted or unsubstituted monovalent non-aromatic condensed heteropolycyclic group.

Hereinafter, compounds and organic light-emitting devices, according to one or more embodiments, will be described in further detail with reference to Synthesis Example and Examples. However, the following examples are not intended to limit the scope of the disclosure. The wording “‘B’ was used instead of ‘A’” used in describing Synthesis Examples means that an amount of ‘A’ used was identical to an amount of ‘B’ used, in terms of a molar equivalent.

### EXAMPLES

### Synthesis Examples

### Synthesis Example 1: Synthesis of Compound 10

### (1) Synthesis of Compound 10_P-3

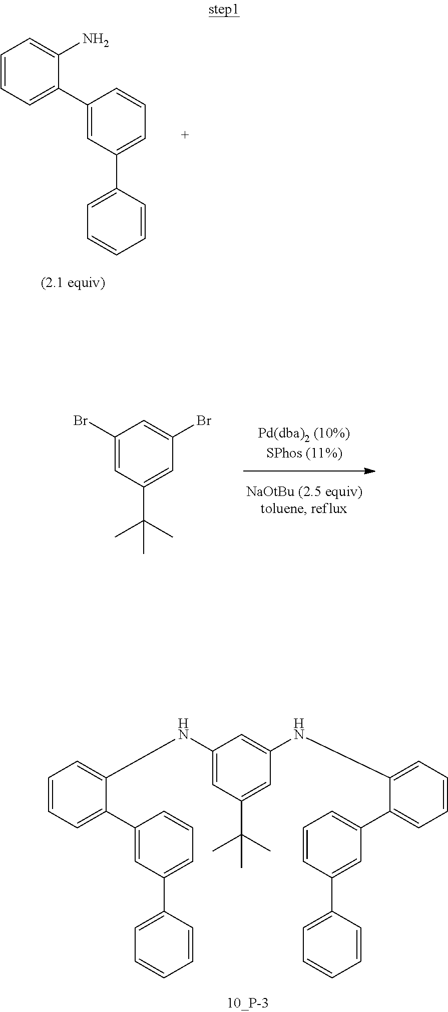 [SMILES: Nc1ccccc1-c1cccc(-c2ccccc2)c1 ; CC(C)(C)c1cc(Br)cc(Br)c1 ; CC(C)(C)c1cc(Nc2ccccc2-c2cccc(-c3ccccc3)c2)cc(Nc2ccccc2-c2cccc(-c3ccccc3)c2)c1]

1,3-dibromo-5(tert-butyl)benzene (11.12 grams (g), 38.1 millimoles (mmol)), [1,1′:3′,1″-terphenyl]-2-amine (19.91 g, 81.2 mmol), tris(dibenzylideneacetone)dipalladium(0) (Pd₂(dba)₃) (2.20 g, 3.87 mmol), 2-dicyclohexylphosphino-2′,6′-dimethoxybiphenyl (SPhos) (1.72 g, 4.25 mmol), and sodium t-butoxide (NaOtBu) (9.17 g, 96.6 mmol) were added to a 1,000 mL three-neck round-bottom flask with a magnetic stir bar. A cycle of vacuuming the flask and back filling it with nitrogen was repeated three times, and toluene (380 milliliters (mL)) was added to the flask and stirred at 110° C. for 7 hours. Then, the reaction was terminated by addition of water thereto. An extraction process was performed on the mixture three times by using dichloromethane, and an organic layer thus obtained was washed with brine water, dried with MgSO₄, and then filtered and concentrated. Resulting crude products were purified by MPLC (hexane/methylene chloride (MC) 8% to 45% gradient by weight) to obtain light gray solids, i.e., Compound 10_P-3 (24.23 g, 38.7 mmol, yield of >99%). As a result of liquid chromatography mass spectrometry (LCMS) analysis, the purity of Compound 10_P-3 was confirmed to be 98.93%. MS (ESI): 621 [M+H]⁺.

### (2) Synthesis of Compound 10_P-2

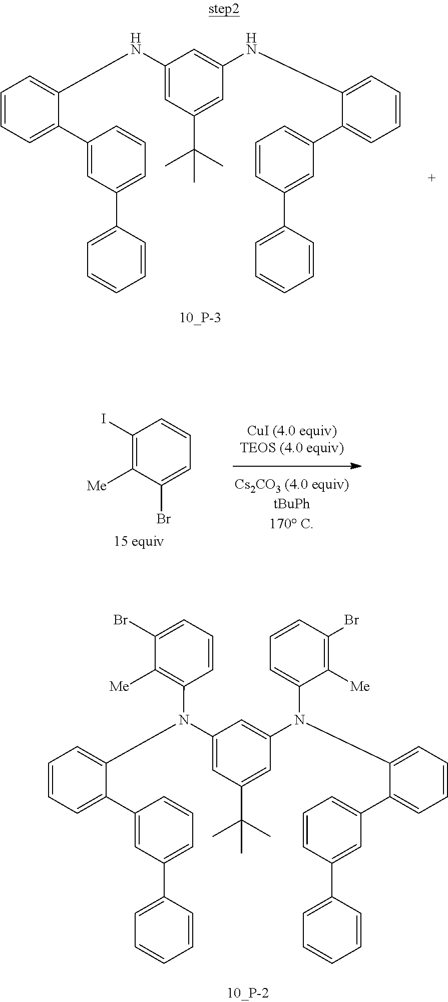 [SMILES: CC(C)(C)c1cc(Nc2ccccc2-c2cccc(-c3ccccc3)c2)cc(Nc2ccccc2-c2cccc(-c3ccccc3)c2)c1 ; Cc1c(Br)cccc1I ; Cc1c(Br)cccc1N(c1cc(N(c2ccccc2-c2cccc(-c3ccccc3)c2)c2cccc(Br)c2C)cc(C(C)(C)C)c1)c1ccccc1-c1cccc(-c2ccccc2)c1]

N¹,N³-di([1,1′:3′,1″-terphenyl]-2-yl)-5-(tert-butyl)benzene-1,3-diamine (Compound 10_P-3, 13.24 g, 20.9 mmol), 1-bromo-3-iodo-2-methylbenzene (44 mL, 312 mmol), CuI (15.9 g, 83.4 mmol), tetraethyl orthosilicate (TEOS, 9.3 mL, 41.7 mmol), and Cs₂CO₃ (27.2 g, 83.4 mmol) were added to a 250 mL three-neck flask round-bottom flask with a magnetic stir bar. A cycle of vacuuming the flask and back filling with nitrogen was repeated three times, and tert-butyl benzene (40 mL) was added to the flask and stirred at 170° C. for 24 hours. Then, the reaction mixture was filtered directly through a silica gel pad. Brown crude products obtained by evaporation-drying volatile materials were purified by MPLC (hexane/MC 5% to 35%) to obtain Compound 10_P-2 (10.35 g, 10.8 mmol, yield of 52%) and monoarylated product (9.50 g). As a result of LCMS analysis, the purity of Compound 10_P-2 was confirmed to be 98.63%. MS (ESI): 959 [M+H]⁺.

### (3) Synthesis of Compound 10_P-1

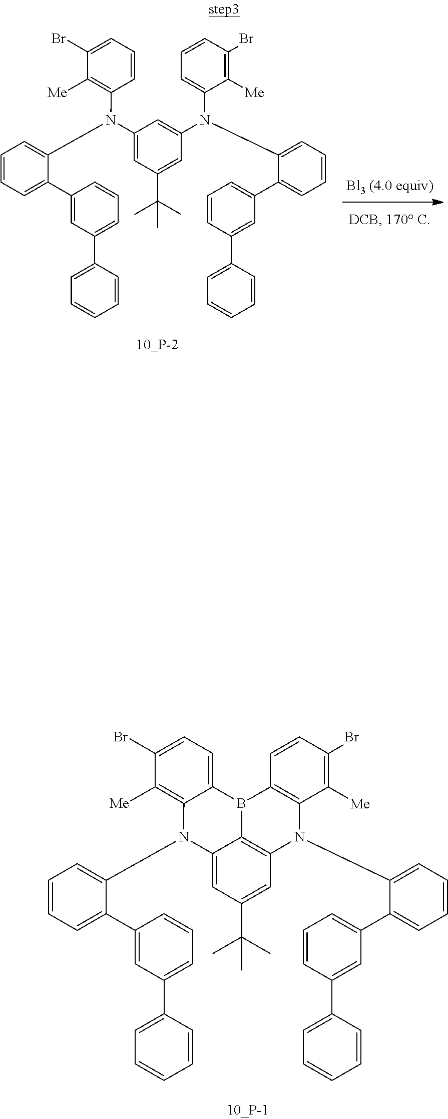 [SMILES: Cc1c(Br)cccc1N(c1cc(N(c2ccccc2-c2cccc(-c3ccccc3)c2)c2cccc(Br)c2C)cc(C(C)(C)C)c1)c1ccccc1-c1cccc(-c2ccccc2)c1 ; Cc1c(Br)ccc2c1N(c1ccccc1-c1cccc(-c3ccccc3)c1)c1cc(C(C)(C)C)cc3c1B2c1ccc(Br)c(C)c1N3c1ccccc1-c1cccc(-c2ccccc2)c1]

N¹,N³-3-di([1,1′:3′,1″-terphenyl]-2-yl)-N¹,N³-bis(3-bromo-2-methylphenyl)-5-(tert-butyl)benzene-1,3-diamine (Compound 10_P-2, 1.98 g, 2.07 mmol) was added to a test tube with a magnetic stir bar, and the test tube was placed in a glove bag. A cycle of vacuuming the glove bag and back filling with nitrogen was repeated three times, and boron triiodide (3.24 g, 8.28 mmol) was added thereto in a nitrogen atmosphere. After removing the test tube from the glove bag, o-dichlorobenzene (DCB) (10 mL) was added to the test tube and the reaction mixture was stirred at 170° C. for 24 hours. Then, the reaction was terminated by addition of a saturated Na₂S₂O₃ aqueous solution (sat. Na₂S₂O₃ aq.) and a saturated NaHCO₃ aqueous solution (sat. NaHCO₃ aq.). An extraction process was performed on the mixture three times by using dichloromethane, and an organic layer thus obtained was washed with brine water, dried with MgSO₄, and then filtered and concentrated. Resulting crude products were purified by MPLC (hexane/methylene chloride 5% to 25%) to obtain orange solids, i.e., Compound 10_P-1 (0.90 g, ca. 0.74 mmol, ca. yield of 36%). As a result of LCMS analysis, the purity of Compound 10_P-1 was confirmed to be about 80% (ca. 1:4 mixture of conformers). MS (ESI): 967 [M+H]⁺.

### (4) Synthesis of Compound 10

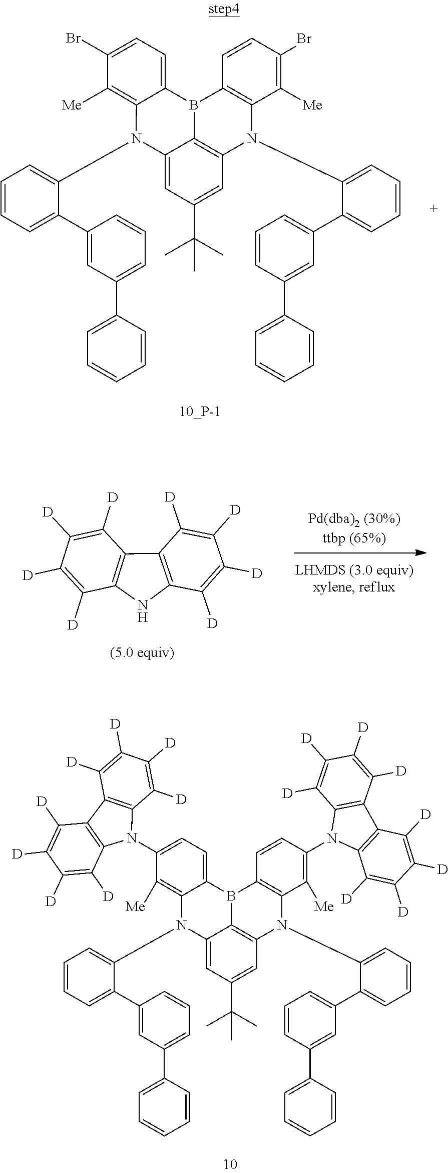 [SMILES: Cc1c(Br)ccc2c1N(c1ccccc1-c1cccc(-c3ccccc3)c1)c1cc(C(C)(C)C)cc3c1B2c1ccc(Br)c(C)c1N3c1ccccc1-c1cccc(-c2ccccc2)c1 ; [2H]c1c([2H])c([2H])c2c([nH]c3c([2H])c([2H])c([2H])c([2H])c32)c1[2H] ; [2H]c1c([2H])c([2H])c2c(c1[2H])c1c([2H])c([2H])c([2H])c([2H])c1n2-c1ccc2c(c1C)N(c1ccccc1-c1cccc(-c3ccccc3)c1)c1cc(C(C)(C)C)cc3c1B2c1ccc(-n2c4c([2H])c([2H])c([2H])c([2H])c4c4c([2H])c([2H])c([2H])c([2H])c42)c(C)c1N3c1ccccc1-c1cccc(-c2ccccc2)c1]

5,9-di([1,1′:3′,1″-terphenyl]-2-yl)-3,11-dibromo-7-(tert-butyl)-4,10-dimethyl-5,9-dihydro-5,9-diaza-13b-boranaphtho[3,2,1-de]anthracene (Compound 10_P-1, 0.75 g, 0.78 mmol), 9H-carbazole-1,2,3,4,5,6,7,8,-d₈ (0.68 g, 3.89 mmol), Pd₂(dba)₃ (0.21 g, 0.23 mmol), and lithium bis(trimethylsilyl)amide (LDMDS) (0.39 g, 2.34 mmol) were added to a flask with a magnetic stir bar. A cycle of vacuuming the flask and back filling with nitrogen was repeated three times, and tri-tert-butylphosphine (ttbp) (50 wt % in toluene, 0.20 mL, 0.51 mmol) and xylene (8.0 mL) were added thereto. After stirring at 140° C. for 18 hours, the reaction mixture was filtered directly through a celite pad. Brown crude products were obtained by evaporation-drying volatile materials. The crude products were purified by MPLC (hexane/methylene chloride 5% to 35% gradient by volume) to obtain orange solids, i.e., Compound 10 (0.03 g, 0.026 mmol, yield of 3%). As a result of LCMS analysis, the purity of Compound 10 was confirmed to exceed 80% (mixture of conformers). MS (ESI): 1155 [M+H]+.

Synthesis methods for the compounds of the present application other than Compound 10 (including Compound 1) may be readily recognized by those skilled in the art by reference to the aforementioned synthesis routes and raw materials.

### Evaluation Example 1: Evaluation of Photoluminescence Quantum Yield (PLQY)

Poly(methyl methacrylate) (PMMA) in CH₂Cl₂ solution, 5 wt % of 4,4-dicarbazolyl-1,1′-biphenyl (CBP), and Compound 1 were mixed, and the resulting product was applied onto a quartz substrate by a spin-coating method using a spin coater. The substrate was heat-treated in an 80° C. oven, and then cooled to room temperature to produce a film.

To evaluate the PLQY in the film, a Hamamatsu Photonics absolute PL quantum yield measurement system equipped with a xenon light source, a monochromator, a photonic multichannel analyzer, and an integrating sphere and utilizing the PLQY measurement software (Hamamatsu Photonics, Ltd., Shizuoka, Japan) were used to evaluate PLQY for Compound 1, and this was repeated for Compounds 10, B, and C. The evaluation results are shown in Table 2.

TABLE 2

| | Maximum luminescence | |
|---|---|---|
| | wavelength (PLₘₐₓ) | PLQY |
| Compound | (nm) | (relative value) |
| Compound 1 | 466 | 0.952 |
| Compound 10 | 465 | 0.947 |
| Compound B | 465 | 0.925 |
| Compound C | 463 | 0.937 |

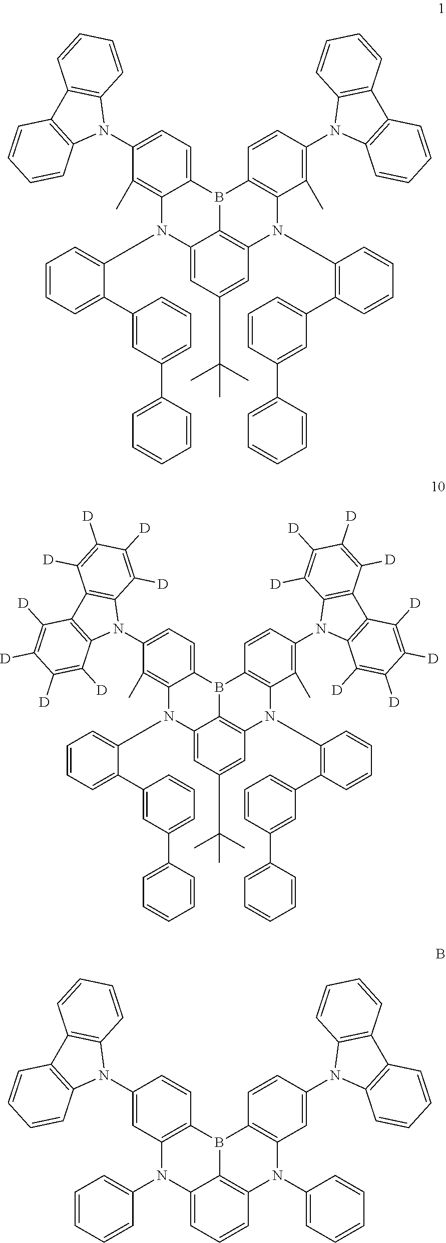 [SMILES: Cc1c(-n2c3ccccc3c3ccccc32)ccc2c1N(c1ccccc1-c1cccc(-c3ccccc3)c1)c1cc(C(C)(C)C)cc3c1B2c1ccc(-n2c4ccccc4c4ccccc42)c(C)c1N3c1ccccc1-c1cccc(-c2ccccc2)c1 ; [2H]c1c([2H])c([2H])c2c(c1[2H])c1c([2H])c([2H])c([2H])c([2H])c1n2-c1ccc2c(c1C)N(c1ccccc1-c1cccc(-c3ccccc3)c1)c1cc(C(C)(C)C)cc3c1B2c1ccc(-n2c4c([2H])c([2H])c([2H])c([2H])c4c4c([2H])c([2H])c([2H])c([2H])c42)c(C)c1N3c1ccccc1-c1cccc(-c2ccccc2)c1 ; c1ccc(N2c3cc(-n4c5ccccc5c5ccccc54)ccc3B3c4ccc(-n5c6ccccc6c6ccccc65)cc4N(c4ccccc4)c4cccc2c43)cc1]

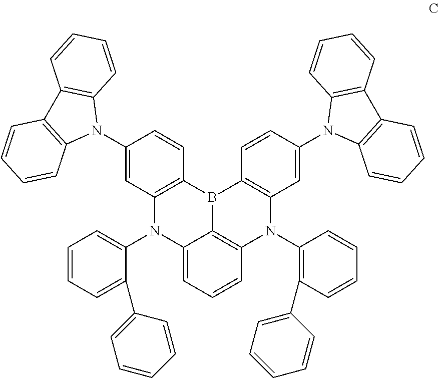 [SMILES: c1ccc(-c2ccccc2N2c3cc(-n4c5ccccc5c5ccccc54)ccc3B3c4ccc(-n5c6ccccc6c6ccccc65)cc4N(c4ccccc4-c4ccccc4)c4cccc2c43)cc1]

Referring to Table 2, it was confirmed that the heterocyclic compound represented by Formula 1 according to one or more embodiments was suitable for emission of a blue light and had excellent PLQY. Also, it was confirmed that the heterocyclic compound represented by Formula 1 according to one or more embodiments had excellent properties based on high PLQY compared to comparative compounds.

### Example 1

An ITO glass substrate was cut to a size of 50 mm×50 mm×0.5 mm, sonicated with acetone, isopropyl alcohol, and pure water each for 15 minutes, and then cleaned by exposure to ultraviolet rays and ozone for 30 minutes. The resultant glass substrate was loaded onto a vacuum deposition apparatus.

Subsequently, HAT-CN was deposited on an ITO electrode (anode) of the glass substrate to form a hole injection layer having a thickness of 100 Å, NPB was deposited on the hole injection layer to form a first hole transport layer having a thickness of 500 Å, TCTA was deposited on the first hole transport layer to form a second hole transport layer having a thickness of 50 Å, and mCP was deposited on the second hole transport layer to form an electron blocking layer having a thickness of 50 Å.

A first host (H25), a second host (H26), a sensitizer (PT1), and an emitter (Compound 10) were co-deposited on the electron blocking layer to form an emission layer having a thickness of 400 Å. Here, the first host and the second host were mixed at a weight ratio of 65:35, and the amounts of the sensitizer and the emitter were adjusted to be 13 wt % and 1.2 wt % per total weight of the first host, the second host, the sensitizer, and the emitter, respectively.

DBFPO was deposited on the emission layer to form a hole blocking layer having a thickness of 100 Å, DBFPO and LiQ were co-deposited at a weight ratio of 5:5 to form an electron transport layer having a thickness of 300 Å, LiQ was deposited on the electron transport layer to form an electron injection layer having a thickness of 10 Å, and Al was deposited on the electron injection layer to form a cathode having a thickness of 1,000 Å, thereby completing the manufacture of an organic light-emitting device.

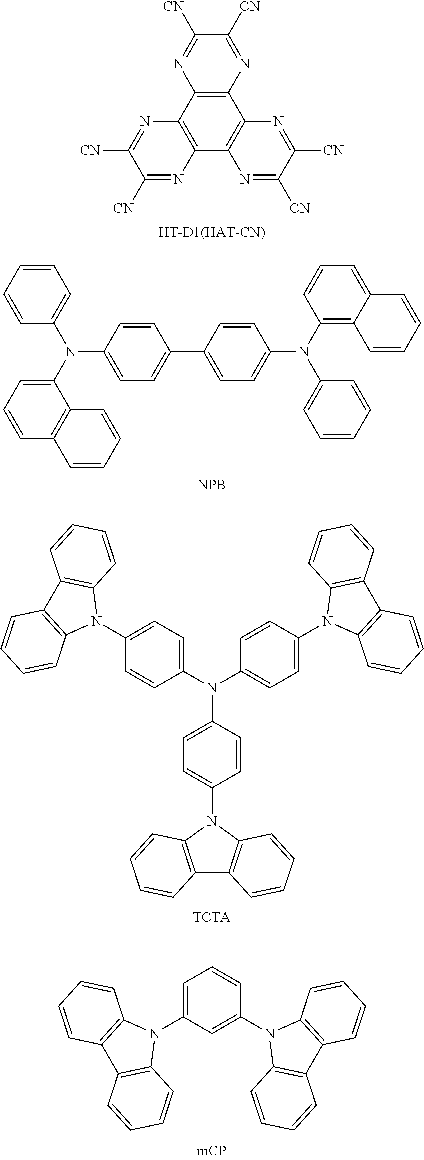

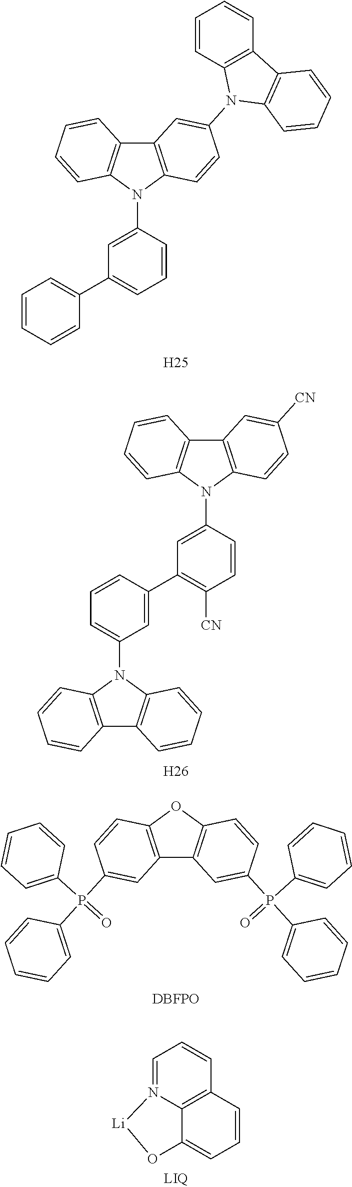

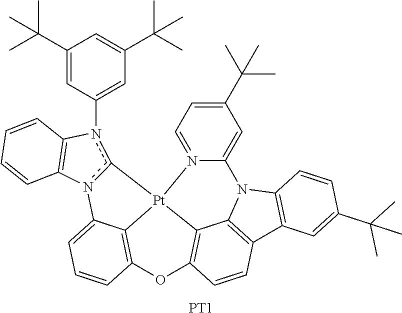

### Example 2 and Comparative Examples 1 and 2

Organic light-emitting devices were manufactured in a similar manner as in Example 1, except that compounds shown in Table 3 were each used as an emitter in forming an emission layer.

For the organic light-emitting devices of Examples 1 and 2 and Comparative Examples 1 and 2, the external quantum efficiency (EQE, %) was measured and evaluated by using a current-voltage meter (Keithley 2400) and a luminescence meter (Minolta Cs-1000A). The evaluation results are shown in Table 3.

TABLE 3

| | Emitter in | |
|---|---|---|
| | emission layer | EQE at 1000 nit (%) |
| Example 1 | Compound 1 | 21.9 |
| Example 2 | Compound 10 | 23.2 |
| Comparative | Compound B | 20.5 |
| Example 1 | | |
| Comparative | Compound C | 17.4 |
| Example 2 | | |

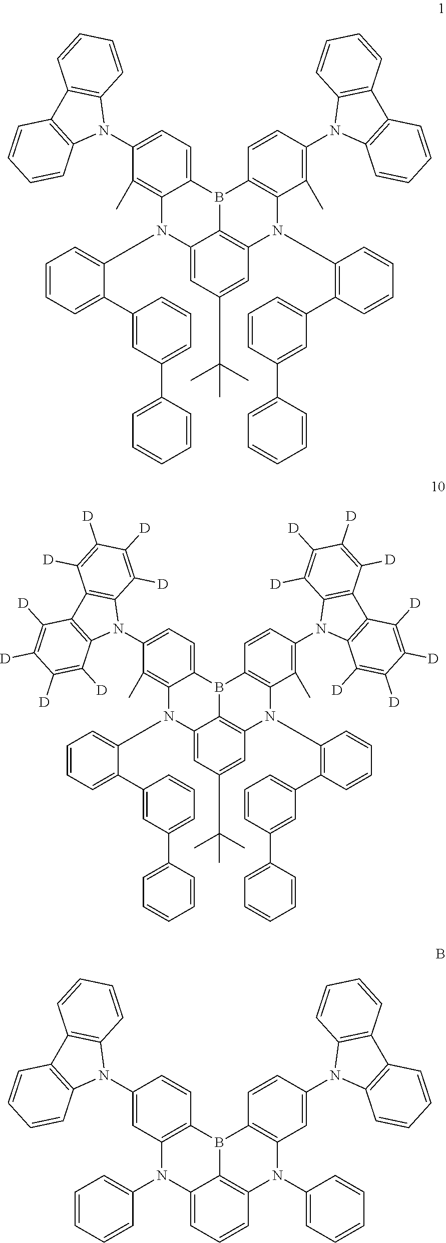 [SMILES: Cc1c(-n2c3ccccc3c3ccccc32)ccc2c1N(c1ccccc1-c1cccc(-c3ccccc3)c1)c1cc(C(C)(C)C)cc3c1B2c1ccc(-n2c4ccccc4c4ccccc42)c(C)c1N3c1ccccc1-c1cccc(-c2ccccc2)c1 ; [2H]c1c([2H])c([2H])c2c(c1[2H])c1c([2H])c([2H])c([2H])c([2H])c1n2-c1ccc2c(c1C)N(c1ccccc1-c1cccc(-c3ccccc3)c1)c1cc(C(C)(C)C)cc3c1B2c1ccc(-n2c4c([2H])c([2H])c([2H])c([2H])c4c4c([2H])c([2H])c([2H])c([2H])c42)c(C)c1N3c1ccccc1-c1cccc(-c2ccccc2)c1 ; c1ccc(N2c3cc(-n4c5ccccc5c5ccccc54)ccc3B3c4ccc(-n5c6ccccc6c6ccccc65)cc4N(c4ccccc4)c4cccc2c43)cc1]

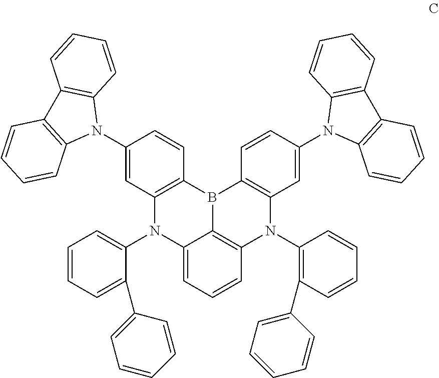 [SMILES: c1ccc(-c2ccccc2N2c3cc(-n4c5ccccc5c5ccccc54)ccc3B3c4ccc(-n5c6ccccc6c6ccccc65)cc4N(c4ccccc4-c4ccccc4)c4cccc2c43)cc1]

Referring to Table 3, it was confirmed that the organic light-emitting device according to one or more embodiments had excellent luminescence efficiency. Also, it was confirmed that the organic light-emitting devices of Examples 1 and 2 had excellent properties based on high EQE compared to the organic light-emitting devices of Comparative Examples 1 and 2.

According to the one or more embodiments, a heterocyclic compound represented by Formula 1 has excellent luminescence characteristics and excellent charge transfer characteristics, and thus an electronic device, e.g., an organic light-emitting device, including at least one of the heterocyclic compound represented by Formula 1 may have a low driving voltage, a high efficiency, and/or long lifespan characteristics. Accordingly, a high-quality organic light-emitting device may be implemented by using at least one of the heterocyclic compounds represented by Formula 1. Also, by using the heterocyclic compound represented by Formula 1, an electronic apparatus having excellent diagnostic efficiency may be implemented.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A heterocyclic compound represented by Formula 1: 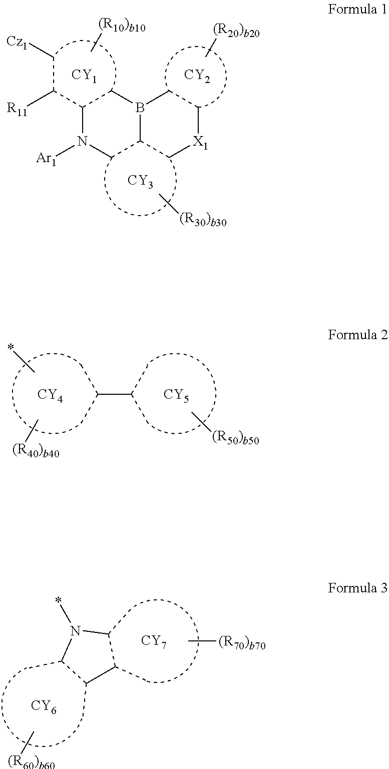
wherein, in Formulae 1, 2, and 3,
X₁ is a single bond, O, S, Se, N(Ar₂), N(R₁), C(R₁)(R₂), Si(R₁)(R₂), Ge(R₁)(R₂), B(R₁), P(R₁), P(═O)(R₁), S(═O)₂, or C(═O),
Ar₁ and Ar₂ are each independently a group represented by Formula 2, a substituted or unsubstituted C₆-C₆₀ aryl group, a substituted or unsubstituted C₁-C₆₀ heteroaryl group, a substituted or unsubstituted C₂-C₆₀ alkyl heteroaryl group, a substituted or unsubstituted monovalent non-aromatic condensed polycyclic group, or a substituted or unsubstituted monovalent non-aromatic condensed heteropolycyclic group,
ring CY₁ to ring CY₇ are each independently a C₅-C₃₀ carbocyclic group or a C₁-C₃₀ heterocyclic group,
Cz₁ is a group represented by Formula 3,
R₁₁ is a substituted or unsubstituted C₁-C₆₀ alkyl group, a substituted or unsubstituted C₃-C₁₀ cycloalkyl group, a substituted or unsubstituted C₆-C₆₀ aryl group, a substituted or unsubstituted C₁-C₆₀ heteroaryl group, a substituted or unsubstituted monovalent non-aromatic condensed polycyclic group, or a substituted or unsubstituted monovalent non-aromatic condensed heteropolycyclic group,
R₁, R₂, R₁₀, R₂₀, R₃₀, R₄₀, and R₅₀ are each independently a group represented by Formula 3, hydrogen, deuterium, —F, —Cl, —Br, —I, —SF₅, a hydroxyl group, a cyano group, a nitro group, an amidino group, a hydrazino group, a hydrazono group, a carboxylic acid group or a salt thereof, a sulfonic acid group or a salt thereof, a phosphoric acid group or a salt thereof, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₁-C₆₀ alkylthio group, a substituted or unsubstituted C₃-C₁₀ cycloalkyl group, a substituted or unsubstituted C₁-C₁₀ heterocycloalkyl group, a substituted or unsubstituted C₃-C₁₀ cycloalkenyl group, a substituted or unsubstituted C₁-C₁₀ heterocycloalkenyl group, a substituted or unsubstituted C₆-C₆₀ aryl group, a substituted or unsubstituted C₇-C₆₀ alkyl aryl group, a substituted or unsubstituted C₇-C₆₀ aryl alkyl group, a substituted or unsubstituted C₆-C₆₀ aryloxy group, a substituted or unsubstituted C₆-C₆₀ arylthio group, a substituted or unsubstituted C₁-C₆₀ heteroaryl group, a substituted or unsubstituted C₂—C₆₀ alkyl heteroaryl group, a substituted or unsubstituted C₂-C₆₀ heteroaryl alkyl group, a substituted or unsubstituted C₁-C₆₀ heteroaryloxy group, a substituted or unsubstituted C₁-C₆₀ heteroarylthio group, a substituted or unsubstituted monovalent non-aromatic condensed polycyclic group, a substituted or unsubstituted monovalent non-aromatic condensed heteropolycyclic group, —N(Q₁)(Q₂), —Si(Q₁)(Q₂)(Q₃), —Ge(Q₁)(Q₂)(Q₃), —C(═O)(Q₁), —S(═O)(Q₁), —S(═O)₂(Q₁), —B(Q₁)(Q₂), —P(Q₁)(Q₂), —P(═O)(Q₁)(Q₂), or —P(═S)(Q₁)(Q₂),
R₆₀ and R₇₀ are each independently hydrogen, deuterium, —F, —Cl, —Br, —I, —SF₅, a hydroxyl group, a cyano group, a nitro group, an amidino group, a hydrazino group, a hydrazono group, a carboxylic acid group or a salt thereof, a sulfonic acid group or a salt thereof, a phosphoric acid group or a salt thereof, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₁-C₆₀ alkylthio group, a substituted or unsubstituted C₃-C₁₀ cycloalkyl group, a substituted or unsubstituted C₁-C₁₀ heterocycloalkyl group, a substituted or unsubstituted C₃-C₁₀ cycloalkenyl group, a substituted or unsubstituted C₁-C₁₀ heterocycloalkenyl group, a substituted or unsubstituted C₆-C₆₀ aryl group, a substituted or unsubstituted C₇-C₆₀ alkyl aryl group, a substituted or unsubstituted C₇-C₆₀ aryl alkyl group, a substituted or unsubstituted C₆-C₆₀ aryloxy group, a substituted or unsubstituted C₆-C₆₀ arylthio group, a substituted or unsubstituted C₁-C₆₀ heteroaryl group, a substituted or unsubstituted C₂-C₆₀ alkyl heteroaryl group, a substituted or unsubstituted C₂-C₆₀ heteroaryl alkyl group, a substituted or unsubstituted C₁-C₆₀ heteroaryloxy group, a substituted or unsubstituted C₁-C₆₀ heteroarylthio group, a substituted or unsubstituted monovalent non-aromatic condensed polycyclic group, a substituted or unsubstituted monovalent non-aromatic condensed heteropolycyclic group, —N(Q₁)(Q₂), —Si(Q₁)(Q₂)(Q₃), —Ge(Q₁)(Q₂)(Q₃), —C(═O)(Q₁), —S(═O)(Q₁), —S(═O)₂(Q₁), —B(Q₁)(Q₂), —P(Q₁)(Q₂), —P(═O)(Q₁)(Q₂), or —P(═S)(Q₁)(Q₂),
b10, b20, b30, b40, and b50 are each independently 1, 2, 3, 4, 5, 6, 7, 8, 9, 10, 11, 12, 13, or 14,
b60 and b70 are each independently 1, 2, 3, 4, 5, 6, 7, or 8,
at least two neighboring groups among R₁, R₂, R₁₀, R₁₁, R₂₀, R₃₀, R₄₀, R₅₀, R₆₀, and R₇₀ are optionally bonded together to form a substituted or unsubstituted C₅-C₃₀ carbocyclic group or a substituted or unsubstituted C₁-C₃₀ heterocyclic group,
substituents of the substituted C₅-C₃₀ carbocyclic group, the substituted C₁-C₃₀ heterocyclic group, the substituted C₁-C₆₀ alkyl group, the substituted C₂-C₆₀ alkenyl group, the substituted C₂-C₆₀ alkynyl group, the substituted C₁-C₆₀ alkoxy group, the substituted C₁-C₆₀ alkylthio group, the substituted C₃-C₁₀ cycloalkyl group, the substituted C₁-C₁₀ heterocycloalkyl group, the substituted C₃-C₁₀ cycloalkenyl group, the substituted C₁-C₁₀ heterocycloalkenyl group, the substituted C₆-C₆₀ aryl group, the substituted C₇-C₆₀ alkyl aryl group, the substituted C₇-C₆₀ aryl alkyl group, the substituted C₆-C₆₀ aryloxy group, the substituted C₆-C₆₀ arylthio group, the substituted C₁-C₆₀ heteroaryl group, the substituted C₂-C₆₀ alkyl heteroaryl group, the substituted C₂-C₆₀ heteroaryl alkyl group, the substituted C₁-C₆₀ heteroaryloxy group, the substituted C₁-C₆₀ heteroarylthio group, the substituted monovalent non-aromatic condensed polycyclic group, and the substituted monovalent non-aromatic condensed heteropolycyclic group are each independently:
deuterium, —F, —Cl, —Br, —I, —SF₅, —CDs, —CD₂H, —CDH₂, —CF₃, —CF₂H, —CFH₂, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₆₀ alkyl group, a C₂-C₆₀ alkenyl group, a C₂-C₆₀ alkynyl group, a C₁-C₆₀ alkoxy group, or a C₁-C₆₀ alkylthio group;
a C₁-C₆₀ alkyl group, a C₂-C₆₀ alkenyl group, a C₂-C₆₀ alkynyl group, a C₁-C₆₀ alkoxy group, or a C₁-C₆₀ alkylthio group, each substituted with deuterium, —F, —Cl, —Br, —I, —SF₅, —CDs, —CD₂H, —CDH₂, —CF₃, —CF₂H, —CFH₂, a hydroxyl group, a cyano group, a nitro group, an amidino group, a hydrazine group, a hydrazone group, a carboxylic acid group or a salt thereof, a sulfonic acid group or a salt thereof, a phosphoric acid group or a salt thereof, a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₇-C₆₀ alkyl aryl group, a C₆-C₆₀ aryloxy group, a C₆-C₆₀ arylthio group, a C₁-C₆₀ heteroaryl group, a C₂-C₆₀ alkyl heteroaryl group, a C₁-C₆₀ heteroaryloxy group, a C₁-C₆₀ heteroarylthio group, a monovalent non-aromatic condensed polycyclic group, a monovalent non-aromatic condensed heteropolycyclic group, —N(Q₁₁)(Q₁₂), —Si(Q₁₁)(Q₁₂)(Q₁₃), —Ge(Q₁₁)(Q₁₂)(Q₁₃), —C(═O)(Q₁₁), —S(═O)(Q₁₁), —S(═O)₂(Q₁₁), —B(Q₁₁)(Q₁₂), —P(Q₁₁)(Q₁₂), —P(═O)(Q₁₁)(Q₁₂), —P(═S)(Q₁₁)(Q₁₂), or a combination thereof;
a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₇-C₆₀ alkyl aryl group, a C₆-C₆₀ aryloxy group, a C₆-C₆₀ arylthio group, a C₁-C₆₀ heteroaryl group, a C₂-C₆₀ alkyl heteroaryl group, a C₁-C₆₀ heteroaryloxy group, a C₁-C₆₀ heteroarylthio group, a monovalent non-aromatic condensed polycyclic group, or a monovalent non-aromatic condensed heteropolycyclic group, each unsubstituted or substituted with deuterium, —F, —Cl, —Br, —I, —SF₅, —CD₃, —CD₂H, —CDH₂, —CF₃, —CF₂H, —CFH₂, a hydroxyl group, a cyano group, a nitro group, an amidino group, a hydrazine group, a hydrazone group, a carboxylic acid group or a salt thereof, a sulfonic acid group or a salt thereof, a phosphoric acid group or a salt thereof, a C₁-C₆₀ alkyl group, a C₂-C₆₀ alkenyl group, a C₂-C₆₀ alkynyl group, a C₁-C₆₀ alkoxy group, a C₁-C₆₀ alkylthio group, a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₇-C₆₀ alkyl aryl group, a C₇-C₆₀ aryl alkyl group, a C₆-C₆₀ aryloxy group, a C₆-C₆₀ arylthio group, a C₁-C₆₀ heteroaryl group, a C₂-C₆₀ alkyl heteroaryl group, a C₂-C₆₀ heteroaryl alkyl group, a C₁-C₆₀ heteroaryloxy group, a C₁-C₆₀ heteroarylthio group, a monovalent non-aromatic condensed polycyclic group, a monovalent non-aromatic condensed heteropolycyclic group, —N(Q₂₁)(Q₂₂), —Si(Q₂₁)(Q₂₂)(Q₂₃), —Ge(Q₂₁)(Q₂₂)(Q₂₃), —C(═O)(Q₂₁), —S(═O)(Q₂₁), —S(═O)₂(Q₂₁), —B(Q₂₁)(Q₂₂), —P(Q₂₁)(Q₂₂), —P(═O)(Q₂₁)(Q₂₂), —P(═S)(Q₂₁)(Q₂₂), or a combination thereof;
—N(Q₃₁)(Q₃₂), —Si(Q₃₁)(Q₃₂)(Q₃₃), —Ge(Q₃₁)(Q₃₂)(Q₃₃), —C(═O)(Q₃₁), —S(═O)(Q₃₁), —S(═O)₂(Q₃₁), —B(Q₃₁)(Q₃₂), —P(Q₃₁)(Q₃₂), —P(═O)(Q₃₁)(Q₃₂), or —P(═S)(Q₃₁)(Q₃₂); or
a combination thereof,
Q₁ to Q₃, Q₁₁ to Q₁₃, Q₂₁ to Q₂₃, and Q₃₁ to Q₃₃ are each independently hydrogen, deuterium, —F, —Cl, —Br, —I, —SF₅, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₁-C₆₀ alkylthio group, a substituted or unsubstituted C₃-C₁₀ cycloalkyl group, a substituted or unsubstituted C₁-C₁₀ heterocycloalkyl group, a substituted or unsubstituted C₃-C₁₀ cycloalkenyl group, a substituted or unsubstituted C₁-C₁₀ heterocycloalkenyl group, a substituted or unsubstituted C₆-C₆₀ aryl group, a substituted or unsubstituted C₇-C₆₀ alkyl aryl group, a substituted or unsubstituted C₇-C₆₀ aryl alkyl group, a substituted or unsubstituted C₆-C₆₀ aryloxy group, a substituted or unsubstituted C₆-C₆₀ arylthio group, a substituted or unsubstituted C₁-C₆₀ heteroaryl group, a substituted or unsubstituted C₂-C₆₀ alkyl heteroaryl group, a substituted or unsubstituted C₂-C₆₀ heteroaryl alkyl group, a substituted or unsubstituted C₁-C₆₀ heteroaryloxy group, a substituted or unsubstituted C₁-C₆₀ heteroarylthio group, a substituted or unsubstituted monovalent non-aromatic condensed polycyclic group, or a substituted or unsubstituted monovalent non-aromatic condensed heteropolycyclic group, and
* indicates a binding site to a neighboring atom.

2. The heterocyclic compound of claim 1, wherein ring CY₁ to ring CY₅ are each independently a benzene group, a naphthalene group, a phenanthrene group, a fluorene group, a pyridine group, a pyrimidine group, a triazine group, a quinoline group, an isoquinoline group, a phthalazine group, a naphthyridine group, a quinoxaline group, a quinazoline group, a carbazole group, a dibenzofuran group, a dibenzothiophene group, a dibenzosilole group, a dibenzoborole group, a dibenzophosphole group, a dibenzoselenophene group, a dibenzogermole group, a dibenzothiophene 5-oxide group, a 9H-fluoren-9-one group, or a dibenzothiophene 5,5-dioxide group.

3. The heterocyclic compound of claim 1, wherein ring CY₆ and ring CY₇ are each independently a benzene group, a naphthalene group, a phenanthrene group, a pyridine group, a pyrimidine group, a quinoline group, an isoquinoline group, a phthalazine group, a naphthyridine group, a quinoxaline group, or a quinazoline group.

4. The heterocyclic compound of claim 1, wherein Ar₁ and Ar₂ are each independently a group represented by one of Formulae 2-1 to 2-3: 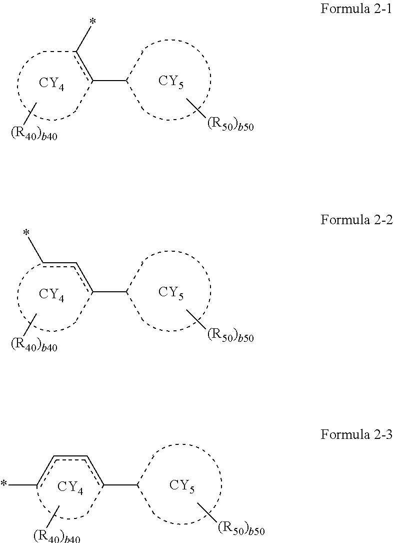
wherein, in Formulae 2-1 to 2-3,
ring CY₄, ring CY₅, R₄₀, R₅₀, b40, and b50 are each the same as those described in claim 1, [symbol]
indicates a single bond or a double bond, and
* indicates a binding site to a neighboring atom.

5. The heterocyclic compound of claim 1, wherein a group represented by Formula 2 is a group represented by one of Formulae 2A to 2C: 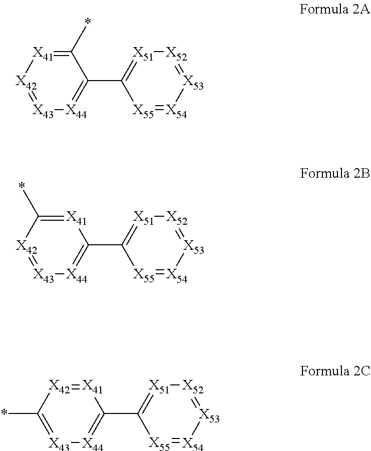
wherein, in Formulae 2A to 2C,
X₄₁ is C(R₄₁) or N, X₄₂ is C(R₄₂) or N, X₄₃ is C(R₄₃) or N, and X₄₄ is C(R₄₄) or N,
X₅₁ is C(R₅₁) or N, X₅₂ is C(R₅₂) or N, X₅₃ is C(R₅₃) or N, X₅₄ is C(R₅₄) or N, and X₅₅ is C(R₅₅) or N,
R₄₁ to R₄₄ are each independently the same as described in connection with R₄₀ in claim 1,
R₅₁ to R₅₅ are each independently the same as described in connection with R₅₀ in claim 1, and
* indicates a binding site to a neighboring atom.

6. The heterocyclic compound of claim 1, wherein a group represented by Formula 3 is a group represented by Formula 3A: 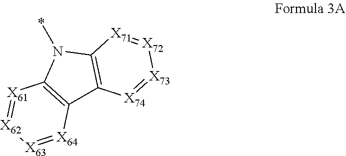
wherein, in Formula 3A,
X₆₁ is C(R₆₁) or N, X₆₂ is C(R₆₂) or N, X₆₃ is C(R₆₃) or N, and X₆₄ is C(R₆₄) or N,
X₇₁ is C(R₇₁) or N, X₇₂ is C(R₇₂) or N, X₇₃ is C(R₇₃) or N, and X₇₄ is C(R₇₄) or N,
R₆₁ to R₆₄ are each independently the same as described in connection with R₆₀ in claim 1,
R₇₁ to R₇₄ are each independently the same as described in connection with R₇₀ in claim 1, and
* indicates a binding site to a neighboring atom.

7. The heterocyclic compound of claim 1, wherein R₁, R₂, R₁₀, R₂₀, R₃₀, R₄₀, R₅₀, R₆₀, and R₇₀ are each independently:
hydrogen, deuterium, —F, —Cl, —Br, —I, —SF₅, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₂₀ alkyl group, a C₁-C₂₀ alkoxy group, or a C₁-C₂₀ alkylthio group;
a C₁-C₂₀ alkyl group, a C₁-C₂₀ alkoxy group, or a C₁-C₂₀ alkylthio group, each substituted with deuterium, —F, —Cl, —Br, —I, —SF₅, —CDs, —CD₂H, —CDH₂, —CF₃, —CF₂H, —CFH₂, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₂₀ alkyl group, a deuterium-containing C₁-C₂₀ alkyl group, a fluorinated C₁-C₂₀ alkyl group, a cyclopentyl group, a cyclohexyl group, a cycloheptyl group, a cyclooctyl group, an adamantanyl group, a norbornenyl group, a cyclopentenyl group, a cyclohexenyl group, a cycloheptenyl group, a bicyclo[1.1.1]pentyl group, a bicyclo[2.1.1]hexyl group, a bicyclo[2.2.1]heptyl group (a norbornanyl group), a bicyclo[2.2.2]octyl group, a (C₁-C₂₀ alkyl)cyclopentyl group, a (C₁-C₂₀ alkyl)cyclohexyl group, a (C₁-C₂₀ alkyl)cycloheptyl group, a (C₁-C₂₀ alkyl)cyclooctyl group, a (C₁-C₂₀ alkyl)adamantanyl group, a (C₁-C₂₀ alkyl)norbornenyl group, a (C₁-C₂₀ alkyl)cyclopentenyl group, a (C₁-C₂₀ alkyl)cyclohexenyl group, a (C₁-C₂₀ alkyl)cycloheptenyl group, a (C₁-C₂₀ alkyl)bicyclo[1.1.1]pentyl group, a (C₁-C₂₀ alkyl)bicyclo[2.1.1]hexyl group, a (C₁-C₂₀ alkyl)bicyclo[2.2.1]heptyl group, a (C₁-C₂₀ alkyl)bicyclo[2.2.2]octyl group, silolanyl group(silolanyl), phenyl group, (C₁-C₂₀ alkyl)phenyl group, a biphenyl group, a terphenyl group, a naphthyl group, a 1,2,3,4-tetrahydronaphthyl group, a pyridinyl group, a pyrimidinyl group, or a combination thereof;
a cyclopentyl group, a cyclohexyl group, a cycloheptyl group, a cyclooctyl group, an adamantanyl group, a norbornenyl group, a cyclopentenyl group, a cyclohexenyl group, a cycloheptenyl group, a bicyclo[1.1.1]pentyl group, a bicyclo[2.1.1]hexyl group, a bicyclo[2.2.1]heptyl group, a bicyclo[2.2.2]octyl group, a silolanyl group, a phenyl group, a (C₁-C₂₀ alkyl)phenyl group, a biphenyl group, a terphenyl group, a naphthyl group, a 1,2,3,4-tetrahydronaphthyl group, a fluorenyl group, a phenanthrenyl group, an anthracenyl group, a fluoranthenyl group, a triphenylenyl group, a pyrenyl group, a chrysenyl group, a pyrrolyl group, a thiophenyl group, a furanyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a quinoxalinyl group, a quinazolinyl group, a cinnolinyl group, a carbazolyl group, a phenanthrolinyl group, a benzoimidazolyl group, a benzofuranyl group, a benzothiophenyl group, an isobenzothiazolyl group, a benzoxazolyl group, an isobenzoxazolyl group, a triazolyl group, a tetrazolyl group, an oxadiazolyl group, a triazinyl group, a dibenzofuranyl group, a dibenzothiophenyl group, a benzocarbazolyl group, a dibenzocarbazolyl group, an imidazopyridinyl group, an imidazopyrimidinyl group, an azacarbazolyl group, an azadibenzofuranyl group, or an azadibenzothiophenyl group, each unsubstituted or substituted with deuterium, —F, —Cl, —Br, —I, —SF₅, —CD₃, —CD₂H, —CDH₂, —CF₃, —CF₂H, —CFH₂, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₂₀ alkyl group, a deuterium-containing C₁-C₂₀ alkyl group, a fluorinated C₁-C₂₀ alkyl group, a C₁-C₂₀ alkoxy group, a C₁-C₂₀ alkylthio group, a cyclopentyl group, a cyclohexyl group, a cycloheptyl group, a cyclooctyl group, an adamantanyl group, a norbornenyl group, a cyclopentenyl group, a cyclohexenyl group, a cycloheptenyl group, a bicyclo[1.1.1]pentyl group, a bicyclo[2.1.1]hexyl group, a bicyclo[2.2.1]heptyl group, a bicyclo[2.2.2]octyl group, a (C₁-C₂₀ alkyl)cyclopentyl group, a (C₁-C₂₀ alkyl)cyclohexyl group, a (C₁-C₂₀ alkyl)cycloheptyl group, a (C₁-C₂₀ alkyl)cyclooctyl group, a (C₁-C₂₀ alkyl)adamantanyl group, a (C₁-C₂₀ alkyl)norbornenyl group, a (C₁-C₂₀ alkyl)cyclopentenyl group, a (C₁-C₂₀ alkyl)cyclohexenyl group, a (C₁-C₂₀ alkyl)cycloheptenyl group, a (C₁-C₂₀ alkyl)bicyclo[1.1.1]pentyl group, a (C₁-C₂₀ alkyl)bicyclo[2.1.1]hexyl group, a (C₁-C₂₀ alkyl)bicyclo[2.2.1]heptyl group, a (C₁-C₂₀ alkyl)bicyclo[2.2.2]octyl group, a silolanyl group, a phenyl group, a (C₁-C₂₀ alkyl)phenyl group, a biphenyl group, a terphenyl group, a naphthyl group, a 1,2,3,4-tetrahydronaphthyl group, a fluorenyl group, a phenanthrenyl group, an anthracenyl group, a fluoranthenyl group, a triphenylenyl group, a pyrenyl group, a chrysenyl group, a pyrrolyl group, a thiophenyl group, a furanyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a quinoxalinyl group, a quinazolinyl group, a cinnolinyl group, a carbazolyl group, a phenanthrolinyl group, a benzoimidazolyl group, a benzofuranyl group, a benzothiophenyl group, an isobenzothiazolyl group, a benzoxazolyl group, an isobenzoxazolyl group, a triazolyl group, a tetrazolyl group, an oxadiazolyl group, a triazinyl group, a dibenzofuranyl group, a dibenzothiophenyl group, a benzocarbazolyl group, a dibenzocarbazolyl group, an imidazopyridinyl group, an imidazopyrimidinyl group, an azacarbazolyl group, an azadibenzofuranyl group, an azadibenzothiophenyl group, or a combination thereof; or
—N(Q₁)(Q₂), —Si(Q₁)(Q₂)(Q₃), —Ge(Q₁)(Q₂)(Q₃), —C(═O)(Q₁), —S(═O)(Q₁), S(═O)₂(Q₁), —B(Q₁)(Q₂), —P(Q₁)(Q₂), —P(═O)(Q₁)(Q₂), or —P(═S)(Q₁)(Q₂).

8. The heterocyclic compound of claim 1, wherein at least one of R₂₀ is a group represented by Formula 3.

9. The heterocyclic compound of claim 1, wherein the heterocyclic compound is represented by Formula 11 or 12: 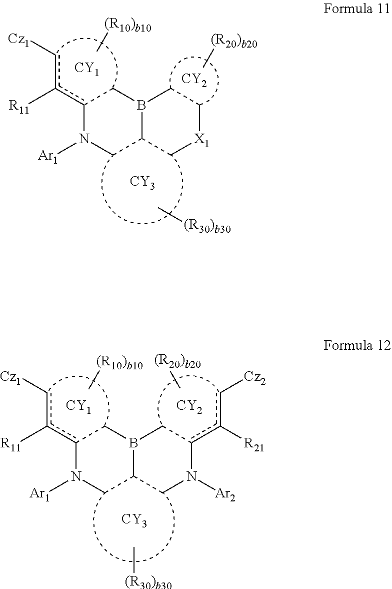
wherein, in Formulae 11 and 12,
ring CY₁ to ring CY₃, X₁, Ar₁, Ar₂, Cz₁, R₁₀, R₁₁, R₂₀, R₃₀, b10, b20, and b30 are the same as those in claim 1,
Cz₂ is the same as described in connection with Cz₁ in claim 1,
R₂₁ is the same as described in connection with R₂₀ in claim 1, and [symbol]
indicates a single bond or a double bond.

10. The heterocyclic compound of claim 1, wherein the heterocyclic compound is represented by Formula 21 or 22: 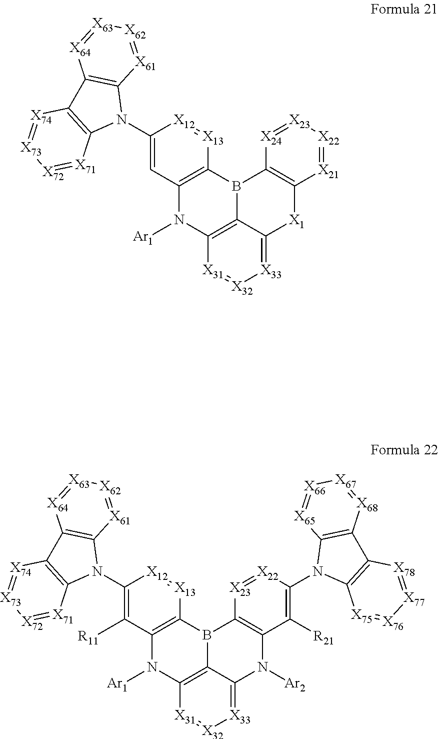
wherein, in Formulae 21 and 22,
Ar₁, Ar₂, X₁, and R₁₁ are each the same as those in claim 1,
X₁₂ is C(R₁₂) or N, and X₁₃ is C(R₁₃) or N,
X₂₁ is C(R₂₁) or N, X₂₂ is C(R₂₂) or N, X₂₃ is C(R₂₃) or N, and X₂₄ is C(R₂₄) or N,
X₃₁ is C(R₃₁) or N, X₃₂ is C(R₃₂) or N, and X₃₃ is C(R₃₃) or N,
X₆₁ is C(R₆₁) or N, X₆₂ is C(R₆₂) or N, X₆₃ is C(R₆₃) or N, X₆₄ is C(R₆₄) or N, X₆₅ is C(R₆₅) or N, X₆₆ is C(R₆₆) or N, X₆₇ is C(R₆₇) or N, and X₆₈ is C(R₆₈) or N,
X₇₁ is C(R₇₁) or N, X₇₂ is C(R₇₂) or N, X₇₃ is C(R₇₃) or N, X₇₄ is C(R₇₄) or N, X₇₅ is C(R₇₅) or N, X₇₆ is C(R₇₆) or N, X₇₇ is C(R₇₇) or N, and X₇₈ is C(R₇₈) or N,
R₁₂ and R₁₃ are each independently the same as described in connection with R₁₀ in claim 1,
R₂₁ to R₂₄ are each independently the same as described in connection with R₂₀ in claim 1,
R₃₁ to R₃₃ are each independently the same as described in connection with R₃₀ in claim 1,
R₆₁ to R₆₈ are each independently the same as described in connection with R₆₀ in claim 1, and
R₇₁ to R₇₈ are each independently the same as described in connection with R₇₀ in claim 1.

11. The heterocyclic compound of claim 1, wherein the heterocyclic compound is represented by Formula 31 or 32: 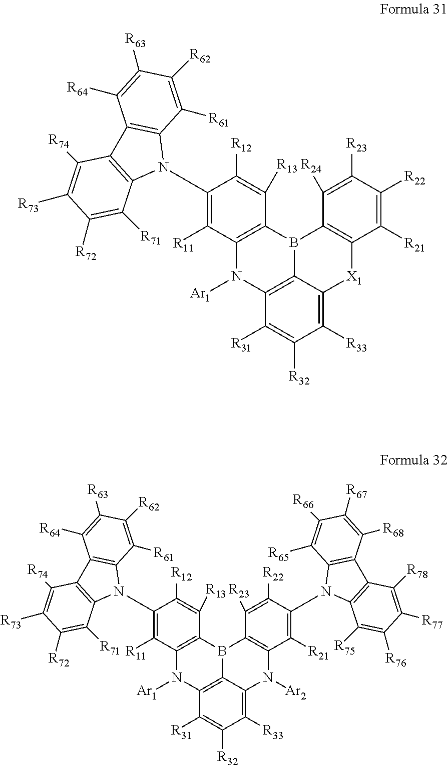
wherein, in Formulae 31 and 32,
Ar₁, Ar₂, X₁, and R₁₁ are each the same as those in claim 1,
R₁₂ and R₁₃ are each independently the same as described in connection with R₁₀ in claim 1,
R₂₁ to R₂₄ are each independently the same as described in connection with R₂₀ in claim 1,
R₃₁ to R₃₃ are each independently the same as described in connection with R₃₀ in claim 1,
R₆₁ to R₆₈ are each independently the same as described in connection with R₆₀ in claim 1, and
R₇₁ to R₇₈ are each independently the same as described in connection with R₇₀ in claim 1.

12. The heterocyclic compound of claim 1, wherein the heterocyclic compound is one of Compounds 1 to 83:

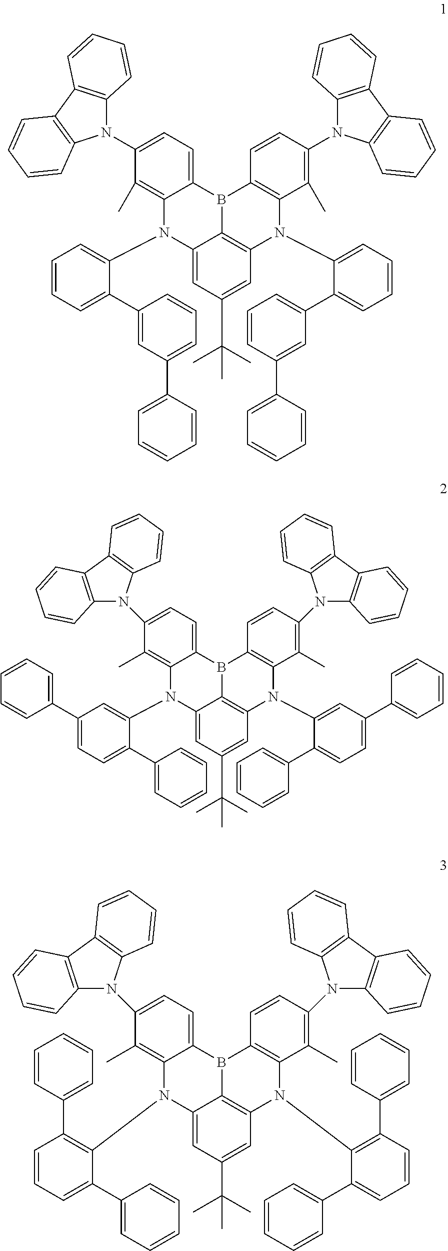 [SMILES: Cc1c(-n2c3ccccc3c3ccccc32)ccc2c1N(c1ccccc1-c1cccc(-c3ccccc3)c1)c1cc(C(C)(C)C)cc3c1B2c1ccc(-n2c4ccccc4c4ccccc42)c(C)c1N3c1ccccc1-c1cccc(-c2ccccc2)c1 ; Cc1c(-n2c3ccccc3c3ccccc32)ccc2c1N(c1cc(-c3ccccc3)ccc1-c1ccccc1)c1cc(C(C)(C)C)cc3c1B2c1ccc(-n2c4ccccc4c4ccccc42)c(C)c1N3c1cc(-c2ccccc2)ccc1-c1ccccc1 ; Cc1c(-n2c3ccccc3c3ccccc32)ccc2c1N(c1c(-c3ccccc3)cccc1-c1ccccc1)c1cc(C(C)(C)C)cc3c1B2c1ccc(-n2c4ccccc4c4ccccc42)c(C)c1N3c1c(-c2ccccc2)cccc1-c1ccccc1]

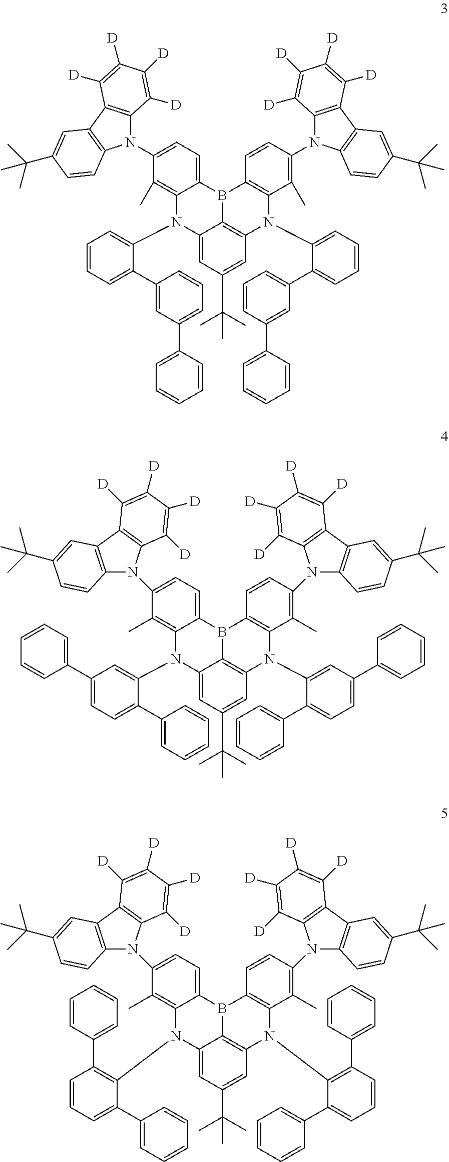

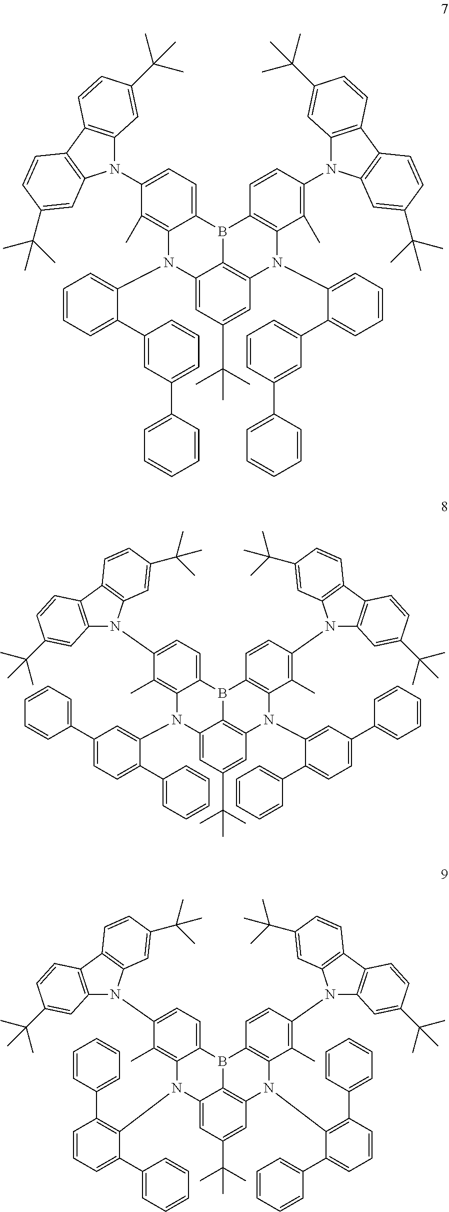

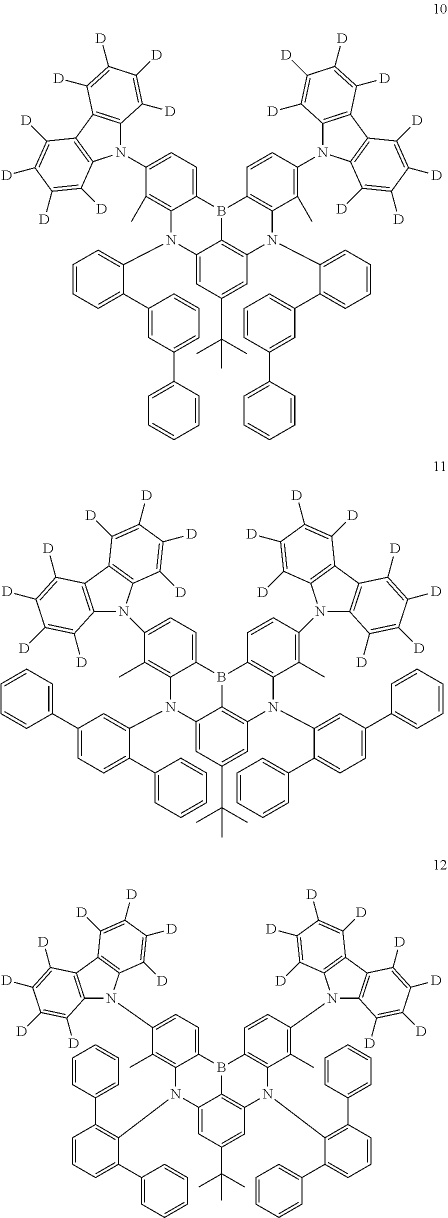

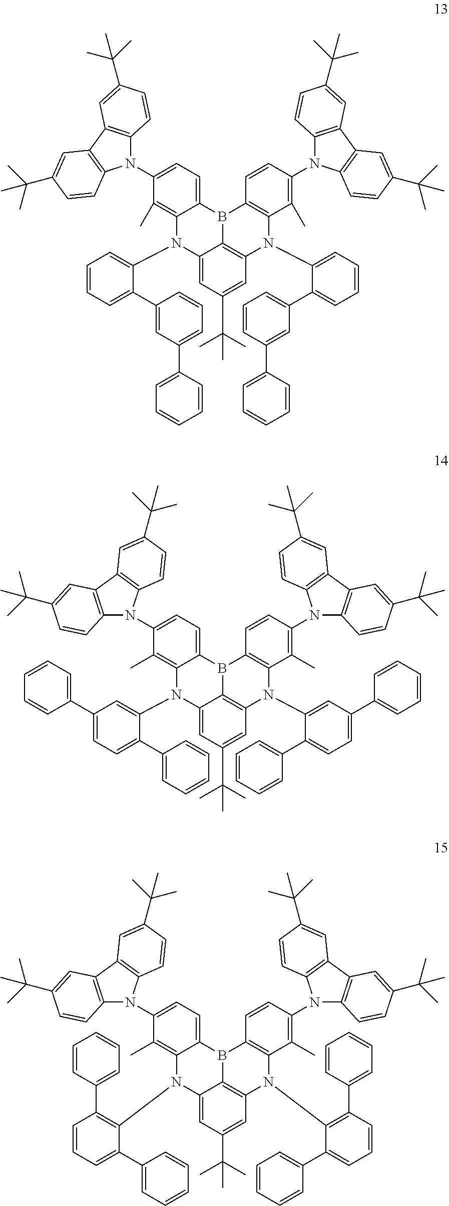

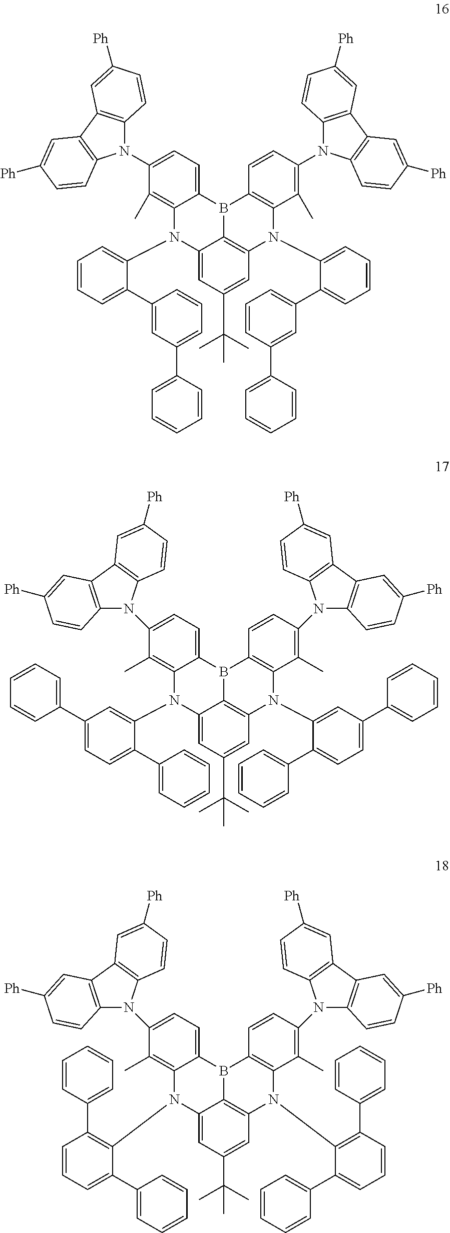

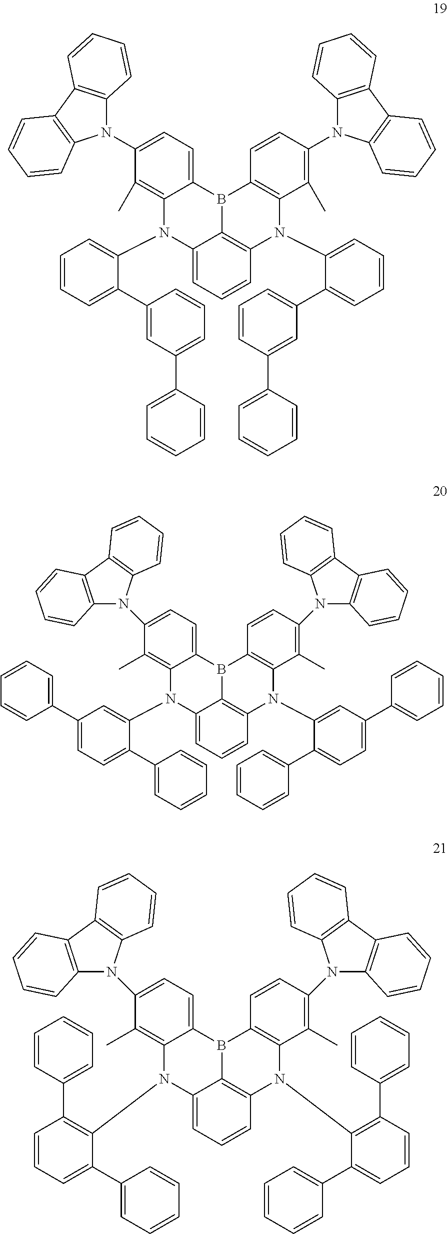 [SMILES: Cc1c(-n2c3ccccc3c3ccccc32)ccc2c1N(c1ccccc1-c1cccc(-c3ccccc3)c1)c1cccc3c1B2c1ccc(-n2c4ccccc4c4ccccc42)c(C)c1N3c1ccccc1-c1cccc(-c2ccccc2)c1 ; Cc1c(-n2c3ccccc3c3ccccc32)ccc2c1N(c1cc(-c3ccccc3)ccc1-c1ccccc1)c1cccc3c1B2c1ccc(-n2c4ccccc4c4ccccc42)c(C)c1N3c1cc(-c2ccccc2)ccc1-c1ccccc1 ; Cc1c(-n2c3ccccc3c3ccccc32)ccc2c1N(c1c(-c3ccccc3)cccc1-c1ccccc1)c1cccc3c1B2c1ccc(-n2c4ccccc4c4ccccc42)c(C)c1N3c1c(-c2ccccc2)cccc1-c1ccccc1]

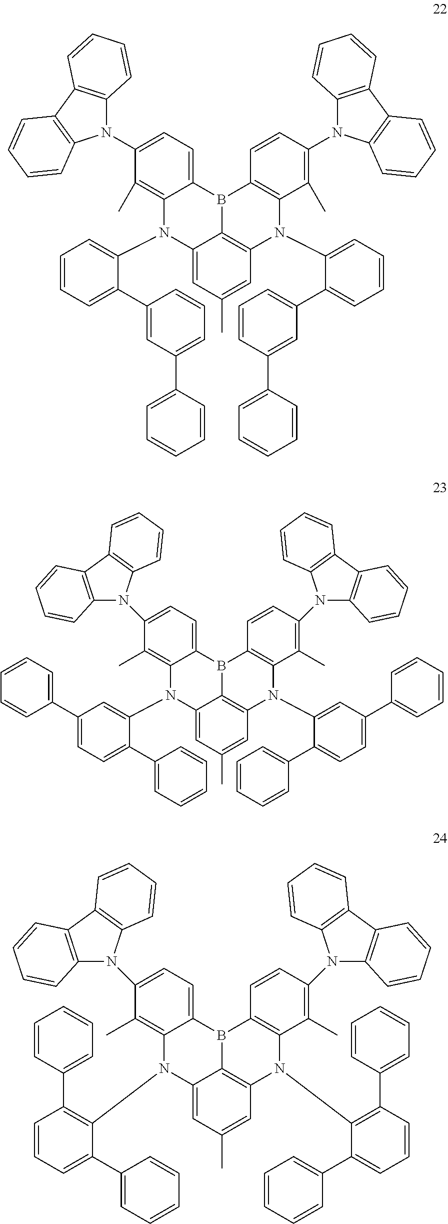 [SMILES: Cc1cc2c3c(c1)N(c1ccccc1-c1cccc(-c4ccccc4)c1)c1c(ccc(-n4c5ccccc5c5ccccc54)c1C)B3c1ccc(-n3c4ccccc4c4ccccc43)c(C)c1N2c1ccccc1-c1cccc(-c2ccccc2)c1 ; Cc1cc2c3c(c1)N(c1cc(-c4ccccc4)ccc1-c1ccccc1)c1c(ccc(-n4c5ccccc5c5ccccc54)c1C)B3c1ccc(-n3c4ccccc4c4ccccc43)c(C)c1N2c1cc(-c2ccccc2)ccc1-c1ccccc1 ; Cc1cc2c3c(c1)N(c1c(-c4ccccc4)cccc1-c1ccccc1)c1c(ccc(-n4c5ccccc5c5ccccc54)c1C)B3c1ccc(-n3c4ccccc4c4ccccc43)c(C)c1N2c1c(-c2ccccc2)cccc1-c1ccccc1]

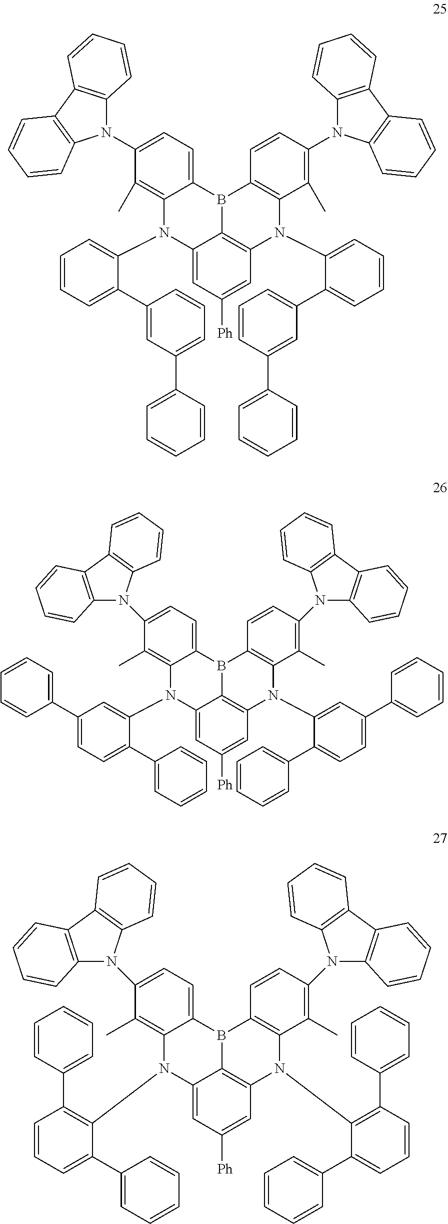 [SMILES: Cc1c(-n2c3ccccc3c3ccccc32)ccc2c1N(c1ccccc1-c1cccc(-c3ccccc3)c1)c1cc(-c3ccccc3)cc3c1B2c1ccc(-n2c4ccccc4c4ccccc42)c(C)c1N3c1ccccc1-c1cccc(-c2ccccc2)c1 ; Cc1c(-n2c3ccccc3c3ccccc32)ccc2c1N(c1cc(-c3ccccc3)ccc1-c1ccccc1)c1cc(-c3ccccc3)cc3c1B2c1ccc(-n2c4ccccc4c4ccccc42)c(C)c1N3c1cc(-c2ccccc2)ccc1-c1ccccc1 ; Cc1c(-n2c3ccccc3c3ccccc32)ccc2c1N(c1c(-c3ccccc3)cccc1-c1ccccc1)c1cc(-c3ccccc3)cc3c1B2c1ccc(-n2c4ccccc4c4ccccc42)c(C)c1N3c1c(-c2ccccc2)cccc1-c1ccccc1]

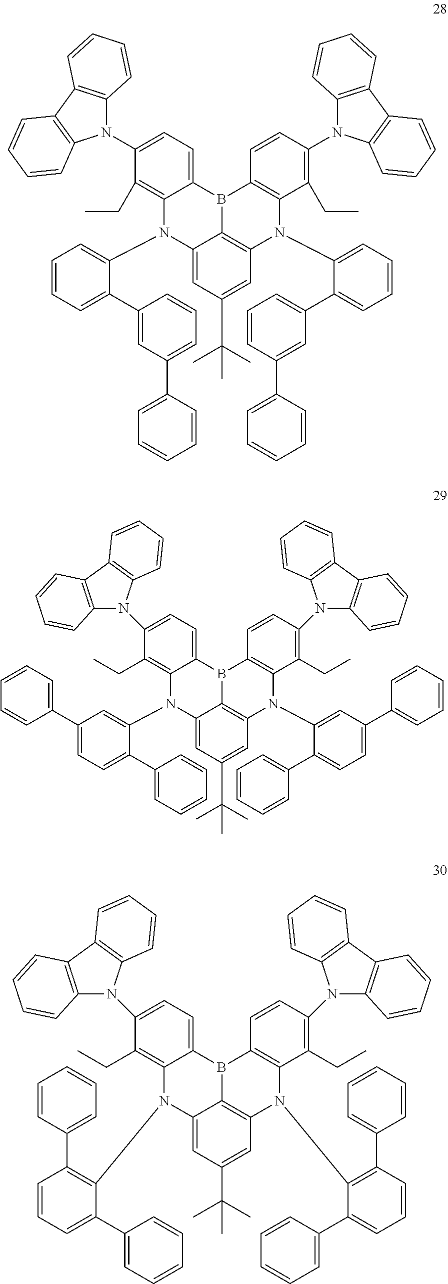 [SMILES: CCc1c(-n2c3ccccc3c3ccccc32)ccc2c1N(c1ccccc1-c1cccc(-c3ccccc3)c1)c1cc(C(C)(C)C)cc3c1B2c1ccc(-n2c4ccccc4c4ccccc42)c(CC)c1N3c1ccccc1-c1cccc(-c2ccccc2)c1 ; CCc1c(-n2c3ccccc3c3ccccc32)ccc2c1N(c1cc(-c3ccccc3)ccc1-c1ccccc1)c1cc(C(C)(C)C)cc3c1B2c1ccc(-n2c4ccccc4c4ccccc42)c(CC)c1N3c1cc(-c2ccccc2)ccc1-c1ccccc1 ; CCc1c(-n2c3ccccc3c3ccccc32)ccc2c1N(c1c(-c3ccccc3)cccc1-c1ccccc1)c1cc(C(C)(C)C)cc3c1B2c1ccc(-n2c4ccccc4c4ccccc42)c(CC)c1N3c1c(-c2ccccc2)cccc1-c1ccccc1]

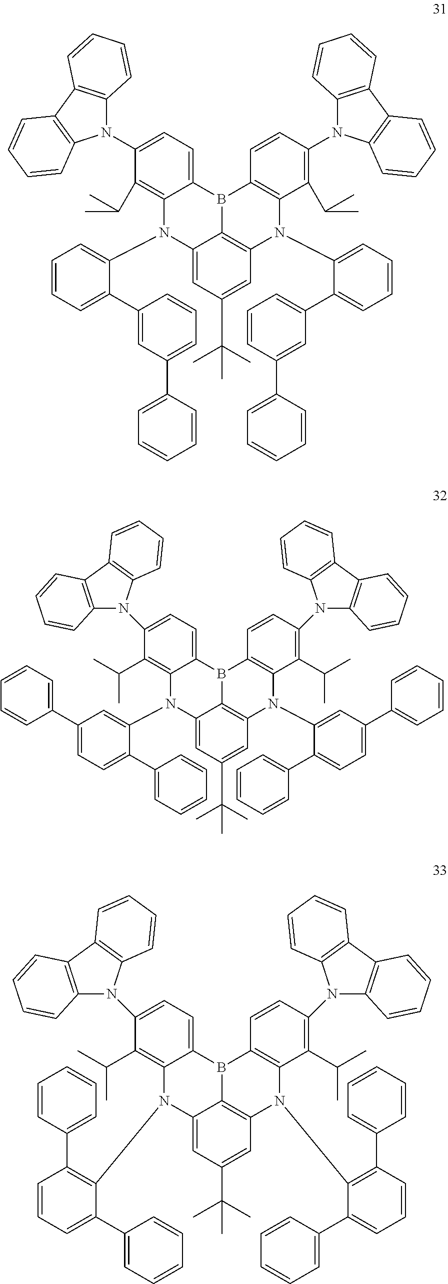 [SMILES: CC(C)c1c(-n2c3ccccc3c3ccccc32)ccc2c1N(c1ccccc1-c1cccc(-c3ccccc3)c1)c1cc(C(C)(C)C)cc3c1B2c1ccc(-n2c4ccccc4c4ccccc42)c(C(C)C)c1N3c1ccccc1-c1cccc(-c2ccccc2)c1 ; CC(C)c1c(-n2c3ccccc3c3ccccc32)ccc2c1N(c1cc(-c3ccccc3)ccc1-c1ccccc1)c1cc(C(C)(C)C)cc3c1B2c1ccc(-n2c4ccccc4c4ccccc42)c(C(C)C)c1N3c1cc(-c2ccccc2)ccc1-c1ccccc1 ; CC(C)c1c(-n2c3ccccc3c3ccccc32)ccc2c1N(c1c(-c3ccccc3)cccc1-c1ccccc1)c1cc(C(C)(C)C)cc3c1B2c1ccc(-n2c4ccccc4c4ccccc42)c(C(C)C)c1N3c1c(-c2ccccc2)cccc1-c1ccccc1]

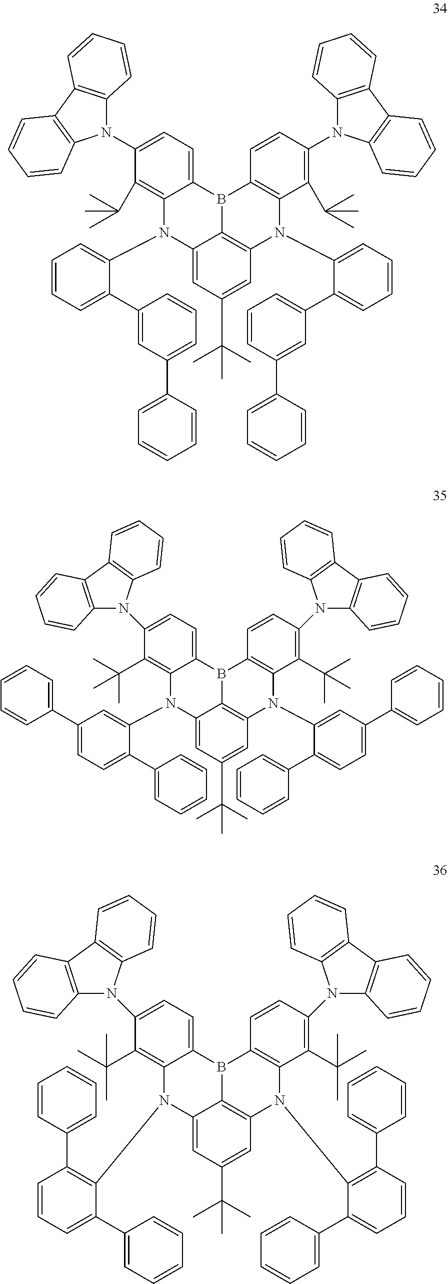 [SMILES: CC(C)(C)c1cc2c3c(c1)N(c1ccccc1-c1cccc(-c4ccccc4)c1)c1c(ccc(-n4c5ccccc5c5ccccc54)c1C(C)(C)C)B3c1ccc(-n3c4ccccc4c4ccccc43)c(C(C)(C)C)c1N2c1ccccc1-c1cccc(-c2ccccc2)c1 ; CC(C)(C)c1cc2c3c(c1)N(c1cc(-c4ccccc4)ccc1-c1ccccc1)c1c(ccc(-n4c5ccccc5c5ccccc54)c1C(C)(C)C)B3c1ccc(-n3c4ccccc4c4ccccc43)c(C(C)(C)C)c1N2c1cc(-c2ccccc2)ccc1-c1ccccc1 ; CC(C)(C)c1cc2c3c(c1)N(c1c(-c4ccccc4)cccc1-c1ccccc1)c1c(ccc(-n4c5ccccc5c5ccccc54)c1C(C)(C)C)B3c1ccc(-n3c4ccccc4c4ccccc43)c(C(C)(C)C)c1N2c1c(-c2ccccc2)cccc1-c1ccccc1]

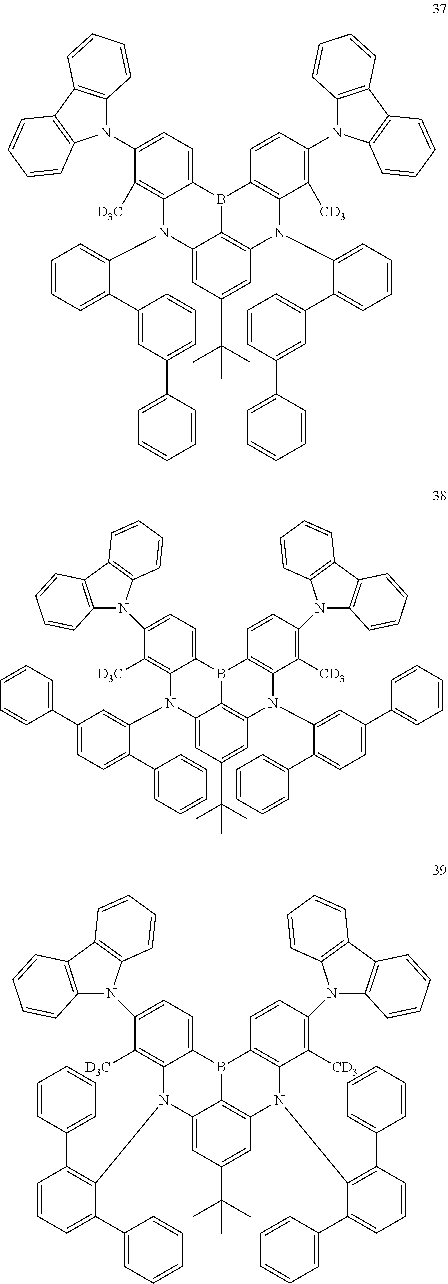

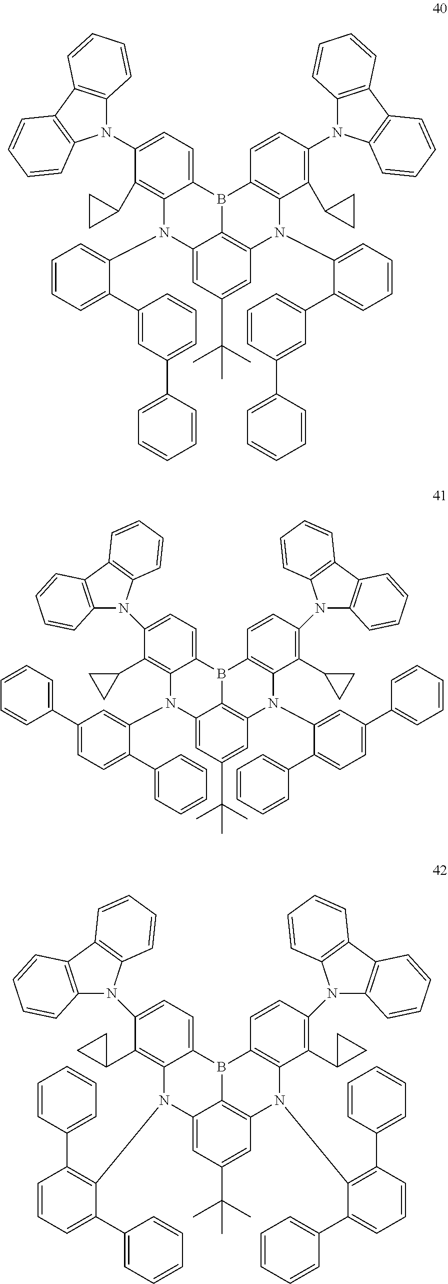 [SMILES: CC(C)(C)c1cc2c3c(c1)N(c1ccccc1-c1cccc(-c4ccccc4)c1)c1c(ccc(-n4c5ccccc5c5ccccc54)c1C1CC1)B3c1ccc(-n3c4ccccc4c4ccccc43)c(C3CC3)c1N2c1ccccc1-c1cccc(-c2ccccc2)c1 ; CC(C)(C)c1cc2c3c(c1)N(c1cc(-c4ccccc4)ccc1-c1ccccc1)c1c(ccc(-n4c5ccccc5c5ccccc54)c1C1CC1)B3c1ccc(-n3c4ccccc4c4ccccc43)c(C3CC3)c1N2c1cc(-c2ccccc2)ccc1-c1ccccc1 ; CC(C)(C)c1cc2c3c(c1)N(c1c(-c4ccccc4)cccc1-c1ccccc1)c1c(ccc(-n4c5ccccc5c5ccccc54)c1C1CC1)B3c1ccc(-n3c4ccccc4c4ccccc43)c(C3CC3)c1N2c1c(-c2ccccc2)cccc1-c1ccccc1]

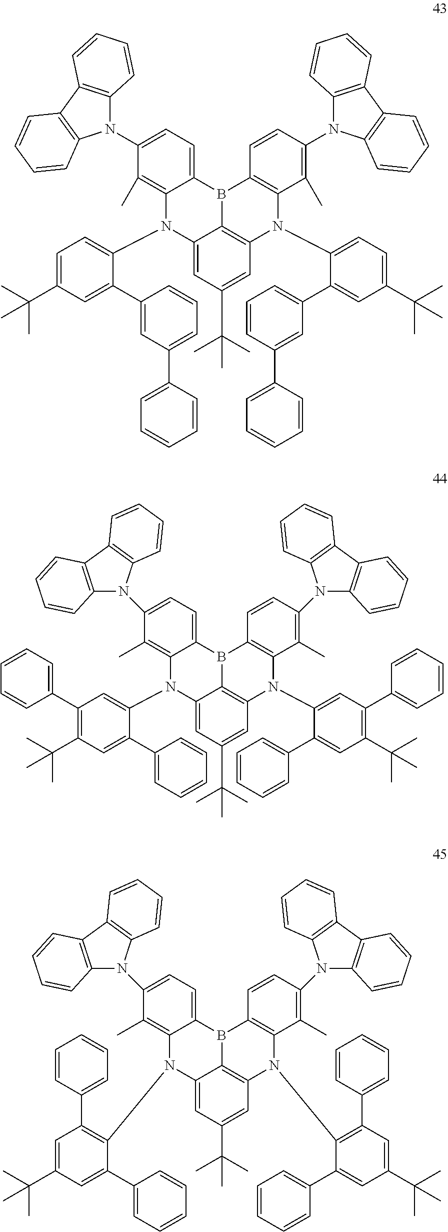

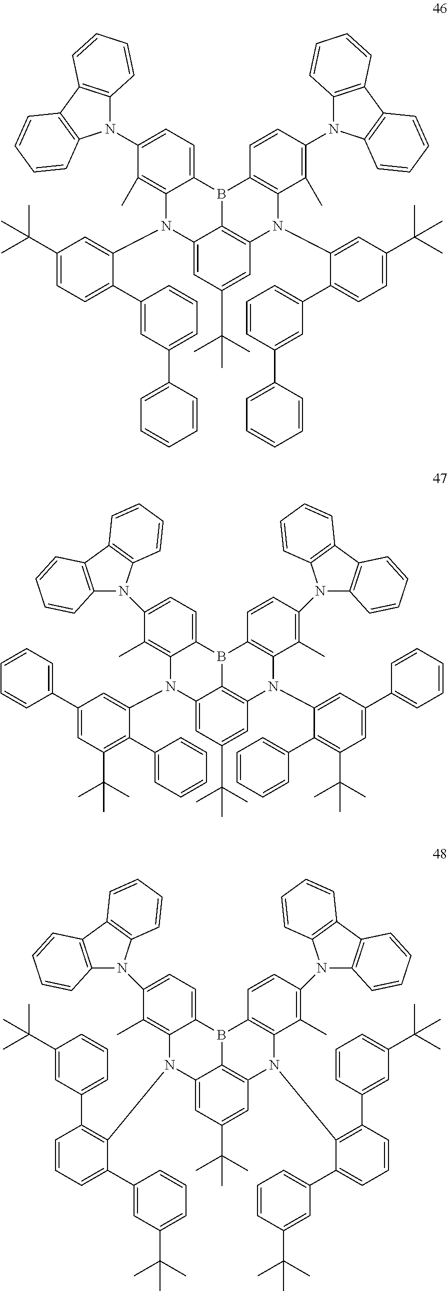

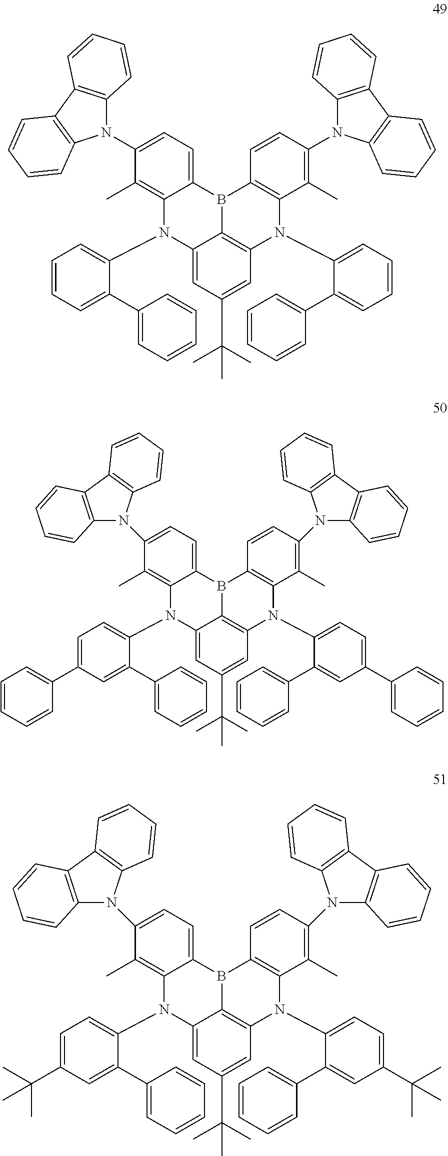 [SMILES: Cc1c(-n2c3ccccc3c3ccccc32)ccc2c1N(c1ccccc1-c1ccccc1)c1cc(C(C)(C)C)cc3c1B2c1ccc(-n2c4ccccc4c4ccccc42)c(C)c1N3c1ccccc1-c1ccccc1 ; Cc1c(-n2c3ccccc3c3ccccc32)ccc2c1N(c1ccc(-c3ccccc3)cc1-c1ccccc1)c1cc(C(C)(C)C)cc3c1B2c1ccc(-n2c4ccccc4c4ccccc42)c(C)c1N3c1ccc(-c2ccccc2)cc1-c1ccccc1 ; Cc1c(-n2c3ccccc3c3ccccc32)ccc2c1N(c1ccc(C(C)(C)C)cc1-c1ccccc1)c1cc(C(C)(C)C)cc3c1B2c1ccc(-n2c4ccccc4c4ccccc42)c(C)c1N3c1ccc(C(C)(C)C)cc1-c1ccccc1]

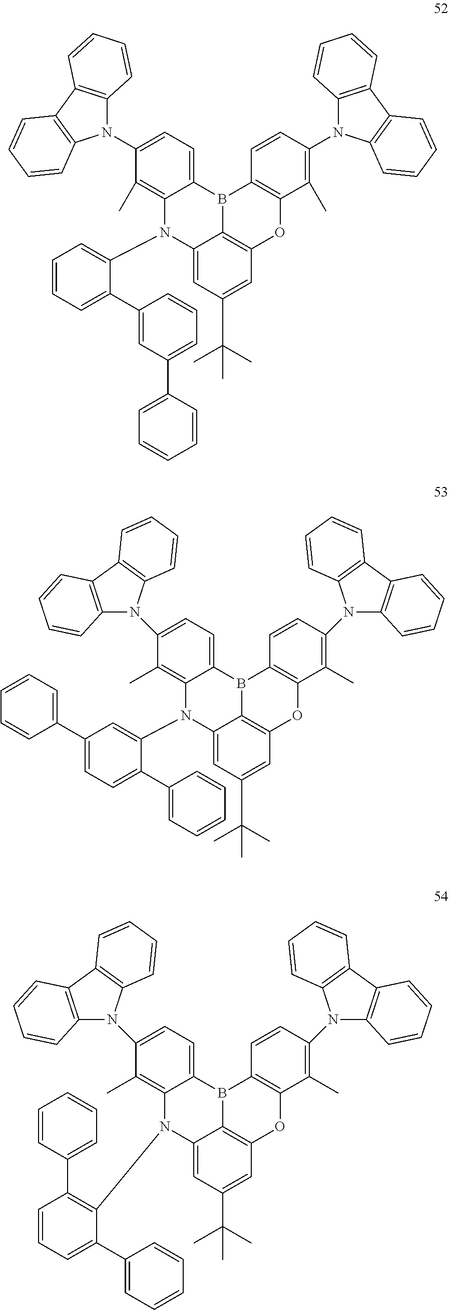 [SMILES: Cc1c(-n2c3ccccc3c3ccccc32)ccc2c1Oc1cc(C(C)(C)C)cc3c1B2c1ccc(-n2c4ccccc4c4ccccc42)c(C)c1N3c1ccccc1-c1cccc(-c2ccccc2)c1 ; Cc1c(-n2c3ccccc3c3ccccc32)ccc2c1Oc1cc(C(C)(C)C)cc3c1B2c1ccc(-n2c4ccccc4c4ccccc42)c(C)c1N3c1cc(-c2ccccc2)ccc1-c1ccccc1 ; Cc1c(-n2c3ccccc3c3ccccc32)ccc2c1Oc1cc(C(C)(C)C)cc3c1B2c1ccc(-n2c4ccccc4c4ccccc42)c(C)c1N3c1c(-c2ccccc2)cccc1-c1ccccc1]

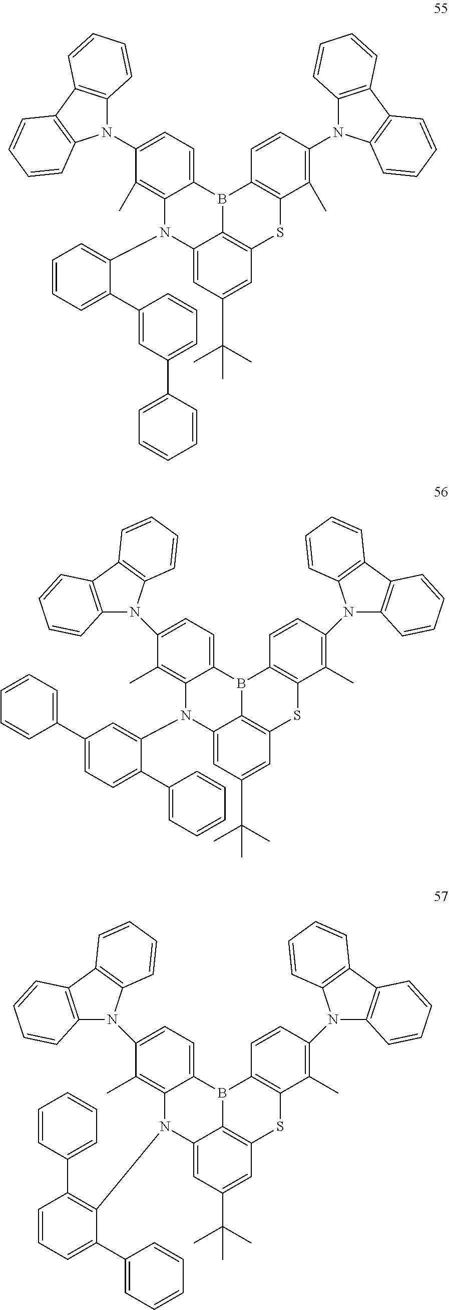 [SMILES: Cc1c(-n2c3ccccc3c3ccccc32)ccc2c1Sc1cc(C(C)(C)C)cc3c1B2c1ccc(-n2c4ccccc4c4ccccc42)c(C)c1N3c1ccccc1-c1cccc(-c2ccccc2)c1 ; Cc1c(-n2c3ccccc3c3ccccc32)ccc2c1Sc1cc(C(C)(C)C)cc3c1B2c1ccc(-n2c4ccccc4c4ccccc42)c(C)c1N3c1cc(-c2ccccc2)ccc1-c1ccccc1 ; Cc1c(-n2c3ccccc3c3ccccc32)ccc2c1Sc1cc(C(C)(C)C)cc3c1B2c1ccc(-n2c4ccccc4c4ccccc42)c(C)c1N3c1c(-c2ccccc2)cccc1-c1ccccc1]

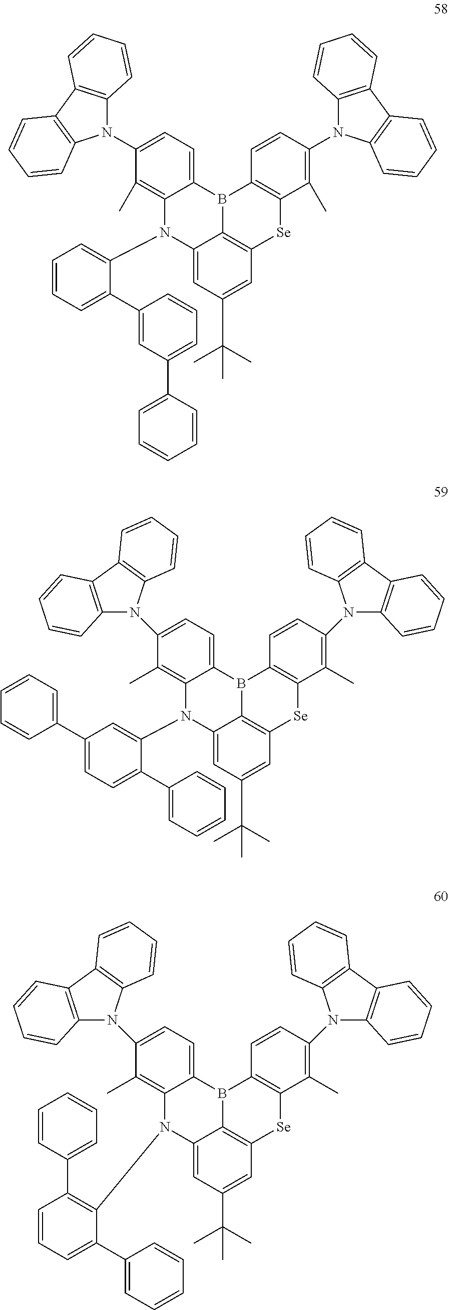 [SMILES: Cc1c(-n2c3ccccc3c3ccccc32)ccc2c1[Se]c1cc(C(C)(C)C)cc3c1B2c1ccc(-n2c4ccccc4c4ccccc42)c(C)c1N3c1ccccc1-c1cccc(-c2ccccc2)c1 ; Cc1c(-n2c3ccccc3c3ccccc32)ccc2c1[Se]c1cc(C(C)(C)C)cc3c1B2c1ccc(-n2c4ccccc4c4ccccc42)c(C)c1N3c1cc(-c2ccccc2)ccc1-c1ccccc1 ; Cc1c(-n2c3ccccc3c3ccccc32)ccc2c1[Se]c1cc(C(C)(C)C)cc3c1B2c1ccc(-n2c4ccccc4c4ccccc42)c(C)c1N3c1c(-c2ccccc2)cccc1-c1ccccc1]

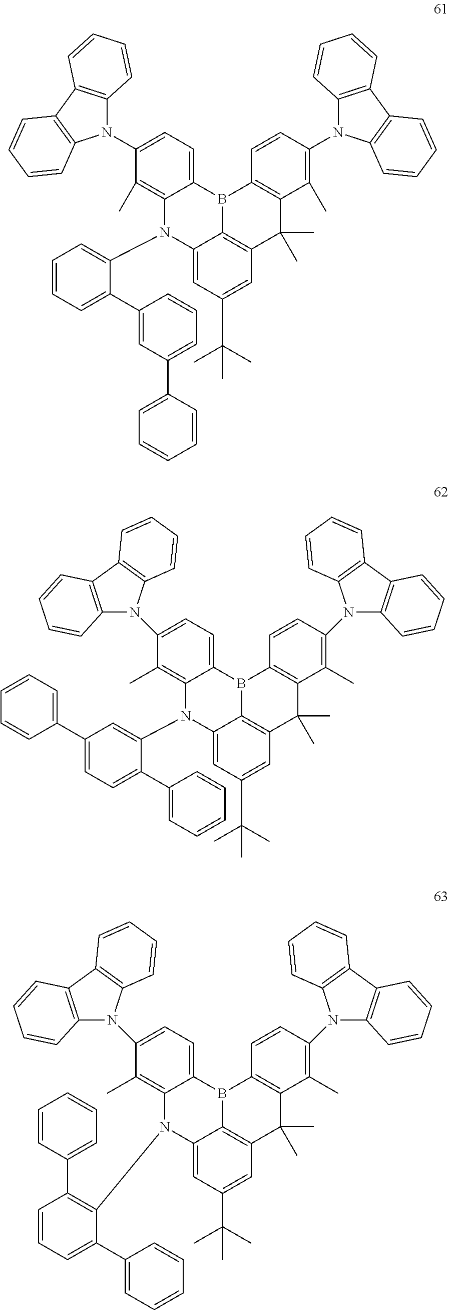 [SMILES: Cc1c(-n2c3ccccc3c3ccccc32)ccc2c1N(c1ccccc1-c1cccc(-c3ccccc3)c1)c1cc(C(C)(C)C)cc3c1B2c1ccc(-n2c4ccccc4c4ccccc42)c(C)c1C3(C)C ; Cc1c(-n2c3ccccc3c3ccccc32)ccc2c1N(c1cc(-c3ccccc3)ccc1-c1ccccc1)c1cc(C(C)(C)C)cc3c1B2c1ccc(-n2c4ccccc4c4ccccc42)c(C)c1C3(C)C ; Cc1c(-n2c3ccccc3c3ccccc32)ccc2c1N(c1c(-c3ccccc3)cccc1-c1ccccc1)c1cc(C(C)(C)C)cc3c1B2c1ccc(-n2c4ccccc4c4ccccc42)c(C)c1C3(C)C]

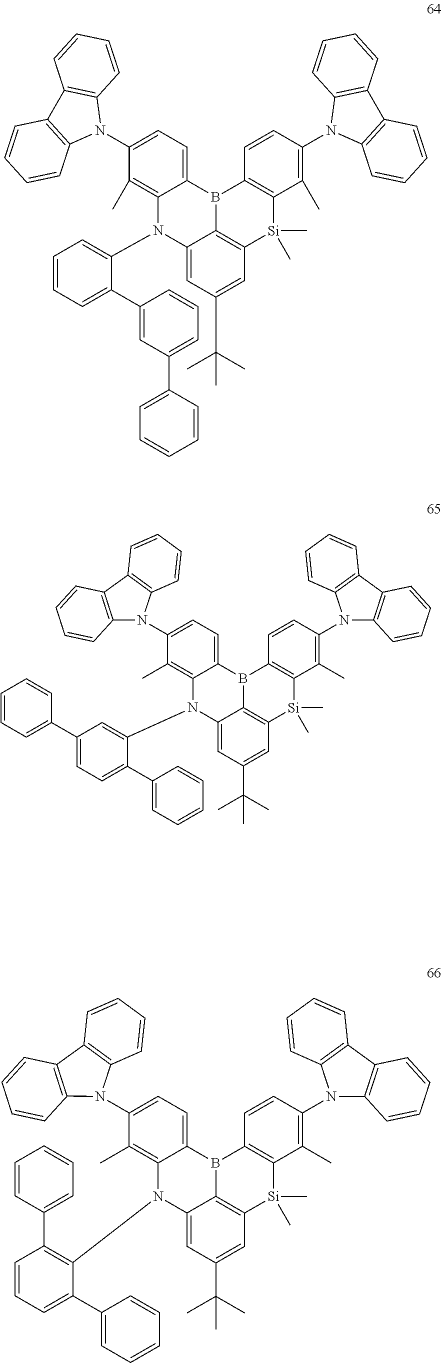 [SMILES: Cc1c(-n2c3ccccc3c3ccccc32)ccc2c1N(c1ccccc1-c1cccc(-c3ccccc3)c1)c1cc(C(C)(C)C)cc3c1B2c1ccc(-n2c4ccccc4c4ccccc42)c(C)c1[Si]3(C)C ; Cc1c(-n2c3ccccc3c3ccccc32)ccc2c1N(c1cc(-c3ccccc3)ccc1-c1ccccc1)c1cc(C(C)(C)C)cc3c1B2c1ccc(-n2c4ccccc4c4ccccc42)c(C)c1[Si]3(C)C ; Cc1c(-n2c3ccccc3c3ccccc32)ccc2c1N(c1c(-c3ccccc3)cccc1-c1ccccc1)c1cc(C(C)(C)C)cc3c1B2c1ccc(-n2c4ccccc4c4ccccc42)c(C)c1[Si]3(C)C]

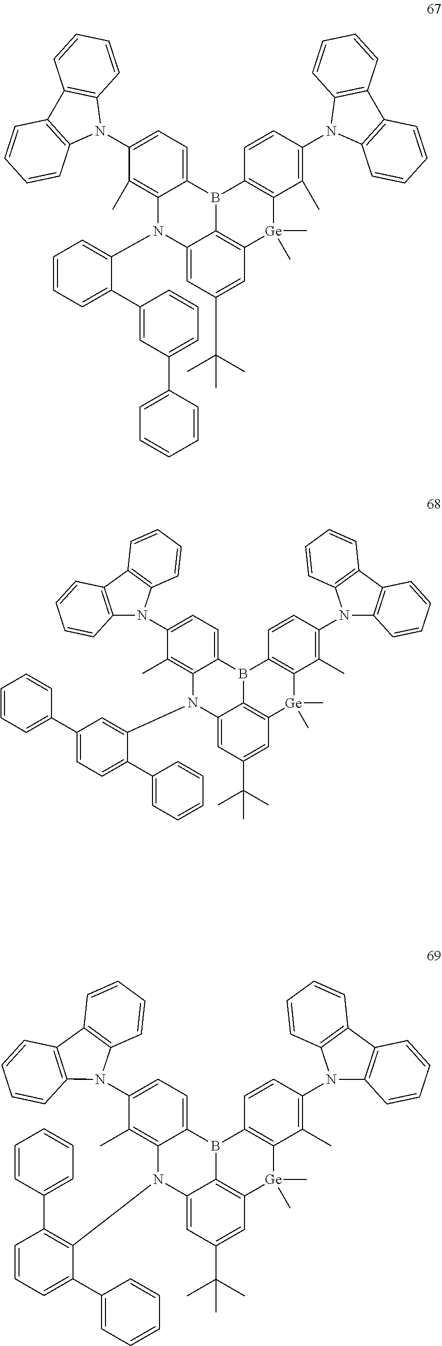

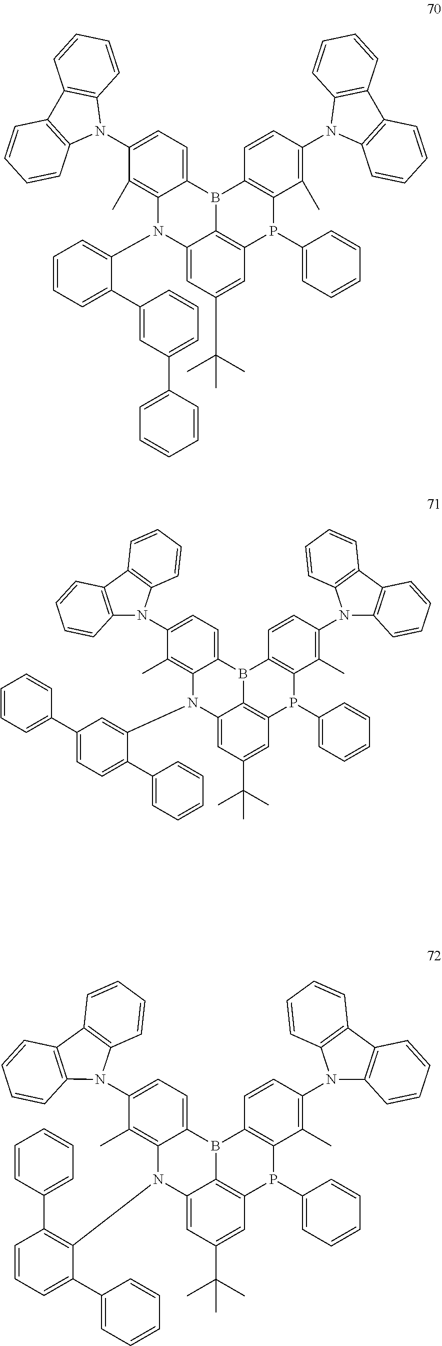 [SMILES: Cc1c(-n2c3ccccc3c3ccccc32)ccc2c1N(c1ccccc1-c1cccc(-c3ccccc3)c1)c1cc(C(C)(C)C)cc3c1B2c1ccc(-n2c4ccccc4c4ccccc42)c(C)c1P3c1ccccc1 ; Cc1c(-n2c3ccccc3c3ccccc32)ccc2c1N(c1cc(-c3ccccc3)ccc1-c1ccccc1)c1cc(C(C)(C)C)cc3c1B2c1ccc(-n2c4ccccc4c4ccccc42)c(C)c1P3c1ccccc1 ; Cc1c(-n2c3ccccc3c3ccccc32)ccc2c1N(c1c(-c3ccccc3)cccc1-c1ccccc1)c1cc(C(C)(C)C)cc3c1B2c1ccc(-n2c4ccccc4c4ccccc42)c(C)c1P3c1ccccc1]

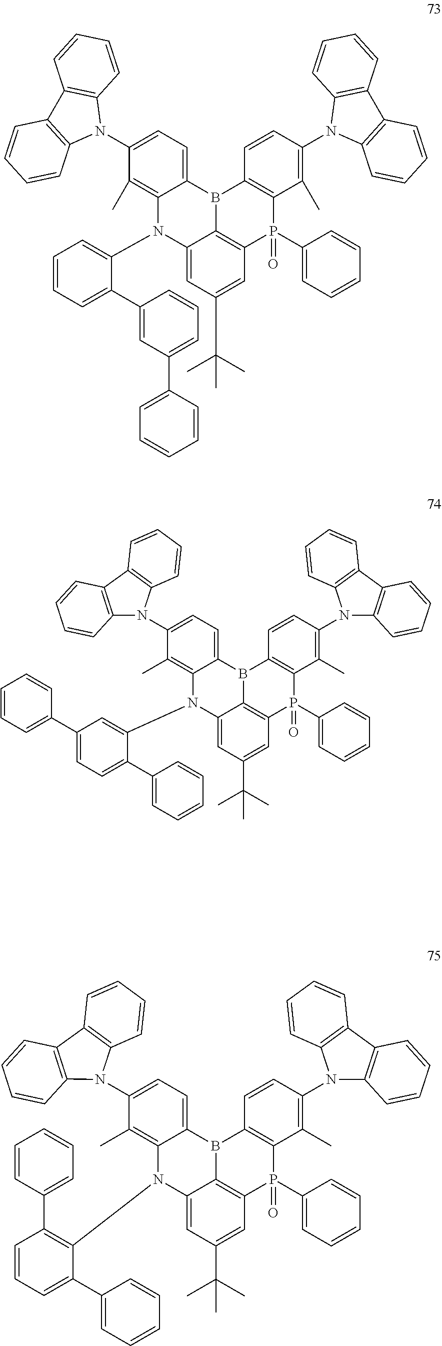 [SMILES: Cc1c(-n2c3ccccc3c3ccccc32)ccc2c1N(c1ccccc1-c1cccc(-c3ccccc3)c1)c1cc(C(C)(C)C)cc3c1B2c1ccc(-n2c4ccccc4c4ccccc42)c(C)c1P3(=O)c1ccccc1 ; Cc1c(-n2c3ccccc3c3ccccc32)ccc2c1N(c1cc(-c3ccccc3)ccc1-c1ccccc1)c1cc(C(C)(C)C)cc3c1B2c1ccc(-n2c4ccccc4c4ccccc42)c(C)c1P3(=O)c1ccccc1 ; Cc1c(-n2c3ccccc3c3ccccc32)ccc2c1N(c1c(-c3ccccc3)cccc1-c1ccccc1)c1cc(C(C)(C)C)cc3c1B2c1ccc(-n2c4ccccc4c4ccccc42)c(C)c1P3(=O)c1ccccc1]

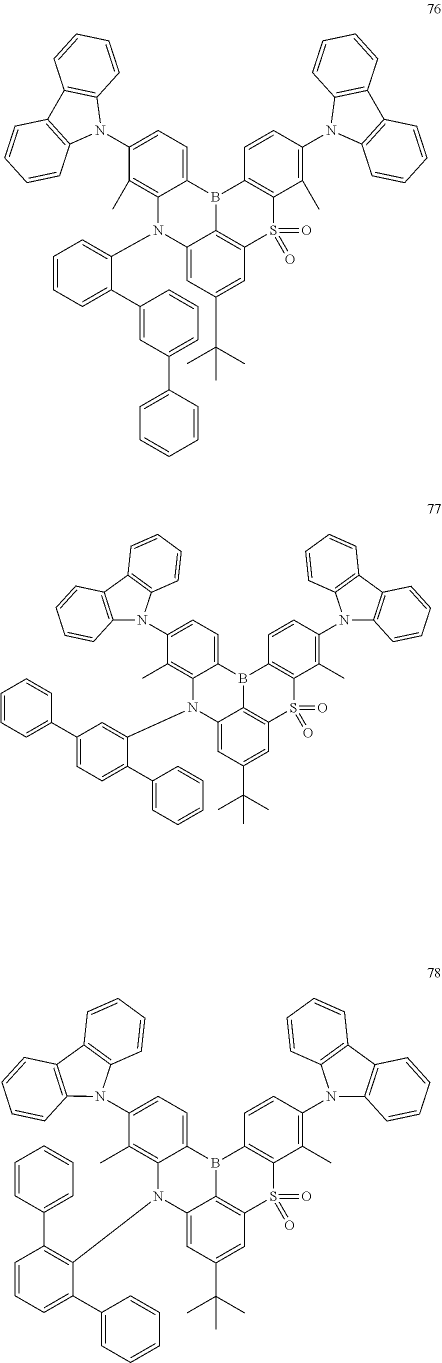 [SMILES: Cc1c(-n2c3ccccc3c3ccccc32)ccc2c1N(c1ccccc1-c1cccc(-c3ccccc3)c1)c1cc(C(C)(C)C)cc3c1B2c1ccc(-n2c4ccccc4c4ccccc42)c(C)c1S3(=O)=O ; Cc1c(-n2c3ccccc3c3ccccc32)ccc2c1N(c1cc(-c3ccccc3)ccc1-c1ccccc1)c1cc(C(C)(C)C)cc3c1B2c1ccc(-n2c4ccccc4c4ccccc42)c(C)c1S3(=O)=O ; Cc1c(-n2c3ccccc3c3ccccc32)ccc2c1N(c1c(-c3ccccc3)cccc1-c1ccccc1)c1cc(C(C)(C)C)cc3c1B2c1ccc(-n2c4ccccc4c4ccccc42)c(C)c1S3(=O)=O]

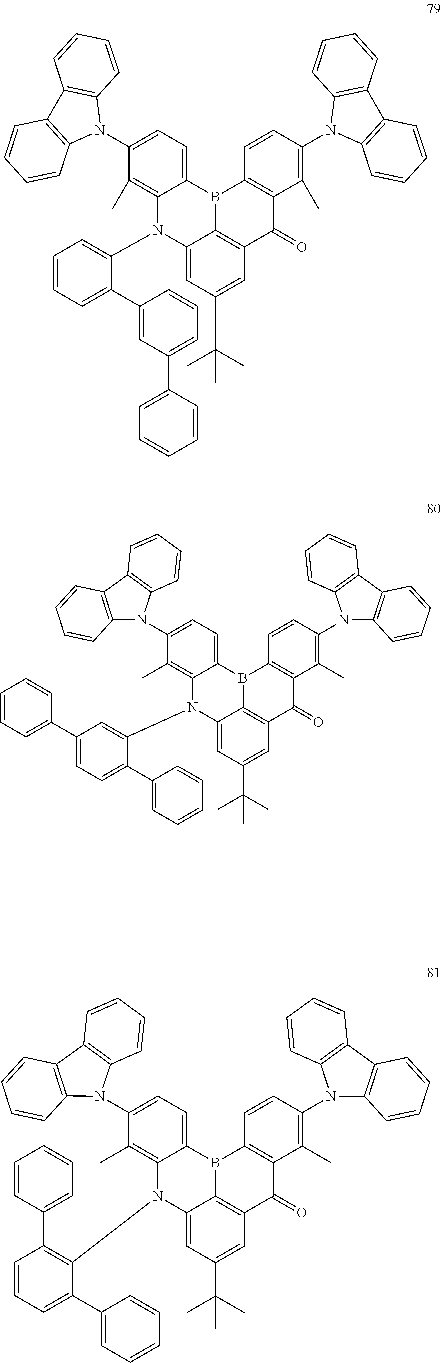 [SMILES: Cc1c(-n2c3ccccc3c3ccccc32)ccc2c1C(=O)c1cc(C(C)(C)C)cc3c1B2c1ccc(-n2c4ccccc4c4ccccc42)c(C)c1N3c1ccccc1-c1cccc(-c2ccccc2)c1 ; Cc1c(-n2c3ccccc3c3ccccc32)ccc2c1C(=O)c1cc(C(C)(C)C)cc3c1B2c1ccc(-n2c4ccccc4c4ccccc42)c(C)c1N3c1cc(-c2ccccc2)ccc1-c1ccccc1 ; Cc1c(-n2c3ccccc3c3ccccc32)ccc2c1C(=O)c1cc(C(C)(C)C)cc3c1B2c1ccc(-n2c4ccccc4c4ccccc42)c(C)c1N3c1c(-c2ccccc2)cccc1-c1ccccc1]

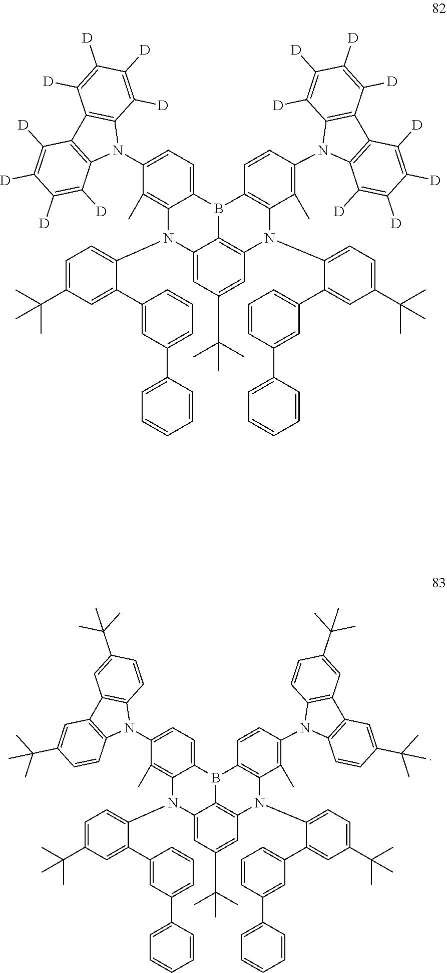 [SMILES: [2H]c1c([2H])c([2H])c2c(c1[2H])c1c([2H])c([2H])c([2H])c([2H])c1n2-c1ccc2c(c1C)N(c1ccc(C(C)(C)C)cc1-c1cccc(-c3ccccc3)c1)c1cc(C(C)(C)C)cc3c1B2c1ccc(-n2c4c([2H])c([2H])c([2H])c([2H])c4c4c([2H])c([2H])c([2H])c([2H])c42)c(C)c1N3c1ccc(C(C)(C)C)cc1-c1cccc(-c2ccccc2)c1 ; Cc1c(-n2c3ccc(C(C)(C)C)cc3c3cc(C(C)(C)C)ccc32)ccc2c1N(c1ccc(C(C)(C)C)cc1-c1cccc(-c3ccccc3)c1)c1cc(C(C)(C)C)cc3c1B2c1ccc(-n2c4ccc(C(C)(C)C)cc4c4cc(C(C)(C)C)ccc42)c(C)c1N3c1ccc(C(C)(C)C)cc1-c1cccc(-c2ccccc2)c1]

13. An organic light-emitting device comprising:
a first electrode;
a second electrode; and
an organic layer arranged between the first electrode and the second electrode,
wherein the organic layer comprises an emission layer, and
wherein the organic layer further comprises at least one heterocyclic compound of claim 1.

14. The organic light-emitting device of claim 13, wherein the emission layer comprises the at least one heterocyclic compound.

15. The organic light-emitting device of claim 14, wherein
the emission layer comprises a host and an emitter, and
the emitter comprises the at least one heterocyclic compound.

16. The organic light-emitting device of claim 15, wherein an amount of the host in the emission layer is greater than an amount of the heterocyclic compound in the emission layer, based on weight.

17. The organic light-emitting device of claim 15, wherein the emission layer further comprises a sensitizer.

18. The organic light-emitting device of claim 17, wherein the sensitizer comprises a phosphorescent dopant.

19. The organic light-emitting device of claim 14, wherein the emission layer emits light having a maximum emission wavelength of about 400 nanometers to about 490 nanometers.

20. An electronic apparatus, comprising the organic light-emitting device of claim 13.
